(19) United States
(12) Patent Application Publication
(10) Pub. No.: US 2025/0201769 A1
(43) Pub. Date: Jun. 19, 2025

(54) COMPUTING SYSTEM ARCHITECTURE HAVING EFFICIENT BUS CONNECTIONS

(71) Applicant: SK hynix Inc., Icheon-si (KR)

(72) Inventor: Seong Ju LEE, San Jose, CA (US)

(21) Appl. No.: 19/070,088

(22) Filed: Mar. 4, 2025

Related U.S. Application Data
(63) Continuation-in-part of application No. 18/955,468, filed on Nov. 21, 2024.
(60) Provisional application No. 63/604,718, filed on Nov. 30, 2023.
(60) Provisional application No. 63/566,570, filed on Mar. 18, 2024.

(30) Foreign Application Priority Data
Jul. 4, 2024 (KR) 10-2024-0088306

(51) Int. Cl. H01L 25/065; G11C 11/4076; G11C 11/408; G11C 11/4093; H01L 23/50; H01L 25/18; H10B 80/00; H10D 89/10

(52) U.S. Cl. CPC H01L 25/0652; G11C 11/4076; G11C 11/4082; G11C 11/4093; H01L 23/50; H01L 25/18; H10B 80/00; H10D 89/10

(57) ABSTRACT

A computing system includes a substrate, a memory apparatus, and a host die. The memory apparatus is disposed on the substrate, and the host die is disposed on the memory apparatus. The host die is coupled to the substrate through a through via formed in a memory die included in the memory apparatus.

### CROSS-REFERENCES TO RELATED APPLICATION

The present application is a continuation-in-part application of U.S. patent application Ser. No. 18/955,468, filed on Nov. 21, 2024, which claims benefit of priority of U.S. provisional application No. 63/604,718, filed on Nov. 30, 2023, U.S. provisional application No. 63/566,570, filed on Mar. 18, 2024, and Korean application number 10-2024-0088306, filed on Jul. 4, 2024. The contents of the applications are incorporated herein by reference in its entirety.

### BACKGROUND

### 1. Technical Field

Various embodiments generally relate to integrated circuit technology, and more particularly, to a computing system architecture having efficient bus connections.

### 2. Related Art

In general, a computing system may have a structure in which a host device and a memory apparatus are electrically connected. The host device may include a processing core and a memory controller. The memory apparatus may include memory cell arrays. The host device may be electrically connected to the memory apparatus through a memory channel, in which the memory channel utilizes serial data transmission. The serial data transmission may minimize the number of data signal transmission lines included in the memory channel, and may reduce skew between data signals and clock signals. However, for serial data transmission, the host device may need a controller physical interface (e.g., a double data rate (DDR) PHY), and the memory apparatus may need a memory physical interface. For example, the controller physical interface and the memory physical interface both may include a Serializer-Deserializer (SerDes).

The controller physical interface may convert parallel data generated by the processor core and the memory controller to serial data, and may transmit the serial data to the memory apparatus through the memory channel. Further, the controller physical interface may convert serial data transmitted from the memory apparatus to parallel data, and provide the parallel data to the memory controller and the host device. The memory physical interface may convert parallel data output from the memory cell array to serial data and transmit the serial data to the host device through the memory channel. The memory physical interface may convert serial data transmitted from the host device through the memory channel to parallel data, and may provide the parallel data to the memory cell array. The above structure of a traditional computing system may have been the best signal transmission structure in an environment where the host device and the memory apparatus are each manufactured in a single chip or a single package. However, in an environment where advanced packaging technologies increase the number of signal transmission lines electrically connecting the host device and the memory apparatus, and where the host device and the memory apparatus are manufactured as chiplets, there is a need for computing system architectures that can more efficiently connect the host device and the memory apparatus.

### SUMMARY

In an embodiment, a computing system may include a substrate, a memory apparatus, and a host die. The memory apparatus may be disposed on the substrate and may include at least one memory die, and the at least one memory die may include a plurality of through vias. The host die may be disposed on the memory apparatus and may be coupled to the substrate through at least one of the plurality of through vias.

In an embodiment, a computing system may include a substrate, a host die, and first and second memory dies. The first and second memory dies may be disposed sequentially between the substrate and the host die. Each of the first and second memory dies may include a first through via formed at a first position, a second through via formed at a second position, and a third through via formed at a third position. The host die may be coupled to the substrate through at least one of the first to third through vias of the first memory die and at least one of the first to third through vias of the second memory die.

In an embodiment, a computing system may include a substrate, a host die, and a first memory die, and a second memory die. The second memory die may be disposed on the substrate, the first memory die may be disposed on the second memory die, and the host die may be disposed on the first memory die. The first memory die may be accessed by a first slice ID signal, may form a first channel, and may include first to third through vias formed at first to third positions, respectively. The second memory die may be accessed by the first slice ID signal, may form a second channel, and may include first to third through vias formed at the first to third positions, respectively. The host die may be coupled to the substrate through one of the first to third through vias of the first memory die and one of the first to third through vias of the second memory die.

In an embodiment, a computing system may include a memory die and a host die. The memory die may include first to fourth through vias. The host die may be disposed on the memory die. The host die may be configured to set a path, through which a first memory signal is transmitted, as the first through via. The host die may be configured to set a path, through which a first host signal is transmitted, as the second through via. The host die may be configured to set a path, through which one of a second memory signal and a third host signal is transmitted, as the third through via based on a plurality of channel mode signals. The host die may be configured to set a path, through which one of a third memory signal and a second host signal is transmitted, as the fourth through via based on a plurality of channel mode signals.

### BRIEF DESCRIPTION OF THE DRAWINGS

FIG. 1 is a diagram illustrating a configuration of a computing system according to an embodiment of the present disclosure.

FIG. 2 is a diagram illustrating connection relationships among a memory controller, an interface circuit, and a memory apparatus shown in FIG. 1.

FIG. 3 is a block diagram illustrating a configuration of an address control circuit shown in FIG. 2.

FIG. 4 is a block diagram illustrating a configuration of a data input/output circuit shown in FIG. 2.

FIG. 5 is a block diagram illustrating a configuration of a clock control circuit shown in FIG. 2.

FIG. 6 is a diagram illustrating a configuration of a memory die according to an embodiment of the present disclosure.

FIG. 7 is a diagram illustrating a configuration of a computing system according to an embodiment of the present disclosure.

FIG. 8 is a diagram illustrating a configuration of a computing system according to an embodiment of the present disclosure.

FIG. 9A is a diagram illustrating a configuration and connection relationship of an integrated circuit package according to an embodiment of the present disclosure.

FIG. 9B is a diagram illustrating a configuration and connection relationship of an integrated circuit package according to an embodiment of the present disclosure.

FIG. 9C is a diagram illustrating a configuration and connection relationship of an integrated circuit package according to an embodiment of the present disclosure.

FIG. 9D is a diagram illustrating a configuration and connection relationship of an integrated circuit package according to an embodiment of the present disclosure.

FIG. 9E is a diagram illustrating a configuration and connection relationship of an integrated circuit package according to an embodiment of the present disclosure.

FIG. 10A is a diagram illustrating a configuration and connection relationship of an integrated circuit package according to an embodiment of the present disclosure.

FIG. 10B is a diagram illustrating a configuration and connection relationship of an integrated circuit package according to an embodiment of the present disclosure.

FIG. 10C is a diagram illustrating a configuration and connection relationship of an integrated circuit package according to an embodiment of the present disclosure.

FIG. 10D is a diagram illustrating a configuration and connection relationship of an integrated circuit package according to an embodiment of the present disclosure.

FIG. 10E is a diagram illustrating a configuration and connection relationship of an integrated circuit package according to an embodiment of the present disclosure.

FIG. 10F is a diagram illustrating a configuration and connection relationship of an integrated circuit package according to an embodiment of the present disclosure.

FIG. 10G is a diagram illustrating a configuration and connection relationship of an integrated circuit package according to an embodiment of the present disclosure.

FIG. 10H is a diagram illustrating a configuration and connection relationship of an integrated circuit package according to an embodiment of the present disclosure.

FIG. 10I is a diagram illustrating a configuration and connection relationship of an integrated circuit package according to an embodiment of the present disclosure.

FIG. 10J is a diagram illustrating a configuration and connection relationship of an integrated circuit package according to an embodiment of the present disclosure.

FIG. 10K is a diagram illustrating a configuration and connection relationship of an integrated circuit package according to an embodiment of the present disclosure.

FIG. 10L is a diagram illustrating a configuration and connection relationship of an integrated circuit package according to an embodiment of the present disclosure.

FIG. 10M is a diagram illustrating a configuration and connection relationship of an integrated circuit package according to an embodiment of the present disclosure.

FIG. 10N is a diagram illustrating a configuration and connection relationship of an integrated circuit package according to an embodiment of the present disclosure.

FIG. 11 is a diagram illustrating a configuration of a computing system according to an embodiment of the present disclosure.

FIG. 12 is a diagram illustrating a configuration of a computing system according to an embodiment of the present disclosure.

FIGS. 13A to 13C are diagrams illustrating a configuration of a semiconductor apparatus according to an embodiment of the present disclosure.

FIGS. 14A to 14C are diagrams illustrating a configuration of a semiconductor apparatus according to an embodiment of the present disclosure.

FIGS. 15A to 15C are diagrams illustrating a configuration of a semiconductor apparatus according to an embodiment of the present disclosure.

FIGS. 16A to 16C are diagrams illustrating a configuration of a semiconductor apparatus according to an embodiment of the present disclosure.

FIGS. 17A to 17C are diagrams illustrating a configuration of a semiconductor apparatus according to an embodiment of the present disclosure.

FIG. 18 is a diagram illustrating a configuration of a semiconductor apparatus according to an embodiment of the present disclosure.

FIG. 19 is a diagram illustrating a configuration of a semiconductor apparatus according to an embodiment of the present disclosure.

FIG. 20 is a diagram illustrating a configuration of a computing system according to an embodiment of the present disclosure.

FIGS. 21A, 21B, and 21C are diagrams schematically illustrating structures of memory dies in a plan view according to embodiments of the present disclosure.

FIG. 22A is a diagram illustrating a connection structure of a computing system according to an embodiment of the present disclosure.

FIG. 22B is a diagram illustrating a connection structure of a computing system according to an embodiment of the present disclosure.

FIG. 22C is a diagram illustrating a connection structure of a computing system according to an embodiment of the present disclosure.

FIG. 23A is diagram illustrating a connection structure of a computing system according to an embodiment of the present disclosure.

FIG. 23B is a diagram illustrating a connection structure of a computing system according to an embodiment of the present disclosure.

FIG. 23C is a diagram illustrating a connection structure of a computing system according to an embodiment of the present disclosure.

FIG. 24 is a diagram illustrating a configuration of a computing system according to an embodiment of the present disclosure.

FIG. 25 is a diagram illustrating a schematic configuration of a path control circuit shown in FIG. 24.

### DETAILED DESCRIPTION

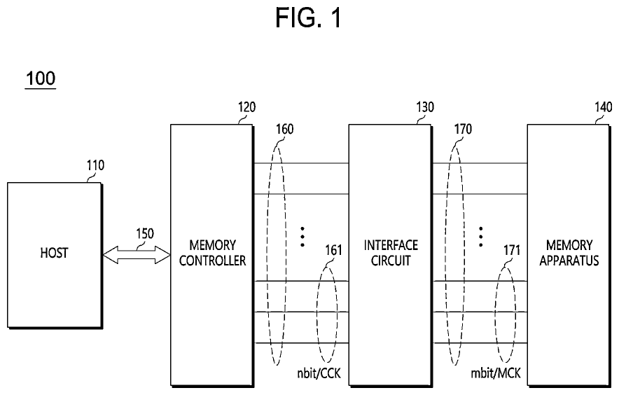

FIG. 1 is a diagram illustrating a configuration of a computing system according to an embodiment of the present disclosure. Referring to FIG. 1, the computing system 100 may include a host 110, a memory controller 120, an interface circuit 130, and a memory apparatus 140. The host 110 may generate an access request to the memory apparatus 140 in response to input from a user (e.g., execution of application program or software). The access request may include a write request and a read request. The host 110 may include any computing architecture most suitable for executing applications required by the user. For example, the host 110 may include at least one of a central processing unit (CPU), a graphic processing unit (GPU), a multi-media processor (MMP), a digital signal processor (DSP), an application processor (AP), a data processing unit (DPU), a neural processing unit (NPU), a system-on-chip (SoC), or any combination of two or more of the foregoing. The host 110 may be electrically connected to the memory controller 120 through a first bus 150. The first bus 150 may be any set of signal transmission lines for electrically connecting the host 110 and the memory controller 120. For example, the first bus 150 may include at least one of Advanced eXtensible Interface (AXI) and Universal Chiplet Interconnect express (UCIe), Advanced Microcontroller Bus Architecture (AMBA), Ultra Path Interconnect (UPI), Infinite Fabric, and NVLINK.

The memory controller 120 may be electrically connected to the host 110 through the first bus 150. The memory controller 120 may facilitate data transmission between the host 110 and the memory apparatus 140. The memory controller 120 may receive write requests and read requests from the host 110 through the first bus 150, and may generate various control signals for accessing the memory apparatus 140 based on the requests. For example, the various control signals may include an address signal, a command signal, a write data signal, a read data signal, a clock signal, and the like. The memory controller 120 may be electrically connected to the interface circuit 130 through a second bus 160. The second bus 160 may include a first data bus 161. The first data bus 161 may transmit a write data signal from the memory controller 120 to the interface circuit 130 and may transmit a read data signal from the interface circuit 130 to the memory controller 120. The memory controller 120 and the interface circuit 130 may perform parallel data communication through the first data bus 161. In an embodiment, the memory controller 120 and the interface circuit 130 may perform partial parallel data communication, which is a combination of serial data communication and parallel data communication, through the first data bus 161. The remainder of the second bus 160, i.e., excluding the first data bus 161, may transmit the address signal, the command signal, and the clock signal, and the like, from the memory controller 120 to the interface circuit 130.

The interface circuit 130 may be electrically connected between the memory controller 120 and the memory apparatus 140. The interface circuit 130 may relay data transmission between the memory controller 120 and the memory apparatus 140, and signal transmission to and from the memory controller 120 and the memory apparatus 140. The interface circuit 130 may convert various signals received from the memory controller 120 to generate signals suitable for use by the memory apparatus 140 (e.g., serialize or de-serialize). The interface circuit 130 may convert signals received from the memory apparatus 140 to generate signals suitable for use by the memory controller 120 (e.g., serialize or de-serialize). The interface circuit 130 may be electrically connected to the memory controller 120 through the second bus 160. The interface circuit 130 may receive the address signal, the command signal, the clock signal, and the write data signal from the memory controller 120 and may transmit the read data signal to the memory controller 120, through the second bus 160. The interface circuit 130 may receive the write data signal from the memory controller 120 through the first data bus 161, and may transmit the read data signal to the memory controller 120 through the first data bus 161. The interface circuit 130 may be electrically connected to the memory apparatus 140 through a third bus 170. Through the third bus 170, the interface circuit 130 may provide the address signal, the command signal, the clock signal and memory data signal received from the memory controller 120 to the memory apparatus 140 and may receive the memory data signal from the memory apparatus 140. The third bus 170 may include a second data bus 171. The second data bus 171 may transmit the memory data signal from the interface circuit 130 to the memory apparatus 140, and may transmit the memory data signal from the memory apparatus 140 to the interface circuit 130. The third bus 170, other than the second data bus 171, may transmit the address signal, the command signal, and the clock signal, and the like, from the interface circuit 130 to the memory apparatus 140. The interface circuit 130 may generate the memory data signal based on the write data signal received from the memory controller 120, and may generate the read data signal based on the memory data signal received from the memory apparatus 140. The interface circuit 130 and the memory apparatus 140 may perform parallel data communication through the second data bus 171. The interface circuit 130 and the memory apparatus 140 may perform full parallel data communication through the second data bus 171.

The memory apparatus 140 may be electrically connected to the interface circuit 130 through the third bus 170. The memory apparatus 140 may receive the address signal, the command signal, the clock signal, and the memory data signal from the interface circuit 130 and may transmit the memory data signal to the interface circuit 130, through the third bus 170. The memory apparatus 140 may transmit the memory data signal to the interface circuit 130 through the second data bus 171, and may receive the memory data signal transmitted from the interface circuit 130 through the second data bus 171. The memory apparatus 140 may include a memory cell array, and a particular region of the memory cell array may be accessed based on the address signal. The memory apparatus 140 may perform a write operation and a read operation based on the command signal. The write operation may be an operation to store the memory data signal transmitted from the interface circuit 130 in an accessed region of the memory cell array based on the address signal. The read operation may be an operation of providing data stored in an accessed region of the memory cell array based on the address signal to the interface circuit 130 as the memory data signal.

The memory apparatus 140 may include at least one memory die. The memory apparatus 140 may include one memory die, or may include two or more memory dies disposed on one interposer and/or substrate. When the memory apparatus includes two or more memory dies, the two or more memory dies may independently form a plurality of channels, and the plurality of channels are independently electrically connected to the interface circuit 130. There may be a plurality of third buses 170 corresponding to the number of the channels. In an embodiment, the two or more memory dies may form one common channel, and may be electrically connected in common with the interface circuit 130. In an embodiment, the memory apparatus 140 may include a plurality of memory groups including two or more memory dies, and the plurality of memory groups may form a plurality of channels. The memory dies included in the plurality of memory groups may form a common channel. A plurality of third buses 170 may be provided corresponding to the number of channels.

In a conventional computing system, a memory controller and a memory apparatus are electrically connected through a high-speed serial bus, and the memory controller and the memory apparatus perform high-speed serial data communication. The high-speed serial bus has the advantage of being implemented at relatively low cost and reducing the number of signal transmission lines required. However, the high-speed serial bus has limitations in expanding the data bandwidth, and the integrity of the signals transmitted through the high-speed serial bus may be reduced as the frequency of the computing system increases. Moreover, in order to perform the serial data communication over the high-speed serial bus, the memory controller and the memory apparatus must be equipped with a serializer-deserializer (SerDes). Furthermore, in order to transmit data signals based on symbols, such as PAM (Pulse Amplitude Modulation), the memory controller and the memory apparatus must be equipped with a special purpose data encoder and a data decoder in addition to the SerDes. As the trend towards miniaturization of integrated circuits continues, the additional circuits required for serial data communication may impose a heavy burden on the host devices and memory apparatuses including memory controllers.

The physical constraints in the number of signal transmission lines can be mitigated through the use of substrates and/or interposers with multiple signal transmission lines and the development of advanced packaging technologies. For example, in the computing system 100, the memory controller 120 may be electrically connected through the interface circuit 130 to the memory apparatus 140 through a parallel bus, and may perform parallel data communication with the memory apparatus 140. When performing parallel data communication between the memory controller 120 and the memory apparatus 140, data bandwidth can be dramatically increased, and the memory apparatus 140 can more quickly provide the necessary data for the host 110 to perform computational operations. As artificial intelligence (AI) technology advances, the amount of data that the host 110 needs to process at one time continues to increase, so increasing the data bandwidth between the memory controller 120 and the memory apparatus 140 may be a key factor in optimizing the performance of the host 110. Furthermore, when the memory controller 120 and the memory apparatus 140 perform parallel data communication through the interface circuit 130, the memory controller 120 and the memory apparatus 140 might not need additional circuits such as SerDes, data encoders, data decoders, and the like. Therefore, the number and/or size of the computational circuits can improve the computational performance of the host 110. Further, the area of the memory dies can be reduced, or the data storage capacity of the memory dies can be increased by forming a larger number of memory cells using the same area.

In the integrated circuit package 100, a clock rate of the second bus 160 may be greater than or equal to a clock rate of the third bus 170. The clock rate may be a clock speed. The clock rate of the buses may refer to a clock frequency of the buses and/or a clock cycle of the buses. The clock frequency of the bus and/or the clock cycle of the bus may define a duration of the signal transmitted through the bus. The higher the clock frequency of the bus and the shorter the clock cycle of the bus, the shorter the duration of the signal transmitted through the bus. The lower the clock frequency of the bus and the longer the clock cycle, the longer the duration of the signal transmitted through the bus. The second bus 160 may operate based on a system clock signal CCK, and the third bus 170 may operate based on a memory clock signal MCK. The computing system 100 may set the ratio of the clock rate of the second bus 160 to the clock rate of the third bus 170 in various ways to ensure operational efficiency of the integrated circuit package 100. For example, the ratio of the clock rate of the second bus 160 to the clock rate of the third bus 170 may be selected as one of 1:1, 2:1, or 4:1. In an embodiment, the system clock signal CCK may have the same frequency as the memory clock signal MCK. In an embodiment, the system clock signal CCK may have a frequency twice as high as the memory clock signal MCK. In an embodiment, the system clock signal CCK may have a frequency four times higher than the memory clock signal MCK.

In the integrated circuit package 100, the first data bus 161 and the second data bus 171 may be parallel data buses that transmit parallel data. A width of the first data bus 161 may be less than or equal to a width of the second data bus 171. The width of the data buses may define the number of data signals and/or the number of bits of data that may be transmitted at one time through the data buses. In an embodiment, the width of the data bus may also define the number of signal transmission lines carrying the data signals. In an embodiment, the width of the second data bus 171 may be substantially the same as the width of the first data bus 161, and the number of data signals and bits transmitted at one time through the second data bus 171 may be substantially the same as the number of data signals and bits transmitted at one time through the first data bus 161. In an embodiment, a width of the second data bus 171 may be twice a width of the first data bus 161, and the number of data signals and bits transmitted at one time through the second data bus 171 may be twice the number of data signals and bits transmitted at one time through the first data bus 161. In an embodiment, a width of the second data bus 171 may be four times a width of the first data bus 161, and the number of data signals and bits transmitted at one time through the second data bus 171 may be four times the number of data signals and bits transmitted at one time through the first data bus 161. For example, the first data bus 161 may include n signal transmission lines, and n bits of data may be transmitted through the first data bus 161 at one time. Here, n may be a multiple of 2. The second data bus 171 may include m signal transmission lines, and m bits of data may be transmitted at a time through the second data bus 171. Here, m may be equal to n or may be a multiple of n. The clock rates of the second and third buses 160, 170 and the widths of the first and second data buses 161, 171 may be changed such that the second data bus 171 may have substantially the same data bandwidth as the first data bus 161.

In an embodiment, the host 110, the memory controller 120, and the interface circuit 130 may be integrated into a first device, and the memory apparatus 140 may be a second device. The first bus 150 and the second bus 160 may be internal buses, and the third bus 170 may be an external bus. The host 110, the memory controller 120, and the interface circuit 130 may be disposed on a first interposer and/or a first substrate, and the memory apparatus 140 may be disposed on a second interposer and/or a second substrate. In an embodiment, the host 110 and the memory controller 120 may be integrated into a first device, and the interface circuit 130 and the memory apparatus 140 may be integrated into a second device. The first and third buses 150, 170 may be internal buses, and the second bus 160 may be an external bus. The host 110 and the memory controller 120 may be disposed on a first interposer and/or a first substrate, and the interface circuit 130 and the memory apparatus 140 may be disposed on a second interposer and/or a second substrate. In an embodiment, the host 110 may be a first device, and the memory controller 120, the interface circuit 130, and the memory apparatus 140 may be integrated into a second device. The first bus 150 may be an external bus, and the second and third buses 160, 170 may be internal buses. The host 110 may be disposed on a first interposer and/or a first substrate, and the memory controller 120, the interface circuit 130, and the memory apparatus 140 may be disposed on a second interposer and/or a second substrate. In an embodiment, the host 110, the memory controller 120, the interface circuit 130, and the memory apparatus 140 may be integrated into a single device. The first to third buses 150, 160, 170 may be internal buses. The host 110, the memory controller 120, the interface circuit 130, and the memory apparatus 140 may be disposed on the same interposer and/or substrate. In an embodiment, some or all of the host 110, the memory controller 120, the interface circuit 130, and the memory apparatus 140 may be manufactured as chiplets.

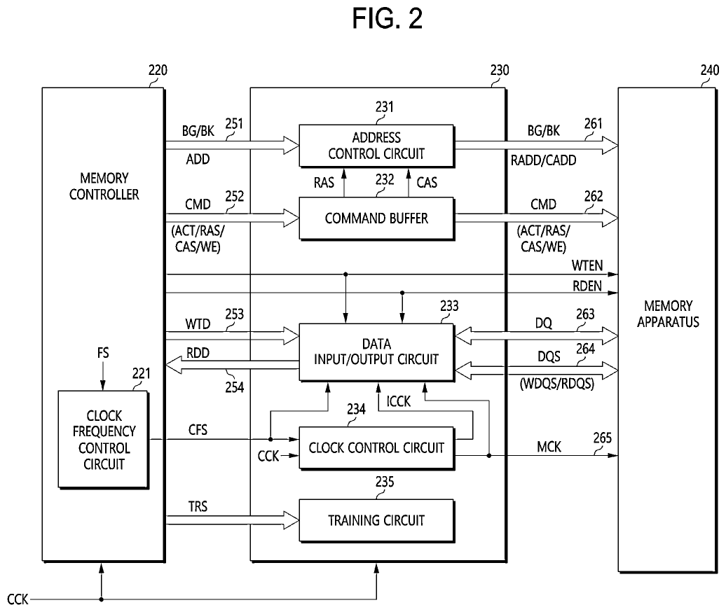

FIG. 2 is a diagram illustrating connection relationships among a memory controller 220, an interface circuit 230, and a memory apparatus 240 according to an embodiment of the present disclosure. The memory controller 220 may be applied as the memory controller 120 shown in FIG. 1, the interface circuit 230 may be applied as the interface circuit 130 shown in FIG. 1, and the memory apparatus 240 may be applied as the memory apparatus 140 shown in FIG. 1. Referring to FIG. 2, the memory controller 220 may generate or receive various control signals in response to an access request provided by the host 110 shown in FIG. 1. The various control signals may include an address signal ADD, a bank group signal BG, a bank address signal BK, a command signal CMD, a write data signal WTD, a read data signal RDD, and the like. The address signal ADD may be a signal used to access rows and columns of the memory cell array of the memory apparatus 240. The bank group signal BG may be an address signal used to access one of a plurality of memory bank groups included in the memory apparatus 240. The bank address signal BK may be an address signal used to access a memory bank of one of a plurality of memory banks constituting a memory bank group. The memory controller 220 may be electrically connected to the interface circuit 230 through an address bus 251. The address bus 251 may be a unidirectional bus from the memory controller 220 to the interface circuit 230. The address signal ADD, the bank group signal BG, and the bank address signal BK may be provided from the memory controller 220 to the interface circuit 230 through the address bus 251. The address bus 251 may include a plurality of signal transmission lines, and the address signal ADD, the bank group signal BG, and the bank address signal BK may be transmitted through separate signal transmission lines. The address bus 251 may be included in the portion of the second bus 160 that excludes the first data bus 161 as shown in FIG. 1.

The command signal CMD may include a plurality of signals. By way of non-limiting examples, the command signal CMD may include an active command signal ACT, a row access command signal RAS, a column access command signal CAS, and a write enable signal WE. The active command signal ACT may be a command signal that instructs the memory apparatus 240 to enter an active mode from a standby mode, or to enter the standby mode from the active mode. The memory apparatus 240 may perform write and read operations in the active mode, and the standby mode may be a low power mode of the memory apparatus 240. The row access command signal RAS may be a row address strobe signal, and may be a command signal that indicates access of a row of the memory apparatus 240. The column access command signal CAS may be a column address strobe signal, and may be a command signal indicating access of a column of the memory apparatus 240. The write enable signal WE may be a signal that determines whether an operation to be performed by the memory apparatus is a write operation or a read operation. For example, when the column access command signal CAS is enabled and the write enable signal WE has a first logic level, the write enable signal WE may be a command signal that instructs the memory apparatus 240 to perform a write operation. When the column access command signal CAS is enabled and the write enable signal WE has a second logic level, the write enable signal WE may be a command signal that instructs the memory apparatus 240 to perform a read operation. The memory controller 220 may be electrically connected to the interface circuit 230 through a command bus 252. The command bus 252 may be a unidirectional bus from the memory controller 220 to the interface circuit 230. The command signal CMD may be provided from the memory controller 220 to the interface circuit 230 through the command bus 252. The command bus 252 may include a plurality of signal transmission lines, and the active command signal ACT, the row access command signal RAS, the column access command signal CAS, and the write enable signal WE may be transmitted through separate signal transmission lines. The command bus 252 may be included in that part of the second bus 160 that might not be included in the first data bus 161 as shown in FIG. 1. Although not shown, the memory controller 220 may further generate control signals, such as a chip selection signal, a clock enable signal, and a reset signal, and may provide the control signals to the interface circuit 230 through other signal transmission lines.

The write data signal WTD may be a data signal provided to the memory apparatus 240 from the memory controller 220 when the memory controller 220 instructs the memory apparatus 240 to perform a write operation, and may be a data signal to be stored in the memory apparatus 240. The memory controller 220 may generate the write data signal WTD based on data transmitted with an access request from the host 110. The read data signal RDD may be a data signal provided to the memory controller 220 from the memory apparatus 240 when the memory controller 220 instructs the memory apparatus 240 to perform a read operation. The memory controller 220 may generate data that is transmitted to the host 110 based on the read data signal RDD. The memory controller 220 may be electrically connected to the interface circuit 230 through a write bus 253 and a read bus 254. The write bus 253 may be a unidirectional bus from the memory controller 220 to the interface circuit 230, and the read bus 254 may be a unidirectional bus from the interface circuit 230 to the memory controller 220. The write data signal WTD may be provided from the memory controller 220 to the interface circuit 230 through the write bus 253. The read data signal RDD may be provided from the interface circuit 230 to the memory controller 220 through the read bus 254. The write bus 253 and the read bus 254 may be included in the first data bus 161 shown in FIG. 1. A width of the write bus 253 and a width of the read bus 254 may be substantially the same, and a clock rate of the write bus 253 and a clock rate of the read bus 254 may be substantially the same. In an embodiment, the write bus 253 and the read bus 254 may be integrated into a single data bus, and the integrated data bus may be implemented as a bidirectional bus between the memory controller 220 and the interface circuit 230. The integrated data bus may have substantially the same width and clock rate as each of the write bus 253 and the read bus 254.

In an embodiment, the memory controller 220 may further provide a write selection signal WTEN and a read selection signal RDEN to the interface circuit 230 and the memory apparatus 240. The write selection signal WTEN may be a signal for enabling buffers in the interface circuit 230 and the memory apparatus 240 that transmit and receive signals related with the write operation when the memory controller 220 instructs the write operation to the memory apparatus 240. The read selection signal RDEN may be a signal for enabling buffers in the interface circuit 230 and the memory apparatus 240 that transmit and receive signals related to the read operation when the memory controller 220 instructs the read operation to the memory apparatus 240. In an embodiment, the memory controller 220 might not separately provide the write selection signal WTEN and the read selection signal RDEN to the interface circuit 230, and the interface circuit 230 may generate the write selection signal WTEN and the read selection signal RDEN based on the command signal CMD.

The interface circuit 230 may be electrically connected to the memory controller 220, and may receive the address signal ADD, the bank group signal BG, the bank address signal BK, the command signal CMD, the write data signal WTD from the memory controller 220, and may transmit the read data signal RDD to the memory controller 220. The interface circuit 230 may be electrically connected to the memory controller 220 through the address bus 251, the command bus 252, the write bus 253, and the read bus 254. The interface circuit 230 may receive the address signal ADD, the bank group signal BG, and the bank address signal BK from the memory controller 220 through the address bus 251. The interface circuit 230 may receive the active command signal ACT, the row access command signal RAS, the column access command signal CAS, and the write enable signal WE through the command bus 252. The interface circuit 230 may receive the write data signal WTD from the memory controller 220 through the write bus 253. The interface circuit 230 may transmit the read data signal RDD to the memory controller 220 through the read bus 254. The interface circuit 230 may be electrically connected to the memory apparatus 240 and may provide signals received from the memory controller 220 to the memory apparatus 240. The interface circuit 230 may buffer and convert signals received from the memory controller 220 to generate signals suitable for use in the memory apparatus 240 (e.g., serialize or de-serialize).

The interface circuit 230 may provide the bank group signal BG, the bank address signal BK, a row address signal RADD, a column address signal CADD, the command signal CMD, and a memory data signal DQ to the memory apparatus 240. The interface circuit 230 may buffer the bank group signal BG and the bank address signal BK received from the memory controller 220. The interface circuit 230 may generate the row address signal RADD and the column address signal CADD based on the address signal ADD and the command signal CMD received from the memory controller 220. The interface circuit 230 may be electrically connected with the memory apparatus 240 through an address bus 261, and may provide the bank group signal BG, the bank address signal BK, and the row address signal RADD and the column address signal CADD to the memory apparatus 240 through the address bus 261. The address bus 261 may be a unidirectional bus from the interface circuit 230 to the memory apparatus 240. The address bus 261 may include a plurality of signal transmission lines, and the bank group signal BG, the bank address signal BK, the row address signal RADD, and the column address signal CADD may be transmitted through separate signal transmission lines. The address bus 261 may be included as part of the third bus 170, but not part of the second data bus 171 shown in FIG. 1.

The interface circuit 230 may buffer the command signal CMD received from the memory controller 220. The interface circuit 230 may be electrically connected to the memory apparatus 240 through a command bus 262, and may provide the active command signal ACT, the row access command signal RAS, the column access command signal CAS, and the write enable signal WE to the memory apparatus 240 through the command bus 262. The command bus 262 may be a unidirectional bus from the interface circuit 230 to the memory apparatus 240. The command bus 262 may include a plurality of signal transmission lines, and the active command signal ACT, the row access command signal RAS, the column access command signal CAS, and the write enable signal WE may be transmitted through separate signal transmission lines. The command bus 262 may be included as part of the third bus 170 other than the second data bus 171 shown in FIG. 1.

The interface circuit 230 may generate the memory data signal DQ based on the write data signal WTD received from the memory controller 220, and may generate the read data signal RDD based on the memory data signal DQ received from the memory apparatus 240. The interface circuit 230 may be electrically connected to the memory apparatus 240 through a memory data bus 263, and may transmit the memory data signal DQ to the memory apparatus 240 or receive the memory data signal DQ transmitted from the memory apparatus 240 through the memory data bus 263. The memory data bus 263 may be a bidirectional bus between the interface circuit 230 and the memory apparatus 240. A width of the memory data bus 263 may be greater than or equal to a width of the write bus 253 or a width of the read bus 254, and a clock rate of the memory data bus 263 may be less than or equal to a clock rate of the write bus 253 or a clock rate of the read bus 254.

The interface circuit 230 may include an address control circuit 231, a command buffer 232, and a data input/output circuit 233. The address control circuit 231 may receive the bank group signal BG, the bank address signal BK, and the address signal ADD from the memory controller 220. The address control circuit 231 may buffer the bank group signal BG and the bank address signal BK, and may provide the buffered bank group signal BG and buffered bank address signal BK to the memory apparatus 240. The address control circuit 231 may generate the row address signal RADD and the column address signal CADD based on the address signal ADD and the command signal CMD. The address control circuit 231 may generate the row address signal RADD based on the address signal ADD and the row access command signal RAS, and may generate the column address signal CADD based on the address signal ADD and the column access command signal CAS. For example, the address control circuit 231 may generate the address signal ADD as the row address signal RADD when the row access command signal RAS is enabled. The address control circuit 231 may generate the address signal ADD as the column address signal CADD when the column access command signal CAS is enabled. The address control circuit 231 may transmit the row address signal RADD and the column address signal CADD to the memory apparatus 240 through the address bus 261.

The command buffer 232 may be electrically connected to the command bus 252 to receive the command signal CMD transmitted from the memory controller 220. The command buffer 232 may buffer the command signal CMD, and may transmit the buffered command signal CMD to the memory apparatus 240 through the command bus 262. The command buffer 232 may buffer the active command signal ACT, the row access command signal RAS, the column access command signal CAS, and the write enable signal WE, respectively, and may provide buffered active command signal ACT, buffered row access command signal RAS, buffered column access command signal CAS, and buffered write enable signal WE to the memory apparatus 240. The command buffer 232 may provide the buffered row access command signal RAS and the buffered column access command signal CAS to the address control circuit 231. The address control circuit 231 may generate the row address signal RADD and the column address signal CADD based on the address signal ADD and the row access command signal RAS and the column access command signal CAS received from the command buffer 232. In an embodiment, the command buffer 232 may be modified to generate the write selection signal WTEN and the read selection signal RDEN based on the write enable signal WE. The command buffer 232 may enable the write selection signal WTEN and disable the read selection signal RDEN when the column access command signal CAS is enabled and the write enable signal WE has a first logic level, i.e., when a write operation is performed. The command buffer 232 may enable the read selection signal RDEN and disable the write selection signal WTEN when the column access command signal CAS is enabled and the write enable signal WE has a second logic level, i.e., when a read operation is performed. The command buffer 232 may provide the write selection signal WTEN and the read selection signal RDEN to the data input/output circuit 233 and the memory apparatus 240.

The data input/output circuit 233 may be electrically connected to the memory controller 220 through the write bus 253 and the read bus 254, and may be electrically connected to the memory apparatus 240 through the memory data bus 263. The data input/output circuit 233 may receive the write data signal WTD from the memory controller 220 through the write bus 253, and may generate the memory data signal DQ based on the write data signal WTD. The data input/output circuit 233 may transmit the memory data signal DQ to the memory apparatus 240 through the memory data bus 263. The data input/output circuit 233 may receive the memory data signal DQ from the memory apparatus 240 through the memory data bus 263, and may generate the read data signal RDD based on the memory data signal DQ. The data input/output circuit 233 may transmit the read data signal RDD to the memory controller 220 through the read bus 254. The data input/output circuit 233 may selectively and electrically connect the memory data bus 263 with one of the write bus 253 and the read bus 254 based on the write enable signal WE of the command signal CMD (i.e., based on whether the signal indicates the write operation or the read operation). The data input/output circuit 233 may receive the write selection signal WTEN and the read selection signal RDEN transmitted from the memory controller 220. In an embodiment, the data input/output circuit 233 may receive the write selection signal WTEN and the read selection signal RDEN from the command buffer 232. The data input/output circuit 233 may electrically connect the write bus 253 with the memory data bus 263 based on the write selection signal WTEN, and may electrically connect the read bus 254 with the memory data bus 263 based on the read selection signal RDEN. The data input/output circuit 233 may buffer the write data signal WTD, and may output the buffered write data signal WTD as the memory data signal DQ when the write selection signal WTEN is enabled. The data input/output circuit 233 may receive the memory data signal DQ, buffer the memory data signal DQ, and output the buffered memory data signal DQ as the read data signal RDD, when the read selection signal RDEN is enabled. In an embodiment, the data input/output circuit 233 may convert the data rate of the write data signal WTD to generate the memory data signal DQ. For example, the data input/output circuit 233 may decrease the data rate of the write data signal WTD to generate the memory data signal DQ. The data input/output circuit 233 may convert the data rate of the memory data signal DQ to generate the read data signal RDD. For example, the data input/output circuit 233 may increase the data rate of the memory data signal DQ to generate the read data signal RDD. The data input/output circuit 233 may generate a data strobe signal DQS, transmit the data strobe signal DQS to the memory apparatus 240, and transmit the memory data signal DQ to the memory apparatus 240 in synchronization with the data strobe signal DQS. The data input/output circuit 233 may receive the data strobe signal DQS transmitted from the memory apparatus 240, and may receive the memory data signal DQ transmitted from the memory apparatus 240 in synchronization with the data strobe signal DQS. The data strobe signal DQS transmitted by the data input/output circuit 233 to the memory apparatus 240 may be a write data strobe signal WDQS. The data strobe signal DQS received by the data input/output circuit 233 from the memory apparatus 240 may be a read data strobe signal RDQS. The data input/output circuit 233 may transmit the write data strobe signal WDQS to the memory apparatus 240 through a strobe bus 264, and may receive the read data strobe signal RDQS transmitted from the memory apparatus 240 through the strobe bus 264. The data input/output circuit 233 may generate the write data strobe signal WDQS based on a memory clock signal MCK, which will be described later.

The memory controller 220 and the interface circuit 230 may receive a system clock signal CCK, and may operate in synchronization with the system clock signal CCK. The host 110 illustrated in FIG. 1 may generate the system clock signal CCK, and may provide the system clock signal CCK to the memory controller 220 and the interface circuit 230. In an embodiment, the memory controller 220 may generate the system clock signal CCK, and the memory controller 220 may provide the system clock signal CCK to the interface circuit 230. The memory controller 220 may provide the write data signal WTD to the interface circuit 230 in synchronization with the system clock signal CCK, and may receive the read data signal RDD in synchronization with the system clock signal CCK. The memory controller 220 may further include a clock frequency control circuit 221. The clock frequency control circuit 221 may set and/or change the operating speed of the interface circuit 230 and the memory apparatus 240. The clock frequency control circuit 221 may receive a frequency control signal FS from the host 110. The clock frequency control circuit 221 may generate a clock frequency setting signal CFS based on the frequency control signal FS. The clock frequency setting signal CFS may include information for setting the clock rate of the buses electrically connecting the memory controller 220 and the interface circuit 230 and the buses electrically connecting the interface circuit 230 and the memory apparatus 240.

The interface circuit 230 may further include a clock control circuit 234. The clock control circuit 234 may generate an interface clock signal ICCK and a memory clock signal MCK based on the system clock signal CCK and the clock frequency setting signal CFS. The clock control circuit 234 may generate the interface clock signal ICCK by buffering the system clock signal CCK, and the interface clock signal ICCK may have substantially the same frequency as the system clock signal CCK. The clock control circuit 234 may selectively delay the system clock signal CCK to generate the interface clock signal ICCK in consideration of delays occurring within the interface circuit 230. The clock control circuit 234 may change the frequency of the memory clock signal MCK based on the clock frequency setting signal CFS. For example, the memory clock signal MCK generated by the clock control circuit 234 based on the clock frequency setting signal CFS may have substantially the same frequency as the interface clock signal ICCK, or may have a frequency that is two or four times lower. The clock control circuit 234 may change the frequency of the memory clock signal MCK to set the ratio of clock rates of the write bus 253 and the read bus 254 to the memory data bus 263. The interface circuit 230 may be electrically connected to the memory apparatus 240 through a memory clock bus 265, and the clock control circuit 234 may transmit the memory clock signal MCK to the memory apparatus 240 through the memory clock bus 265. The clock control circuit 234 may provide the memory clock signal MCK and a complementary signal together, and may provide the memory clock signal MCK and the complementary signal as a differential clock signal to the memory apparatus 240.

The data input/output circuit 233 may further receive the clock frequency setting signal CFS, the interface clock signal ICCK, and the memory clock signal MCK. The data input/output circuit 233 may perform a data conversion operation based on the clock frequency setting signal CFS. When it is determined that the frequencies of the interface clock signal ICCK and the memory clock signal MCK are substantially the same according to the clock frequency setting signal CFS, the data input/output circuit 233 may buffer the write data signal WTD to generate the memory data signal DQ, and may buffer the memory data signal DQ to generate the read data signal RDD. When it is determined that the interface clock signal ICCK has a higher frequency than the memory clock signal MCK according to the clock frequency setting signal CFS, the data input/output circuit 233 may perform deserialization and serialization operations, and may perform operations similar to SerDes. The data input/output circuit 233 may deserialize the write data signal WTD to generate the memory data signal DQ, and may serialize the memory data signal DQ to generate the read data signal RDD. For example, the data input/output circuit 233 may latch the write data signal WTD based on the interface clock signal ICCK and transmit the latched write data signal WTD to the memory apparatus 240 as the memory data signal DQ in synchronization with the write data strobe signal WDQS. The data input/output circuit 233 may latch the memory data signal DQ based on the read data strobe signal RDQS, and transmit the latched memory data signal DQ in synchronization with the interface clock signal ICCK to the memory controller 220 as the read data signal RDD.

The interface circuit 230 may further include a training circuit 235. The memory controller 220 may provide a training signal TRS to the interface circuit 230 when a computing system is initialized or upon request of the host 110. The training circuit 235 enables training operations to be performed on internal circuits provided in the interface circuit 230 based on the training signal TRS. The internal circuits in which the training operation is performed will be described in more detail below.

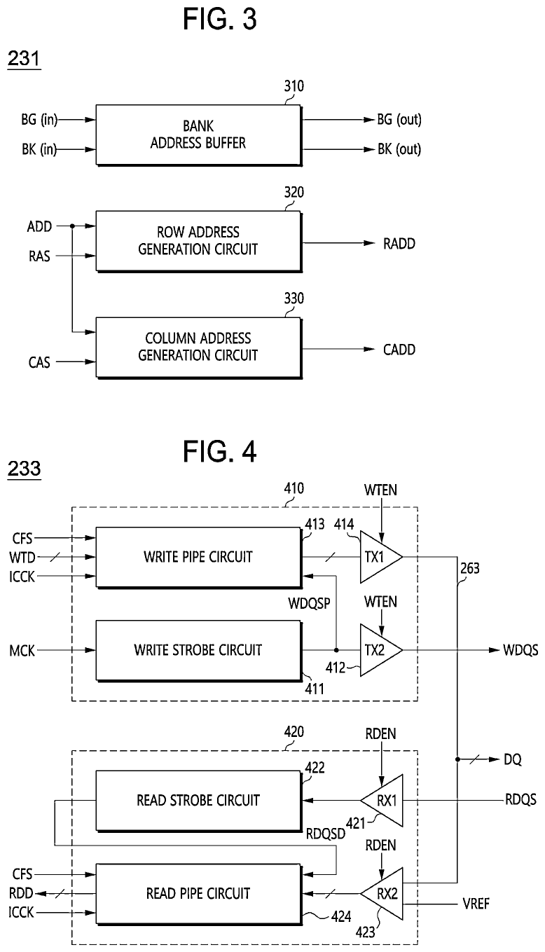

FIG. 3 is a block diagram illustrating a configuration of the address control circuit 231 shown in FIG. 2. Referring to FIGS. 2 and 3, the address control circuit 231 may include a bank address buffer 310, a row address generation circuit 320, and a column address generation circuit 330. The bank address buffer 310 may buffer the bank group signal BG and the bank address signal BK received from the memory controller 220 to generate the bank group signal BG and the bank address signal BK transmitted to the memory apparatus 240. In FIG. 3, the bank group signal and the bank address signal input to the bank address buffer 310 from the memory controller 220 are denoted as BG(in) and BK(in), respectively, and the bank group signal and the bank address signal output from the bank address buffer 310 to the memory apparatus 240 are denoted as BG(out) and BK(out), respectively. The bank address buffer 310 may perform a general buffering operation without changing the characteristics of the bank group signal BG and the bank address signal BK.

The row address generation circuit 320 may receive the address signal ADD from the memory controller 220 and may receive the row access command signal RAS from the command buffer 232. The row address generation circuit 320 may output the address signal ADD as the row address signal RADD when the row access command signal RAS is enabled. The row address generation circuit 320 might not output the address signal ADD as the row address signal RADD when the row access command signal RAS is disabled. The row address generation circuit 320 may transmit the row address signal RADD to the memory apparatus 240.

The column address generation circuit 330 may receive the address signal ADD from the memory controller 220 and may receive the column access command signal CAS from the command buffer 232. The column address generation circuit 330 may output the address signal ADD as the column address signal CADD when the column access command signal CAS is enabled. When the column access command signal CAS is disabled, the column address generation circuit 330 may not output the address signal ADD as the column address signal CADD. The column address generation circuit 330 may transmit the column address signal CADD to the memory apparatus 240.

FIG. 4 is a diagram illustrating a configuration of the data input/output circuit 233 shown in FIG. 2. Referring to FIGS. 2 and 4, the data input/output circuit 233 may include a write control circuit 410 and a read control circuit 420. The write control circuit 410 may receive the write selection signal WTEN, the write data signal WTD, and the interface clock signal ICCK, and may generate the memory data signal DQ and the write data strobe signal WDQS. The write control circuit 410 may be selectively activated based on the write selection signal WTEN. The write control circuit 410 may generate the write data strobe signal WDQS based on the interface clock signal ICCK. The write control circuit 410 may latch the write data signal WTD based on the interface clock signal ICCK, and may output the latched write data signal WTD as the memory data signal DQ based on the write data strobe signal WDQS.

The write control circuit 410 may include a write strobe circuit 411, a strobe transmitter 412, TX2, a write pipe circuit 413, and a data transmitter 414, TX1. The write strobe circuit 411 may receive the memory clock signal MCK and generate a pre-write data strobe signal WDQSP based on the memory clock signal MCK. The write strobe circuit 411 may buffer or divide the memory clock signal MCK to generate the pre-write data strobe signal WDQSP. In an embodiment, the write strobe circuit 411 may buffer the memory clock signal MCK to generate the pre-write data strobe signal WDQSP including a differential clock signal having a phase difference of 180 degrees. In an embodiment, the write strobe circuit 411 may divide the memory clock signal MCK to generate the pre-write data strobe signal WDQSP including multi-phase clock signals having a phase difference of 90 degrees. The write strobe circuit 411 may selectively delay the interface clock signal ICCK so that the memory data signal DQ and the pre-write data strobe signal WDQSP can be synchronized, and then generate the pre-write data strobe signal WDQSP based on a delayed interface clock signal ICCK. The strobe transmitter 412 may be electrically connected to the write strobe circuit 411 to receive the pre-write data strobe signal WDQSP. The strobe transmitter 412 may receive the write selection signal WTEN and may be activated when the write selection signal WTEN is enabled. The strobe transmitter 412 may transmit the write strobe signal WDQS to the memory apparatus 240 based on the pre-write data strobe signal WDQSP. The write strobe signal WDQS may be substantially the same signal as the pre-write data strobe signal WDQSP.

The write pipe circuit 413 may receive the write data signal WTD, the interface clock signal ICCK, and the pre-write data strobe signal WDQSP. The write pipe circuit 413 may sequentially store the write data signal WTD in synchronization with the interface clock signal ICCK. The write pipe circuit 413 may output the sequentially stored write data signal WTD as the memory data signal DQ in synchronization with the pre-write data strobe signal WDQSP. The write pipe circuit 413 may be implemented with a deserializer that converts a ratio of the duration of the write data signal WTD and the memory data signal DQ to 1:1, 1:2, or 1:4 depending on a frequency ratio of the interface clock signal ICCK to the pre-write data strobe signal WDQSP and/or the write data strobe signal WDQS. The write pipe circuit 413 may further receive the clock frequency setting signal CFS. Based on the clock frequency setting signal CFS, the write pipe circuit 413 may determine a frequency ratio of the interface clock signal ICCK and the write data strobe signal WDQS, and may change the ratio of the duration of the write data signal WTD and the memory data signal DQ. The data transmitter 414 may be electrically connected with the write pipe circuit 413 to receive an output signal of the write pipe circuit 413. The data transmitter 414 may receive the write selection signal WTEN and may be activated when the write selection signal WTEN is enabled. The data transmitter 414 may drive the memory data bus 263 based on the output signal of the write pipe circuit 413 to transmit the memory data signal DQ to the memory apparatus 240.

The read control circuit 420 may receive the read selection signal RDEN, the memory data signal DQ, the interface clock signal ICCK, and the read data strobe signal RDQS, and may generate the read data signal RDD. The read control circuit 420 may be selectively activated based on the read selection signal RDEN. The read control circuit 420 may latch the memory data signal DQ based on the read data strobe signal RDQS, and may output a latched memory data signal DQ as the read data signal RDD based on the interface clock signal ICCK.

The read control circuit 420 may include a strobe receiver 421, RX1, a read strobe circuit 422, a data receiver 423, RX2, and a read pipe circuit 424. The strobe receiver 421 may receive the read selection signal RDEN and the read data strobe signal RDQS. The strobe receiver 421 may be activated when the read selection signal RDEN is enabled. The strobe receiver 421 may receive the read data strobe signal RDQS from the memory apparatus 240. The read data strobe signal RDQS may include a differential clock signal having a phase difference of 180 degrees, or may include multi-phase clock signals having a phase difference of 90 degrees. The read strobe circuit 422 may be electrically connected to the strobe receiver 421 to receive an output signal of the strobe receiver 421, and may buffer the output signal of the strobe receiver 421. The read strobe circuit 422 may selectively delay the output signal of the strobe receiver 421 to match a delay time of the memory data signal DQ with a delay time of the read data strobe signal RDQS. The read strobe circuit 422 may generate a delayed read data strobe signal RDQSD from the output signal of the strobe receiver 421. The delayed read data strobe signal RDQSD may have substantially the same frequency characteristics as the read strobe signal RDQS.

The data receiver 423 may receive the read selection signal RDEN and the memory data signal DQ. The data receiver 423 may be selectively activated based on the read selection signal RDEN. The data receiver 423 may use a reference voltage VREF to receive the memory data signal DQ. The reference voltage VREF may have an appropriate voltage level based on a range of voltage level in which the memory data signal DQ swings. For example, when the memory data signal DQ is an NRZ signal, the reference voltage VREF may have a voltage level corresponding to a middle of the voltage level range in which the memory data signal DQ swings. The read pipe circuit 424 may receive the memory data signal DQ, the delayed read data strobe signal RDQSD, and the interface clock signal ICCK. The read pipe circuit 424 may sequentially store the memory data signal DQ in synchronization with the delayed read data strobe signal RDQSD. The read pipe circuit 424 may output the sequentially stored memory data signal DQ as the read data signal RDD in synchronization with the interface clock signal ICCK. The read pipe circuit 424 may be implemented with a serializer that converts the ratio of the duration of the memory data signal DQ and the read data signal RDD to 1:1, 2:1, or 4:1 depending on a frequency ratio of the delayed read data strobe signal RDQSD and/or the read data strobe signal RDQS to the interface clock signal ICCK. The read pipe circuit 424 may further receive the clock frequency setting signal CFS. The read pipe circuit 424 may determine a frequency ratio of the interface clock signal ICCK and the read strobe signal RDQS based on the clock frequency setting signal CFS, and may change the ratio of the duration of the memory data signal DQ and the read data signal RDD.

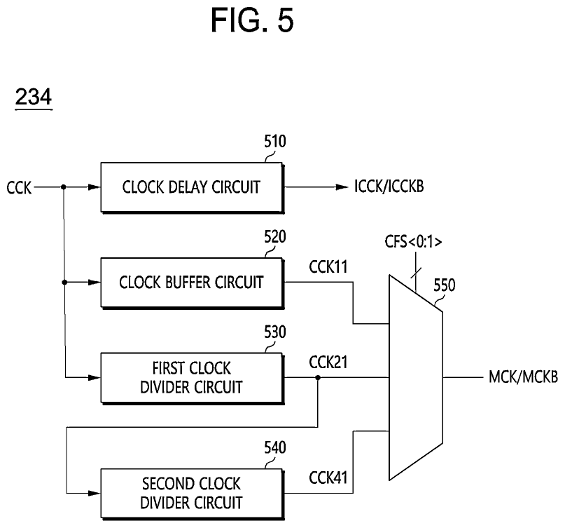

FIG. 5 is a diagram illustrating a configuration of the clock control circuit 234 shown in FIG. 2. Referring to FIG. 5, the clock control circuit 234 may include a clock delay circuit 510, a clock buffer circuit 520, a first clock divider circuit 530, a second clock divider circuit 540, and a clock selection circuit 550. The clock delay circuit 510 may receive the system clock signal CCK and may buffer the system clock signal CCK. The system clock signal CCK may be selectively delayed to generate an interface clock signal pair ICCK, ICCKB. The clock delay circuit 510 may generate the interface clock signal pair ICCK, ICCKB without substantially delaying the system clock signal CCK (except for a delay caused by a buffering operation). The clock delay circuit 510 may delay the system clock signal CCK by an arbitrary delay time (in addition to the delay time caused by the buffering operation) to generate the interface clock signal pair ICCK, ICCKB having a lagging phase relative to the system clock signal CCK. The clock delay circuit 510 may include digital and/or analog variable delay lines, and the delay time of the clock delay circuit 510 may be changed based on any digital and/or analog control signal.

The clock buffer circuit 520 may receive the system clock signal CCK, and may buffer the system clock signal CCK to generate a first clock signal pair CCK11. The first clock signal pair CCK11 may have substantially the same frequency as the system clock signal CCK. The first clock divider circuit 530 may receive the system clock signal CCK, and may divide a frequency of the system clock signal CCK by two to generate a second clock signal pair CCK21. The frequency of the second clock signal pair CCK21 may be ½ of the system clock signal CCK. The second clock divider circuit 540 may divide the frequency of the second clock signal pair CCK21 by two to generate a third clock signal pair CCK41. The frequency of the third clock signal pair CCK41 may be ½ of the frequency of the second clock signal pair CCK21, and may be ¼ of the frequency of the system clock signal CCK.

The clock selection circuit 550 may receive the first clock signal pair CCK11, the second clock signal pair CCK21, the third clock signal pair CCK41, and the clock frequency setting signal CFS. The clock selection circuit 550 may output one of the first to third clock signal pairs CCK11, CCK21, CCK41 as a memory clock signal pair MCK, MCKB based on the clock frequency setting signal CFS. The clock frequency setting signal CFS may be a digital signal having at least two bits. The clock selection circuit 550 may output the first clock signal pair CCK11 as the memory clock signal pair MCK, MCKB when the clock frequency setting signal CFS has a first logic value. The clock selection circuit 550 may output the second clock signal pair CCK21 as the memory clock signal pair MCK, MCKB when the clock frequency setting signal CFS has a second logic value. The clock selection circuit 550 may output the third clock signal pair CCK41 as the memory clock signal pair MCK, MCKB when the clock frequency setting signal CFS has a third logic value. The clock selection circuit 550 may be implemented with a 3 to 1 multiplexer using the clock frequency setting signal CFS as a control signal. Referring again to FIG. 2, the training circuit 235 may perform a training operation on the components shown in FIGS. 3 to 5 based on the training signal TRS. For example, based on the training signal TRS, the training circuit 235 may adjust the driving strength and/or delay time of the bank address buffer 310, the data transmitter 414, the write strobe circuit 411, and the strobe transmitter 412, the strobe receiver 421, the read strobe circuit 422, the data receiver 423, the clock delay circuit 510, the clock buffer circuit 520, etc.

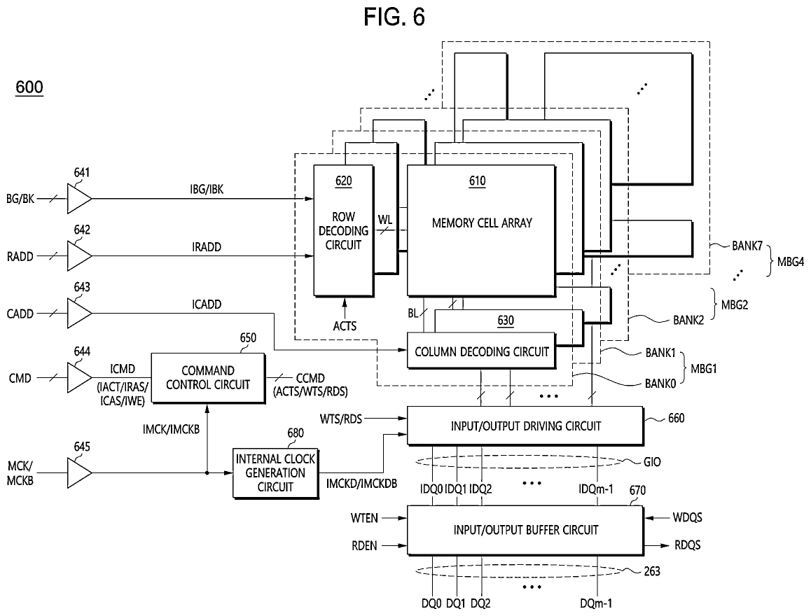

FIG. 6 is a diagram illustrating a configuration of a memory die 600 according to an embodiment of the present disclosure. The memory apparatus 240 shown in FIG. 2 may include the memory die 600. When the memory apparatus 240 includes a plurality of memory dies, the plurality of memory dies may each have substantially the same configuration as the memory die 600. Referring to FIGS. 2 and 6, the memory die 600 may receive the bank group signal BG, the bank address signal BK, the row address signal RADD, the column address signal CADD, the command signal CMD, the memory clock signal pair MCK, MCKB, and the memory data signal DQ from the interface circuit 230. The memory die 600 may include a plurality of memory bank groups MBG1 to MBG4, a first address receiver 641, a second address receiver 642, a third address receiver 643, a command receiver 644, a clock receiver 645, a command control circuit 650, an input/output driving circuit 660, and an input/output buffer circuit 670. The memory die 600 may include a first to fourth memory bank groups MBG1 to MBG4. While FIG. 6 illustrates that the number of memory bank groups included by the memory die 600 is four, the number of memory bank groups included by the memory die 600 may be two, eight or more. Each of the first to fourth memory bank groups may include a plurality of memory banks BANK0, BANK1, BANK2, . . . , BANK7. For example, the first to fourth memory bank groups MBG1 to MBG4 may each include two memory banks. The first memory bank group MBG1 may include a first memory bank BANK0 and a second memory bank BANK1, the second memory bank group MBG1 may include a third memory bank BANK3 and a fourth memory bank, the third memory bank group may include a fifth memory bank and a sixth memory bank, and the fourth memory bank group MBG4 may include a seventh memory bank and an eighth memory bank BANK7. In FIG. 6, each memory bank group includes two memory banks, but the number of memory banks included in each memory bank group may be four or more. Each of the first to eighth memory banks BANK0, BANK2, BANK3, . . . , BANK7 may include a memory cell array 610, a row decoding circuit 620, and a column decoding circuit 630. The memory cell array 610, the row decoding circuit 620, and the column decoding circuit 630 may be provided as many in number as the number of the memory banks. A plurality of row lines WL may be disposed in a row direction of each memory cell array, a plurality of column lines BL may be disposed in a column direction of each memory cell array, and a plurality of memory cells may be electrically connected at points where the plurality of row lines and the plurality of column lines intersect.

Each of the row decoding circuits 620 may receive an internal bank group signal IBG, an internal bank address signal IBK, an internal row address signal IRADD, and an active signal ACTS. Each of the row decoding circuits 620 may select and/or enable a row line of the memory cell array 610 provided in the first to eighth memory bank when the active signal ACTS is enabled. Each of the row decoding circuits 620 may decode the internal bank group signal IBG to select and/or access at least one memory bank group of the plurality of memory bank groups MBG1 to MBG4. Each of the row decoding circuits 620 may decode the internal bank address signal IBK to select and/or access at least one memory bank of a plurality of memory banks of a selected memory bank group. Each of the row decoding circuits 620 may select and/or enable at least one of a plurality of row lines disposed in each of the memory cell arrays 610 based on the internal row address signal IRADD. Each of the column decoding circuits 630 may receive an internal column address signal ICADD. Each of the column decoding circuits 630 may decode the internal column address signal ICADD to select and/or access at least one of a plurality of column lines disposed in each of the memory cell arrays 610.

The first address receiver 641 may receive the bank group signal BG and the bank address signal BK transmitted from the interface circuit 230 through the address bus 261. The first address receiver 641 may receive the bank group signal BG and the bank address signal BK to generate an internal bank group signal IBG and an internal bank address signal IBK. The first address receiver 641 may generate the internal bank group signal IBG and the internal bank address signal IBK having substantially the same characteristics as the bank group signal BG and the bank address signal BK, without changing the characteristics of the bank group signal IBG and the bank address signal IBK. The first address receiver 641 may provide the internal bank group signal IBG and the internal bank address signal IBK to the respective row decoding circuits 620. The second address receiver 642 may receive the row address signal RADD transmitted from the interface circuit 230 through the address bus 261. The second address receiver 642 may receive the row address signal RADD to generate an internal row address signal IRADD. The second address receiver 642 may generate the internal row address signal IRADD having substantially the same characteristics as the row address signal RADD without changing the characteristics of the row address signal RADD. The second address receiver 642 may provide the internal row address signal IRADD to the respective row decoding circuits 620. The third address receiver 643 may receive the column address signal CADD transmitted from the interface circuit 230 through the address bus 261. The third address receiver 643 may receive the column address signal CADD to generate an internal column address signal ICADD. The third address receiver 643 may generate the internal column address signal ICADD having substantially the same characteristics as the column address signal CADD without changing the characteristics of the column address signal CADD. The third address receiver 643 may provide the internal column address signal ICADD to the respective column decoding circuits 630. The command receiver 644 may receive the command signal CMD transmitted from the interface circuit 230 through the command bus 262. The command receiver 644 may receive the command signal CMD to generate an internal command signal ICMD. The internal command signal ICMD may include an internal active command signal IACT, an internal row access command signal IRAS, an internal column access command signal ICAS, and an internal write enable signal IWE. The command receiver 644 may provide the internal command signal ICMD to the command control circuit 650. The clock receiver 645 may receive the memory clock signal pair MCK, MCKB transmitted from the interface circuit 230 through the memory clock bus 265. The clock receiver 645 may receive the memory clock signal pair MCK, MCKB to generate an internal clock signal pair IMCK, IMCKB.

The command control circuit 650 may receive the internal command signal ICMD and the internal memory clock signal pair IMCK, IMCKB. The command control circuit 650 may latch the internal command signal ICMD in synchronization with the internal memory clock signal pair IMCK, IMCKB. The command control circuit 650 may generate a conversion command signal CCMD based on the internal command signal ICMD. The command control circuit 650 may combine logic levels of at least one of the internal command signal ICMD to generate the conversion command signal CCMD. The conversion command signal CCMD may include at least an active signal ACTS, a write signal WTS, and a read signal RDS. The active signal ACTS may be a signal that instructs an active operation of the memory die 600, and the active operation may be an operation that selects and/or enables a row line of the memory cell array 610. The write signal WTS may be a signal that instructs a write operation of the memory die 600, and the write operation may be an operation of the memory die 600 storing the memory data signal DQ received through the memory data bus 263 into the memory cell array 610. The read signal RDS may be a signal that instructs a read operation of the memory die 600, and the read operation may be an operation of the memory die 600 outputting data stored in the memory cell array 610 as the memory data signal DQ through the memory data bus 263. The command control circuit 650 may delay the internal command signal ICMD by a time corresponding to a latency to generate the conversion command signal CCMD. The latency may refer to a delay time from when the memory die 600 receives the command signal CMD until the memory die 600 actually performs an operation directed by the command signal CMD. For example, the latency may include a CAS latency, a write latency, a read latency, or the like. The latency may be defined as an integer of one or more, and the latency of the command control circuit 650 according to the latency may be set to an integer multiple of a clock cycle of the memory clock signal pair MCK, MCKB. The command control circuit 650 may provide the conversion command signal CCMD to internal circuits of the memory die 600. The command control circuit 650 may provide the active signal ACTS to the respective row decoding circuits 620. The command control circuit 650 may provide the write signal WTS and the read signal RDS to the input/output driving circuit 660.

The input/output driving circuit 660 may be electrically connected to a plurality of column lines of the respective memory cell array 610 through each of the column decoding circuit 630. The input/output driving circuit 660 may receive the write signal WTS and the read signal RDS. Based on the write signal WTS, the input/output driving circuit 660 may provide internal data signals IDQ0, IDQ1, IDQ2, . . . , IDQm-1 (wherein m is an integer of 4 or more) transmitted through a global data line GIO to each of the memory cell array 610 through each of the column decoding circuit 630, and the internal data signals IDQ0, IDQ1, IDQ2, . . . , IDQm-1 may be stored in memory cells electrically connected with column lines accessed by the each of the column decoding circuit 630. The input/output driving circuit 660 may include a write driver circuit for providing the internal data signals IDQ0, IDQ1, IDQ2, . . . , IDQm-1 to the respective memory cell array 610 based on the write signal WTS. The input/output driving circuit 660 may receive data signal output from each of the memory cell array 610 based on the read signal RDS. The input/output driving circuit 660 may generate the internal data signals IDQ0, IDQ1, IDQ2, . . . , IDQm-1 by receiving output data signals output from the respective memory cell arrays 610 through the respective column decoding circuit 630. The input/output driving circuit 660 may output the internal data signals IDQ0, IDQ1, IDQ2, . . . , IDQm-1 through the global data line GIO. The input/output driving circuit 660 may include a read driver circuit for providing data signals output from the respective memory cell arrays 610 to the global data line GIO based on the read signal RDS. The input/output driving circuit 660 may operate based on the internal memory clock signal pair IMCK, IMCKB. The memory die 600 may further include an internal clock generation circuit 680. The internal clock generation circuit 680 may receive the internal memory clock signal pair IMCK, IMCKB, and may delay the internal memory clock signal pair IMCK, IMCKB to generate a delayed memory clock signal pair IMCKD, IMCKDB. The internal clock generation circuit 680 may provide the delayed memory clock signal pair IMCKD, IMCKDB to the input/output driving circuit 660, and the input/output driving circuit 660 may receive the internal data signals IDQ0, IDQ1, IDQ2, . . . , IDQm-1 in synchronization with the delayed memory clock signal pair IMCKD, IMCKDB, and may output the internal data signals IDQ0, IDQ1, IDQ2, . . . , IDQm-1 in synchronization with the delayed memory clock signal pair IMCKD, IMCKDB.

The input/output buffer circuit 670 may be electrically connected with the interface circuit 230 through the memory data bus 263, and may be electrically connected with the input/output driving circuit 660 through the global data line GIO. During the write operation, the input/output buffer circuit 670 may generate the internal data signals IDQ0, IDQ1, IDQ2, . . . IDQm-1 based on memory data signals DQ0, DQ1, DQ2, . . . , DQm-1 transmitted from the interface circuit 230 through the memory data bus 263, and output the internal data signals IDQ0, IDQ1, IDQ2, . . . , IDQm-1 to the global data line GIO. During the read operation, the input/output buffer circuit 670 receives the internal data signals IDQ0, IDQ1, IDQ2, . . . , IDQm-1 transmitted from the input/output driving circuit 660 through the global data line GIO, generate the memory data signals DQ0, DQ1, DQ2, . . . , DQm-1 based on the internal data signals IDQ0, IDQ1, DQ2, . . . , DQm-1, and transmit the memory data signals DQ0, DQ1, DQ2, . . . , DQm-1 to the interface circuit 230 through the memory data bus 263. The input/output buffer circuit 670 may buffer the memory data signals DQ0, DQ1, DQ2, . . . , DQm-1 during the write operation to generate the internal data signals IDQ0, IDQ1, IDQ2, . . . , IDQm-1, and buffer the internal data signals IDQ0, IDQ1, IDQ2, . . . , IDQm-1 during the read operation to generate the memory data signals DQ0, DQ1, DQ2, . . . , DQm-1. The internal data signals IDQ0, IDQ1, IDQ2, . . . , IDQm-1 and the memory data signals DQ0, DQ1, DQ2, . . . , DQm-1 may be data signals of substantially the same type or of the same characteristics, and the type or characteristics of the internal data signals IDQ0, IDQ1, IDQ2, . . . , IDQm-1 and the memory data signals DQ0, DQ1, DQ2, . . . , DQm-1 might not be changed by the input/output buffer circuit 670.

For example, the internal data signals IDQ0, IDQ1, IDQ2, . . . , IDQm-1 and the memory data signals DQ0, DQ1, DQ2, . . . , DQm-1 may be parallel data signals having the same number of bits. The number of signal transmission lines included in the global data line GIO may be substantially the same as the number of signal transmission lines included in the memory data bus 263. A width of the data signal stored in each of the memory cell array 610 through a single write operation may be substantially the same as a width of the internal data signals IDQ0, IDQ1, IDQ2, . . . , IDQm-1 and a width of the memory data signals DQ0, DQ1, DQ2, . . . , DQm-1. A width of the data signal output from each of the memory cell array 610 in a single read operation may be substantially the same as a width of the internal data signals IDQ0, IDQ1, IDQ2, . . . , IDQm-1 and a width of the memory data signals DQ0, DQ1, DQ2, . . . , DQm-1. A width of the data signal may mean the number and/or the number of bits of the data signal. The input/output buffer circuit 670 may receive the write data strobe signal WDQS and generate the read data strobe signal RDQS. During the write operation, the input/output buffer circuit 670 may receive the write data strobe signal WDQS from the interface circuit 230 shown in FIG. 2, and may receive the memory data signals DQ0, DQ1, DQ2, . . . , DQm-1 transmitted from the interface circuit 230 in synchronization with the write data strobe signal WDQS. During the read operation, the input/output buffer circuit 670 may generate the read data strobe signal RDQS based on the write data strobe signal WDQS. The input/output buffer circuit 670 may output the memory data signals DQ0, DQ1, DQ2, . . . , DQm-1 to the interface circuit 230 in synchronization with the read data strobe signal RDQS. The input/output buffer circuit 670 may output the read data strobe signal RDQS along with the memory data signals DQ0, DQ1, DQ2, . . . , DQm-1 to the interface circuit 230. The input/output buffer circuit 670 may further receive the write selection signal WTEN and the read selection signal RDEN. The input/output buffer circuit 670 may activate a write path of the input/output buffer circuit 670 based on the write selection signal WTEN and may activate a read path of the input/output buffer circuit 670 based on the read selection signal RDEN. For example, the input/output buffer circuit 670 may include a transmitter for outputting the memory data signals DQ0, DQ1, DQ2, . . . , DQm-1 to the interface circuit 230 and a receiver for receiving the memory data signals DQ0, DQ1, DQ2, . . . , DQm-1 transmitted from the interface circuit 230. The transmitter of the input/output buffer circuit 670 may be activated based on the write selection signal WTEN. The receiver of the input/output buffer circuit 670 may be activated based on the read selection signal RDEN.

Because the memory die 600 receives the row address signal RADD and the column address signal CADD from the interface circuit 230, the memory die 600 might not have circuits for converting the address signal ADD to the row address signal RADD and the column address signal CADD according to the command signal CMD and for latching the converted address signals. For example, the input/output buffer circuit 670 might not include a SerDes to serialize the internal data signals IDQ0, IDQ1, IDQ2, . . . , IDQm-1 or to deserialize the memory data signals DQ0, DQ1, DQ2, . . . , DQm-1. With a large number of removable circuits, the memory die 600 may have a larger data storage capacity compared to a conventional memory die, and the memory die 600 may be smaller than a conventional memory die while maintaining the same data storage capacity. Furthermore, when the input/output buffer circuit 670 does not perform serialization and deserialization operations on data signals, timing delay of the command control circuit 650, that is, latencies of the memory die 600 and a memory apparatus including the memory die 600, may be very short compared to a conventional memory die and memory apparatus. Thus, the memory die 600 can perform a write operation and a read operation on more data signals in a shorter time period compared with a conventional device.

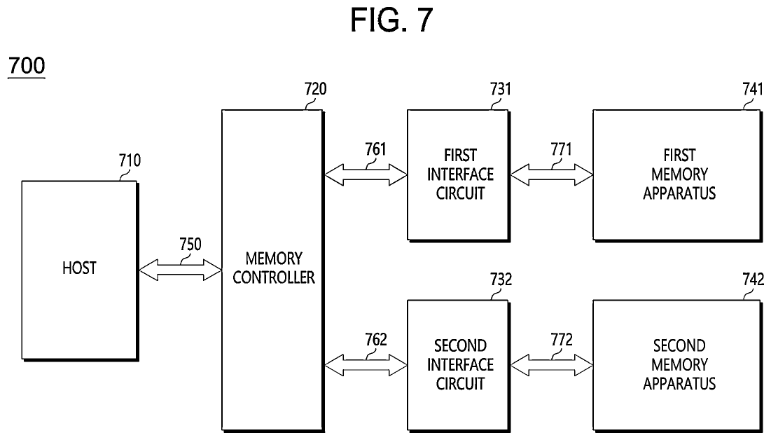

FIG. 7 is a diagram illustrating a configuration of a computing system 700 according to an embodiment of the present disclosure. Referring to FIG. 7, the computing system 700 may include a host 710, a memory controller 720, a first interface circuit 731, a second interface circuit 732, a first memory apparatus 741, and a second memory apparatus 742. The host 710 may be electrically connected to the memory controller 720 through a host bus 750. The memory controller 720 may be electrically connected to the first interface circuit 731 through a first controller bus 761, and may be electrically connected to the second interface circuit 732 through a second controller bus 762. The first interface circuit 731 may be electrically connected to the first memory apparatus 741 through a first memory bus 771. The second interface circuit 732 may be electrically connected to the second memory apparatus 742 through a second memory bus 772. The host 710 may have substantially the same configuration as the host 110 illustrated in FIG. 1 and may perform substantially the same functions. The memory controller 720 may have substantially the same configuration and perform substantially the same functions as the memory controller 120 shown in FIG. 1. However, the memory controller 720 may be electrically connected to first and second controller buses 761, 762 to enable data communication with a plurality of memory apparatuses. The host 710 may access any one of the first and second memory apparatuses 741, 742 or may access both the first and second memory apparatuses 741, 742 simultaneously through the memory controller 720 and the first and second controller buses 761, 762. The host 710 may independently generate an access request for the first memory apparatus 741 and an access request for the second memory apparatus 742 to access the first and second memory apparatuses 741, 742 separately or simultaneously. The memory controller 720 may independently generate a control signal for accessing the first memory apparatus 741 and a control signal for accessing the second memory apparatus 742 to access the first and second memory apparatuses 741, 742 separately or simultaneously.

The host bus 750 may have substantially the same type and characteristics as the first bus 150 illustrated in FIG. 1. The first controller bus 761 may have substantially the same type and characteristics as the second bus 160 shown in FIG. 1. The first memory bus 771 may have substantially the same type and characteristics as the third bus 170 shown in FIG. 1. In an embodiment, a width of the data bus included in the first controller bus 761 may be less than or equal to a width of the data bus included in the first memory bus 771. The first interface circuit 731 may have substantially the same configuration and perform substantially the same functions as the interface circuits 130, 230 illustrated in FIGS. 1 and 2. The first memory apparatus 741 may have substantially the same configuration and perform substantially the same functions as the memory apparatuses 140, 240 shown in FIGS. 1 and 2.

The second controller bus 762 may have substantially the same type and characteristics as the first controller bus 761. The second memory bus 772 may have substantially the same type and characteristics as the first memory bus 771. In an embodiment, a width of the data bus included in the second controller bus 762 may be less than or equal to a width of the data bus included in the second memory bus 772. The second interface circuit 732 may have substantially the same configuration as the first interface circuit 731 and may perform substantially the same functions. The second memory apparatus 742 may have substantially the same configuration as the first memory apparatus 741 and may perform substantially the same functions.

In an embodiment, the second memory bus 772 may have a different type and characteristics than the first memory bus 771. For example, the second memory bus 772 may include a serial data bus. A width of the data bus included in the second memory bus 772 may be less than a width of the data bus included in the second controller bus 762. A clock rate of the second memory bus 772 may be higher than a clock rate of the second controller bus 762. In this case, the second interface circuit 732 may have a different configuration than the first interface circuit 731 and perform different functions, and the second memory apparatus 742 may have a different configuration than the first memory apparatus 741 and perform different functions. For example, the first interface circuit 731 and the first memory apparatus 741 may perform parallel data communication, while the second interface circuit 732 and the second memory apparatus 742 may perform serial data communication. The first interface circuit 731 and the first memory apparatus 741 do not need to perform data conversion, and therefore might not be equipped with a SerDes. The second interface circuit 732 and the second memory apparatus 742 need to perform data conversion for serial data communication, and therefore may include a SerDes.

In an embodiment, the host 710, the memory controller 720, the first interface circuit 731 and the second interface circuit 732 may be integrated into a first device, and the first memory apparatus 741 and the second memory apparatus 742 may be integrated into a second device. Alternatively, the first memory apparatus 741 may constitute the second device and the second memory apparatus 742 may constitute a third device. The host 710, the memory controller 720, the first interface circuit 731, and the second interface circuit 732 may be disposed on a first interposer and/or a first substrate. The first and second memory apparatuses 741, 742 may be disposed on a second interposer and/or a second substrate. The host bus 750, the first and second controller buses 761, 762 may be internal buses, and the first and second memory buses 771, 772 may be external buses. In an embodiment, the first memory apparatus 741 may be disposed on a second interposer and/or a second substrate, and the second memory apparatus 742 may be disposed on a third interposer and/or a third substrate.

In an embodiment, the host 710 and the memory controller 720 may be integrated into a first device, and the first and second interface circuits 731, 732 and the first and second memory apparatuses 741, 742 may be integrated into a second device. Alternatively, the first interface circuit 731 and the first memory apparatus 741 may be integrated into a second device, and the second interface circuit 732 and the second memory apparatus 742 may be integrated into a third device. The host 710 and the memory controller 720 may be disposed on a first interposer and/or a first substrate. The first interface circuit 731, the second interface circuit 732, the first memory apparatus 741, and the second memory apparatus 742 may be disposed on a second interposer and/or a second substrate. The host bus 750, the first memory bus 771 and the second memory bus 772 may be internal buses, and the first and second controller buses 761, 762 may be external buses. In an embodiment, the first interface circuit 731 and the first memory apparatus 741 may be disposed on a second interposer and/or a second substrate, and the second interface circuit 732 and the second memory apparatus 742 may be disposed on a third interposer and/or a third substrate.

In an embodiment, the host 710 may constitute a first device, and the memory controller 720, the first and second interface circuits 731, 732, and the first and second memory apparatuses 741, 742 may be integrated into a second device. The host 710 may be disposed on a first interposer and/or a first substrate. The memory controller 720, the first interface circuit 731, the second interface circuit 732, the first memory apparatus 741, and the second memory apparatus 742 may be disposed on a second interposer and/or a second substrate. The host bus 750 may be an external bus, the first and second controller buses 761, 762, and the first and second memory buses 771, 772 may be internal buses. In an embodiment, the host 710, the memory controller 720, the first and second interface circuits 731, 732, and the first and second memory apparatuses 741, 742 may be disposed on a single interposer and/or a single substrate. The host bus 750, the first and second controller buses 761, 762, and the first and second memory buses 771, 772 may all be internal buses. In an embodiment, some or all of the host 710, the memory controller 720, the first and second interface circuits 731, 732, and the first and second memory apparatuses 741, 742 may be manufactured as chiplets.

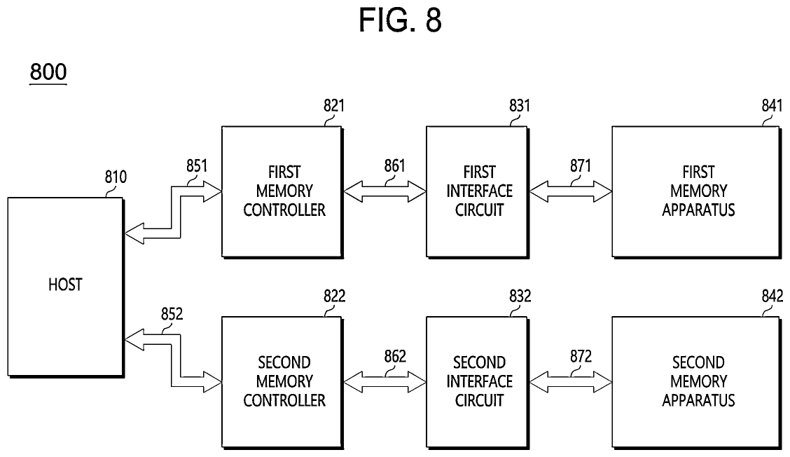

FIG. 8 is a diagram illustrating a configuration of a computing system 800 according to an embodiment of the present disclosure. Referring to FIG. 8, the computing system 800 may include a host 810, a first memory controller 821, a second memory controller 822, a first interface circuit 831, a second interface circuit 832, a first memory apparatus 841, and a second memory apparatus 842. The first memory controller 821 may be electrically connected to the host 810 through a first host bus 851. The second memory controller 822 may be electrically connected to the host 810 through a second host bus 852. The first interface circuit 831 may be electrically connected to the first memory controller 821 through a first controller bus 861. The second interface circuit 832 may be electrically connected to the second memory controller 822 through a second controller bus 862. The first memory apparatus 841 may be electrically connected to the first interface circuit 831 through a first memory bus 871. The second memory apparatus 842 may be electrically connected to the second interface circuit 832 through a second memory bus 872. The host 810 may be independently electrically connected with the first and second memory controllers 821, 822 for independent access to the first and second memory apparatuses 841, 842. The host 810 may independently generate a first access request to the first memory apparatus 841 and a second access request to the second memory apparatus 842. In an embodiment, the host 810 may include a plurality of processor cores to independently generate the first and second access requests. The host 810 may provide the first access request to the first memory controller 821 through the first host bus 851, and may provide the second access request to the second memory controller 822 through the second host bus 852.

The first host bus 851 and the second host bus 852 may each have substantially the same type and characteristics as the first bus 150 illustrated in FIG. 1. The first controller bus 861 and the second controller bus 862 may each have substantially the same type and characteristics as the second bus 160 shown in FIG. 1. The first memory bus 871 may have substantially the same type and characteristics as the third bus 170 shown in FIG. 1. In an embodiment, a width of the data bus included in the first controller bus 861 may be less than or equal to a width of the data bus included in the first memory bus 871. The first interface circuit 831 may have substantially the same configuration and perform substantially the same functions as the interface circuits 130, 230 illustrated in FIGS. 1 and 2. The first memory apparatus 841 may have substantially the same configuration and perform substantially the same functions as the memory apparatuses 140, 240 shown in FIGS. 1 and 2.

The second controller bus 862 may have substantially the same type and characteristics as the first controller bus 861. The second memory bus 872 may have substantially the same type and characteristics as the first memory bus 871. In an embodiment, a width of the data bus included in the second controller bus 862 may be less than or equal to a width of the data bus included in the second memory bus 872. The second interface circuit 832 may have substantially the same configuration as the first interface circuit 831 and may perform substantially the same functions. The second memory apparatus 842 may have substantially the same configuration as the first memory apparatus 841 and may perform substantially the same functions. In an embodiment, the second memory bus 872 may have a different type and characteristics than the first memory bus 871. For example, the second memory bus 872 may include a serial data bus. A width of the data bus included in the second memory bus 872 may be less than a width of the data bus included in the second controller bus 862. A clock rate of the second memory bus 872 may be higher than a clock rate of the second controller bus 862. In this case, the second interface circuit 832 may have a different configuration than the first interface circuit 831 and perform different functions, and the second memory apparatus 842 may have a different configuration than the first memory apparatus 841 and perform different functions. For example, the first interface circuit 831 and the first memory apparatus 841 may perform parallel data communication, while the second interface circuit 832 and the second memory apparatus 842 may perform serial data communication. The first interface circuit 831 and the first memory apparatus 841 do not need to perform data conversion, and therefore might not be equipped with a SerDes. The second interface circuit 832 and the second memory apparatus 842 need to perform data conversion for serial data communication, and therefore may include a SerDes.

In an embodiment, the host 810, the first memory controller 821, the second memory controller 822, the first interface circuit 831, and the second interface circuit 832 may be integrated into a first device. The first and second memory apparatuses 841, 842 may be integrated into a second device. Alternatively, the first memory apparatus 841 may constitute a second device, and the second memory apparatus 842 may constitute a third device. The host 810, the first and second memory controllers 821, 822, and the first and second interface circuits 831, 832 may be disposed on a first interposer and/or a first substrate. The first and second memory apparatuses 841, 842 may be disposed on a second interposer and/or a second substrate. The first and second host buses 851, 852, the first and second controller buses 861, 862 may be internal buses, and the first and second memory buses 871, 872 may be external buses. In an embodiment, the first memory apparatus 841 may be disposed on a second interposer and/or a second substrate, and the second memory apparatus 842 may be disposed on a third interposer and/or a third substrate.

In an embodiment, the host 810, the first and second memory controllers 821, 822 may be integrated into a first device. The first and second interface circuits 831, 832, the first and second memory apparatuses 841, 842 may be integrated into a second device. Alternatively, the first interface circuit 831 and the first memory apparatus 841 may be integrated into a second device, and the second interface circuit 832 and the second memory apparatus 842 may be integrated into a third device. The host 810, the first and second memory controllers 821, 822 may be disposed on a first interposer and/or a first substrate. The first and second interface circuits 831, 832, the first and second memory apparatuses 841, 842 may be disposed on a second interposer and/or a second substrate. The first and second host buses 851, 852, the first and second memory buses 871, 872 may be internal buses, and the first and second controller buses 861, 862 may be external buses. In an embodiment, the first interface circuit 831 and the first memory apparatus 841 may be disposed on a second interposer and/or a second substrate, and the second interface circuit 832 and the second memory apparatus 842 may be disposed on a third interposer and/or a third substrate.

In an embodiment, the host 810 may constitute a first device, and the first and second memory controllers 821, 822, the first and second interface circuits 831, 832, and the first and second memory apparatuses 841, 842 may be integrated into a second device. Alternatively, the first memory controller 821, the first interface circuit 831 and the first memory apparatus 841 may be integrated into a second device, and the second memory controller 822, the second interface circuit 832 and the second memory apparatus 842 may be integrated into a third device. The host 810 may be disposed on a first interposer and/or a first substrate. The first and second memory controllers 821, 822, the first and second interface circuits 831, 832, and the first and second memory apparatuses 841, 842 may be disposed on a second interposer and/or a second substrate. The first and second host buses 851, 852 may be external buses, and the first and second controller buses 861, 862 and the first and second memory buses 871, 872 may be internal buses. In an embodiment, the first memory controller 821, the first interface circuit 831 and the first memory apparatus 841 may be disposed on a second interposer and/or a second substrate, and the second memory controller 822, the second interface circuit 832 and the second memory apparatus 842 may be disposed on a third interposer and/or a third substrate.

In an embodiment, the host 810, the first and second memory controllers 821, 822, the first and second interface circuits 831, 832, and the first and second memory apparatuses 841, 842 may be disposed on a single interposer and/or a single substrate. The first and second host buses 851, 852, the first and second controller buses 861, 862, and the first and second memory buses 871, 872 may all be internal buses. In an embodiment, some or all of the host 810, the first and second memory controllers 821, 822, the first and second interface circuits 831, 832, and the first and second memory apparatuses 841, 842 may be manufactured as chiplets.

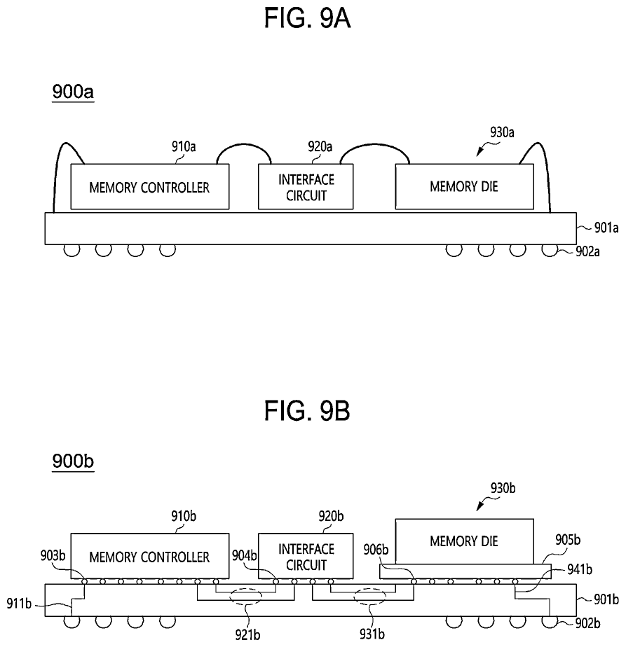

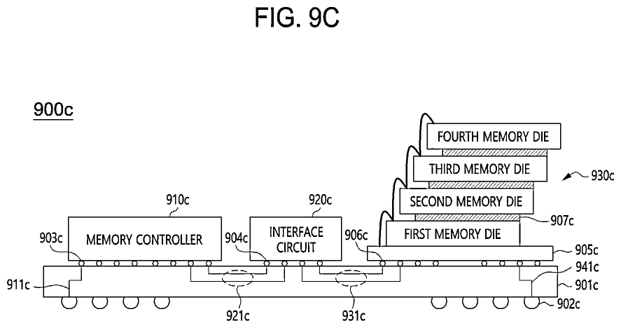

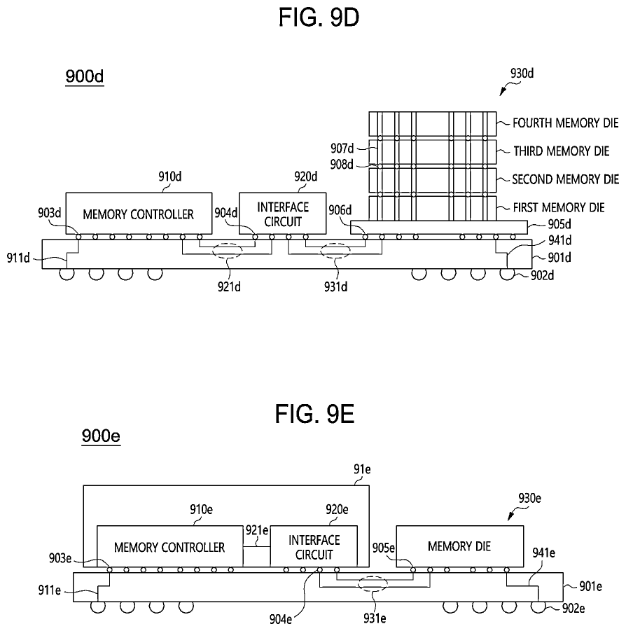

FIG. 9A is a diagram illustrating a configuration and connection relationship of an integrated circuit package 900a according to an embodiment of the present disclosure. Referring to FIG. 9A, the integrated circuit package may include a substrate 901a, a memory controller 910a, an interface circuit 920a, and a memory apparatus 930a. The memory controller 910a, the interface circuit 920a, and the memory apparatus 930a may be manufactured as separate dies and/or chiplets. Some or all of the memory controller 910a, the interface circuit 920a, and the memory apparatus 930a may be manufactured using process technologies with different characteristics. The memory controller 910a, the interface circuit 920a, and the memory apparatus 930a may be disposed on the substrate 901a. The memory controller 910a may be disposed in a first region on the substrate 901a. The interface circuit 920a may be disposed in a second region on the substrate 901a. The memory apparatus 930a may be disposed in a third region on the substrate 901a. The first and third regions might not overlap, and the second region may be between the first and third regions. The memory apparatus 930a is illustrated to include a single memory die. For example, the memory controller 910a, the interface circuit 920a, and the memory apparatus 930a may be attached to the substrate 901a using an adhesive. The substrate 901a may include any substrate having pads capable of wire bonding, and may be one of, for example, a package substrate, an organic substrate, and a module substrate. The substrate 901a may include external terminals 902a underneath the substrate that are used to electrically connect with external devices. The external terminals 902a may include solder balls or package balls.

The memory controller 910a may be electrically connected to the substrate 901a by wire bonding a pad formed on a first side (e.g., a left side in FIG. 9A) Tof the memory controller 910a to a pad formed on the substrate 901a. The wire bonding between the memory controller 910a and the substrate 901a may be a first wire bonding. The memory controller 910a may be electrically connected to the interface circuit 920a by wire bonding a pad formed on a second side (e.g., a right side in FIG. 9A) of the memory controller 910a to a pad formed on a first side of the interface circuit 920a. The wire bonding between the memory controller 910a and the interface circuit 920a may be a second wire bonding. The interface circuit 920a may be electrically connected to the memory apparatus 930a by wire bonding a pad formed on a second side of the interface circuit 920a to a pad formed on a first side of the memory apparatus 930a. The wire bonding between the interface circuit 920a and the memory apparatus 930a may be a third wire bonding. The memory apparatus 930a may be electrically connected to the substrate 901a by wire bonding a pad formed on a second side of the memory apparatus 930a to a pad formed on the substrate 901a. The wire bonding between the memory apparatus 930a and the substrate 901a may be a fourth wire bonding. The substrate 901a, the memory controller 910a, the interface circuit 920a, and the memory apparatus 930a may be packaged in a single package. Because the memory controller 910a, the interface circuit 920a, and the memory apparatus 930a are electrically connected by wire bonding, a low-cost substrate can be used and the manufacturing cost of an integrated circuit package can be reduced. The first wire bonding between the memory controller 910a and the substrate 901a may correspond to some or all of the first bus 150 shown in FIG. 1. The second wire bonding between the memory controller 910a and the interface circuit 920a may correspond to the second bus 160 shown in FIG. 1. The third wire bonding between the interface circuit 920a and the memory apparatus 930a may correspond to the third bus 170 shown in FIG. 1. The fourth wire bonding between the memory apparatus 930a and the substrate 901a may correspond to a direct access path for the external device to access the memory apparatus 930a. A frequency of signal transmitted through the second wire bonding may be greater than or equal to a frequency of signal transmitted through the third wire bonding. A frequency of signal transmitted through a wire bonding may be related to a clock rate or a clock frequency. The signal may be transmitted at a first clock rate through the second wire bonding, and the signal may be transmitted at a second clock rate through the third wire bonding. The first clock rate may be greater than or equal to the second clock rate. The second wire bonding may include a first data bus, and the third wire bonding may include a second data bus. The number of data signals transmitted at one time through the first data bus may be less than or equal to the number of data signals transmitted at one time through the second data bus.

FIG. 9B is a diagram illustrating a configuration and connection relationship of an integrated circuit package 900b according to an embodiment of the present disclosure. Referring to FIG. 9B, the integrated circuit package 900b may include a first substrate 901b, a memory controller 910b, an interface circuit 920b, and a memory apparatus 930b. The memory controller 910b, the interface circuit 920b, and the memory apparatus 930b may be disposed on the first substrate 901b. The first substrate 901b may include an interposer. The memory controller 910b may be disposed in a first region on the first substrate 901b. The interface circuit 920b may be disposed in a second region on the first substrate 901b. The memory apparatus 930b may be disposed in a third region on the first substrate 901b. The first and third regions might not overlap, and the second region may be between the first and third regions. The memory apparatus 930b is illustrated to include a single memory die. The integrated circuit package 900b may further include a second substrate 905b. The second substrate 905b may include a redistribution layer or interposer. The second substrate 905b may be provided to electrical connect the memory apparatus 930b and the first substrate 901b, and the second substrate 905b may be disposed on the first substrate 901b. The second substrate 905b may be disposed in the third region of the first substrate 901b. The second substrate 905b may include a plurality of signal paths for electrically connecting the memory apparatus 930b to the first substrate 901b. The memory apparatus 930b may be disposed on the second substrate 905b. When the second substrate 905b is an interposer, the memory apparatus 930b may be electrically connected to the second substrate 905b through microbumps. When the second substrate 905b is a redistribution layer, the memory apparatus 930b may be electrically connected to the second substrate 905b through microbumps, or may be electrically connected to the second substrate 905b without microbumps. In an embodiment, the memory apparatus 930b may be directly electrically connected to the first substrate 901b without the second substrate 905b. The first substrate 901b may include external terminals 902b underneath the first substrate 901b that are used to electrically connect with external devices. The external terminals 902b may include microbumps or bumps. In an embodiment, the integrated circuit package 900b may further include another substrate, and the first substrate 901b may be disposed on the another substrate. The another substrate may include another interposer or package substrate. When the another substrate is provided, the first substrate 901b may be electrically connected to the another substrate through microbumps or bumps and may be electrically connected to the external devices through the another substrate.

The first substrate 901b may include a plurality of signal paths 911b, 921b, 931b, 941b used to electrically connect components disposed on the first substrate 901b. The memory controller 910b may be electrically connected to the first substrate 901b through microbumps 903b. The interface circuit 920b may be electrically connected to the first substrate 901b through microbumps 904b. The memory apparatus 930b may be electrically connected with first substrate 901b through microbumps 906b. The memory controller 910b may be electrically connected to the signal path 911b of the first substrate 901b and the external terminals 902b through a microbump 903b at a first side of the memory controller 910b. Through the microbumps 903b at a second side of the memory controller 910b, the memory controller 910b may be electrically connected with microbumps 904b at a first side of the interface circuit 920b and the signal path 921b of the first substrate 901b. The interface circuit 920b may be electrically connected with microbumps 906b at a first side of the second substrate 905b through the microbumps 904b at a second side of the interface circuit 920b and the signal path 931b of the first substrate 901b. The memory apparatus 930b may be electrically connected with the external terminals 902b through a microbump 906b at a second side of the second substrate 905b and the signal path 941b of the first substrate 901b.

The first substrate 901b, the memory controller 910b, the interface circuit 920b, and the memory apparatus 930b may be packaged in a single package. Disposing the memory controller 910b, the interface circuit 920b, and the memory apparatus 930b on the first substrate 901b may facilitate integrated circuit package manufacturing and reduce integrated circuit package size because wire bonding is not required. The electrical connection between the memory controller 910b and the signal path 911b of the first substrate 901b may correspond to some or all of the first bus 150 shown in FIG. 1. The signal path 921b of the first substrate 901b electrically connecting the memory controller 910b and the interface circuit 920b may correspond to the second bus 160 shown in FIG. 1. The signal path 931b of the first substrate 901b electrically connecting the interface circuit 920b and the memory apparatus 930b may correspond to the third bus 170 shown in FIG. 1. The electrical connection between the memory apparatus 930b and the signal path 941b of the first substrate 901b may correspond to a direct access path to the memory apparatus 930b. A frequency of signal transmitted through the signal path 921b may be greater than or equal to a frequency of signal transmitted through the signal path 931b. The signal may be transmitted at a first clock rate through the signal path 921b, and the signal may be transmitted at a second clock rate through the signal path 931b. The first clock rate may be greater than or equal to the second clock rate. The signal path 921b may include a first data bus, and the signal path 931b may include a second data bus. The number of data signals transmitted at one time through the first data bus may be less than or equal to the number of data signals transmitted at one time through the second data bus.

FIG. 9C is a diagram illustrating a configuration and connection relationship of an integrated circuit package 900c according to an embodiment of the present disclosure. Referring to FIG. 9C, the integrated circuit package 900c may include a first substrate 901c, a memory controller 910c, an interface circuit 920c, and a memory apparatus 930c. The memory controller 910c, the interface circuit 920c, and the memory apparatus 930c may be disposed on the first substrate 901c. The first substrate 901c may include an interposer. The memory controller 910c may be disposed in a firstregion on the first substrate 901c. The interface circuit 920c may be disposed in a second region on the first substrate 901c. The memory apparatus 930c may be disposed in a third region on the first substrate 901c. The first and third regions might not overlap, and the second region may be between the first and third regions. The memory apparatus 930c may include one or more memory dies. The number of memory dies included by the memory apparatus 930c may be two, four, eight, or more. For example, the memory apparatus 930c may include first to fourth memory dies. The number of memory dies that the memory apparatus 930c includes may be two, or may be eight or more. The integrated circuit package 900c may further include a second substrate 905c. The second substrate 905c may include a redistribution layer or interposer. The second substrate 905c may be provided for electrically connecting the memory apparatus 930c and the first substrate 901c, and the second substrate 905c may be disposed on the first substrate 901c. The second substrate 905c may be disposed in the third region of the first substrate 901c. The second substrate 905c may include a plurality of signal paths for electrically connecting the memory apparatus 930c to the first substrate 901c. The first to fourth memory dies may be disposed on the second substrate 905c. The memory controller 910c may be electrically connected to the first substrate 901c through microbumps 903c. The interface circuit 920c may be electrically connected to the first substrate 901c through microbumps 904c. The second substrate 905c may be electrically connected with the first substrate 901c through microbumps 906c. The first substrate 901c may include external terminals 902c underneath the first substrate 901c that are used to electrically connect with external devices. The external terminals 902c may include microbumps or bumps. In an embodiment, the integrated circuit package 900c may further include another substrate, and the first substrate 901c may be disposed on the another substrate. The another substrate may include another interposer or package substrate. When the another substrate is provided, the first substrate 901c may be electrically connected to the another substrate through microbumps or bumps and may be electrically connected to the external devices through the another substrate.

The memory controller 910c may be electrically connected to a signal path 911c of the first substrate 901c and external terminals 902c through a microbump 903c at a first side of the memory controller 910c. Through the microbumps 903c at a second side of the memory controller 910c, the memory controller 910c may be electrically connected with the microbumps 904c at a first side of the interface circuit 920c and a signal path 921c of the first substrate 901c. The interface circuit 920c may be electrically connected with the microbumps 906c at a first side of the second substrate 905c through the microbumps 904c at a second side of the interface circuit 920c and a signal path 931c of the first substrate 901c. The second substrate 905c may be electrically connected to the external terminals 902c through the microbumps 906c at a second side of the second substrate 905c and a signal path 941c of the first substrate 901c. The first to fourth memory dies may be stacked sequentially on the second substrate 905c. A DAF (die attached film) 907c may be provided between the first memory die and the second memory die, between the second memory die and the third memory die, and between the third memory die and the fourth memory die, respectively, and the first to fourth memory dies may be adhered using the DAF 907c. The DAF 907c may increase the strength of the memory die to prevent the memory die from warping and allow space for wire bonding. The first to fourth memory dies may be stacked in a stepwise manner. The pads of the fourth memory die may be wire bonded to the pads of the third memory die, and the pads of the third memory die may be wire bonded to the pads of the second memory die. The pads of the second memory die may be wire bonded with the pads of the first memory die, and the pads of the first memory die may be wire bonded with the pads formed on the second substrate 905c. In an embodiment, the pads of the first memory die may be wire bonded to the pads formed on the second substrate 905c, and the pads of the second memory die may be wire bonded to the pads formed on the second substrate 905c. The pads of the third memory die may be wire bonded to the pads formed on the second substrate 905c, and the pads of the fourth memory die may be wire bonded to pads formed on the second substrate 905c. The pads of the first and fourth memory dies may be common wire bonded to the same pads on the second substrate 905c, and the first and fourth memory dies may form a common channel. In an embodiment, the pads of the first to fourth memory dies may be wire bonded to different pads of the second substrate 905c, and the first to fourth memory dies may form channels independent of each other.

The first substrate 901c, the memory controller 910c, the interface circuit 920c, and the memory apparatus 930c may be packaged in a single package. The signal path 911c between the memory controller 910c and the first substrate 901c may correspond to some or all of the first bus 150 shown in FIG. 1. The signal path 921c of the first substrate 901c electrically connecting the memory controller 910c and the interface circuit 920c may correspond to the second bus 160 shown in FIG. 1. The signal path 931c of the first substrate 901c electrically connecting the interface circuit 920c and the second substrate 905c. and the wire bondings electrically connecting the second substrate 905c and the first to fourth memory dies, may correspond to the third bus 170 shown in FIG. 1. The signal path 941c of the first substrate 901c may correspond to a direct access path to the memory apparatus 930c. A frequency of signal transmitted through the signal path 921c may be greater than or equal to a frequency of signal transmitted through the signal path 931c. The signal may be transmitted at a first clock rate through the signal path 921c, and the signal may be transmitted at a second clock rate through the signal path 931c. The first clock rate may be greater than or equal to the second clock rate. The signal path 921c may include a first data bus, and the signal path 931c may include a second data bus. The number of data signals transmitted at one time through the first data bus may be less than or equal to the number of data signals transmitted at one time through the second data bus.

FIG. 9D is a diagram illustrating a configuration and connection relationship of an integrated circuit package 900d according to an embodiment of the present disclosure. Referring to FIG. 9D, the integrated circuit package 900d may include a first substrate 901d, a memory controller 910d, an interface circuit 920d, and a memory apparatus 930d. The memory controller 910d, the interface circuit 920d, and the memory apparatus 930d may be disposed on the first substrate 901d. The first substrate 901d may include an interposer. The memory controller 910d may be disposed in a first region on the first substrate 901d. The interface circuit 920d may be disposed in a second region on the first substrate 901d. The memory apparatus 930d may be disposed in a third region on the first substrate 901d. The first and third regions might not overlap, and the second region may be between the first and third regions. The memory apparatus 930d may include one or more memory dies. The number of memory dies included by the memory apparatus 930d may be two, four, eight, or more. For example, the memory apparatus 930d may include first to fourth memory dies. The integrated circuit package 900d may further include a second substrate 905d. The second substrate 905d may include a redistribution layer or an interposer. The second substrate 905d may be provided for electrically connecting the memory apparatus 930c and the first substrate 901d, and the second substrate 905d may be disposed on the first substrate 901d. The second substrate 905d may be disposed in the third region of the first substrate 901d. The second substrate 905d may include a plurality of signal paths for electrically connecting the memory apparatus 930d to the first substrate 901d. The first to fourth memory dies may be stacked on the second substrate 905d. The first substrate 901d may include external terminals 902d underneath the first substrate 901d that are used to electrically connect with external devices. The external terminals 902d may include microbumps or bumps. In an embodiment, the integrated circuit package 900d may further include another substrate, and the first substrate 901d may be disposed on the another substrate. The another substrate may include another interposer or package substrate. When the another substrate is provided, the first substrate 901d may be electrically connected to the another substrate through microbumps or bumps and electrically connected to the external devices through the another substrate.

The memory controller 910d may be electrically connected to the first substrate 901d through microbumps 903d. The interface circuit 920d may be electrically connected with the first substrate 901d through microbumps 904d. The second substrate 905d may be electrically connected with the first substrate 901d through microbumps 906d. The memory controller 910d may be electrically connected with a signal path 911d and external terminals 902d of the first substrate 901d through a microbump 903d at a first side of the memory controller 910d. Through the microbumps 903d at a second side of the memory controller 910d, the memory controller 910d may be electrically connected with the microbumps 904d at a first side of the interface circuit 920d and a signal path 921d of the first substrate 901d. Through the microbumps 904d at a second side of the interface circuit 920d, the interface circuit 920d may be electrically connected with the microbumps 906d at a first side of the second substrate 905d and a signal path 931d of the first substrate 901d. Through microbumps 906d at the second side of the second substrate 905d, the second substrate 905d may be electrically connected to the external terminals 902d and a signal path 941d of the first substrate 901d. The first to fourth memory dies may be stacked sequentially on the second substrate 905d. The first to fourth memory dies may be vertically aligned and stacked. Through vias 907d may be formed in the first to fourth memory dies, and the first to fourth memory dies may be electrically connected to each other through the through vias 907d and microbumps 908d. When the first to fourth memory dies are electrically connected through the through vias 907d, the first to fourth memory dies need not be stacked in a stepwise manner as shown in FIG. 9C, but may be stacked in a vertically aligned manner. Accordingly, the area of the second substrate 905d and the integrated circuit package size may be reduced. The first to fourth memory dies may be electrically connected with a common signal path of the second substrate 905d, and the first to fourth memory dies may form a common channel. In an embodiment, the first to fourth memory dies may be electrically connected with different signal paths to the second substrate 905d, and the first to fourth memory dies may form channels independent of each other.

The first substrate 901d, the memory controller 910d, the interface circuit 920d and the memory apparatus 930d may be packaged in a single package. The signal path 911d between the memory controller 910d and the first substrate 901d may correspond to some or all of the first bus 150 shown in FIG. 1. The signal path 921d of the first substrate 901d electrically connecting the memory controller 910d and the interface circuit 920d may correspond to the second bus 160 shown in FIG. 1. The signal path 931d of the first substrate 901d electrically connecting the interface circuit 920d, and the second substrate 905d, and the microbumps 908d and through vias 907d electrically connecting the second substrate 905d and the first to fourth memory dies may correspond to the third bus 170 shown in FIG. 1. The signal path 941d of the first substrate 901d may correspond to a direct access path to the memory apparatus 930d. A frequency of signal transmitted through the signal path 921d may be greater than or equal to a frequency of signal transmitted through the signal path 931d. The signal may be transmitted at a first clock rate through the signal path 921d, and the signal may be transmitted at a second clock rate through the signal path 931d. The first clock rate may be greater than or equal to the second clock rate. The signal path 921d may include a first data bus, and the signal path 931d may include a second data bus. The number of data signals transmitted at one time through the first data bus may be less than or equal to the number of data signals transmitted at one time through the second data bus.

FIG. 9E is a diagram illustrating a configuration and connection relationship of an integrated circuit package 900e according to an embodiment of the present disclosure. Referring to FIG. 9E, the integrated circuit package 900e may include a substrate 901e, a die 91e, and a memory apparatus 930e. The die 91e may include a memory controller 910e and an interface circuit 920e. The memory controller 910e and the interface circuit 920e may be internal circuits of the die 91e. The die 91e and the memory apparatus 930e may be manufactured as separate dies and/or chiplets. The die 91e and the memory apparatus 930e may be manufactured using process technologies with different characteristics or may be manufactured using process technologies with the same characteristics. The die 91e and the memory apparatus 930e may be disposed on the substrate 901e. The substrate 901e may include an interposer. The die 91e may be disposed in a first region on the substrate 901e, and the memory apparatus 930e may be disposed in a second region on the substrate 901e. The first and second regions might not overlap. The memory apparatus 930e is illustrated to include a single memory die. The substrate 901e may include external terminals 902e underneath the substrate 901e that are used to electrically connect with external devices. The external terminals 902e may include microbumps or bumps. In an embodiment, the integrated circuit package 900e may further include another substrate, and the substrate 901e may be disposed on this other substrate. This other substrate may include another interposer or package substrate. When another substrate is provided, the substrate 901e may be electrically connected to this other substrate through microbumps or bumps and electrically connected to the external devices through this other substrate.

The substrate 901e may include a plurality of signal paths 911e, 931e, 941e used to electrically connect components disposed on the substrate 901e. The memory controller 910e may be electrically connected to the signal path 911e and the external terminals 902e through a microbump 903e at a first side of the die 91e. The memory controller may be electrically connected to the interface circuit 920e through a signal transmission line 921e inside the die 91e. Hereinafter, the electrical connection means for electrically connecting the internal circuits formed inside one die may be referred to as signal transmission lines, and the electrical connection means formed on the interposer and/or substrate may be referred to as signal paths. The interface circuit 920e may be electrically connected with the signal path 931e through the microbumps 904e at a second side of the die 91e. The memory apparatus 930e may be electrically connected to the signal path 931e through the microbumps 905e at a first side of the memory apparatus 930e. The memory apparatus 930b may be electrically connected with the external terminals 902e through microbumps 905e at a second side of the memory apparatus 930b and the signal path 941e.

The substrate 901e, the die 91e and the memory apparatus 930e may be packaged in a single package. Disposing the die 91e and the memory apparatus 930e on the substrate 901e may facilitate integrated circuit package manufacturing and reduce integrated circuit package size because wire bonding is not required. The electrical connection of the memory controller 910e to the signal path 911e may correspond to some or all of the first bus 150 shown in FIG. 1. The signal transmission line 921e electrically connecting the memory controller 910e and the interface circuit 920e may correspond to the second bus 160 shown in FIG. 1. The signal path 931e electrically connecting the interface circuit 920e and the memory apparatus 930e may correspond to the third bus 170 shown in FIG. 1. The electrical connection between the memory apparatus 930e and the signal path 941e may correspond to a direct access path to the memory apparatus 930e. A frequency of signal transmitted through the signal transmission line 921e may be greater than or equal to a frequency of signal transmitted through the signal path 931e. The signal transmission line 921e may include a first data bus, and the signal path 931e may include a second data bus. The signal may be transmitted at a first clock rate through the signal transmission line 921e, and the signal may be transmitted at a second clock rate through the signal path 931e. The first clock rate may be greater than or equal to the second clock rate. The number of data signals transmitted at one time through the first data bus may be less than or equal to the number of data signals transmitted at one time through the second data bus.

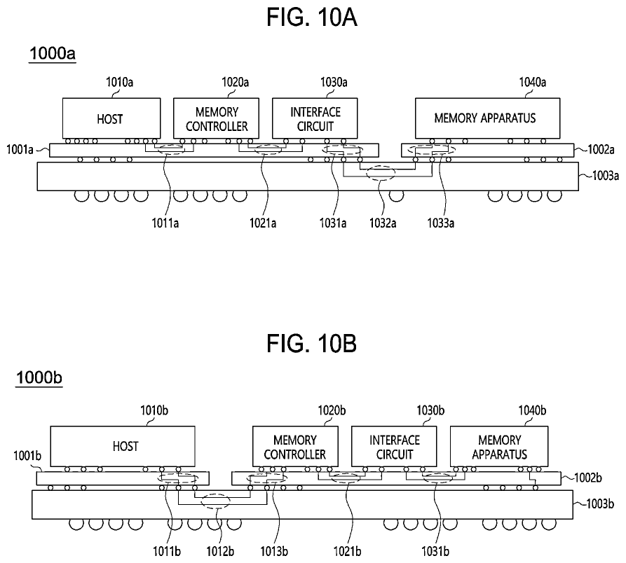

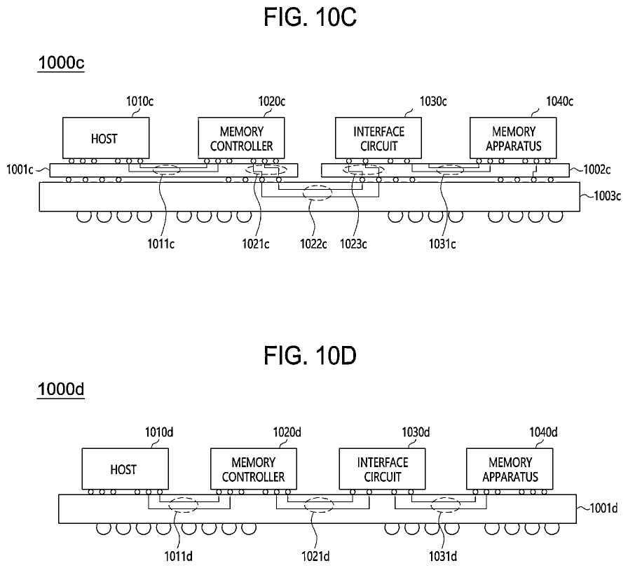

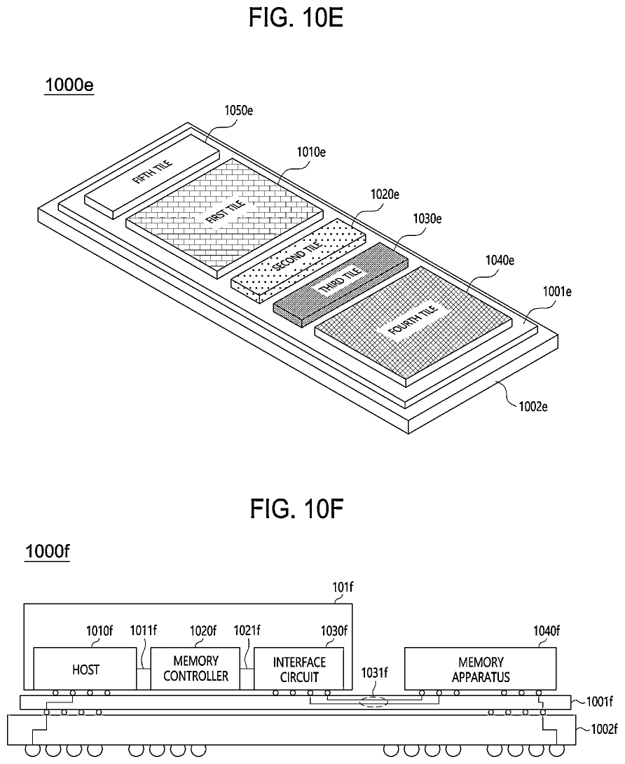

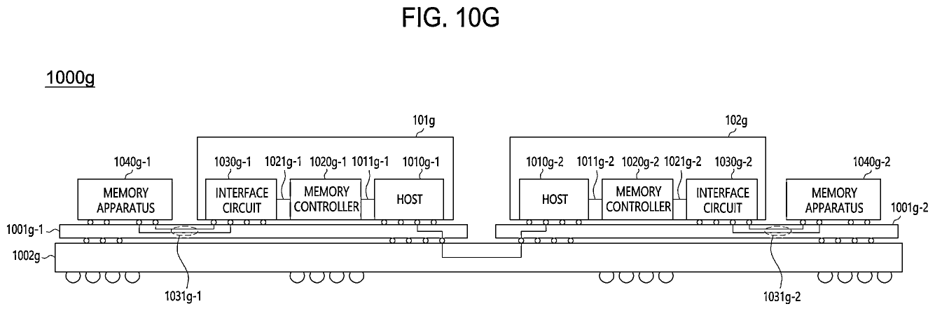

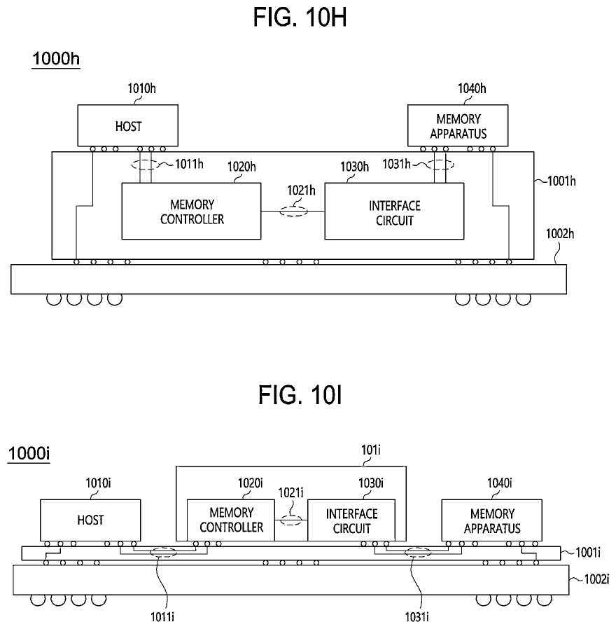

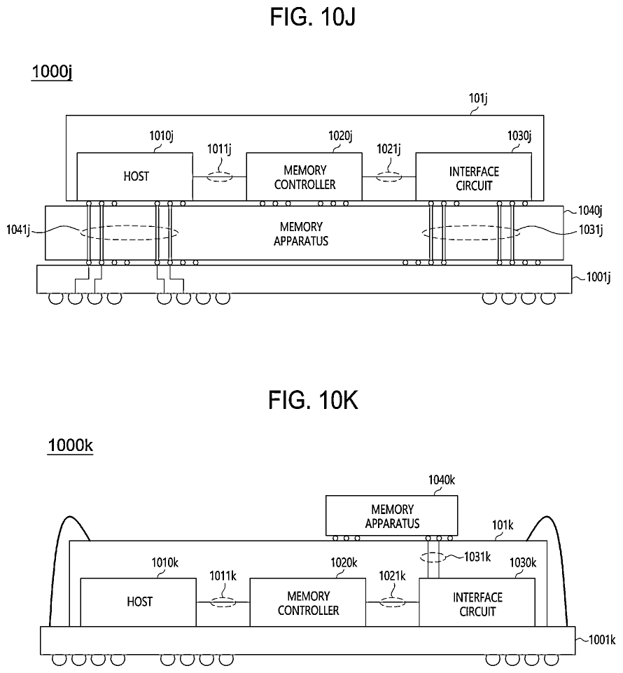

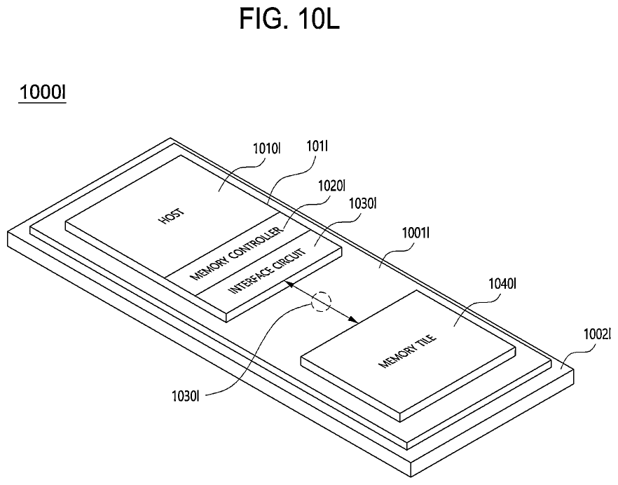

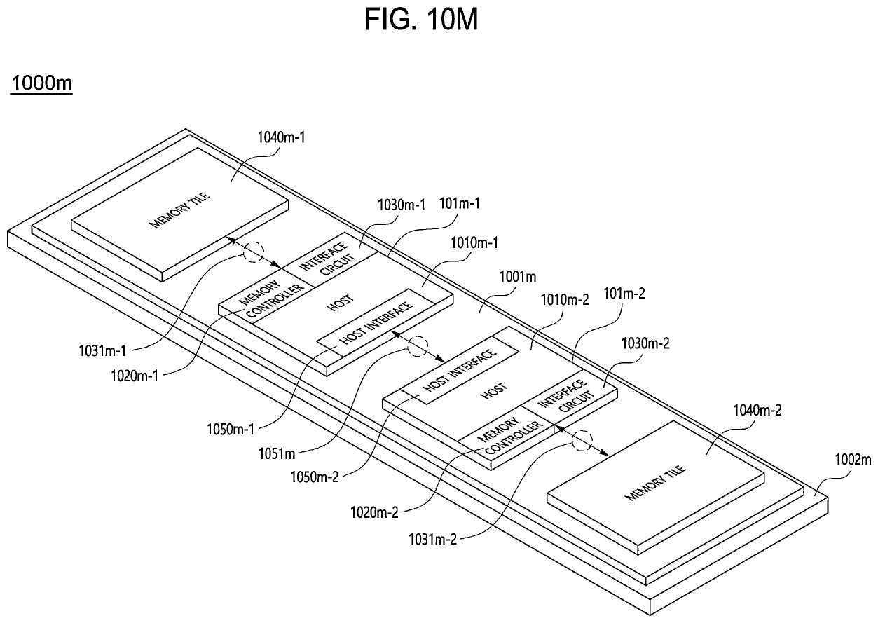

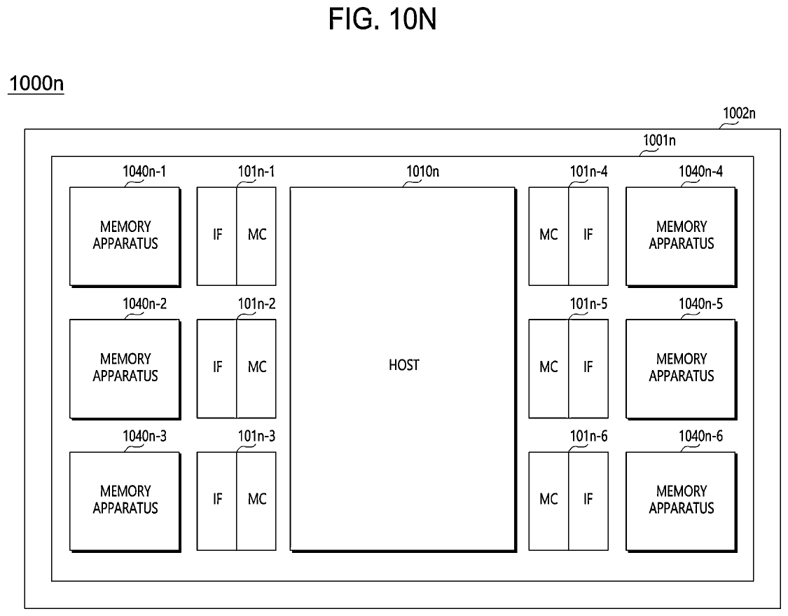

FIG. 10A is a diagram illustrating a configuration and connection relationship of an integrated circuit package 1000a according to an embodiment of the present disclosure. Referring to FIG. 10A, the integrated circuit package 1000a may include a first substrate 1001a, a second substrate 1002a, a host 1010a, a memory controller 1020a, an interface circuit 1030a, and a memory apparatus 1040a. The memory apparatus 1040a may include any of the memory apparatuses 930b to 930d shown in FIGS. 9B to 9D. The host 1010a, the memory controller 1020a, the interface circuit 1030a, and the memory apparatus 1040a may be manufactured as separate dies and/or chiplets. Some or all of the host 1010a, the memory controller 1020a, the interface circuit 1030a, and the memory apparatus 1040a may be manufactured using process technologies with different characteristics. The host 1010a, the memory controller 1020a, and the interface circuit 1030a may be disposed on a first substrate 1001a. The first substrate 1001a may include a first interposer. The host 1010a may be disposed in a first region on the first substrate 1001a. The memory controller 1020a may be disposed in a second region on the first substrate 1001a. The interface circuit 1030a may be disposed in a third region on the first substrate 1001a. The first and third regions might not overlap each other, and the second region may be between the first and third regions. The host 1010a may be electrically connected to the first substrate 1001a through microbumps of the host 1010a. The memory controller 1020a may be electrically connected to the first substrate 1001a through microbumps of the memory controller 1020a. The interface circuit 1030a may be electrically connected to the first substrate 1001a through microbumps of the interface circuit 1030a. The memory apparatus 1040a may be disposed on a second substrate 1002a. The second substrate 1002a may include a second interposer. The memory apparatus 1040a may be electrically connected to the second substrate 1002a through microbumps of the memory apparatus 1040a. The first substrate 1001a and the second substrate 1002a may be disposed on a third substrate 1003a. The third substrate 1003a may include another interposer or package substrate. The first substrate 1001a may be disposed in a first region on the third substrate 1003a, and the second substrate 1002a may be disposed in a second region on the third substrate 1003a. The first and second regions might not overlap each other. The first and second substrates 1001a, 1002a may be electrically connected to the third substrate 1003a through microbumps or bumps in the first and second substrates 1001a, 1002a, respectively. The third substrate 1003a may be electrically connected to an external device through external terminals of the third substrate 1003a. The external terminals may include microbumps, bumps, solder balls, or package balls.

The host 1010a may be electrically connected to the memory controller 1020a through a signal path 1011a formed in the first substrate 1001a. The memory controller 1020a may be electrically connected to the interface circuit 1030a through a signal path 1021a of the first substrate 1001a. The interface circuit 1030a may be electrically connected with the memory apparatus 1040a through a signal path 1031a of the first substrate 1001a, a signal path 1032a formed in the third substrate 1003a, and a signal path 1033a of the second substrate 1002a. The signal path 1011a between the host 1010a and the memory controller 1020a may correspond to the first bus 150 shown in FIG. 1. The signal path 1021a between the memory controller 1020a and the interface circuit 1030a may correspond to the second bus 160 shown in FIG. 1. The signal paths 1031a, 1032a, 1033a between the interface circuit 1030a and the memory apparatus 1040a may correspond to the third bus 170 shown in FIG. 1. A frequency of signal transmitted through the signal path 1021a may be greater than or equal to a frequency of signal transmitted through the signal paths 1031a, 1032a, 1033a. The signal may be transmitted at a first clock rate through the signal path 1021a, and the signal may be transmitted at a second clock rate through the signal paths 1031a, 1032a, 1033a. The first clock rate may be greater than or equal to the second clock rate. The signal path 1021a may include a first data bus, and the signal paths 1031a, 1032a, 1033a may include a second data bus. The number of data signals transmitted at one time through the first data bus may be less than or equal to the number of data signals transmitted at one time through the second data bus. In an embodiment, the first substrate 1001a, the host 1010a, the memory controller 1020a, and the interface circuit 1030a on the first substrate 1001a may be packaged in a first package. The memory apparatus 1040a on the second substrate 1002a may be packaged in a second package. The first and second packages may be disposed on the third substrate 1003a and packaged in a third package, and the integrated circuit package 1000a may be manufactured in a PIP (package in package) structure.

FIG. 10B is a diagram illustrating a configuration and connection relationship of an integrated circuit package 1000b according to an embodiment of the present disclosure. Referring to FIG. 10B, the integrated circuit package 1000b may include a first substrate 1001b, a second substrate 1002b, a host 1010b, a memory controller 1020b, an interface circuit 1030b, and a memory apparatus 1040b. The memory apparatus 1040b may include any of the memory apparatuses 930b to 930d shown in FIGS. 9B to 9D. The host 1010b may be disposed on a first substrate 1001b. The first substrate 1001b may include a first interposer. The host 1010b may be electrically connected to the first substrate 1001b through microbumps of the host 1010b. The memory controller 1020b, the interface circuit 1030b, and the memory apparatus 1040b may be disposed on a second substrate 1002b. The second substrate 1002b may include a second interposer. The memory controller 1020b may be disposed in a first region on the second substrate 1002b. The interface circuit 1030b may be disposed in a second region on the second substrate 1002b. The memory apparatus 1040b may be disposed in a third region on the second substrate 1002b. The first and third regions might not overlap each other, and the second region may be between the first and third regions. The memory controller 1020b may be electrically connected to the second substrate 1002b through microbumps of the memory controller 1020b. The interface circuit 1030b may be electrically connected to the second substrate 1002b through microbumps of the interface circuit 1030b. The memory apparatus 1040b may be electrically connected to the second substrate 1002b through microbumps of the memory apparatus 1040b. The first substrate 1001b and the second substrate 1002b may be disposed on a third substrate 1003b. The third substrate 1003b may include another interposer or package substrate. The first substrate 1001b may be disposed in a first region on the third substrate 1003b, and the second substrate 1002b may be disposed in a second region on the third substrate 1003b. The first and second regions might not overlap each other. The first and second substrates 1001b, 1002b may be electrically connected to the third substrate 1003b through microbumps or bumps in the first and second substrates 1001b, 1002b, respectively. The third substrate 1003b may be electrically connected to an external device through external terminals of the third substrate 1003b. The external terminals may include microbumps, bumps, solder balls, or package balls.

The host 1010b may be electrically connected to the memory controller 1020b through a signal path 1011b formed in the first substrate 1001b, a signal path 1012b formed in the third substrate 1003b, and a signal path 1013b formed in the second substrate 1002b. The memory controller 1020b may be electrically connected to the interface circuit 1030b through a signal path 1021b of the second substrate 1002b. The interface circuit 1030b may be electrically connected to the memory apparatus 1040b through a signal path 1031b of the second substrate 1002b. The signal paths 1011b, 1012b, 1013b between the host 1010b and the memory controller 1020b may correspond to the first bus 150 shown in FIG. 1. The signal path 1021b between the memory controller 1020b and the interface circuit 1030b may correspond to the second bus 160 shown in FIG. 1. The signal path 1031b between the interface circuit 1030b and the memory apparatus 1040b may correspond to the third bus 170 shown in FIG. 1. A frequency of signal transmitted through the signal path 1021b may be greater than or equal to a frequency of signal transmitted through the signal path 1031b. The signal may be transmitted at a first clock rate through the signal path 1021b, and the signal may be transmitted at a second clock rate through the signal path 1031b. The first clock rate may be greater than or equal to the second clock rate. The signal path 1021b may include a first data bus, and the signal path 1031b may include a second data bus. The number of data signals transmitted at one time through the first data bus may be less than or equal to the number of data signals transmitted at one time through the second data bus. In an embodiment, the first substrate 1001b and the host 1010b may be packaged in a first package. The second substrate 1002b, the memory controller 1020b, the interface circuit 1030b, and the memory apparatus 1040b on the second substrate 1002b may be packaged in a second package. The first and second packages may be disposed on the third substrate 1003b and packaged in a third package, and the integrated circuit package 1000b may be manufactured in a PIP (package in package) structure.

FIG. 10C is a diagram illustrating a configuration and connection relationship of an integrated circuit package 1000c according to an embodiment of the present disclosure. Referring to FIG. 10C, the integrated circuit package 1000c may include a first substrate 1001c, a second substrate 1002c, a host 1010c, a memory controller 1020c, an interface circuit 1030c, and a memory apparatus 1040c. The memory apparatus 1040c may include any of the memory apparatuses 930b to 930d shown in FIGS. 9B to 9D. The host 1010c and the memory controller 1020c may be disposed on a first substrate 1001c. The first substrate 1001c may include a first interposer. The host 1010c may be disposed in a first region on the first substrate 1001c, and the memory controller 1020c may be disposed in a second region on the first substrate 1001c. The first and second regions might not overlap each other. The host 1010c may be electrically connected to the first substrate 1001c through microbumps of the host 1010c. The memory controller 1020c may be electrically connected to the first substrate 1001c through microbumps of the memory controller 1020c. The interface circuit 1030c and the memory apparatus 1040c may be disposed on a second substrate 1002c. The second substrate 1002c may include a second interposer. The interface circuit 1030c may be disposed in a first region on the second substrate 1002c, and the memory apparatus 1040c may be disposed in a second region on the second substrate 1002c. The first and second regions might not overlap. The interface circuit 1030c may be electrically connected to the second substrate 1002c through microbumps of the interface circuit 1030c. The memory apparatus 1040c may be electrically connected to the second substrate 1002c through microbumps of the memory apparatus 1040c. The first substrate 1001c and the second substrate 1002c may be disposed on a third substrate 1003c. The third substrate 1003c may include another interposer or package substrate. The first substrate 1001c may be disposed in a first region on the third substrate 1003c, and the second substrate 1002c may be disposed in a second region on the third substrate 1003c. The first and second regions might not overlap each other. The first and second substrates 1001c, 1002c may be electrically connected to the third substrate 1003c through microbumps or bumps in the first and second substrates 1001c, 1002c, respectively. The third substrate 1003c may be electrically connected to an external device through external terminals of the third substrate 1003c. The external terminals may include microbumps, bumps, solder balls, or package balls.

The host 1010c may be electrically connected to the memory controller 1020c through a signal path 1011c formed in the first substrate 1001c. The memory controller 1020c may be electrically connected to the interface circuit 1030c through a signal path 1021c of the first substrate 1001c, a signal path 1022c formed in the third substrate 1003c, and a signal path 1023c formed in the second substrate 1002c. The interface circuit 1030c may be electrically connected with the memory apparatus 1040c through a signal path 1031c formed in the second substrate 1002c. The signal path 1011c between the host 1010c and the memory controller 1020c may correspond to the first bus 150 shown in FIG. 1. The signal paths 1021c, 1022c, 1023c between the memory controller 1020c and the interface circuit 1030c may correspond to the second bus 160 shown in FIG. 1. The signal path 1031c between the interface circuit 1030c and the memory apparatus 1040c may correspond to the third bus 170 shown in FIG. 1. A frequency of signal transmitted through the signal paths 1021c, 1022c, 1023c may be greater than or equal to a frequency of signal transmitted through the signal path 1031c. The signal may be transmitted at a first clock rate through the signal paths 1021c, 1022c, 1023c, and the signal may be transmitted at a second clock rate through the signal path 1031c. The first clock rate may be greater than or equal to the second clock rate. The signal paths 1021c, 1022c, 1023c may include a first data bus, and the signal path 1031c may include a second data bus. The number of data signals transmitted at any one time through the first data bus may be less than or equal to the number of data signals transmitted at any one time through the second data bus. In an embodiment, the first substrate 1001c, the host 1010c and the memory controller 1020c may be packaged in a first package. The second substrate 1002c, the interface circuit 1030c and the memory apparatus 1040c may be packaged in a second package. The first and second packages may be disposed on the third substrate 1003c and packaged in a third package, and the integrated circuit package 1000c may be manufactured in a PIP (package in package) structure.

FIG. 10D is a diagram illustrating a configuration and connection relationship of an integrated circuit package 1000d according to an embodiment of the present disclosure. Referring to FIG. 10D, the integrated circuit package 1000d may include a substrate 1001d, a host 1010d, a memory controller 1020d, an interface circuit 1030d, and a memory apparatus 1040d. The memory apparatus 1040d may include any of the memory apparatuses 930b to 930d shown in FIGS. 9B to 9D. The host 1010d, the memory controller 1020d, the interface circuit 1030d, and the memory apparatus 1040d may be disposed on the substrate 1001d. The substrate 1001d may be an interposer and/or glass substrate containing various signal paths. The host 1010d may be disposed in a first region on the substrate 1001d. The memory controller 1020d may be disposed in a second region on the substrate 1001d. The interface circuit 1030d may be disposed in a third region on the substrate 1001d. The memory apparatus 1040d may be disposed in a fourth region on the substrate 1001d. The first and fourth regions might not overlap each other. The second region may be between the first region and the third region, and the third region may be between the second region and the fourth region. The host 1010d may be electrically connected to the substrate 1001d through microbumps of the host 1010d. The memory controller 1020d may be electrically connected to the substrate 1001d through microbumps of the memory controller 1020d. The interface circuit 1030d may be electrically connected to the substrate 1001d through microbumps of the interface circuit 1030d. The memory apparatus 1040d may be electrically connected with the substrate 1001d through microbumps of the memory apparatus 1040d. The substrate 1001d may include external terminals underneath the substrate 1001d used to electrically connect with an external device. The external terminals may include micro-bumps, bumps, solder balls, or package balls. The host 1010d, the memory controller 1020d, the interface circuit 1030d, and the memory apparatus 1040d disposed on the substrate 1001d may be packaged in a single package.

The host 1010d may be electrically connected to the memory controller 1020d through a signal path 1011d formed in the substrate 1001d. The memory controller 1020d may be electrically connected with the interface circuit 1030d through a signal path 1021d formed in the substrate 1001d. The interface circuit 1030d may be electrically connected with the memory apparatus 1040d through a signal path 1031d formed in the substrate 1001d. The signal path 1011d between the host 1010d and the memory controller 1020d may correspond to the first bus 150 shown in FIG. 1. The signal path 1021d between the memory controller 1020d and the interface circuit 1030d may correspond to the second bus 160 shown in FIG. 1. The signal path 1031d between the interface circuit 1030d and the memory apparatus 1040d may correspond to the third bus 170 shown in FIG. 1. A frequency of signal transmitted through the signal path 1021d may be greater than or equal to a frequency of signal transmitted through the signal path 1031d. The signal may be transmitted at a first clock rate through the signal path 1021d, and the signal may be transmitted at a second clock rate through the signal path 1031d. The first clock rate may be greater than or equal to the second clock rate. The signal path 1021d may include a first data bus, and the signal path 1031d may include a second data bus. The number of data signals transmitted at one time through the first data bus may be less than or equal to the number of data signals transmitted at one time through the second data bus.

FIG. 10E is a diagram illustrating a configuration and connection relationship of an integrated circuit package 1000e according to an embodiment of the present disclosure. Referring to FIG. 10E, the integrated circuit package 1000e may include a first tile 1010e, a second tile 1020e, a third tile 1030e, and a fourth tile 1040e. In FIG. 10E, a tile may refer to a die, structure, unit module, or chiplet of a single device. The first tile 1010e may correspond to the host 110 shown in FIG. 1. The second tile 1020e may correspond to the memory controller 120 shown in FIG. 1. The third tile 1030e may correspond to the interface circuit 130 shown in FIG. 1. The fourth tile 1040e may correspond to the memory apparatus 140 shown in FIG. 1. The first to fourth tiles 1010e, 1020e, 1030e, 1040e may be mounted on a base tile 1001e. The base tile 1001e may include a plurality of tile sockets or connectors to allow the first to fourth tiles 1010e, 1020e, 1030e, 1040e and additional tiles (i.e., a fifth tile 1050e) to be mounted on the base tile 1001e. The base tile 1001e may include signal paths for electrically connecting the plurality of tiles mounted to the base tile 1001e. Although not shown, a plurality of signal paths may be formed within the base tile 1001e for electrically connecting each of the first to fourth tiles 1010e, 1020e, 1030e, 1040e. The base tile 1001e may be disposed on a substrate 1002e. The substrate 1002e may include any one of an interposer, a package substrate, an organic substrate, and a redistribution layer. A signal path between the first tile 1010e and the second tile 1020e may correspond to the first bus 150 shown in FIG. 1. A signal path between the second tile 1020e and the third tile 1030e may correspond to the second bus 160 shown in FIG. 1. A signal path between the third tile 1030e and the fourth tile 1040e may correspond to the third bus 170 shown in FIG. 1. The integrated circuit package 1000e may further include the fifth tile 1050e. The fifth tile 1050e may be a logic tile performing the same or different functions as any one of the first to fourth tiles 1010e, 1020e, 1030e, 1040e. Some or all of the first to fifth tiles 1010e, 1020e, 1030e, 1040e, 1050e may be manufactured using different process technologies. In an embodiment, the first and second tiles 1010e, 1020e may be integrated into a single tile, and the integrated tile may be mounted to the base tile 1001e through a single socket or connector. In an embodiment, the second and third tiles 1020e, 1030e may be integrated into a single tile, and the integrated tile may be mounted to the base tile 1001e through a single socket or connector.

FIG. 10F is a diagram illustrating a configuration and connection relationship of an integrated circuit package 1000f according to an embodiment of the present disclosure. Referring to FIG. 10F, the integrated circuit package 1000f may include a first substrate 1001f, a host die 101f and a memory apparatus 1040f. The memory apparatus 1040f may include any of the memory apparatuses 930b to 930d shown in FIGS. 9B to 9D. The host die 101f may include a host 1010f, a memory controller 1020f, and an interface circuit 1030f. The host 1010f, the memory controller 1020f, and the interface circuit 1030f may be internal circuits of the host die 101f. The host die 101f and the memory apparatus 1040f may be manufactured as separate dies and/or chiplets. The host die 101f and the memory apparatus 1040f may be manufactured using process technologies with different characteristics or may be manufactured using process technologies with the same characteristics. The host die 101f and the memory apparatus 1040f may be disposed on the first substrate 1001f. The first substrate 1001f may include an interposer. The host die 101f may be disposed in a first region on the first substrate 1001f, and the memory apparatus 1040f may be disposed in a second region on the first substrate 1001f. The first and second regions might not overlap each other.

The host die 101f may be electrically connected to the first substrate 1001f through microbumps of the host die 101f. The memory apparatus 1040f may be electrically connected with the first substrate 1001f through microbumps of the memory apparatus 1040f. The integrated circuit package 1000f may further include a second substrate 1002f. The first substrate 1001f may be disposed on the second substrate 1002f. The second substrate may include another interposer or package substrate. The first substrate 1001f may be electrically connected to the second substrate 1002f through microbumps or bumps of the first substrate 1001f. The second substrate 1002f may be electrically connected to an external device through external terminals of the second substrate 1002f. The external terminals may include microbumps, bumps, solder balls, or package balls.

The host 1010f may be electrically connected to the memory controller 1020f through a signal transmission line 1011f inside the host die 101f. The memory controller 1020f may be electrically connected with the interface circuit 1030f through a signal transmission line 1021f inside the host die 101f. The interface circuit 1030f may be electrically connected to the memory apparatus 1040f through microbumps of the host die 101f and a signal path 1031f formed in the first substrate 1001f. The memory apparatus 1040f may be electrically connected to the signal path 1031f through microbumps of the memory apparatus 1040f. In an embodiment, the host 1010f may be directly electrically connected to an external device through a signal path formed in the first substrate 1001f and a signal path formed in the second substrate 1002f and external terminals of the second substrate 1002f. The memory apparatus 1040f may be directly electrically connected to an external device through a signal path formed in the first substrate 1001f, a signal path formed in the second substrate 1002f, and external terminals of the second substrate 1002f. The signal transmission line 1011f electrically connecting the host 1010f and the memory controller 1020f may correspond to the first bus 150 shown in FIG. 1. The signal transmission line 1021f electrically connecting the memory controller 1020f and the interface circuit 1030f may correspond to the second bus 160 shown in FIG. 1. The signal path 1031f between the interface circuit 1030f and the memory apparatus 1040f may correspond to the third bus 170 shown in FIG. 1. A frequency of signal transmitted through the signal transmission line 1021f may be greater than or equal to a frequency of signal transmitted through the signal path 1031f. The signal may be transmitted at a first clock rate through the signal transmission line 1021f, and the signal may be transmitted at a second clock rate through the signal path 1031f. The first clock rate may be greater than or equal to the second clock rate. The signal transmission line 1021f may include a first data bus, and the signal path 1031f may include a second data bus. The number of data signals transmitted at one time through the first data bus may be less than or equal to the number of data signals transmitted at one time through the second data bus. The first substrate 1001f, the second substrate 1002f, host die 101f and the memory apparatus 1040f may be packaged in a single package.

FIG. 10G is a diagram illustrating a configuration and connection relationship of an integrated circuit package 1000g according to an embodiment of the present disclosure. Referring to FIG. 10G, the integrated circuit package 1000g may include a first substrate 1001g-1, a second substrate 1001g-2, a first host die 101g, a second host die 102g, a first memory apparatus 1040g-1, and a second memory apparatus 1040g-2. The first and second memory apparatuses 1040g-1, 1040g-2 may each include any one of the memory apparatuses 930b to 930d shown in FIGS. 9B to 9D. The first host die 101g may include a host 1010g-1, a memory controller 1020g-1, and an interface circuit 1030g-1. The host 1010g-1, the memory controller 1020g-1, and the interface circuit 1030g-1 may be internal circuits of the first host die 101g. The first host die 101g and the first memory apparatus 1040g-1 may be disposed on the first substrate 1001g-1. The first substrate 1001g-1 may include a first interposer. The first host die 101g may be disposed in a first region on the first substrate 1001g-1, and the first memory apparatus 1040g-1 may be disposed in a second region on the first substrate 1001g-1. The first and second regions might not overlap. The first host die 101g may be electrically connected to the first substrate 1001g-1 through microbumps of the first host die 101g. The first memory apparatus 1040g-1 may be electrically connected to the first substrate 1001g-1 through microbumps of the first memory apparatus 1040g-1. The integrated circuit package 1000g may further include a third substrate 1002g. The first substrate 1001g-1 may be disposed on the third substrate 1002g. The third substrate 1002g may include another interposer or package substrate. The first substrate 1001g-1 may be electrically connected to the third substrate 1002g through microbumps or bumps of the first substrate 1001g-1. The third substrate 1002g may be electrically connected to an external device through external terminals of the third substrate 1002g. The external terminals may include microbumps, bumps, solder balls, or package balls.

The host 1010g-1 may be electrically connected to the memory controller 1020g-1 through a signal transmission line 1011g-1 inside the firsthost die 101g. The memory controller 1020g-1 may be electrically connected with the interface circuit 1030g-1 through a signal transmission line 1021g-1 inside the first host die 101g. The interface circuit 1030g-1 may be electrically connected with the first memory apparatus 1040g-1 through microbumps of the first host die 101g and a signal path 1031g-1 formed in the first substrate 1001g-1. The first memory apparatus 1040g-1 may be electrically connected to the signal path 1031g-1 through microbumps of the first memory apparatus 1040g-1. The signal transmission line 1011g-1 electrically connecting the host 1010g-1 and the memory controller 1020g-1 may correspond to the first bus 150 shown in FIG. 1. The signal transmission line 1021g-1 electrically connecting the memory controller 1020g-1 and the interface circuit 1030g-1 may correspond to the second bus 160 shown in FIG. 1. The signal path 1031g-1 between the interface circuit 1030g-1 and the first memory apparatus 1040g-1 may correspond to the third bus 170 shown in FIG. 1. A frequency of signal transmitted through the signal transmission line 1021g-1 may be greater than or equal to a frequency of signal transmitted through the signal path 1031g-1. The signal may be transmitted at a first clock rate through the signal transmission line 1021g-1, and the signal may be transmitted at a second clock rate through the signal path 1031g-1. The first clock rate may be greater than or equal to the second clock rate. The signal transmission line 1021g-1 may include a first data bus, and the signal path 1031g-1 may include a second data bus. The number of data signals transmitted at one time through the first data bus may be less than or equal to the number of data signals transmitted at one time through the second data bus. The first substrate 1001g-1, the first host die 11g and the first memory apparatus 1040g-1 may be packaged in a first package.

The second host die 102g may include a host 1010g-2, a memory controller 1020g-2, and an interface circuit 1030g-2. The host 1010g-2, the memory controller 1020g-2, and the interface circuit 1030g-2 may be internal circuits of the second host die 102g. The second host die 102g and the second memory apparatus 1040g-2 may be disposed on a second substrate 1001g-2. The second substrate 1001g-2 may include a second interposer. The second host die 102g may be disposed in a first region on the second substrate 1001g-2, and the second memory apparatus 1040g-2 may be disposed in a second region on the second substrate 1001g-2. The first and second regions might not overlap. The second host die 102g may be electrically connected to the second substrate 1001g-2 through microbumps of the second host die 102g. The second memory apparatus 1040g-2 may be electrically connected to the second substrate 1001g-2 through microbumps of the second memory apparatus 1040g-2. The second substrate 1001g-2 may be disposed on the third substrate 1002g. The second substrate 1001g-2 may be disposed on the third substrate 1002g in a region different from the region where the first substrate 1001g-1 is disposed. The second substrate 1001g-2 may be electrically connected to the third substrate 1002g through microbumps or bumps of the second substrate 1001g-2.

The host 1010g-2 may be electrically connected to the memory controller 1020g-2 through a signal transmission line 1011g-2 inside the second host die 102g. The memory controller 1020g-2 may be electrically connected with the interface circuit 1030g-2 through a signal transmission line 1021g-2 inside the second host die 102g. The interface circuit 1030g-2 may be electrically connected with the second memory apparatus 1040g-2 through microbumps of the second host die 102g and a signal path 1031g-2 formed in the second substrate 1001g-2. The second memory apparatus 1040g-2 may be electrically connected to the signal path 1031g-2 through microbumps of the second memory apparatus 1040g-2. The signal transmission line 1011g-2 electrically connecting the host 1010g-2 and the memory controller 1020g-2 may correspond to the first bus 150 shown in FIG. 1. The signal transmission line 1021g-2 electrically connecting the memory controller 1020g-2 and the interface circuit 1030g-2 may correspond to the second bus 160 shown in FIG. 1. The signal path 1031g-2 between the interface circuit 1030g-2 and the second memory apparatus 1040g-2 may correspond to the third bus 170 shown in FIG. 1. A frequency of signal transmitted through the signal transmission line 1021g-2 may be greater than or equal to a frequency of signal transmitted through the signal path 1031g-2. The signal may be transmitted at a third clock rate through the signal path 1021g-2, and the signal may be transmitted at a fourth clock rate through the signal path 1031g-2. The third clock rate may be greater than or equal to the fourth clock rate. The third clock rate may be equal to or different from the first clock rate. The fourth clock rate may be equal to or different from the fourth clock rate. The signal transmission line 1021g-2 may include a third data bus, and the signal path 1031g-2 may include a fourth data bus. The number of data signals transmitted at one time through the third data bus may be less than or equal to the number of data signals transmitted at one time through the fourth data bus. In an embodiment, the first substrate 1001g-1, the first host die 101g, and the first memory apparatus 1040g-1 may be packaged in a first package. The second substrate 1001g-2, the second host die 102g and the second memory apparatus 1040g-2 may be packaged in a second package. The first and second packages may be disposed on the third substrate 1002g and packaged in a third package, and the integrated circuit package 1000g may be manufactured in a PIP (package in package) structure. The host 1010g-1 may be electrically connected with the host 1010g-2 through the microbumps of the first host die 101g, the signal path formed in the first substrate 1001g-1, the microbumps of the first substrate 1001g-1, the signal path of the third substrate 1002g, the microbumps of the second substrate 1001g-2, the signal path of the second substrate 1001g-2, and the microbumps of the second host die 102g.

FIG. 10H is a diagram illustrating a configuration and connection relationship of an integrated circuit package 1000h according to an embodiment of the present disclosure. Referring to FIG. 10H, the integrated circuit package 1000h may include a first substrate 1001h, a host 1010h, a memory controller 1020h, an interface circuit 1030h, and a memory apparatus 1040h. The memory apparatus 1040h may include any one of the memory apparatuses 930b to 930d shown in FIGS. 9B to 9D. The host 1010h and the memory apparatus 1040h may be disposed on the first substrate 1001h. The host 1010h may be disposed in a first region on the first substrate 1001h, and the memory apparatus 1040h may be disposed in a second region on the first substrate 1001h. The first and second regions might not overlap each other. The first substrate 1001h may be an active interposer that includes various signal paths as well as circuits to perform various functions. The host 1010h may be electrically connected to the first substrate 1001h through microbumps of the host 1010h. The memory apparatus 1040h may be electrically connected to the first substrate 1001h through microbumps of the memory apparatus 1040h. The integrated circuit package 1000h may further include a second substrate 1002h. The first substrate 1001h may be disposed on the second substrate 1002h. The second substrate 1002h may include an interposer or package substrate. The first substrate 1001h may be electrically connected to the second substrate 1002h through microbumps or bumps of the first substrate 1001h. The second substrate 1002h may be electrically connected to external devices through external terminals of the second substrate 1002h. The external terminals may include microbumps, bumps, solder balls, or package balls. The memory controller 1020h and the interface circuit 1030h may be formed within the first substrate 1001h. The memory controller 1020h and the interface circuit 1030h may be manufactured with the first substrate 1001h as internal circuits of the first substrate 1001h. The memory controller 1020h and the interface circuit 1030h may be electrically connected to the host 1010h and the memory apparatus 1040h through a plurality of signal paths formed within the first substrate 1001h. The second substrate 1002h, the first substrate 1001h, and the host 1010h and the memory apparatus 1040h disposed on the first substrate 1001h, may be packaged in a single package. In an embodiment, the first region of the first substrate 1001h where the host 1010h is disposed may be closer to the region where the memory controller 1020h is disposed than the region where the interface circuit 1030h is disposed within the first substrate 1001h. The second region of the first substrate 1001h where the memory apparatus 1040h is disposed may be closer to the region where the interface circuit 1030h is disposed than to the region where the memory controller 1020h is disposed within the first substrate 1001h.

The memory controller 1020h may be electrically connected to the host 1010h through a signal path 1011h and microbumps of the host 1010h. The memory controller 1020h may be electrically connected to the interface circuit 1030h through a signal path 1021h. The interface circuit 1030h may be electrically connected to the memory apparatus 1040h through a signal path 1031h and microbumps of the memory apparatus 1040h. The signal path 1011h between the host 1010h and the memory controller 1020h may correspond to the first bus 150 illustrated in FIG. 1. The signal path 1021h between the memory controller 1020h and the interface circuit 1030h may correspond to the second bus 160 shown in FIG. 1. The signal path 1031h between the interface circuit 1030h and the memory apparatus 1040h may correspond to the third bus 170 shown in FIG. 1. A frequency of signal transmitted through the signal path 1021h may be greater than or equal to a frequency of signal transmitted through the signal path 1031h. The signal may be transmitted at a first clock rate through the signal path 1021h, and the signal may be transmitted at a second clock rate through the signal path 1031h. The first clock rate may be greater than or equal to the second clock rate. The signal path 1021h may include a first data bus, and the signal path 1031h may include a second data bus. The number of data signals transmitted at one time through the first data bus may be less than or equal to the number of data signals transmitted at one time through the second data bus. In an embodiment, the first substrate 1001h may include some or all of the cache utilized by the host 1010h. If some or all of the cache utilized by the host 1010h is formed in the first substrate 1001h, then the host 1010h may include processing cores capable of performing more computational functions without increasing the size of the host 1010h. In an embodiment, a low-speed input/output circuit that allows the host 1010h to communicate directly with external devices may be further provided, and the low-speed input/output circuit may be formed in the first substrate 1001h. In an embodiment, a test circuit that allows the external devices to directly access the memory apparatus 1040h to test the memory apparatus 1040h may be further provided, and the test circuit may be formed in the first substrate 1001h.

FIG. 10I is a diagram illustrating a configuration and connection relationship of an integrated circuit package 1000i according to an embodiment of the present disclosure. Referring to FIG. 10I, the integrated circuit package 1000i may include a first substrate 1001i, a host 1010i, a controller die 101i, and a memory apparatus 1040i. The memory apparatus 1040i may include any one of the memory apparatuses 930b to 930d shown in FIGS. 9B to 9D. The controller die 101i may include a memory controller 1020i and an interface circuit 1030i. The controller die 101i may be manufactured as a separate die or chiplet from the host 1010i. The memory controller 1020i and the interface circuit 1030i may be internal circuits of the controller die 101i. The host 1010i, the controller die 101i, and the memory apparatus 1040i may be disposed on the first substrate 1001i. The first substrate 1001i may include an interposer. The host 1010i may be disposed in a first region on the first substrate 1001i. The controller die 101i may be disposed in a second region on the first substrate 1001i. The memory apparatus 1040i may be disposed in a third region on the first substrate 1001i. The first and third regions might not overlap each other. The host 1010i may be electrically connected to the first substrate 1001i through microbumps of the host 1010i. The controller die 101i may be electrically connected to the first substrate 1001i through microbumps of the controller die 101i. The memory apparatus 1040i may be electrically connected with the first substrate 1001i through microbumps of the memory apparatus 1040i. The integrated circuit package 1000i may further include a second substrate 1002i. The first substrate 1001i may be disposed on the second substrate 1002i. The second substrate 1002i may include an interposer or package substrate. The first substrate 1001i may be electrically connected to the second substrate 1002i through microbumps or bumps of the first substrate 1001i. The second substrate 1002i may be electrically connected to an external device through external terminals of the second substrate 1002i. The external terminals may include microbumps, bumps, solder balls, or package balls. The memory controller 1020i may be electrically connected to the first substrate 1001i through microbumps at a first side of the controller die 101i. The interface circuit 1030i may be electrically connected to the first substrate 1001i through microbumps at a second side of the controller die 101i. The second substrate 1002i, the first substrate 1001i, the host 1010i, the controller die 101i, and the memory apparatus 1040i may be packaged in a single package.

The host 1010i may be electrically connected to the memory controller 1020i through a signal path 1011i formed in the first substrate 1001i. The memory controller 1020i and the interface circuit 1030i may be electrically connected through a signal path 1021i inside the controller die 101i. The interface circuit 1030i may be electrically connected to the memory apparatus 1040i through a signal path 1031i formed in the first substrate 1001i. The signal path 1011i between the host 1010i and the memory controller 1020i may correspond to the first bus 150 shown in FIG. 1. The signal path 1021i electrically connecting the memory controller 1020i and the interface circuit 1030i may correspond to the second bus 160 shown in FIG. 1. The signal path 1031i between the interface circuit 1030i and the memory apparatus 1040i may correspond to the third bus 170 shown in FIG. 1. A frequency of signal transmitted through the signal path 1021i may be greater than or equal to a frequency of signal transmitted through the signal path 1031i. The signal may be transmitted at a first clock rate through the signal path 1021i, and the signal may be transmitted at a second clock rate through the signal path 1031i. The first clock rate may be greater than or equal to the second clock rate. The signal path 1021i may include a first data bus, and the signal path 1031i may include a second data bus. The number of data signals transmitted at one time through the first data bus may be less than or equal to the number of data signals transmitted at one time through the second data bus.

FIG. 10J is a diagram illustrating a configuration and connection relationship of an integrated circuit package 1000j according to an embodiment of the present disclosure. Referring to FIG. 10J, the integrated circuit package 1000j may include a substrate 1001j, a host die 101j and a memory apparatus 1040j. The memory apparatus 1040j may include any one of the memory apparatuses 940b, 940d shown in FIGS. 9B and 9D. Through vias may be formed in the memory apparatus 1040j. The host die 101j may include a host 1010j, a memory controller 1020j, and an interface circuit 1030j. The host 1010j, the memory controller 1020j, and the interface circuit 1030j may be internal circuits of the host die 101j. The host die 101j and the memory apparatus 1040j may be disposed on the substrate 1001j. The memory apparatus 1040j may be disposed on the substrate 1001j, and the host die 101j may be disposed on the memory apparatus 1040j. The host die 101j may be electrically connected to the memory apparatus 1040j through microbumps of the host die 101j. The host die 101j may be electrically connected with the substrate 1001j and the memory apparatus 1040j through vias formed in the memory apparatus 1040j. The memory apparatus 1040j may be electrically connected to the substrate 1001j through microbumps of the memory apparatus 1040j. The substrate 1001j may include at least one of an interposer, a redistribution layer, and a glass substrate. In an embodiment, the integrated circuit package 1000j may further include another substrate, and the substrate 1001j may be disposed on the another substrate. The substrate 1001j may be electrically connected to an external device through the another substrate. The another substrate may include another interposer or package substrate.

The host 1010j may be electrically connected to the memory controller 1020j through a signal transmission line 1011j inside the host die 101j. The host 1010j may be electrically connected to a signal path formed in the substrate 1001j through microbumps of the host die 101j, through vias 1041j formed in the memory apparatus 1040j, and microbumps of the memory apparatus 1040j. The signal path may be electrically connected to the another substrate or an external device through microbumps, bumps, solder balls, or package balls on the substrate 1001j. The memory controller 1020j may be electrically connected to the interface circuit 1030j through a signal transmission line 1021j inside the host die 101j. The interface circuit 1030j may be electrically connected with the memory apparatus 1040j through microbumps of the host die 101j and through vias 1031j formed in the memory apparatus 1040j. The signal transmission line 1011j electrically connecting the host 1010j and the memory controller 1020j may correspond to the first bus 150 shown in FIG. 1. The signal transmission line 1021j electrically connecting the memory controller 1020j and the interface circuit 1030j may correspond to the second bus 160 shown in FIG. 1. The microbumps and through vias 1031j electrically connecting the interface circuit 1030j and the memory apparatus 1040j may correspond to the third bus 170 shown in FIG. 1. The substrate 1001j, the host die 101j and the memory apparatus 1040j may be packaged in a single package. A frequency of signal transmitted through the signal transmission line 1021j may be greater than or equal to a frequency of signal transmitted through the through via 1031j. The signal may be transmitted at a first clock rate through the signal transmission line 1021j, and the signal may be transmitted at a second clock rate through the through via 1031j. The first clock rate may be greater than or equal to the second clock rate. The signal transmission line 1021j may include a first data bus, and the through via 1031j may include a second data bus. The number of data signals transmitted at one time through the first data bus may be less than or equal to the number of data signals transmitted at one time through the second data bus.

FIG. 10K is a diagram illustrating a configuration and connection relationship of an integrated circuit package 1000k according to an embodiment of the present disclosure. Referring to FIG. 10K, the integrated circuit package 1000k may include a substrate 1001k, a host die 101k and a memory apparatus 1040k. The memory apparatus 1040k may include any one of the memory apparatuses 930b to 930d illustrated in FIGS. 9B to 9D. The host die 101k may include a host 1010k, a memory controller 1020k, and an interface circuit 1030k. The host 1010k, the memory controller 1020k, and the interface circuit 1030k may be internal circuits of the host die 101k. The host die 101k and the memory apparatus 1040k may be disposed on the substrate 1001k. The substrate 1001k may include a package substrate. The host die 101k may be disposed on the substrate 1001k, and the memory apparatus 1040k may be disposed on the host die 101k. The memory apparatus 1040k may be electrically connected to the host die 101k through microbumps of the memory apparatus 1040k. The host die 101k may be electrically connected to the substrate 1001k through wire bondings. In an embodiment, the substrate 1001k may be replaced by an interposer, and the host die 101k may include microbumps. The host die 101k may be electrically connected to the interposer through the microbumps instead of the wire bonding, or may be electrically connected to the redistribution layer through microbumps or without microbumps. The substrate 1001k may be electrically connected to an external device through external terminals (e.g., solder balls or package balls).

The host 1010k may be electrically connected to the memory controller 1020k through a signal transmission line 1011k inside the host die 101k. The host 1010k may be electrically connected to the external devices through wire bonding between the host die 101k and the substrate 1001k. The memory controller 1020k may be electrically connected with the interface circuit 1030k through a signal transmission line 1021k inside the host die 101k. The interface circuit 1030k may be electrically connected with the memory apparatus 1040k through a signal transmission line 1031k inside the host die 101k and microbumps of the memory apparatus 1040k. The signal transmission line 1011k electrically connecting the host 1010k and the memory controller 1020k may correspond to the first bus 150 shown in FIG. 1. The signal transmission line 1021k electrically connecting the memory controller 1020k and the interface circuit 1030k may correspond to the second bus 160 shown in FIG. 1. The signal transmission line 1031k electrically connecting the interface circuit 1030k and the memory apparatus 1040k and the microbumps may correspond to the third bus 170 shown in FIG. 1. A frequency of signal transmitted through the signal transmission line 1021k may be greater than or equal to a frequency of signal transmitted through the signal transmission line 1031k. The signal may be transmitted at a first clock rate through the signal transmission line 1021k, and the signal may be transmitted at a second clock rate through the signal transmission line 1031k. The first clock rate may be greater than or equal to the second clock rate. The signal transmission line 1021k may include a first data bus, and the signal transmission line 1031k may include a second data bus. The number of data signals transmitted at one time through the first data bus may be less than or equal to the number of data signals transmitted at one time through the second data bus. The substrate 1001k, the host die 101k and the memory apparatus 1040k may be packaged in a single package.

FIG. 10L is a diagram illustrating a configuration and connection relationship of an integrated circuit package 10001 according to an embodiment of the present disclosure. Referring to FIG. 10L, the integrated circuit package 10001 may include a host tile 1011 and a memory tile 10401. In FIG. 10L, a tile may refer to a die, structure, unit module, or chiplet of a single device. The host tile 1011 may include a host 10101, a memory controller 10201, and an interface circuit 10301. The memory tile 10401 may include at least one memory die, and may include any one of the memory apparatuses 930a to 930d shown in FIGS. 9A to 9D. The host tile 1011 and the memory tile 10401 may be disposed on and electrically connected to a base tile 10011. The base tile 10011 may include signal paths for electrically connecting a plurality of tiles mounted on the base tile 10011. The base tile 10011 may be disposed on a substrate 10021. The substrate 10021 may include any one of an interposer, a package substrate, an organic substrate, and a redistribution layer. The host 10101 and the memory controller 10201 may be electrically connected through a signal transmission line inside the host tile 1011, and the memory controller 10201 and the interface circuit 10301 may be electrically connected through a signal transmission line inside the host tile 1011. The interface circuit 10301 may be electrically connected to the memory tile 10401 through a signal path 10311 formed inside the base tile 10011. The signal transmission line electrically connecting the host 10101 and the memory controller 10201 may correspond to the first bus 150 shown in FIG. 1. The signal transmission line electrically connecting the memory controller 10201 to the interface circuit 10301 may correspond to the second bus 160 shown in FIG. 1. The signal path 10311 formed inside the base tile 10011 and electrically connecting the interface circuit 10301 and the memory tile 10401 may correspond to the third bus 170 shown in FIG. 1. Some or all of the host tile 1011 and the memory tile 10401 may be manufactured using process technologies of different characteristics. The host tile 1011, the memory tile 10401, the base tile 10011, and the substrate 10021 may be packaged in one package to form a single semiconductor apparatus.

FIG. 10M is a diagram illustrating a configuration and connection relationship of an integrated circuit package 1000m according to an embodiment of the present disclosure. Referring to FIG. 10M, the integrated circuit package 1000m may include a plurality of host tiles and a plurality of memory tiles. The integrated circuit package 1000m may include a first host tile 101m-1, a second host tile 101m-2, a first memory tile 1040m-1, and a second memory tile 1040m-2. The first host tile 101m-1 may include a first host 1010m-1, a first memory controller 1020m-1, and a first interface circuit 1030m-1. The second host tile 101m-2 may include a second host 1010m-2, a second memory controller 1020m-2, and a second interface circuit 1030m-2. The first memory tile 1040m-1 may include at least one memory die, and may include any one of the memory apparatuses 930b to 930d shown in FIGS. 9B to 9D. The second memory tile 1040m-2 may include at least one memory die, and may include any one of the memory apparatuses 930a to 930d shown in FIGS. 9A to 9D. The second memory tile 1040m-2 may have substantially the same structure as the first memory tile 1040m-1, or may have a different structure than the first memory tile 1040m-1. In an embodiment, the first host tile 101m-1 may further include a first host interface 1050m-1 and the second host tile 101m-2 may further include a second host interface 1050m-2. The first and second host tiles 101m-1, 101m-2 may be electrically connected through the first and second host interfaces 1050m-1, 1050m-2.

The first host tile 101m-1, the second host tile 101m-2, the first memory tile 1040m-1, and the second memory tile 1040m-2 may be disposed on and electrically connected to a base tile 1001m. The base tile 1001m may include signal paths for electrically connecting a plurality of tiles mounted on the base tile 1001m. Although not shown, a plurality of signal paths may be formed within the base tile 1001m for electrically connecting the first host tile 101m-1 and the second host tile 101m-2, the first host tile 101m-1 and the first memory tile 1040m-1, and the second host tile 101m-2 and the second memory tile 1040m-2. The base tile 1001m may be disposed on a substrate 1002m. The substrate 1002m may include any one of an interposer, a package substrate, an organic substrate, and a redistribution layer. The first host 1010m-1 and the first memory controller 1020m-1 may be electrically connected through a signal transmission line inside the first host tile 101m-1, and the first memory controller 1020m-1 and the first interface circuit 1030m-1 may be electrically connected through a signal transmission line inside the first host tile 101m-1. The first interface circuit 1030m-1 may be electrically connected to the first memory tile 1040m-1 through a signal path 1031m-1 formed in the base tile 1001m. The second host 1010m-2 and the second memory controller 1020m-2 may be electrically connected through a signal transmission line inside the second host tile 101m-2, and the second memory controller 1020m-2 and the second interface circuit 1030m-2 may be electrically connected through a signal transmission line inside the second host tile 101m-2. The second interface circuit 1030m-2 may be electrically connected to the second memory tile 1040m-2 through a signal path 1031m-2 formed in the base tile 1001m. The first host tile 101m-1 may be electrically connected to the second host tile 101m-2 through a signal path 1051m formed in the base tile 1001m. The signal path 1051m may electrically connect between the first and second host interfaces 1050m-1 and 1050m-2. The signal transmission lines electrically connecting the first and second hosts 1010m-1, 1010m-2 and the signal transmission lines electrically connecting the first and second memory controllers 1020m-1, 1020m-2, may correspond respectively to the first bus 150 shown in FIG. 1. The signal transmission lines electrically connecting the first and second memory controllers 1020m-1 and 1020m-2 and the signal transmission lines electrically connecting the first and second interface circuits 1030m-1 and 1030m-2, may correspond respectively to the second bus 160 shown in FIG. 1. The signal paths formed in the base tile 1001m and electrically connecting the first and second interface circuits 1030m-1 and 1030m-2 and the signal transmission lines electrically connecting the first and second memory tiles 1040m-1 and 1040m-2 may correspond respectively to the third bus 170 shown in FIG. 1. The first host tile 101m-1, the second host tile 101m-2, the first memory tile 1040m-1, the second memory tile 1040m-2, the base tile 1001m, and the substrate 1002m may be packaged in a single package to form a single semiconductor apparatus.

FIG. 10N is a diagram illustrating a configuration and connection relationship of an integrated circuit package 1000n according to an embodiment of the present disclosure. Referring to FIG. 10N, the integrated circuit package 1000n may include at least one host, a plurality of controller dies, and a plurality of memory apparatuses. In FIG. 10N, the integrated circuit package 1000n is shown to include six controller dies and six memory apparatuses, but this exemplary illustration is not intended to limit the number of controller dies and memory apparatuses that the integrated circuit package 1000n includes. The integrated circuit package 1000n may include two, four, or eight or more controller dies, and may include two, four, or eight or more memory apparatuses electrically connected with each of the controller dies. In an embodiment, the number of memory apparatuses electrically connected with one controller die may be two or more. The integrated circuit package 1000n may include a host 1010n, a first controller die 101n-1, a second controller die 101n-2, a third controller die 101n-3, a fourth controller die 101n-4, and a fifth controller die 101n-5, a sixth controller die 101n-6, a first memory apparatus 1040n-1, a second memory apparatus 1040n-2, a third memory apparatus 1040n-3, a fourth memory apparatus 1040n-4, a fifth memory apparatus 1040n-5, and a sixth memory apparatus 1040n-6. The host 1010n may be manufactured in a single die or tile, and may include a plurality of processor cores. The host 1010n may be manufactured as a core complex die, which includes at least two processor cores. Each of the first to six controller dies 101n-1, 101n-2, 101n-3, 101n-4, 101n-5, 101n-6 may be manufactured in a single die or tile. Each of the first to six controller dies 101n-1, 101n-2, 101n-3, 101n-4, 101n-5, 101n-6 may include a memory controller MC and an interface circuit IF. The memory controllers MC and the interface circuits IF of the first to sixth controller dies 101n-1, 101n-2, 101n-3, 101n-4, 101n-5, 101n-6 may be respectively electrically connected through signal transmission paths inside the first to sixth controller dies 101n-1, 101n-2, 101n-3, 101n-4, 101n-5, 101n-6, respectively. The first to six memory apparatuses 1040n-1, 1040n-2, 1040n-3, 1040n-4, 1040n-5, 1040n-6 may each include at least one memory die. Each of the first to six memory apparatuses 1040n-1, 1040n-2, 1040n-3, 1040n-4, 1040n-5, 1040n-6 may include at least one of the memory apparatuses 940a to 940d illustrated in FIGS. 9A to 9D. All of the first to six memory apparatuses 1040n-1, 1040n-2, 1040n-3, 1040n-4, 1040n-5, 1040n-6 may have the same structure, or some or all of the first to six memory apparatuses 1040n-1, 1040n-2, 1040n-3, 1040n-4, 1040n-5, 1040n-6 may have different structures.

The host 1010n, the first to six controller dies 101n-1, 101n-2, 101n-3, 101n-4, 101n-5, 101n-6, and the first to six memory apparatuses 1040n-1, 1040n-2, 1040n-3, 1040n-4, 1040n-5, 1040n-6 may be disposed on a first substrate 1001n. The first substrate 1001n may include an interposer. The first substrate 1001n may include signal paths for electrically connecting the host 1010n and the first to six controller dies 101n-1, 101n-2, 101n-3, 101n-4, 101n-5, 101n-6, respectively, and signal paths for electrically connecting the first to six controller dies 101n-1, 101n-2, 101n-3, 101n-4, 101n-5, 101n-6 and the first to sixth memory apparatuses 1040n-1, 1040n-2, 1040n-3, 1040n-4, 1040n-5, 1040n-6, respectively. In an embodiment, the first substrate 1001n may be replaced by a base tile, and the host 1010n, the first to six controller dies 101n-1, 101n-2, 101n-3, 101n-4, 101n-5, 101n-6, and the first to six memory apparatuses 1040n-1, 1040n-2, 1040n-3, 1040n-4, 1040n-5, 1040n-6 may each be manufactured as a separate and independent tile that is electrically connected with the base tile. The integrated circuit package 1000n may further include a second substrate 1002n, and the first substrate 1001n may be disposed on the second substrate 1002n. The second substrate 1002n may include an interposer or package substrate. The host 1010n and a memory controller MC of the first controller die 101n-1 may be electrically connected through a signal path formed in the first substrate 1001n. An interface circuit IF of the first controller die 101n-1 and the first memory apparatus 1040n-1 may be electrically connected through a signal path formed in the first substrate 1001n. The host 1010n and a memory controller MC of the second controller die 101n-2 may be electrically connected through a signal path formed in the first substrate 1001n. An interface circuit IF of the second controller die 101n-2 and the second memory apparatus 1040n-2 may be electrically connected through a signal path formed in the first substrate 1001n. The host 1010n and a memory controller MC of the third controller die 101n-3 may be electrically connected through a signal path formed in the first substrate 1001n. An interface circuit IF of the third controller die 101n-3 and the third memory apparatus 1040n-3 may be electrically connected through a signal path formed in the first substrate 1001n. The host 1010n and a memory controller MC of the fourth controller die 101n-4 may be electrically connected through a signal path formed in the first substrate 1001n. An interface circuit IF of the fourth controller die 101n-4 and the fourth memory apparatus 1040n-4 may be electrically connected through a signal path formed in the first substrate 1001n. The host 1010n and a memory controller MC of the fifth controller die 101n-5 may be electrically connected through a signal path formed in the first substrate 1001n. An interface circuit IF of the fifth controller die 101n-5 and the fifth memory apparatus 1040n-5 may be electrically connected through a signal path formed in the first substrate 1001n. The host 1010n and a memory controller MC of the sixth controller die 101n-6 may be electrically connected through a signal path formed in the first substrate 1001n. An interface circuit IF of the sixth controller die 101n-6 and the sixth memory apparatus 1040n-6 may be electrically connected through a signal path formed in the first substrate 1001n. The signal paths electrically connecting the host 1010n and the memory controllers MC of the first to six controller dies 101n-1, 101n-2, 101n-3, 101n-4, 101n-5, 101n-6, respectively, may each correspond to the first bus 150 shown in FIG. 1. The signal transmission lines electrically connecting the memory controllers MC of the first to sixth controller dies 101n-1, 101n-2, 101n-3, 101n-4, 101n-5, 101n-6 to the interface circuits IF, respectively, may each correspond to the second bus 160 shown in FIG. 1. The signal paths electrically connecting the interface circuits IF of the first to six controller dies 101n-1, 101n-2, 101n-3, 101n-4, 101n-5, 101n-6 and the first to six memory apparatuses 1040n-1, 1040n-2, 1040n-3, 1040n-4, 1040n-5, 1040n-6, respectively, may each correspond to the third bus 170 shown in FIG. 1. The host 1010n, the first to six controller dies 101n-1, 101n-2, 101n-3, 101n-4, 101n-5, 101n-6, the first to six memory apparatuses 1040n-1, 1040n-2, 1040n-3, 1040n-4, 1040n-5, 1040n-6, the first substrate 1001n, and the second substrate 1002n may be packaged in one package to form a single semiconductor apparatus.

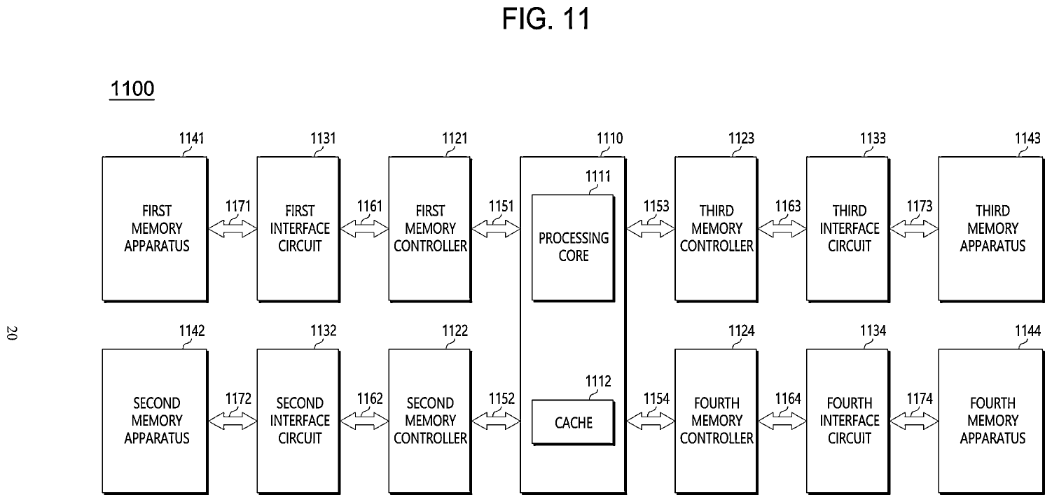

FIG. 11 is a diagram illustrating a configuration of a computing system 1100 according to an embodiment of the present disclosure. Referring to FIG. 11, the computing system 1100 may be a computing logic hardware that includes at least one of a system on chip (SoC), a central processing unit (CPU), a graphic processing unit (GPU), a field programmable gate array (FPGA), a data processing unit (DPU), a vision processing unit (VPU), a neural processing unit (NPU), and an application specific integrated circuit (ASIC) as a computing architecture suitable for performing various applications executed by a user. The computing system 1100 may include a host 1110, a first memory controller 1121, a second memory controller 1122, a third memory controller 1123, a fourth memory controller 1124, a first interface circuit 1131, a second interface circuit 1132, a third interface circuit 1133, a fourth interface circuit 1134, a first memory apparatus 1141, a second memory apparatus 1142, a third memory apparatus 1143, and a fourth memory apparatus 1144. The host 1110 may generate access requests to access the first to fourth memory apparatuses 1141, 1142, 1143, 1144 to perform data communications. The host 1110 may selectively access at least one of the first to fourth memory apparatuses 1141, 1142, 1143, 1144, and may access at least two of the first to fourth memory apparatuses 1141, 1142, 1143, 1144 simultaneously. The host 1110 may include a processing core 1111 and a cache 1112. The processing core 1111 may generate a plurality of access requests to access each of the first to fourth memory apparatuses 1141, 1142, 1143, 1144 to perform computational operations required for execution of the applications. The processing core 1111 may include at least one core. The processing core 1111 may include one core, and the one core may generate a plurality of access requests to access the first to fourth memory apparatuses 1141, 1142, 1143, 1144 one by one or simultaneously. The processing core 1111 may include two or more cores, and the two or more cores may independently generate a plurality of access requests for accessing one or more of the first to fourth memory apparatuses 1141, 1142, 1143, 1144. The cache 1112 may be configured as a computer memory buffer to mitigate the difference in operating speed between the host 1110 and the first to fourth memory apparatuses 1141, 1142, 1143, 1144. The cache 1112 may improve the operating speed and/or performance of the host 1110 because the processing core 1111 does not need to access the first to fourth memory apparatuses 1141, 1142, 1143, 1144 if the data or computation results required by the processing core 1111 are stored in the cache 1112.

The host 1110 may be electrically connected to the first memory controller 1121 through a first host bus 1151. The host 1110 may transmit an access request and data to the first memory controller 1121 through the first host bus 1151 to access the first memory apparatus 1141, and may receive data from the first memory controller 1121. The host 1110 may be electrically connected to the second memory controller 1122 through a second host bus 1152. The host 1110 may transmit an access request and data to the second memory controller 1122 through the second host bus 1152 to access the second memory apparatus 1142, and may receive data from the second memory controller 1122. The host 1110 may be electrically connected to the third memory controller 1123 through a third host bus 1153. The host 1110 may transmit an access request and data to the third memory controller 1123 through the third host bus 1153 to access the third memory apparatus 1143, and may receive data from the third memory controller 1123. The host 1110 may be electrically connected to the fourth memory controller 1124 through a fourth host bus 1154. The host 1110 may transmit an access request and data to the fourth memory controller 1124 through the fourth host bus 1154 to access the fourth memory apparatus 1144, and may receive data from the fourth memory controller 1124. The first bus 150 illustrated in FIG. 1 may be applied as each of the first to fourth host buses 1151, 1152, 1153, 1154, and each of the first to fourth host buses 1151, 1152, 1153, 1154 may have substantially the same characteristics as the first bus 150.

The first memory controller 1121 may be electrically connected to the first interface circuit 1131 through a first controller bus 1161. The first memory controller 1121 may generate a command signal, an address signal, and a write data signal based on the access request and data received from the host 1110. The first memory controller 1121 may transmit the command signal, the address signal, and the write data signal to the first interface circuit 1131 through the first controller bus 1161, and may receive a read data signal from the first interface circuit 1131. The first memory controller 1121 may generate data that is transmitted to the host 1110 through the first host bus 1151 based on the read data signal. The second memory controller 1122 may be electrically connected to the second interface circuit 1132 through a second controller bus 1162. The second memory controller 1122 may generate a command signal, an address signal, and a write data signal based on the access request and data received from the host 1110. The second memory controller 1122 may transmit the command signal, the address signal, and the write data signal to the second interface circuit 1132 through the second controller bus 1162, and may receive a read data signal from the second interface circuit 1132. The second memory controller 1122 may generate data based on the read data signal that is transmitted to the host 1110 through the second host bus 1152. The third memory controller 1123 may be electrically connected to the third interface circuit 1133 through a third controller bus 1163. The third memory controller 1123 may generate a command signal, an address signal, and a write data signal based on the access request and data received from the host 1110. The third memory controller 1123 may transmit the command signal, the address signal, and the write data signal to the third interface circuit 1133 through the third controller bus 1163, and may receive a read data signal from the third interface circuit 1133. The third memory controller 1123 may generate data that is transmitted to the host 1110 through the third host bus 1153 based on the read data signal. The fourth memory controller 1124 may be electrically connected to the fourth interface circuit 1134 through a fourth controller bus 1164. The fourth memory controller 1124 may generate a command signal, an address signal, and a write data signal based on the access request and data received from the host 1110. The fourth memory controller 1124 may transmit the command signal, the address signal, and the write data signal to the fourth interface circuit 1134 through the fourth controller bus 1164, and may receive a read data signal from the fourth interface circuit 1134. The fourth memory controller 1124 may generate data that is transmitted to the host 1110 through the fourth host bus 1154 based on the read data signal. The second bus 160 illustrated in FIG. 1 may be applied as each of the first to fourth controller buses 1161, 1162, 1163, 1164, and each of the first to fourth controller buses 1161, 1162, 1163, 1164 may have substantially the same characteristics as the second bus 160.

The first interface circuit 1131 may be electrically connected to the first memory apparatus 1141 through a first memory bus 1171. The first interface circuit 1131 may generate a row address signal, a column address signal, a command signal, and a memory data signal based on the command signal, the address signal, and the write data signal received from the first memory controller 1121 through the first controller bus 1161. The first interface circuit 1131 may transmit the row address signal, the column address signal, the command signal, and the memory data signal to the first memory apparatus 1141 through the first memory bus 1171. The first interface circuit 1131 may receive the memory data signal transmitted from the first memory apparatus 1141 through the first memory bus 1171, and may generate a read data signal based on the memory data signal. The first interface circuit 1131 may transmit the read data signal to the first memory controller 1121 through the first controller bus 1161. The second interface circuit 1132 may be electrically connected to the second memory apparatus 1142 through a second memory bus 1172. The second interface circuit 1132 may generate a row address signal, a column address signal, a command signal, and a memory data signal based on the command signal, the address signal, and the write data signal received from the second memory controller 1122 through the second controller bus 1162. The second interface circuit 1132 may transmit the row address signal, the column address signal, the command signal, and the memory data signal to the second memory apparatus 1142 through the second memory bus 1172. The second interface circuit 1132 may receive the memory data signal transmitted from the second memory apparatus 1142 through the second memory bus 1172, and may generate a read data signal based on the memory data signal. The second interface circuit 1132 may transmit the read data signal to the second memory controller 122 through the second controller bus 1162. The third interface circuit 1133 may be electrically connected to the third memory apparatus 1143 through a third memory bus 1173. The third interface circuit 1133 may generate a row address signal, a column address signal, a command signal, and a memory data signal based on the command signal, the address signal, and the write data signal received from the third memory controller 1123 through the third controller bus 1163. The third interface circuit 1133 may transmit the row address signal, the column address signal, the command signal, and the memory data signal to the third memory apparatus 1143 through the third memory bus 1173. The third interface circuit 1133 may receive the memory data signal transmitted from the third memory apparatus 1143 through the third memory bus 1173, and may generate a read data signal based on the memory data signal. The third interface circuit 1133 may transmit the read data signal to the third memory controller 1123 through the third controller bus 1163. The fourth interface circuit 1134 may be electrically connected to the fourth memory apparatus 1144 through a fourth memory bus 1174. The fourth interface circuit 1134 may generate a row address signal, a column address signal, a command signal, and a memory data signal based on the command signal, the address signal, and the write data signal received from the fourth memory controller 1124 through the fourth controller bus 1164. The fourth interface circuit 1134 may transmit the row address signal, the column address signal, the command signal, and the memory data signal to the fourth memory apparatus 1144 through the fourth memory bus 1174. The fourth interface circuit 1134 may receive the memory data signal transmitted from the fourth memory apparatus 1144 through the fourth memory bus 1174, and may generate a read data signal based on the memory data signal. The fourth interface circuit 1134 may transmit the read data signal to the fourth memory controller 1124 through the fourth controller bus 1164. The third bus 170 illustrated in FIG. 1 may be applied as each of the first to fourth memory buses 1171, 1172, 1173, 1174, and each of the first to fourth memory buses 1171, 1172, 1173, 1174 may have substantially the same characteristics as the third bus 170.

Each of the first to fourth memory apparatuses 1141, 1142, 1143, 1144 may include at least one memory die. When the first to fourth memory apparatuses 1141, 1142, 1143, 1144 each include two or more memory dies, the first to fourth memory apparatuses 1141, 1142, 1143, 1144 may each have a stacked chip structure. The two or more memory dies may be electrically connected to each other through wire bonding or through vias.

In an embodiment, the host 1110, the first to fourth memory controllers 1121, 1122, 1123, 1124, and the first to fourth interface circuits 1131, 1132, 1133, 1134 may be integrated into a first device, and the first to fourth memory apparatuses 1141, 1142, 1143, 1144 may constitute second to fifth devices, respectively. In an embodiment, the host 1110 and the first to fourth memory controllers 1121, 1122, 1123, 1124 may be integrated into a first device, the first interface circuit 1131 and the first memory apparatus 1141 may be integrated into a second device. The second interface circuit 1132 and the second memory apparatus 1142 may be integrated into a third device, the third interface circuit 1133 and the third memory apparatus 1143 may be integrated into a fourth device, and the fourth interface circuit 1134 and the fourth memory apparatus 1144 may be integrated into a fifth device. In an embodiment, the host 1110 may constitute a first device, and the first memory controller 1121, the first interface circuit 1131, and the first memory apparatus 1141 may be integrated into a second device. The second memory controller 1122, the second interface circuit 1132, and the second memory apparatus 1142 may be integrated into a third device. The third memory controller 1123, the third interface circuit 1133, and the third memory apparatus 1143 may be integrated into a fourth device. The fourth memory controller 1124, the fourth interface circuit 1134, and the fourth memory apparatus 1144 may be integrated into a fifth device. In an embodiment, the host 1110, the first to fourth memory controllers 1121, 1122, 1123, 1124, the first to fourth interface circuits 1131, 1132, 1133, 1134, and the first to fourth memory apparatuses 1141, 1142, 1143, 1144 may each be manufactured as independent semiconductor apparatuses. The host 1110, the first to fourth memory controllers 1121, 1122, 1123, 1124, the first to fourth interface circuits 1131, 1132, 1133, 1134, and the first to fourth memory apparatuses 1141, 1142, 1143, 1144 may be manufactured as tiles or chiplets and mounted on at least one base tile or base chiplet.

The first memory apparatus 1141 may perform parallel data communication with the first interface circuit 1131 and the first memory controller 1121 through the first memory bus 1171. The second memory apparatus 1142 may perform parallel data communication with the second interface circuit 1132 and the second memory controller 1122 through the second memory bus 1172. The third memory apparatus 1143 may perform parallel data communication with the third interface circuit 1133 and the third memory controller 1123 through the third memory bus 1173. The fourth memory apparatus 1144 may perform parallel data communication with the fourth interface circuit 1134 and the fourth memory controller 1124 through the fourth memory bus 1174. In an embodiment, at least one of the first to fourth memory buses 1171, 1172, 1173, 1174 may have different characteristics than the third bus 170. For example, a width of the fourth memory bus 1174 may be less than a width of the fourth controller bus 1164, and a clock rate of the fourth memory bus 1174 may be higher than a clock rate of the fourth controller bus 1164. When the first to third memory apparatuses 1141, 1142, 1143 perform parallel data communication through the first to third memory buses 1171, 1172, 1173, the fourth memory apparatus 1144 may perform serial data communication through the fourth memory bus 1174. When the fourth memory apparatus 1144 performs serial data communication, the fourth memory apparatus 1144 and the fourth interface circuit 1134 may be equipped with a SerDes for converting parallel data to serial data or converting serial data to parallel data.

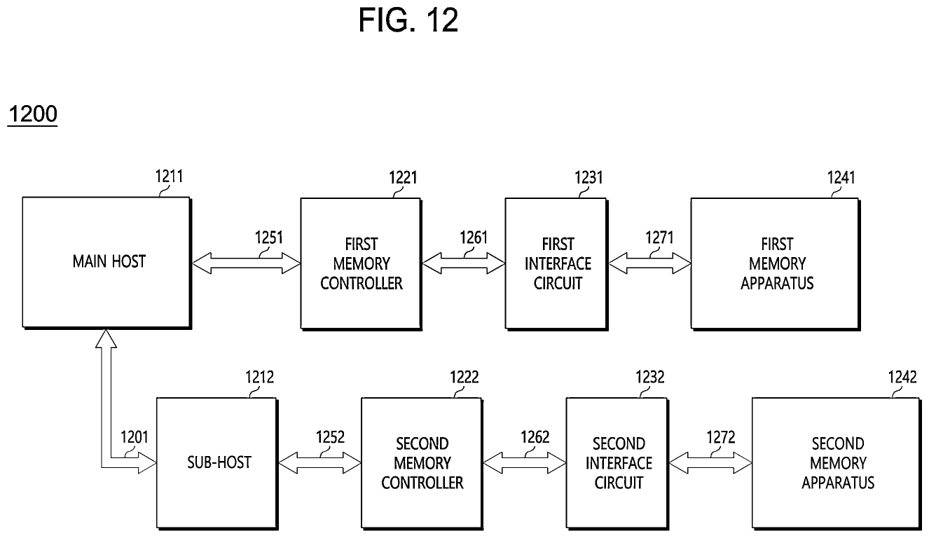

FIG. 12 is a diagram illustrating a configuration of a computing system 1200 according to an embodiment of the present disclosure. Referring to FIG. 12, the computing system 1200 may include a main host 1211, a sub-host 1212, a first memory controller 1221, a first interface circuit 1231, a first memory apparatus 1241, a second memory controller 1222, a second interface circuit 1232, and a second memory apparatus 1242. The main host 1211 may generate an access request to access the first memory apparatus 1241, and may provide the access request to the first memory controller 1221. The main host 1211 may be electrically connected to the first memory controller 1221 through a first host bus 1251, and may provide the access request to the first memory controller 1221 through the first host bus 1251. The first host bus 1251 may have substantially the same characteristics as the first bus 150 illustrated in FIG. 1. The main host 1211 may perform various computational operations, and may access the sub-host 1212 to perform all or some of computational operations in parallel. For example, the main host 1211 may perform a portion of total workload, and the sub-host 1212 may be controlled by the main host 1211 to perform remaining workload among the total workload. The sub-host 1212 may have the same kind of processing core as the main host 1211, or may have a different kind of processing core than the main host 1211. In an embodiment, the sub-host 1212 may be controlled by the main host 1211 to perform functions that increase the amount of memory capacity that can be utilized by the main host 1211. The sub-host 1212 may accelerate the computational performance and/or speed of the main host 1211 by providing additional data required for computational operations of the main host 1211. The sub-host 1212 may be, for example, a Compute eXpress Link (CXL) core. The main host 1211 may be electrically connected to the sub-host 1212 through a system bus 1201, and may provide a control signal for controlling the sub-host 1212 to the sub-host 1212 through the system bus 1201. The sub-host 1212 may generate an access request for accessing the second memory apparatus 1242 based on the control signal provided from the main host 1211, and may provide the access request to the second memory controller 1222. The system bus 1201 may include a standard protocol for electrically connecting the main host 1211 and the sub-host 1212.

The sub-host 1212 may generate an access request to access the second memory apparatus 1242, and may provide the access request to the second memory controller 1222. The sub-host 1212 may be electrically connected to the second memory controller 1222 through a second host bus 1252, and may transmit the access request to the second memory controller 1222 through the second host bus 1252. The second host bus 1252 may have substantially the same characteristics as the first host bus 1251. In an embodiment, the second host bus 1252 may have different characteristics than the first host bus 1251, and may utilize a standard protocol having a different specification than the first host bus 1251.

The first memory controller 1221 may be electrically connected to the first interface circuit 1231 through a first controller bus 1261. The first interface circuit 1231 may be electrically connected to the first memory apparatus 1241 through a first memory bus 1271. The first controller bus 1261 may have substantially the same characteristics as the second bus 160 illustrated in FIG. 1, and the first memory bus 1271 may have substantially the same characteristics as the third bus 170 illustrated in FIG. 1. In an embodiment, a width of the data bus included in the first controller bus 1261 may be less than or equal to a width of the data bus included in the first memory bus 1271. The second memory controller 1222 may be electrically connected to the second interface circuit 1232 through a second controller bus 1262. The second interface circuit 1232 may be electrically connected to the second memory apparatus 1242 through a second memory bus 1272. The second controller bus 1262 may have substantially the same characteristics as the first controller bus 1261, and the second memory bus 1272 may have substantially the same characteristics as the first memory bus 1271. In an embodiment, a width of the data bus included in the second controller bus 1262 may be less than or equal to a width of the data bus included in the second memory bus 1272.

In an embodiment, the first controller bus 1261 and the first memory bus 1271 may have substantially the same characteristics as the second bus 160 and the third bus 170, respectively, while the second controller bus 1262 and the second memory bus 1272 may have different characteristics than the first controller bus 1261 and the first memory bus 1271. For example, the first memory apparatus 1241 may perform parallel data communication with the first interface circuit 1231, while the second memory apparatus 1242 may perform serial data communication with the second interface circuit 1232. A width of the data bus included in the second memory bus 1272 may be less than a width of the data bus included in the second controller bus 1262. A clock rate of the second memory bus 1272 may be higher than a clock rate of the second controller bus 1262. In an embodiment, the second controller bus 1262 and the second memory bus 1272 may have substantially the same characteristics as the second bus 160 and third bus 170, respectively, while the first controller bus 1261 and the first memory bus 1271 may have different characteristics than the second controller bus 1262 and the second memory bus 1272. For example, the second memory apparatus 1242 may perform parallel data communication with the second interface circuit 1232, while the first memory apparatus 1241 may perform serial data communication with the first interface circuit 1231. A width of the first memory bus 1271 may be less than a width of the first controller bus 1261, and a clock rate of the first memory bus 1271 may be higher than a clock rate of the first controller bus 1261.

In an embodiment, the sub-host 1212, the second memory controller 1222, the second interface circuit 1232, and the second memory apparatus 1242 may be disposed on a single interposer and/or substrate, and may be manufactured as a single semiconductor apparatus. The sub-host 1212, the second memory controller 1222, and the second interface circuit 1232 may perform functions of a dedicated controller device to allow the second memory apparatus 1242 to perform data communication with an external host device (e.g., the main host 1211). The single semiconductor apparatus may be manufactured as a dual in-line memory module (DIMM) to provide a large amount of data storage space to the main host 1211. For example, the single semiconductor apparatus may be a Managed Dram Solution (MDS). In an embodiment, the sub-host 1212, the second memory controller 1222, the second interface circuit 1232, and the second memory apparatus 1242 may be manufactured as independent dies, tiles, or chiplets.

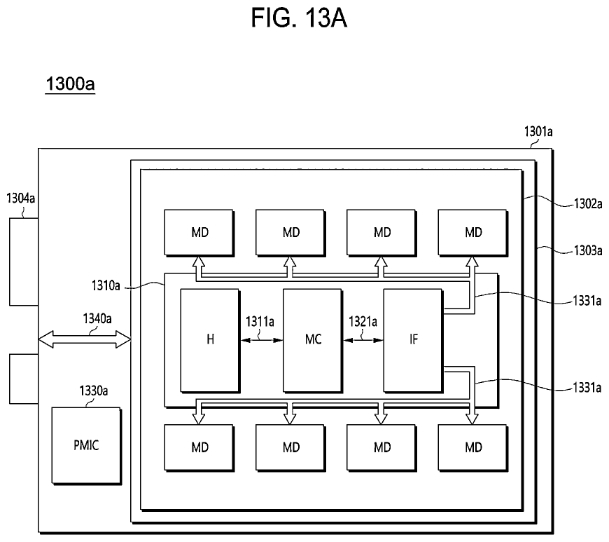

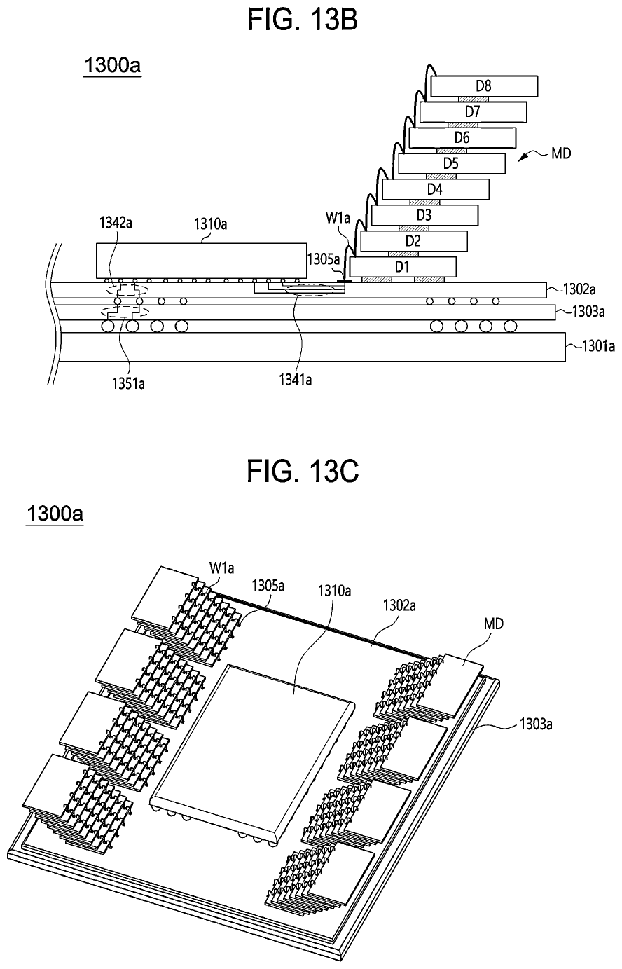

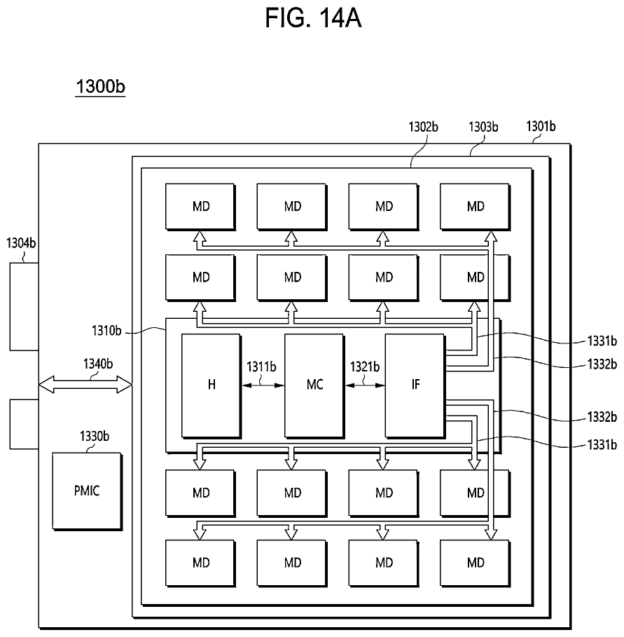

FIGS. 13A to 13C are diagrams illustrating a configuration of a semiconductor apparatus 1300a according to an embodiment of the present disclosure. FIG. 13A is a conceptual plan view of the semiconductor apparatus 1300a, FIG. 13B is a cross-sectional view of the semiconductor apparatus 1300a, and FIG. 13C is a perspective view of the semiconductor apparatus 1300a. The semiconductor apparatus 1300a may be a memory system, such as a CXL module or a CXL device. The semiconductor apparatus 1300a may include a controller device 1310a and a plurality of memory media MD. The semiconductor apparatus 1300a may include a module substrate 1301a. The module substrate 1301a may include a module pin 1304a, and may communicate with an external device through the module pin 1304a. For example, the external device may be the main host 1211 shown in FIG. 12, and the module pin 1304a may be electrically connected to the system bus 1201 shown in FIG. 12. The semiconductor apparatus 1300a may be electrically connected to the external device through the module pin 1304a by inserting the module pin 1304a into a slot and/or channel formed in a main board. A package substrate 1303a may be mounted on the module substrate 1301a, and the package substrate 1303a may be electrically connected to the module substrate 1301a through package balls and/or solder balls. On the package substrate 1303a, an interposer 1302a may be stacked. The interposer 1302a may be electrically connected to the package substrate 1303a using bumps. The controller device 1310a and the plurality of memory media MD may be disposed on the interposer 1302a. The package substrate 1303a, the interposer 1302a, the controller device 1310a, and the plurality of memory media MD may be packaged in a single package, and the single package may be mounted on the module substrate 1301a. The controller device 1310a may be disposed on the interposer 1302a and electrically connected to the interposer 1302a through microbumps. The plurality of memory media MD may be disposed on the interposer 1302a. The controller device 1310a may be disposed in a first region on the interposer 1302a, and the plurality of memory media MD may be disposed in a second region on the interposer 1302a. The first and second regions might not overlap each other.

The host H may be electrically connected to the module substrate 1301a and the external device through a system bus 1340a. The host H may be electrically connected to the memory controller MC through a host bus 1311a. The memory controller MC may be electrically connected to the interface circuit IF through a controller bus 1321a, and the interface circuit IF may be electrically connected to each of the plurality of memory media MD through a plurality of memory buses 1331a. The controller bus 1321a may have substantially the same characteristics as the second bus 160 shown in FIG. 1, and each of the plurality of memory buses 1331a may have substantially the same characteristics as the third bus 170 shown in FIG. 1. Each of the plurality of memory media MD may perform parallel data communication with the interface circuit IF. The interface circuit IF may perform parallel data communication with the memory controller MC, or may perform partial parallel data communication. A width of each of the plurality of memory buses 1331a may be greater than or equal to a width of the controller bus 1321a, and a clock rate of each of the plurality of memory buses 1331a may be less than or equal to a clock rate of the controller bus 1321a.

The controller device 1310a may relay data communication between the external device and the plurality of memory media MD. The controller device 1310a may include a host H, a memory controller MC, and an interface circuit IF. The host H may correspond to the sub-host 1212 shown in FIG. 12, the memory controller MC may correspond to the second memory controller 1222 shown in FIG. 12, and the interface circuit IF may correspond to the second interface circuit 1232 shown in FIG. 12. A redundant description of the corresponding components will be omitted. The controller device 1310a may be electrically connected with a plurality of memory media MD and may perform data communication with the plurality of memory media MD. The controller device 1310a may be electrically connected to each of the plurality of memory media MD through the interface circuit IF. Each of the plurality of memory media MD may correspond to the second memory apparatus 1242 shown in FIG. 12. The plurality of memory media MD may form independent channels and may each be electrically connected with the interface circuit IF of the controller device 1310a through independent memory buses. In FIGS. 13A to 13C, the semiconductor apparatus 1300a is illustrated as having eight memory media, but the number of memory media that the semiconductor apparatus 1300a has may be less than eight or more than eight. Each of the plurality of memory media MD may include at least one memory die. When each of the plurality of memory media MD includes two or more memory dies, the two or more memory dies may be stacked to form a single memory media. In FIGS. 13B and 13C, one memory media includes eight memory dies, but the number of memory dies that one memory media includes may be less than or greater than eight.

The controller device 1310a may be electrically connected to the module substrate 1301a through a signal path 1342a formed in the interposer 1302a and a signal path 1351a formed in the package substrate 1303a. The controller device 1310a may be electrically connected to the pads 1305a formed in the interposer 1302a through a signal path 1341a formed in the interposer 1302a. The host H may be electrically connected to the module substrate 1301a through the signal path 1342a and the signal path 1351a. The interface circuit IF may be electrically connected to the pads 1305a through the signal path 1341a. The plurality of memory media MD may be electrically connected to the pads 1305a through a wire bonding W1a, respectively. The plurality of memory media MD may be electrically connected to the controller device 1310a through the wire bonding W1a and the signal path 1341a. The interface circuit IF may be electrically connected to the plurality of memory media MD through the signal path 1341a and the wire bonding W1a, respectively. The signal path 1341a and the wire bonding W1a may correspond to the plurality of the memory busses 1331a.

A first memory die D1 of the memory media MD may be bonded to the interposer 1302a using DAF. The second to eighth memory dies D2, D3, D4, D5, D6, D7, D8 may also be bonded sequentially with the first to seventh memory dies D1, D2, D3, D4, D5, D6, D7, respectively, using DAF. The first to eighth memory dies D1, D2, D3, D4, D5, D6, D7, D8 may be electrically connected using a wire bonding. The first to eighth memory dies D1, D2, D3, D4, D5, D6, D7, D8 may be electrically connected to the interposer 1302a by wire bonding with the pads 1305a. The pads 1305a may be electrically connected to the controller device 1310a through the signal path 1341a. The interface circuit IF may be electrically connected with the signal path 1341a through the microbumps, so that electrical connection may be formed between the interface circuit IF and the memory dies. A frequency of the signals transmitted through the controller bus 1321a between the memory controller MC and the interface circuit IF may be greater than or equal to a frequency of the signals transmitted through the signal path 1341c and the wire bonding W1a between the interface circuit IF and the memory media MD. The controller bus 1321a may include a first data bus that electrically connects the memory controller MC and the interface circuit IF, and the signal path 1341a may include a second data bus that electrically connects the interface circuit IF and the memory media MD. A width of the first data bus may be less than or equal to a width of the second data bus.

The semiconductor apparatus 1300a may further include a power management integrated circuit PMIC 1330a. The power management integrated circuit PMIC may be disposed on the module substrate 1301a. In an embodiment, the power management integrated circuit PMIC may be disposed on the interposer 1302a. The power management integrated circuit PMIC may receive an externally applied power supply voltage through the module pin 1304a, and may generate a plurality of internal voltages from the power supply voltage. The power management integrated circuit PMIC may generate the plurality of internal voltages by changing or regulating a voltage level of the externally applied power supply voltage. The plurality of internal voltages may be applied to the host H, the memory controller MC, the interface circuit IF, and the memory media MD, and may be used as operating power voltages for components of the semiconductor apparatus 1300a. The power management integrated circuit PMIC may independently generate internal voltages for the host H, the memory controller MC, the interface circuit IF, and the memory media MD, and the internal voltages may have different voltage levels. In an embodiment, at least two of the internal voltages may have the same voltage level and remaining internal voltages may have different voltage levels.

In an embodiment, the first to eighth memory dies D1, D2, D3, D4, D5, D6, D7, D8 may be stacked in a vertical direction using through vias, and may be electrically connected to the interposer 1302a and adjacent memory dies through the microbumps. When the first to eighth memory dies D1, D2, D3, D4, D5, D6, D7, D8 are stacked on the interposer 1302a using microbumps, the interposer 1302a should be implemented as a silicon interposer. However, if the first to eighth memory dies D1, D2, D3, D4, D5, D6, D7, D8 are stacked using wire bonding and the plurality of memory media MD perform parallel data communication with the controller device 1310a, the interposer 1302a may be an organic interposer instead of the silicon interposer, which is less expensive than the silicon interposer. Thus, if the plurality of memory media MD are stacked using wire bonding, the manufacturing cost of the semiconductor apparatus 1300a may be reduced. Furthermore, if the plurality of memory media MD perform parallel data communication with the controller device 1310a, the bandwidth of the memory bus 1331a can be expanded so that a larger number of data can be received from or transmitted to the controller device 1310a in a shorter time.

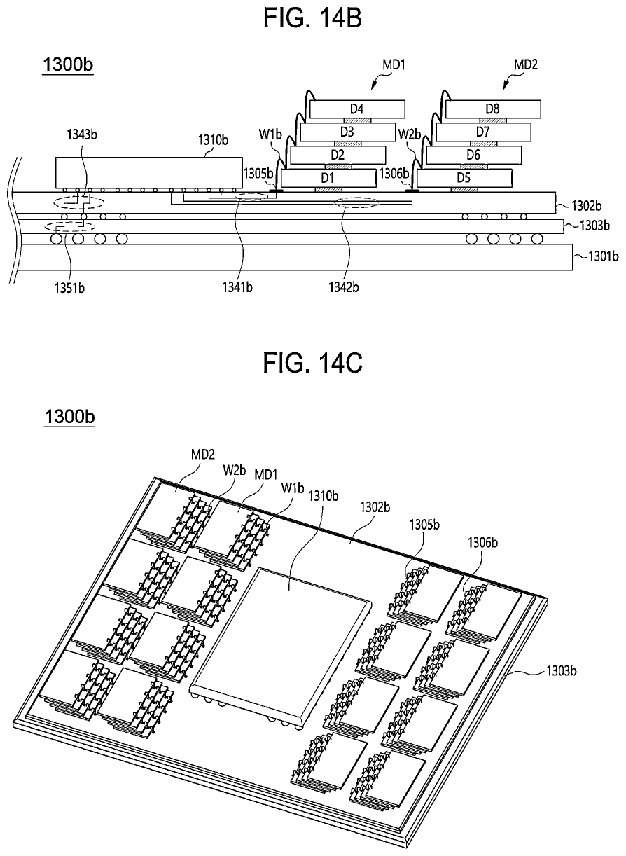

FIGS. 14A to 14C are diagrams illustrating a configuration of a semiconductor apparatus 1300b according to an embodiment of the present disclosure. FIG. 14A may be a conceptual plan view of the semiconductor apparatus 1300b, FIG. 14B may be a cross-sectional view of the semiconductor apparatus 1300b, and FIG. 14C may be a perspective view of the semiconductor apparatus 1300b. The semiconductor apparatus 1300b may be a memory system, such as a CXL module or a CXL device. The semiconductor apparatus 1300b may include a controller device 1310b and a plurality of memory media MD. The semiconductor apparatus 1300b may include a module substrate 1301b. The module substrate 1301b may include a module pin 1304b, and may communicate with an external device through the module pin 1304b. For example, the external device may be the main host 1211 shown in FIG. 12, and the module pin 1304b may be electrically connected to the system bus 1201 shown in FIG. 12. The semiconductor apparatus 1300b may be electrically connected to the external device through a main board by inserting the module pin 1304b into a slot and/or channel formed in the main board. A package substrate 1303b may be mounted on the module substrate 1301b, and the package substrate 1303b may be electrically connected with the module substrate 1301b through package balls and/or solder balls. On the package substrate 1303b, an interposer 1302b may be stacked. The interposer 1302b may be electrically connected to the package substrate 1303b using bumps. The controller device 1310b and the plurality of memory media MD may be disposed on the interposer 1302b. The package substrate 1303b, the interposer 1302b, the controller device 1310b. and the plurality of memory media MD may be packaged in a single package, and the single package may be mounted on the module substrate 1301b. The controller device 1310b may be disposed on the interposer 1302b and electrically connected to the interposer 1302b through microbumps. The plurality of memory media MD may be disposed on the interposer 1302b. The controller device 1310b may be disposed in a first region on the interposer 1302b, and the plurality of memory media MD may be disposed in a second region and a third region on the interposer 1302b. The first, second, and third regions might not overlap each other. For example, some of the plurality of memory media MD may be disposed in the second region, and the remainder of the plurality of memory media MD may be disposed in the third region.

The controller device 1310b may relay data communication between the external device and the plurality of memory media MD. The controller device 1310b may include a host H, a memory controller MC, and an interface circuit IF. The host H may correspond to the sub-host 1212 shown in FIG. 12, the memory controller MC may correspond to the second memory controller 1222 shown in FIG. 12, and the interface circuit IF may correspond to the second interface circuit 1232 shown in FIG. 12. Redundant descriptions of the corresponding components will be omitted. The controller device 1310b may be electrically connected with the plurality of memory media MD, and may perform data communication with the plurality of memory media MD. The controller device 1310b may be electrically connected to each of the plurality of memory media MD through the interface circuit IF. Each of the plurality of memory media MD may correspond to the second memory apparatus 1242 shown in FIG. 12. The plurality of memory media MD may form independent channels and may each be electrically connected with the interface circuit IF of the controller device 1310b through independent memory buses. In FIGS. 14A to 14C, the semiconductor apparatus 1300b is illustrated as having sixteen memory media, but the number of memory media that the semiconductor apparatus 1300b has may be less than sixteen or more than sixteen. Each of the plurality of memory media MD may include at least one memory die. When each of the plurality of memory media includes two or more memory dies, the two or more memory dies may be stacked to form a single memory media. In FIGS. 14B and 14C, one memory media is illustrated to include four memory dies, but the number of memory dies that one memory media includes may be less than or greater than four.

The host H may be electrically connected to the module substrate 1301b and the external device through a system bus 1340b. The host H may be electrically connected to the memory controller MC through a host bus 1311b. The memory controller MC is electrically connected to the interface circuit IF through a controller bus 1321b, and the interface circuit IF may be electrically connected to the plurality of memory media MD through a plurality of memory buses 1331b, 1332b, respectively. The controller bus 1321b may have substantially the same characteristics as the second bus 160 shown in FIG. 1, and each of the plurality of memory buses 1331b, 1332b may have substantially the same characteristics as the third bus 170 shown in FIG. 1. Each of the plurality of memory media MD may perform parallel data communication with the interface circuit IF. The interface circuit IF may perform parallel data communication with the memory controller MC, or may perform partial parallel data communication. A width of each of the plurality of memory buses 1331b, 1332b may be greater than or equal to a width of the controller bus 1321b, and a clock rate of each of the plurality of memory buses 1331b, 1332b may be less than or equal to a clock rate of the controller bus 1321b.

The controller device 1310b may be electrically connected to the module substrate 1301b through a signal path 1343b formed in the interposer 1302b and a signal path 1351b formed in the package substrate 1303b. The controller device 1310b may be electrically connected to a first pads 1305b formed in the interposer 1302b through a first signal path 1341b formed in the interposer 1302b. The controller device 1310b may be electrically connected to a second pads 1306b formed in the interposer 1302b through a second signal path 1342b formed in the interposer 1302b. The host H may be electrically connected to the module substrate 1301b through the signal path 1343b and the signal path 1351b. The interface circuit IF may be electrically connected to the first pads 1305b through the first signal path 1341b, and electrically connected to the second pads 1306b through the second signal path 1342b. The plurality of memory media MD may be electrically connected to the first and second pads 1305b, 1306b through wire bonding, respectively. The plurality of memory media MD may be electrically connected to the controller device 1310b through the wire bonding and the first and second signal paths 1341b, 1342b. The first memory media MD1 may be electrically connected to the first pads 1305b through a wire bonding W1b, and be electrically connected to the controller device 1310b through the first pads 1305b and the first signal path 1341b. The second memory media MD2 may be electrically connected to the second pads 1306b through a wire bonding W2b, and be electrically connected to the controller device 1310b through the second pads 1306b and the second signal path 1342b. The interface circuit IF may be electrically connected to the first memory media MD1 through the first signal path 1341b and the wire bonding W1b. The interface circuit IF may be electrically connected to the second memory media MD2 through the second signal path 1342b and the wire bonding W2b. The first signal path 1341b and the wire bonding W1b may correspond to the first memory bus 1331b, and the second signal path 1342b and the wire bonding W2b may correspond to the second memory bus 1332b.

A first memory die D1 of the first memory media MD1 may be bonded with the interposer 1302b using DAF. The second to fourth memory dies D2, D3, D4 may also be bonded sequentially with the first to third memory dies D1, D2, D3, respectively, using DAF. The first to fourth memory dies D1, D2, D3, D4 may be electrically connected using a wire bonding. The first to fourth memory dies D1, D2, D3, D4 may be electrically connected to the interposer 1302b by wire bonding with first pads 1305b formed on the interposer 1302b. The first pads 1305b may be electrically connected to the controller device 1310b through a first signal path 1341b formed in the interposer 1302b. A first memory die D5 of the second memory media MD2 may be bonded with the interposer 1302b using DAF. The second to fourth memory dies D6, D7, D8 may also be bonded sequentially with the first to third memory dies D5, D6, D7, respectively, using DAF. The first to fourth memory dies D5, D6, D7, D8 may be electrically connected using a wire bonding. The first to fourth memory dies D5, D6, D7, D8 may be electrically connected to the interposer 1302b by wire bonding with second pads 1306b formed on the interposer 1302b. The second pads 1306b may be electrically connected to the controller device 1310b through a second signal path 1342b formed in the interposer 1302b. The interface circuit IF may be electrically connected to the first and second signal paths 1341b, 1342b through the microbumps, so that an electrical connection may be formed between the interface circuit IF and the first and second memory media MD1, MD2. A frequency of the signals transmitted through the controller bus 1321b between the memory controller MC and the interface circuit IF may be greater than or equal to a frequency of the signals transmitted through the first signal path 1341b and the wire bonding W1b between the interface circuit IF and the first memory media MD1 and the signals transmitted through the second signal path 1342b and the wire bonding W2b between the interface circuit IF and the second memory media MD2. The controller bus 1321b may include a first data bus that electrically connects the memory controller MC and the interface circuit IF. The first signal path 1341b may include a second data bus that electrically connects the interface circuit IF and the first memory media MD1. The second signal path 1342b may include a third data bus that electrically connects the interface circuit IF and the second memory media MD2. A width of the first data bus may be less than or equal to a width of the second data bus and a width of the third data bus. The semiconductor apparatus 1300b may further include a power management integrated circuit PMIC 1330b. The power management integrated circuit PMIC may be disposed on the module substrate 1301b. In an embodiment, the power management integrated circuit PMIC may be disposed on the interposer 1302b.

In the semiconductor apparatus 1300a shown in FIGS. 13A and 13C, four memory media MD may be disposed at a first side of the controller device 1310a, and another four memory media MD may be disposed at a second side of the controller device 1310a. In the semiconductor apparatus 1300b, eight memory media MD may be disposed at a first side of the controller device 1310b in two rows of four, and eight memory media MD may be disposed at a second side of the controller device 1310b in two rows of four. The data bandwidth of the memory bus of the semiconductor apparatus 1300a may be substantially the same as the data bandwidth of the memory bus of the semiconductor apparatus 1300b. The structure of the semiconductor apparatus 1300a may decrease the area of the interposer 1302a and the package substrate 1303a, while the structure of the semiconductor apparatus 1300b may increase the area of the interposer 1302b and the package substrate 1303b but decrease the height of the package.

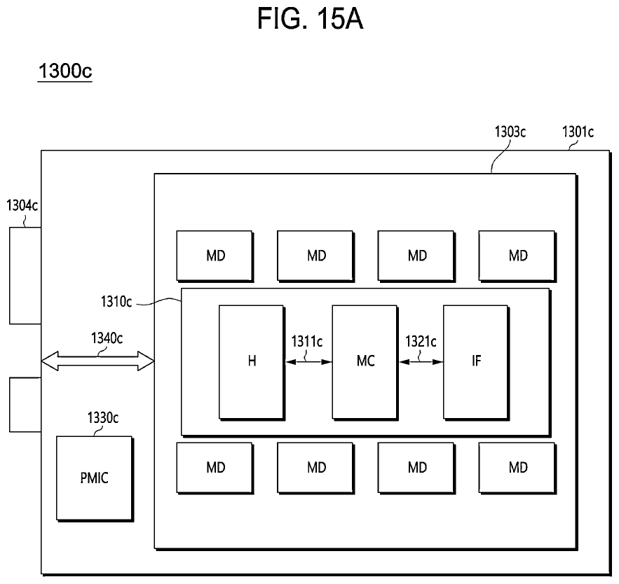

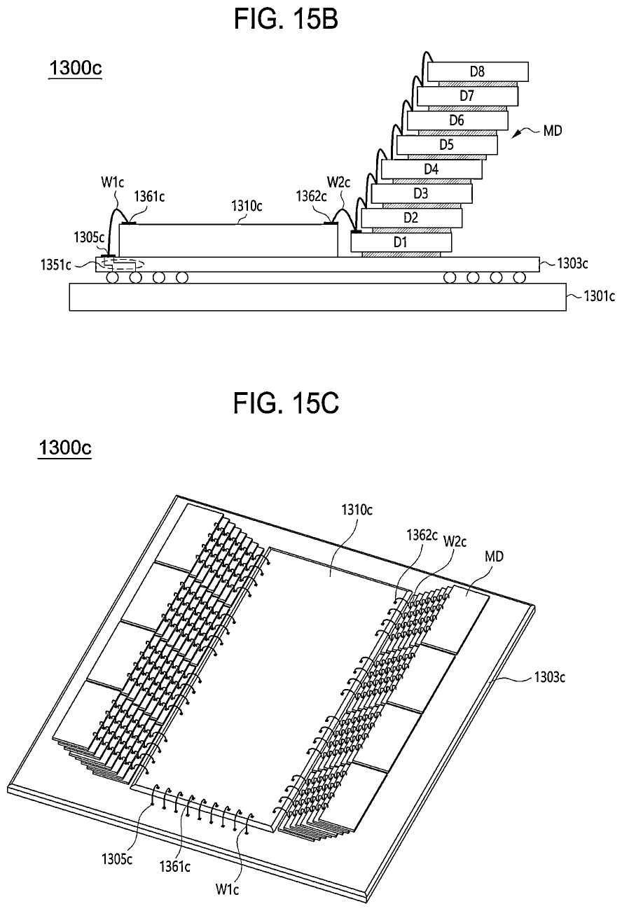

FIGS. 15A to 15C are diagrams illustrating a configuration of a semiconductor apparatus 1300c according to an embodiment of the present disclosure. FIG. 15A may be a conceptual plan view of the semiconductor apparatus 1300c, FIG. 15B may be a cross-sectional view of the semiconductor apparatus 1300c, and FIG. 15C may be a perspective view of the semiconductor apparatus 1300c. The semiconductor apparatus 1300c may be a memory system, such as a CXL module or a CXL device. The semiconductor apparatus 1300c may include a controller device 1310c and a plurality of memory media MD. The semiconductor apparatus 1300c may include a module substrate 1301c. The module substrate 1301c may include a module pin 1304c, and may communicate with an external device through the module pin 1304c. For example, the external device may be the main host 1211 shown in FIG. 12, and the module pin 1304c may be electrically connected to the system bus 1201 shown in FIG. 12. The semiconductor apparatus 1300c may be electrically connected to the external device through a main board by inserting the module pin 1304c into a slot and/or channel formed in the main board. A package substrate 1303c may be mounted on the module substrate 1301c, and the package substrate 1303c may be electrically connected with the module substrate 1301c through package balls and/or solder balls. The semiconductor apparatus 1300c might not include an interposer. The package substrate 1303c, the controller device 1310c, and the plurality of memory media MD may be packaged in a single package, and the single package may be mounted on the module substrate 1301c. The controller device 1310c may be disposed on the package substrate 1303c. The first Pads 1361c on the controller device 1310c may be wire bonded to pads 1305c on the package substrate 1303c, and the controller device 1310c may be electrically connected to the package substrate 1303c through the wire bonding. The plurality of memory media MD may be disposed on the package substrate 1303c. The controller device 1310c may be disposed in a first region on the package substrate 1303c, and the plurality of memory media MD may be disposed in a second region on the package substrate 1303c. The first and second regions might not overlap each other.

The controller device 1310c may relay data communication between the external device and the plurality of memory media MD. The controller device 1310c may include a host H, a memory controller MC, and an interface circuit IF. The host H may correspond to the sub-host 1212 shown in FIG. 12, the memory controller MC may correspond to the second memory controller 1222 shown in FIG. 12, and the interface circuit IF may correspond to the second interface circuit 1232 shown in FIG. 12. Redundant descriptions of the corresponding components will be omitted. The controller device 1310c may be electrically connected with a plurality of memory media MD and may perform data communication with the plurality of memory media MD. The controller device 1310c may be electrically connected to each of the plurality of memory media MD through the interface circuit IF. Each of the plurality of memory media MD may correspond to the second memory apparatus 1242 shown in FIG. 12. The plurality of memory media MD may form independent channels and may be electrically connected with the interface circuit IF of the controller device 1310c through independent memory buses. In FIGS. 15A to 15C, the semiconductor apparatus 1300c is illustrated as having eight memory media, but the number of memory media that the semiconductor apparatus 1300c has may be less than eight or more than eight. Each of the plurality of memory media MD may include at least one memory die. When each of the plurality of memory media includes two or more memory dies, the two or more memory dies may be stacked to form a single memory media. In FIGS. 15B and 15C, one memory media is illustrated to include eight memory dies, but the number of memory dies that one memory media includes may be less than or greater than eight.

The host H may be electrically connected to the external device through a system bus 1340c, and may be electrically connected to the memory controller MC through a host bus 1311c. The memory controller MC may be electrically connected to the interface circuit IF through a controller bus 1321c, and the interface circuit IF may be electrically connected to each of the plurality of memory media MD through a plurality of memory buses. The controller bus 1321c may have substantially the same characteristics as the second bus 160 shown in FIG. 1, and each of the plurality of memory buses may have substantially the same characteristics as the third bus 170 shown in FIG. 1. Each of the plurality of memory media MD may perform parallel data communication with the interface circuit IF. The interface circuit IF may perform parallel data communication with the memory controller MC, or may perform partial parallel data communication. A width of each of the plurality of memory buses may be greater than or equal to a width of the controller bus 1321c, and a clock rate of each of the plurality of memory buses may be less than or equal to a clock rate of the controller bus 1321c.

The controller device 1310c may be electrically connected to the module substrate 1301c through a wire bonding W1c between the first pads 1361c and the pads 1305c and the signal path 1351c formed in the package substrate 1303c. The controller device 1310c may be electrically connected to the plurality of memory media MD through the second pads 1362c. The host H may be electrically connected to the module substrate 1301a through the wire bonding W1c and the signal path 1351c. The interface circuit IF may be electrically connected to the memory media MD through the second pads 1362c. The memory media MD may be electrically connected to the second pads 1362c through a wire bonding W2c. The interface circuit IF may be electrically connected to the memory media MD through the wire bonding W2c. The wire bonding W2c may correspond to one of the plurality of the memory buses.

A first memory die D1 of the memory media MD may be bonded to the package substrate 1303c using DAF. The second to eighth memory dies D2, D3, D4, D5, D6, D7, D8 may also be bonded sequentially with the first to seventh memory dies D1, D2, D3, D4, D5, D6, D7, respectively, using DAF. The first to eighth memory dies D1, D2, D3, D4, D5, D6, D7, D8 may be electrically connected using a wire bonding. The first to eighth memory dies D1, D2, D3, D4, D5, D6, D7, D8 may be electrically connected to the the interface circuit IF of the controller device 1310c by wire bonding with the second pads 1362c formed on the controller device 1310c. If the plurality of memory media MD are wire bonded directly to the second pads 1362c of the controller device 1310c, the manufacturing cost of the semiconductor apparatus 1300c may be further reduced because the semiconductor apparatus 1300c does not require the use of an interposer.

A frequency of the signals transmitted through the controller bus 1321c between the memory controller MC and the interface circuit IF may be greater than or equal to a frequency of the signals transmitted through the wire bonding W2c between the interface circuit IF and the memory media MD. The controller bus 1321a may include a first data bus which electrically connects the memory controller MC and the interface circuit IF, and the wire bonding W2c may include a second data bus which electrically connects the interface circuit IF and the memory media MD. A width of the first data bus may be less than or equal to a width of the second data bus. The semiconductor apparatus 1300c may further include a power management integrated circuit PMIC 1330c. The power management integrated circuit PMIC may be disposed on the module substrate 1301c.

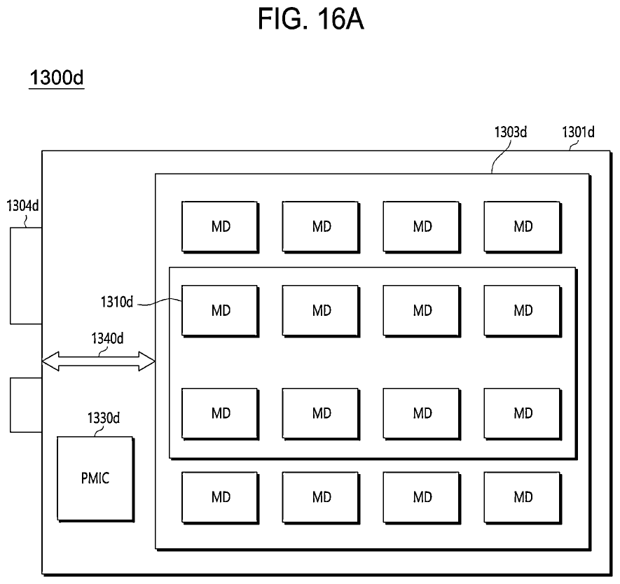

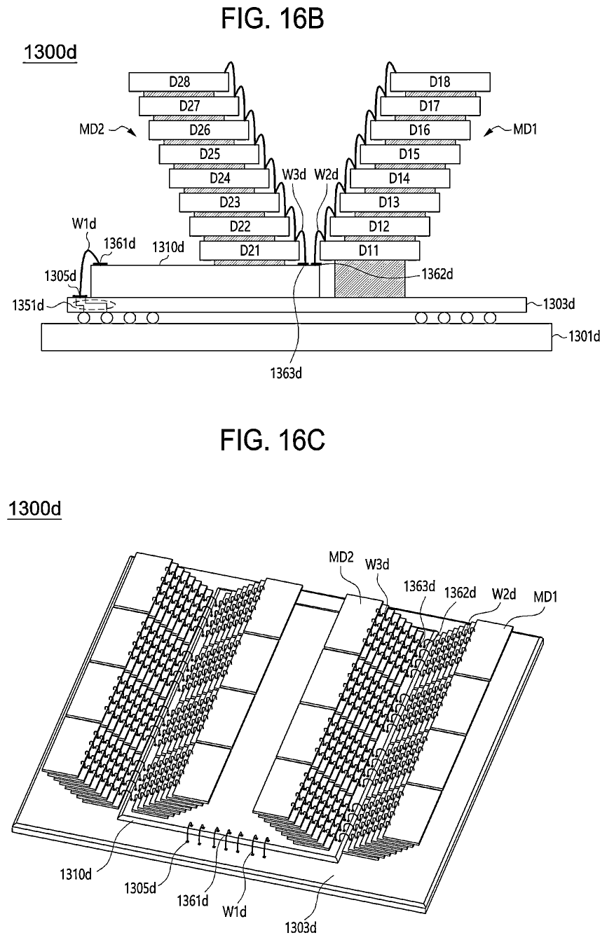

FIGS. 16A to 16C are diagrams illustrating a configuration of a semiconductor apparatus 1300d according to an embodiment of the present disclosure. FIG. 16A may be a conceptual plan view of the semiconductor apparatus 1300d, FIG. 16B may be a cross-sectional view of the semiconductor apparatus 1300d, and FIG. 16C may be a perspective view of the semiconductor apparatus 1300d. Redundant descriptions of the corresponding components will be omitted. The semiconductor apparatus 1300d may be a memory system, such as a CXL module or a CXL device. The semiconductor apparatus 1300d may include a controller device 1310d and a plurality of memory media MD. The semiconductor apparatus 1300d may include a module substrate 1301d. The module substrate 1301d may include a module pin 1304d, and may communicate with an external device through the module pin 1304d. For example, the external device may be the main host 1211 shown in FIG. 12, and the module pin 1304d may be electrically connected to the system bus 1201 shown in FIG. 12. The semiconductor apparatus 1300d may be electrically connected to the external device through a main board by inserting the module pin 1304d into a slot and/or channel formed in the main board. A package substrate 1303d may be mounted on the module substrate 1301d, and the package substrate 1303d may be electrically connected with the module substrate 1301d through package balls and/or solder balls. The semiconductor apparatus 1300d might not include an interposer. The package substrate 1303d, the controller device 1310d, and the plurality of memory media MD may be packaged in a single package and the single package may be mounted on the module substrate 1301d. The controller device 1310d may be disposed on the package substrate 1303d. The controller device 1310d may be disposed in a first region on the package substrate 1303d. The controller device 1310d may be electrically connected to the package substrate 1303d using a wire bonding. First pads 1361d of the controller device 1310d may be electrically connected with pads 1305d on the package substrate 1303d through wire bonding. The pads 1305d may be electrically connected to a signal path 1351d formed in the package substrate 1303d. Some of the plurality of memory media MD may be disposed on the package substrate 1303d, and the remainder of the plurality of memory media MD may be disposed on the controller device 1310d. The some of the plurality of memory media MD may be disposed in a second region on the package substrate 1303d. The first and second regions might not overlap each other. The remainder of the plurality of memory media MD may be disposed in the first region on the controller device 1310d. For example, eight memory media may be disposed on the package substrate 1303d, and the remaining eight memory media may be disposed on the controller device 1310d.

The controller device 1310d may relay data communication between the external device and the plurality of memory media MD. Although not shown, the controller device 1310d may include a host, a memory controller, and an interface circuit, and have substantially the same configuration as the controller device 1310c shown in FIG. 15A. The controller device 1310d may be electrically connected with a plurality of memory media MD, and may perform data communication with the plurality of memory media MD. The controller device 1310d may be electrically connected with each of the plurality of memory media MD through an interface circuit. Each of the plurality of memory media MD may correspond to the second memory apparatus 1242 shown in FIG. 12. The plurality of memory media MD may form independent channels and may each be electrically connected with the interface circuit of the controller device 1310d through independent memory buses. In FIGS. 16A to 16C, the semiconductor apparatus 1300d is illustrated as having sixteen memory media, but the number of memory media that the semiconductor apparatus 1300d has may be less than sixteen or more than sixteen. Each of the plurality of memory media MD may include at least one memory die. When each of the plurality of memory media MD includes two or more memory dies, the two or more memory dies may be stacked to form a single memory media. In FIGS. 16B and 16C, one memory media includes eight memory dies, but the number of memory dies that one memory media includes may be less than or greater than eight.

The controller device 1310d may be electrically connected to the module substrate 1301d through a wire bonding W1d between the first pads 1361d and the pads 1305d and the signal path 1351d formed in the package substrate 1303d. The controller device 1310d may be electrically connected to the plurality of memory media MD through the second and third pads 1362d, 1363d. The host may be electrically connected to the module substrate 1301d through the wire bonding W1d and the signal path 1351d. The interface circuit IF may be electrically connected to the plurality of memory media MD through the second and third pads 1362d, 1363d. The host may be electrically connected to the memory controller through a host bus. The memory controller may be connected to the interface circuit through a controller bus. The interface circuit may be electrically connected to the plurality of memory media MD through wire bonding between the second and third pads 1362d, 1363d and the plurality of memory media MD. The wire bonding between the second and third pads 1362d, 1363d and the plurality of memory media MD may correspond to a plurality of memory buses. For example, the first memory media MD1 may be electrically connected to the interface circuit through a wire bonding W2d between the first memory media MD1 and the second pads 1362d. The second memory media MD2 may be electrically connected to the interface circuit through a wire bonding W3d between the second memory media MD2 and the third pads 1363d.

A first memory die D11 of the first memory media MD1 may be bonded to the package substrate 1303d using DAF. The second to eighth memory dies D12, D13, D14, D15, D16, D17, D18 may also be bonded sequentially with the first to seventh memory dies D11, D12, D13, D14, D15, D16, D17, respectively, using DAF. The first to eighth memory dies D11, D12, D13, D14, D15, D16, D17, D18 may be electrically connected using a wire bonding. The first to eighth memory dies D1i, D12, D13, D14, D15, D16, D17, D18 may be electrically connected to the controller device 1310d by wire bonding with the second pads 1362d. A first memory die D21 of the second memory media MD2 may be bonded to top surface of the controller device 1310d using DAF. The second to eighth memory dies D22, D23, D24, D25, D26, D27, D28 may also be bonded sequentially with the first to seventh memory dies D21, D22, D23, D24, D25, D26, D27, respectively, using DAF. The first to eighth memory dies D21, D22, D23, D24, D25, D26, D27, D28 may be electrically connected using a wire bonding. The first to eighth memory dies D21, D22, D23, D24, D25, D26, D27, D28 may be electrically connected to the controller device 1310d by wire bonding with third pads 1363d. When the plurality of memory media MD are disposed on the controller device 1310d, the capacity of the semiconductor apparatus 1300d can be increased without increasing the area of the package. The semiconductor apparatus 1300d may further include a power management integrated circuit PMIC 1330d. The power management integrated circuit PMIC may be disposed on the module substrate 1301d. In an embodiment, the power management integrated circuit PMIC may be disposed on the package substrate 1303d.

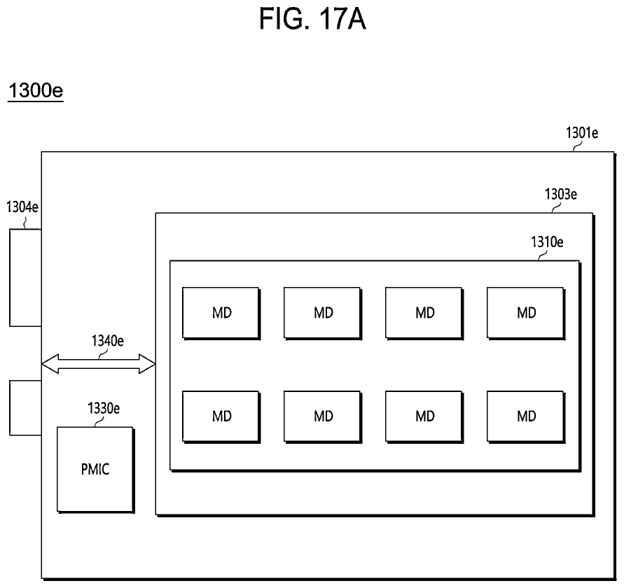

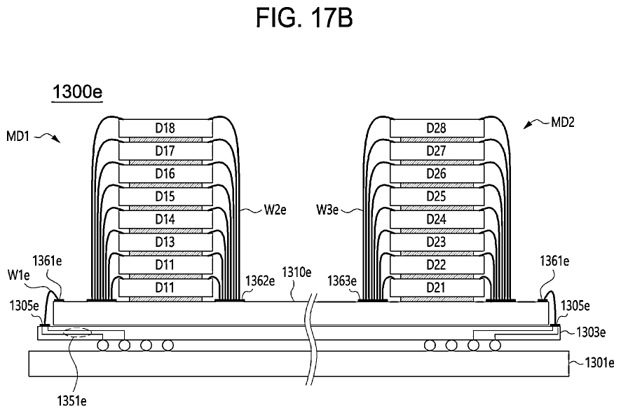

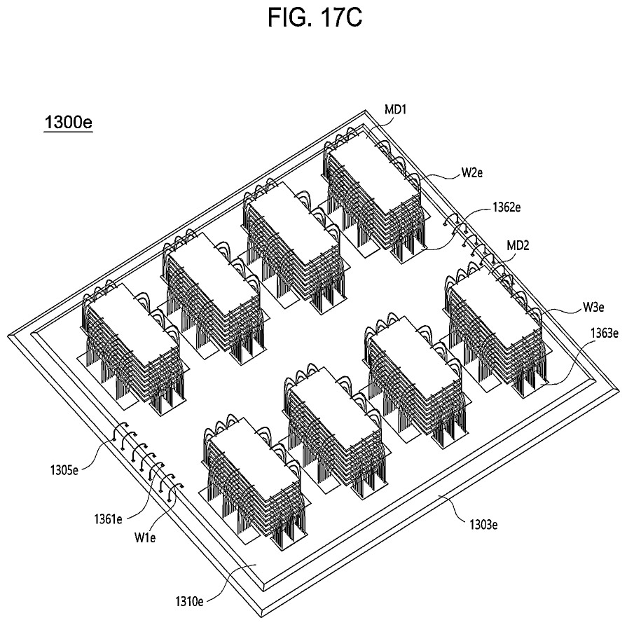

FIGS. 17A to 17C are diagrams illustrating a configuration of a semiconductor apparatus 1300e according to an embodiment of the present disclosure. FIG. 17A may be a conceptual plan view of the semiconductor apparatus 1300e, FIG. 17B may be a cross-sectional view of the semiconductor apparatus 1300e, and FIG. 17C may be a perspective view of the semiconductor apparatus 1300e. Redundant descriptions of the corresponding components will be omitted. The semiconductor apparatus 1300e may be a memory system, such as a CXL module or a CXL device. The semiconductor apparatus 1300e may include a controller device 1310e and a plurality of memory media MD. The semiconductor apparatus 1300e may include a module substrate 1301e. The module substrate 1301e may include a module pin 1304e, and may communicate with an external device through the module pin 1304e. For example, the external device may be the main host 1211 shown in FIG. 12, and the module pin 1304e may be electrically connected to the system bus 1201 shown in FIG. 12. The semiconductor apparatus 1300e may be electrically connected to the external device through a main board by inserting the module pin 1304e into a slot and/or channel formed in the main board. A package substrate 1303e may be mounted on the module substrate 1301e, and the package substrate 1303e may be electrically connected with the module substrate 1301e through package balls and/or solder balls. The semiconductor apparatus 1300e might not include an interposer. The package substrate 1303e, the controller device 1310e, and the plurality of memory media MD may be packaged in a single package, and the single package may be mounted on the module substrate 1301e. The controller device 1310e may be disposed on the package substrate 1303e. The controller device 1310e may be electrically connected to the package substrate 1303e using a wire bonding. First pads 1361e formed in the controller device 1310e may be electrically connected to the pads 1305e formed in the package substrate 1303e through wire bonding. The pads 1305e may be electrically connected to a signal path 1351e formed in the package substrate 1303e. All of the plurality of memory media MD may be disposed on the controller device 1310e. Some of the plurality of the memory media MD may be disposed in a first region on the controller device 1310e, and the remainder of the plurality of memory media MD may be disposed in a second region on the controller device 1310e. The first and second regions might not overlap each other. For example, when the semiconductor apparatus 1300e includes sixteen memory media, eight memory media may be disposed in the first region of the controller device 1310e, and other eight memory media may be disposed in the second region of the controller device 1310e.

The controller device 1310e may relay data communication between the external device and the plurality of memory media MD. Although not shown, the controller device 1310e may include a host, a memory controller, and an interface circuit, and may have substantially the same configuration as the controller device 1310c shown in FIG. 15A. The controller device 1310e may be electrically connected with a plurality of memory media MD, and may perform data communication with the plurality of memory media MD. The controller device 1310e may be electrically connected with each of the plurality of memory media MD through an interface circuit. Each of the plurality of memory media MD may correspond to the second memory apparatus 1242 shown in FIG. 12. The plurality of memory media MD may form independent channels and may each be electrically connected with the interface circuit of the controller device 1310e through independent memory buses. In FIGS. 17A to 17C, the semiconductor apparatus 1300e is illustrated as having eight memory media, but the number of memory media that the semiconductor apparatus 1300e has may be less than eight or more than eight. Each of the plurality of memory media MD may include at least one memory die. When each of the plurality of memory media MD includes two or more memory dies, the two or more memory dies may be stacked to form a single memory media. In FIGS. 17B and 17C, one memory media includes eight memory dies, but the number of memory dies that one memory media includes may be less than or greater than eight.

The controller device 1310e may be electrically connected to the module substrate 1301e through a wire bonding W1e between the first pads 1361e and the pads 1305e and the signal path 1351e formed in the package substrate 1303d. The controller device 1310e may be electrically connected to the plurality of memory media MD through the second and third pads 1362e, 1363e. The host may be electrically connected to the module substrate 1301e through the wire bonding W1e and the signal path 1351e. The host may be electrically connected to the memory controller through a host bus. The memory controller may be connected to the interface circuit through a controller bus. The interface circuit may be connected to the plurality of the memory media MD through the second and third pads 1362e, 1363e. The interface circuit may be electrically connected to the plurality of memory media MD through wire bonding between the second and third pads 1362e, 1363e and the plurality of memory media MD. The wire bonding between the second and third pads 1362e, 1363e and the plurality of memory media MD may correspond to a plurality of memory buses. For example, the first memory media MD1 may be electrically connected to the interface circuit through a wire bonding W2e between the first memory media MD1 and the second pads 1362e. The second memory media MD2 may be electrically connected to the interface circuit through a wire bonding W3e between the second memory media MD2 and the third pads 1363e.

A first memory die D11 of the first memory media MD1 may be bonded to the controller device 1310e using DAF. The second to eighth memory dies D12, D13, D14, D15, D16, D17, D18 may also be bonded sequentially with the first to seventh memory dies D11, D12, D13, D14, D15, D16, D17, respectively, using DAF. The first to eighth memory dies D11, D12, D13, D14, D15, D16, D17, D18 may be electrically connected using a wire bonding. The first to eighth memory dies D1i, D12, D13, D14, D15, D16, D17, D18 may be electrically connected to the controller device 1310e by wire bonding with second pads 1362e formed on the controller device 1310e. A first memory die D21 of the second memory media MD2 may be bonded to top surface of the controller device 1310e using DAF. The second to eighth memory dies D22, D23, D24, D25, D26, D27, D28 may also be bonded sequentially with the first to seventh memory dies D21, D22, D23, D24, D25, D26, D27 respectively, using DAF. The first to eighth memory dies D21, D22, D23, D24, D25, D26, D27, D28 may be electrically connected using a wire bonding. The first to eighth memory dies D21, D22, D23, D24, D25, D26, D27, D28 may be electrically connected to the controller device 1310e by wire bonding with third pads 1363e formed on the controller device 1310e. When the plurality of memory media MD are disposed on the controller device 1310e, the capacity of the semiconductor apparatus 1300e can be increased without increasing the area of the package. Further, if the plurality of memory dies is stacked in a vertical alignment rather than in a stepwise manner, then wire bonding may be possible on all four sides of the memory dies as shown in FIG. 17C. Thus, the semiconductor apparatus may have a large capacity, while being manufactured at a much lower cost. The semiconductor apparatus 1300e may further include a power management integrated circuit PMIC 1330e. The power management integrated circuit PMIC may be disposed on the module substrate 1301e. In an embodiment, the power management integrated circuit PMIC may be disposed on the package substrate 1303e.

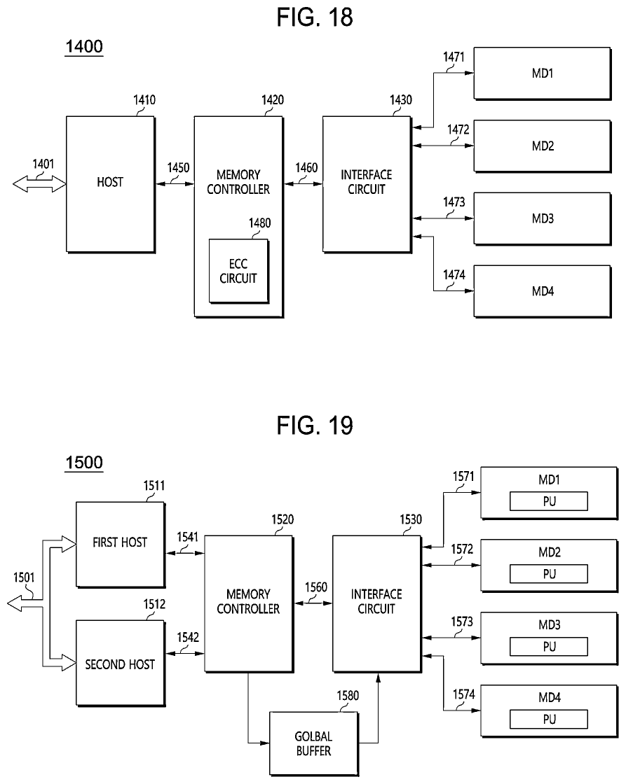

FIG. 18 is a diagram illustrating a configuration of a semiconductor apparatus 1400 according to an embodiment of the present disclosure. Referring to FIG. 18, the semiconductor apparatus 1400 may be a memory system, such as a CXL module or a CXL device. The semiconductor apparatus 1400 may include a host 1410, a memory controller 1420, an interface circuit 1430, and a plurality of memory media MD1, MD2, MD3, MD4. The host 1410 may be electrically connected to an external device, such as the main host 1211 shown in FIG. 12, through a system bus 1401. The memory controller 1420 may be electrically connected to the host 1410 through a host bus 1450. The memory controller 1420 may include an enhanced error correction code (ECC) circuit. The memory controller 1420 may correct fail bit errors in data signals provided to the interface circuit 1430, and may correct fail bit errors in data signals received from the interface circuit 1430, through the enhanced ECC circuit 1480. If the memory controller 1420 includes the enhanced ECC circuit 1480, it can detect and correct a greater number of fail bits generated by the memory media MD1, MD2, MD3, MD4. In an embodiment, the enhanced ECC circuit 1480 may correct fail bit errors in command signals, address signals provided from the memory controller 1420 to the interface circuit 1430 along with the data signals. In an embodiment, the enhanced ECC circuit 1480 may be disposed external to the memory controller 1420. For example, the enhanced ECC circuit 1480 may be disposed to electrically connect between the memory controller 1420 and the interface circuit 1430. The interface circuit 1430 may be electrically connected to the memory controller 1420 through a controller bus 1460, and may be electrically connected to the plurality of memory media MD1, MD2, MD3, MD4 through a plurality of memory buses 1471, 1472, 1473, 1474. In FIG. 18, the semiconductor apparatus 1400 is shown as including four memory media, but the number of memory media included by the semiconductor apparatus 1400 may be less or more than four. The interface circuit 1430 may be electrically connected with a first memory media MD1 through a first memory bus 1471, electrically connected with a second memory media MD2 through a second memory bus 1472, electrically connected with a third memory media MD3 through a third memory bus 1473, and electrically connected with a fourth memory media MD4 through a fourth memory bus 1474. The interface circuit 1430 may perform parallel data communication or partial parallel data communication with the memory controller 1420 through the controller bus 1460. The interface circuit 1430 may perform parallel data communication with the first to fourth memory media MD1, MD2, MD3, MD4 through the first to fourth memory buses 1471, 1472, 1473, 1474, respectively. The controller bus 1460 may have substantially the same characteristics as the second bus 160 shown in FIG. 1. Each of the first to fourth memory buses 1471, 1472, 1473, 1474 may have substantially the same characteristics as the third bus 170 shown in FIG. 1.

Each of the first to fourth memory media MD1, MD2, MD3, MD4 may include a plurality of memory dies. The plurality of memory dies may have a simplified structure when compared to a conventional memory die. In the plurality of memory dies, the number of memory cells may be increased, while the number of row address decoders and redundancy cells may be decreased. Thus, the plurality of memory dies may have a smaller size than a conventional memory die. Further, because the plurality of memory dies can be stacked through wire bonding, memory media having a large data storage capacity can be realized at a low manufacturing cost. However, as the number of row address decoders and redundancy cells is reduced, the number of fail bits in the data signals stored in or output from the memory cell regions may be increased. Typically, a memory die and a memory controller has an ECC logic to correct fail bits in the data signals. The memory controller 1420 may further include the enhanced ECC circuit 1480 (i.e., enhanced ECC performance) to further relieve increased fail bits in the memory die through the ECC circuit 1480, thereby improving the reliability of the semiconductor apparatus 1400. The host 1410, the memory controller 1420, and the interface circuit 1430 may be integrated into a controller device. Because the interface circuit 1430 performs parallel data communication with the memory controller 1420 and the plurality of memory media MD1, MD2, MD3, MD4, respectively, the memory controller 1420 may have no SerDes or only minimal-sized SerDes. Thus, utilizing some or all of the area allocated for the SerDes, the controller device may add the enhanced ECC circuit 1480 without increasing the overall area of the controller device. As a result, the semiconductor apparatus 1400 may have a reduced overall area and manufacturing cost compared to a conventional semiconductor apparatus, while still providing a memory system with the same or improved performance as a conventional semiconductor apparatus.

FIG. 19 is a diagram illustrating a configuration of a semiconductor apparatus 1500 according to an embodiment of the present disclosure. Referring to FIG. 19, the semiconductor apparatus 1500 may be a memory system, such as a CXL module or a CXL device. The semiconductor apparatus 1500 may include a first host 1511, a second host 1512, a memory controller 1520, an interface circuit 1530, and a plurality of memory media MD1, MD2, MD3, MD4. The first and second hosts 1511, 1512 may each be electrically connected to an external device, such as the main host 1211 shown in FIG. 12, through a system bus 1501. The first and second hosts 1511, 1512 may perform different functions. Basically, the first host 1511 may perform data communication operations between the semiconductor apparatus 1500 and the external device, and the second host 1512 may perform computational operations of the semiconductor apparatus 1500. The first host 1511, based on a first request from the external device, may generate an access request to the plurality of memory media MD1, MD2, MD3, MD4, thereby providing data and/or computational data stored on the plurality of memory media MD1, MD2, MD3, MD4 to the external device through the system bus 1501, and may provide data transmitted through the system bus 1501 to the plurality of memory media MD1, MD2, MD3, MD4 or as data used for computational operations. The second host 1512 may perform computational operations on data output from the plurality of memory media MD1, MD2, MD3, MD4 and/or data provided from the external device through the system bus 1501 by generating a computational request based on a second request from the external device.

The memory controller 1520 may be electrically connected to the first host 1511 through a first host bus 1541, and may be electrically connected to the second host 1512 through a second host bus 1542. The memory controller 1520 may generate command signals and address signals for accessing the plurality of memory media MD1, MD2, MD3, MD4 based on the access request provided by the first host 1511. The memory controller 1520 may generate command signals and address signals to instruct computational operations of the plurality of memory media MD1, MD2, MD3, MD4 based on the computational request provided from the second host 1512. The semiconductor apparatus 1500 may further include a global buffer 1580. The global buffer 1580 may be electrically connected between the memory controller 1520 and the interface circuit 1530. The global buffer 1580 may store and output data corresponding to vectors so that the plurality of memory media MD1, MD2, MD3, MD4 can perform matrix operations. The global buffer 1580 may receive data corresponding to the vectors from the memory controller 1520, and may store data corresponding to the vectors. The global buffer 1580 may output data corresponding to the vectors to the interface circuit 1530, which may provide data corresponding to the vectors to the plurality of memory media MD1, MD2, MD3, MD4. In an embodiment, the global buffer 1580 may be implemented with a register or static random access memory (SRAM). The interface circuit 1530 may be electrically connected to the memory controller 1520 through a controller bus 1560, and may be electrically connected to the plurality of memory media MD1, MD2, MD3, MD4 through a plurality of memory buses 1571, 1572, 1573, 1574. In FIG. 19, the semiconductor apparatus 1500 is shown as including four memory media, but the number of memory media included by the semiconductor apparatus 1500 may be less than or greater than four. The interface circuit 1530 may be electrically connected with a first memory media MD1 through a first memory bus 1571, electrically connected with a second memory media MD2 through a second memory bus 1572, electrically connected with a third memory media MD3 through a third memory bus 1573, and electrically connected with a fourth memory media MD4 through a fourth memory bus 1574. The interface circuit 1530 may perform parallel data communication or partial parallel data communication with the memory controller 1520 through the controller bus 1560. The interface circuit 1530 may perform parallel data communication with the first to fourth memory media MD1, MD2, MD3, MD4, respectively, through the first to fourth memory buses 1571, 1572, 1573, 1574. The controller bus 1560 may have substantially the same characteristics as the second bus 160 shown in FIG. 1. Each of the first to fourth memory buses 1571, 1572, 1573, 1574 may have substantially the same characteristics as the third bus 170 shown in FIG. 1.

Each of the first to fourth memory media MD1, MD2, MD3, MD4 may include a plurality of memory dies. Because each of the plurality of memory dies performs parallel data communication with the interface circuit 1530, they might not include an additional circuit such as SerDes. The area from which the SerDes is removed may be provided with a processing unit PU. The processing unit PU may include a MAC (Multiply and Accumulation) unit. Each of the plurality of memory dies may include a memory cell array and the processing unit PU to perform a computational operation requested from the second host 1512. The first host 1511, the second host 1512, the memory controller 1520, the global buffer 1580, and the interface circuit 1530 may be integrated into a controller device. Because the interface circuit 1530 performs parallel data communication with the memory controller 1520 and the plurality of memory media MD1, MD2, MD3, MD4, respectively, the memory controller 1520 may have no SerDes or only a minimal-sized SerDes. Thus, utilizing some or all of the area allocated for the SerDes, the controller device may add the second host 1512 and the global buffer 1580 without increasing the overall area of the controller device. As a result, the semiconductor apparatus 1500 can realize a memory system that performs the function of PIM (Processing In Memory) in substantially the same area as a conventional semiconductor apparatus.

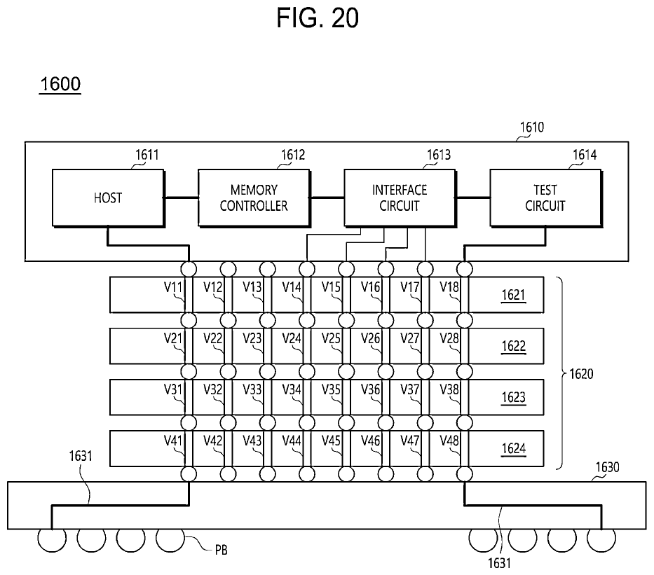

FIG. 20 is a diagram illustrating a configuration of a computing system 1600 according to an embodiment of the present disclosure. The computing system 1600 may be an embodiment that further implements a computing system 1000j shown in FIG. 10j. Referring to FIG. 20, the computing system 1600 may include a host die 1610 and a memory apparatus 1620. The host die 1610 and the memory apparatus 1620 may be disposed on a single substrate 1630, and may be packaged in a single package. Typically, a memory apparatus communicates with a host die, but the host die also needs to communicate with an external device as well and therefore, it may be advantageous to dispose the host die on the substrate first. Then, the memory apparatus is disposed on the host die to facilitate communication paths between the host die and the memory apparatus and between the host die and an external device through the substrate. However, if the host die is disposed between the substrate and the memory apparatus, the performance of the computing system may be reduced because the heat generated by the host die cannot be sufficiently dissipated, and the design difficulty and manufacturing cost of the host die may be increased because it is necessary to form through vias in the host die. To address these problems, embodiments of the present disclosure include a computing system 1600 with a host die 1610 disposed on the memory apparatus 1620 to more efficiently dissipate heat generated by the host die 1610. Further, disclosed embodiments include a computing system 1600 that implements a structure in which the host die 1610 can communicate with an external device through the memory apparatus 1620, thereby minimizing design changes of the host die 1610 and the memory apparatus 1620 and efficiently reducing the manufacturing cost of the computing system 1600.

For example, the memory apparatus 1620 may be disposed on the substrate 1630 in a first direction (e.g. a z-direction), and the host die 1610 may be disposed on the memory apparatus 1620 in the first direction. The memory apparatus 1620 may include at least one memory die. Each memory die may include a plurality of through vias as well as an internal circuit. The internal circuit is coupled to the host die 1610 using at least one of the plurality of through vias while another via in the memory die is coupled to the substrate 1630. The via in the memory die coupled to the substrate 1630 may also be coupled to the host die 1610. In each memory die, the via coupled to the substrate 1630 may be electrically isolated from the internal circuit of the memory die. In FIG. 20, the memory apparatus 1620 is shown as including four memory dies, but the number of memory dies included in the memory apparatus 1620 may be varied to include one, two, three, five or more memory dies. In an example, the memory apparatus 1620 may include a first memory die 1621, a second memory die 1622, a third memory die 1623, and a fourth memory die 1624. The first to fourth memory dies 1621, 1622, 1623, 1624 may have the same or substantially the same structure and may be manufactured using the same process. The first to fourth memory dies 1621, 1622, 1623, 1624 may be disposed or stacked sequentially between the host die 1610 and the substrate 1630. For example, the fourth memory die 1624 may be disposed on the substrate 1630 in the first direction, the third memory die 1623 may be disposed on the fourth memory die 1624 in the first direction, the second memory die 1622 may be disposed on the third memory die 1623 in the first direction, and the first memory die 1621 may be disposed on the second memory die 1622 in the first direction. Each of the first to fourth memory dies 1621, 1622, 1623, 1624 may include a plurality of through vias, and the first to fourth memory dies 1621, 1622, 1623, 1624 may be electrically connected to each other through the plurality of through vias. For example, each of the first to fourth memory dies 1621, 1622, 1623, 1624 may include first to eighth through vias V11-V18, V21-V28, V31-V38, V41-V48, respectively. The first to eighth through vias V11-V18, V21-V28, V31-V38, V41-V48 may be located at first to eighth positions of the first to fourth memory dies 1621, 1622, 1623, 1624, respectively. The first to fourth memory dies 1621, 1622, 1623, 1624 may be arranged to align the through vias at each position in a second direction and a third direction (e.g., a x-direction and a y-direction). The first through vias V11, V21, V31, V41 of the first to fourth memory dies 1621, 1622, 1623, 1624 are located at the first positions of the first to fourth memory dies 1621, 1622, 1623, 1624, respectively; the second through vias V12, V22, V32, V42 of the first to fourth memory dies 1621, 1622, 1623, 1624 may be located at the second positions of the first to fourth memory dies 1621, 1622, 1623, 1624, respectively; the third through vias V13, V23, V33, V43 of the first to fourth memory dies 1621, 1622, 1623, 1624 may be located at the third positions of the first to fourth memory dies 1621, 1622, 1623, 1624, respectively; the fourth through vias V14, V24, V34, V44 of the first to fourth memory dies 1621, 1622, 1623, 1624 may be located at the fourth position of the first to fourth memory dies 1621, 1622, 1623, 1624, respectively; the fifth through vias V15, V25, V35, V45 of the first to fourth memory dies 1621, 1622, 1623, 1624 may be located at the fifth positions of the first to fourth memory dies 1621, 1622, 1623, 1624, respectively; the sixth through vias V16, V26, V36, V46 of the first to fourth memory dies 1621, 1622, 1623, 1624 may be located at the sixth positions of the first to fourth memory dies 1621, 1622, 1623, 1624, respectively; the seventh through vias V17, V27, V37, V47 of the first to fourth memory dies 1621, 1622, 1623, 1624 may be located at the seventh positions of the first to fourth memory dies 1621, 1622, 1623, 1624, respectively; and the eighth through vias V18, V28, V38, V48 of the first to fourth memory dies 1621, 1622, 1623, 1624 may be located at the eighth positions of the first to fourth memory dies 1621, 1622, 1623, 1624, respectively. The first to eighth through vias V11-V18, V21-V28, V31-V38, V41-V48 of the first to fourth memory dies 1621, 1622, 1623, 1624 may be coupled by one of a multi-drop method and a point-to-point (P2P) method. For example, the first to eighth through vias V11-V18, V21-V28, V31-V38, V41-V48 may be coupled using the multi-drop method such that the first through vias V11, V21, V31, V41 are electrically connected to each other; the second through vias V12, V22, V32, V42 are electrically connected to each other; the third through vias V13, V23, V33, V43 are electrically connected to each other; the fourth through vias V14, V24, V34, V44 are electrically connected to each other; the fifth through vias V15, V25, V35, V45 are electrically connected to each other; the sixth through vias V16, V26, V36, V46 are electrically connected to each other; the seventh through vias V17, V27, V37, V47 are electrically connected to each other; and the eighth through vias V18, V28, V38, V48 are electrically connected to each other. Each of first to eighth through vias V11-V18, V21-V28, V31-V38, V41-V48 may be electrically connected to another via, a host die or a substrate through a microbump.

The host die 1610 may be coupled to the memory apparatus 1620 through fourth to seventh through vias V14-V17, V24-V27, V34-V37, V44-V47. For example, the host die 1610 may be coupled to the first to fourth memory dies 1621, 1622, 1623, 1624, through the fourth to seventh through vias V14-V17, V24-V27, V34-V37, V44-V47. The host die 1610 may transmit signals to each of the first to fourth memory dies 1621, 1622, 1623, 1624 through the fourth to seventh through vias V14-V17, V24-V27, V34-V37, V44-V47, and may receive signals transmitted from the first to fourth memory dies 1621, 1622, 1623, 1624 through the through vias. The host die 1610 may be coupled to an internal circuit of the first memory die 1621 through the through vias V14-V17, and may be coupled to an internal circuit of the second memory die 1622 through first memory die 1621 and the through vias V24-V27. The host die 1610 may be coupled to an internal circuit of the third memory die 1623 through first and second memory dies 1621, 1622 and the through vias V34-V37, and may be coupled to an internal circuit of the fourth memory die 1624 through the through vias V44-V47 and any intervening memory dies. The host die 1610 may be coupled to the substrate 1630 using through vias other than the through vias electrically coupling the host die 1610 to the first to fourth memory dies 1621, 1622, 1623, 1624 as described above. For example, the host die 1610 may be coupled to the substrate 1630 through the first through vias V11, V21, V31, V41 of the first to fourth memory dies 1621, 1622, 1623, 1624. By being coupled to the substrate through the first through vias V11, V21, V31, V41, the host die 1610 may communicate with a device external to the computing system 1600. The host die 1610 may receive signals transmitted from the external device and may transmit signals to the external device through the first through vias V11, V21, V31, V41. The substrate 1630 may include a plurality of signal paths 1631. The substrate 1630 may couple the first through vias V11, V21, V31, V41 to an external terminal PB through the signal path 1631, and may electrically connect the first through vias V11, V21, V31, V41 and the host die 1610 with the external device through the external terminal PB and the signalpath 1631. The host die 1610 may be further coupled to the substrate 1630 through eighth through vias V18, V28, V38, V48 of the first to fourth memory dies 1621, 1622, 1623, 1624. The substrate 1630 may electrically connect the eighth through vias V18, V28, V38, V48 with the external terminal PB through the signal path 1631, and may electrically connect the eighth through vias V18, V28, V38, V48 and the host die 1610 with the external device through the external terminal PB and the signal path 1631.

In an embodiment, the substrate 1630 may be an interposer. When the substrate 1630 is an interposer, the memory apparatus 1620 may be coupled to the substrate 1630 through microbumps. The external terminal PB of the substrate 1630 may be a bump. When the substrate 1630 is an interposer, the computing system 1600 may further include a package substrate. The substrate 1630 may be disposed on the package substrate. The package substrate may be coupled to the substrate 1630 through the external terminal PB. The substrate 1630 may be coupled to the external device through package balls and/or solder balls and signal paths in the package substrate. In an embodiment, the substrate 1630 may be a redistribution layer. When the substrate 1630 is a redistribution layer, the memory apparatus 1620 may be coupled to the substrate 1630 using microbumps or without using microbumps. When the substrate 1630 is a redistribution layer, the computing system 1600 might not have a separate package substrate, and may be packaged using the redistribution layer as a package substrate. In an embodiment, the computing system 1600 may further include a package substrate, and the redistribution layer may be disposed on the package substrate with or without microbumps. In an embodiment, the substrate 1630 may be a glass substrate. When the substrate 1630 is a glass substrate, the memory apparatus 1620 may be coupled to the substrate 1630 through microbumps. The external terminal PB of the substrate 1630 may be a solder ball or a package ball. When the substrate 1630 is the glass substrate, the computing system 1600 might not have a separate package substrate and may be packaged using the glass substrate as a package substrate.

The host die 1610 may include a host 1611, a memory controller 1612, and an interface circuit 1613. The host 1611 may be coupled to the memory controller 1612 through signal transmission lines inside the host die 1610. The host 1611 may be coupled to the substrate 1630 and the external device through the first through vias V11, V21, V31, V41 of the first to fourth memory dies 1621, 1622, 1623, 1624. The memory controller 1612 may be coupled to the interface circuit 1613 through signal transmission lines inside the host die 1610. The interface circuit 1613 may be coupled to the first to fourth memory dies 1621, 1622, 1623, 1624 through the fourth to seventh through vias V14-V17, V24-V27, V34-V37, V44-V47, respectively. The signal transmission lines electrically connecting the host 1611 and the memory controller 1612 may correspond to a first bus 150 described above and illustrated in FIG. 1. The signal transmission lines electrically connecting the memory controller 1612 and the interface circuit 1613 may correspond to a second bus 160 described above and illustrated in FIG. 1. The fourth to seventh through vias V14-V17, V24-V27, V34-V37, V44-V47 electrically connecting the interface circuit 1613 with the first to fourth memory dies 1621, 1622, 1623, 1624 may correspond to a third bus 170 described above and illustrated in FIG. 1. The host die 1610 may further include a test circuit 1614. The test circuit 1614 may be coupled to the interface circuit 1613 through signal transmission lines inside the host die 1610. The test circuit 1614 may be configured to perform tests on the interface circuit 1613 and the first to fourth memory dies 1621, 1622, 1623, 1624. The test circuit 1614 is coupled to the substrate 1630 and the external device through the eighth through vias V18, V28, V38, V48, which may constitute a direct access path. The test circuit 1614 may receive control signals for test operations from the external device through the substrate 1630 and the eighth through vias V18, V28, V38, V48, generate test signals for testing the interface circuit 1613 and the first to fourth memory dies 1621, 1622, 1623, 1624, and provide the test signals to the interface circuit 1613.

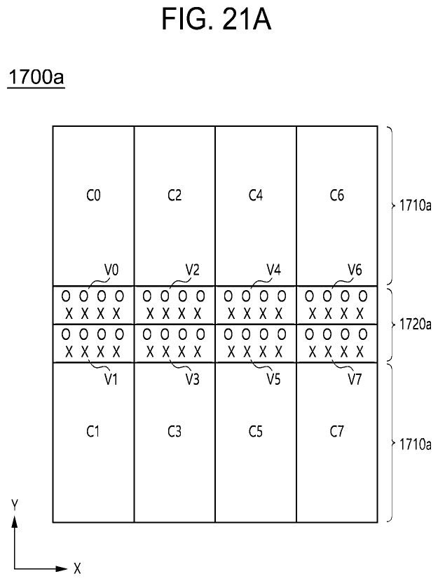

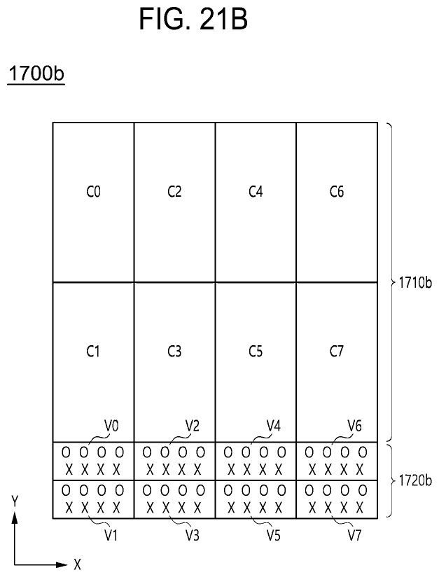

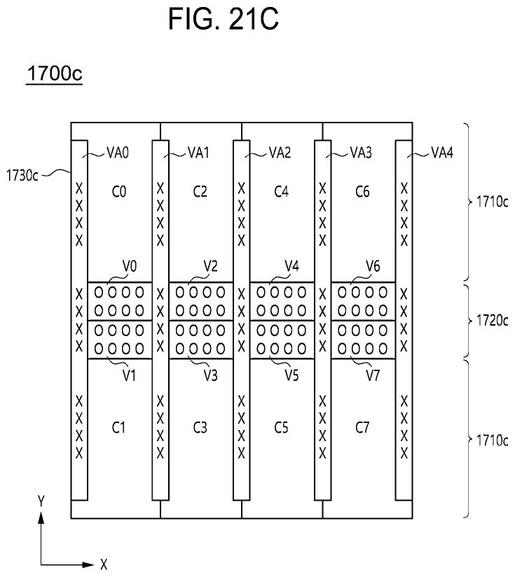

FIGS. 21A, 21B, and 21C are diagrams schematically illustrating structures of memory dies in a plan view according to embodiments of the present disclosure. Referring to FIG. 21A, a memory die 1700a may include a channel region 1710a extending in a y-axis direction and a through via region 1720a extending in the x-axis direction across the channel region 1710a. Thus, the memory die 1700a is divided into a channel region 1710a with a through via region 1720a in a central portion of the memory die 1700a in the y-axis direction. The channel region 1710a may extend in the y-axis direction from both sides of the through via region 1720a. The channel region 1710a includes a memory cell array and various internal circuits capable of writing data to the memory cell array and reading data stored in the memory cell array. The memory die 1700a may include a plurality of channels. For example, the memory die 1700a illustrated in FIG. 21A may include first to fourth channels. The first to fourth channels may perform data input and output operations independently of each other. The channel region 1710a may include first to eighth channel regions C0-C7, and the through via region 1720a may include first to eighth through via regions V0-V7. The number of channel regions and through via regions included by the memory die 1700a may change depending on the number of channels in the memory die 1700a. For example, in FIG. 21A, the first channel region C0 and the second channel region C1 may constitute a first channel. Through vias coupled to the first channel region C0 may be located in the first through via region V0, and through vias coupled to the second channel region C1 may be located in the second through via region V1. The third channel region C2 and the fourth channel region C3 may constitute a second channel. Through vias coupled to the third channel region C2 may be located in the third through via region V2, and through vias coupled to the fourth channel region C3 may be located in the fourth through via region V3. The fifth channel region C4 and the sixth channel region C5 may constitute a third channel. Through vias coupled to the fifth channel region C4 may be located in the fifth through via region V4, and through vias coupled to the sixth channel region C5 may be located in the sixth through via region V5. The seventh channel region C6 and the eighth channel region C7 may constitute a fourth channel. Through vias coupled to the seventh channel region C6 may be located in the seventh through via region V6, and through vias coupled to the eighth channel region C7 may be located in the eighth through via region V7. A plurality of through vias may be included in the first to eighth through via regions V0-V7 to electrically connect an internal circuit of the memory die 1700a to a host die, such as host die 1610 of FIG. 20. Internal circuits of other memory dies stacked above or below memory die 1700a may be electrically connected to the host die using aligned through vias in respective through via regions. Remaining through vias in the through via regions may be used as signal paths. For example, when one or more memory dies 1700a is disposed between the host die 1610 and the substrate 1630, remaining through vias (except for the through vias electrically connecting the internal circuit of the memory die 1700a with the host die 1610) may be used as signal paths to electrically connect the host die 1610 with the substrate 1630 and the external device. In FIG. 21A, the through vias labelled “O” may be through vias for electrically connecting the internal circuit of a memory die with a host die 1610, and the through vias labelled “X” may be through vias for electrically connecting a host die 1610 to an external device. Within the through via regions V0-V8, the number of through vias for electrically connecting the host die 1610 with the external device may change depending on the number of memory dies that the memory apparatus 1620 includes and/or the number of channels in a memory die.

Referring to FIG. 21B, a memory die 1700b may include a channel region 1710b and a through via region 1720b. The through via region 1720b may be disposed at one end of the memory die 1700b in the y-axis direction. The channel region 1710b may extending in a positive or negative direction from the through via region 1720b in the y-axis direction. The channel region 1710b may include first to eighth channel regions C0-C7, and the through via region 1720b may include first to eighth through via regions V0-V7. The first channel region C0 and the second channel region C1 may constitute a first channel. Through vias coupled to the first channel region C0 may be disposed in the first through via region V0, and through vias coupled to the second channel region C1 may be disposed in the second through via region V1. The third channel region C2 and the fourth channel region C3 may constitute a second channel. Through vias coupled to the third channel region C2 may be disposed in the third through via region V2, and through vias coupled to the fourth channel region C3 may be disposed in the fourth through via region V3. The fifth channel region C4 and the sixth channel region C5 may constitute a third channel. Through vias coupled to the fifth channel region C4 may be disposed in the fifth through via region V4, and through vias coupled to the sixth channel region C5 may be disposed in the sixth through via region V5. The seventh channel region C6 and the eighth channel region C7 may constitute a fourth channel. Through vias coupled to the seventh channel region C6 may be disposed in the seventh through via region V6, and through vias coupled to the eighth channel region C7 may be disposed in the eighth through via region V7. A plurality of through vias may be disposed in the first to eighth through via regions V0-V7 to electrically connect an internal circuit of the memory die 1700b, or another memory die disposed above or below the memory die 1700b, to the host die 1610 shown in FIG. 20. Remaining through vias in the through via regions may be used as signal paths. For example, when one or more memory dies 1700a is disposed between the host die 1610 and the substrate 1630, remaining through vias (except for the through vias electrically connecting the internal circuit of the memory die 1700b with the host die 1610), the remaining through vias may be used as signal paths to electrically connect the host die 1610 with the substrate 1630 and the external device. In FIG. 21B, the through vias labelled “O” may be through vias for electrically connecting the internal circuit of a memory die 1700b or another memory die disposed above or below the memory die 1700b to the host die 1610, and the through vias labelled “X” may be through vias for electrically connecting a host die 1610 to an external device. Within the through via regions V0-V8, the number of through vias for electrically connecting the host die 1610 with the external device may change depending on the number of memory dies that the memory apparatus 1620 includes and/or the number of channels in a memory die.

Referring to FIG. 21C, a memory die 1700c, like a memory die 1700a, may include a channel region 1710c with a transverse through via region 1720c, and may further include a through via region 1730c. For example, the through via region 1730c may include first to fifth additional through via regions VA0-VA4. A plurality of through vias may be disposed in each of the first to fifth additional through via regions VA0-VA4. When one or more memory dies 1700a is disposed between the host die 1610 and an external device, the plurality of through vias in through via region 1730c may be provided as signal paths for electrically connecting the host die 1610 and the external device. Thus, the through vias in the first to eighth through via regions V0-V7 may be used as signal paths to connect an internal circuit of the memory die 1700c, or another memory die disposed above or below the memory die 1700c, with the host die 1610. In FIG. 21C, a first channel includes first and second channel regions C0, C1; a second channel includes third and fourth channel regions C2, C3; a third channel includes fifth and sixth channel regions C4, C5; and a fourth channel includes seventh and eighth channel regions C6, C7. The first through fourth channels extend in the y-direction. The first additional through via region VA0 may extend in the y-axis direction common to the leftmost side (i.e., an edge in the x-axis direction) of the first channel and first and second through via regions V0, V1. the second additional through via region VA1 may extend in the y-axis direction on the opposite side from first additional through via region VA0 and common to first and second channels and first through fourth through via regions V0, V1, V2 and V3. the first and second channel regions C0, C1 and the third and fourth channel regions C2, C3. Similarly, the third additional through via region VA2 extend in the y-axis direction between the third and fourth channel regions C2, C3 and the fifth and sixth channel regions C4, C5, and between third and fourth through via regions V2, V3 and fifth and sixth through via regions V4, V5. The fourth additional through via region VA3 may extend in the y-axis direction between the fifth and sixth channel regions C4, C5 and the seventh and eighth channel regions C6, C7, and between fifth and sixth through via regions V4, V5 and seventh and eighth through via regions V6, V7. The fifth additional through via region VA5 may extend in the y-axis direction at the farthest right side of memory die 1700c in the x-axis direction. The structure of the memory die 1700c shown in FIG. 21C may be advantageous in that a maximum bandwidth can be obtained without reducing the number of channels of a memory apparatus that includes the memory die 1700c. On the other hand, the area of the channel region 1710c may be reduced by forming the through via region 1730c, and additional wirings may be required to connect the through vias in the through via region 1730c. In comparison, the structures of memory dies 1700a, 1700b illustrated in FIGS. 21A and 21B may reduce the number of channels and bandwidth of memory apparatuses including the memory dies 1700a, 1700b, but might not require any design changes to the memory dies 1700a, 1700b to utilize the through vias in the through via regions 1720a, 1720b to connect the host die 1610 to the external device.

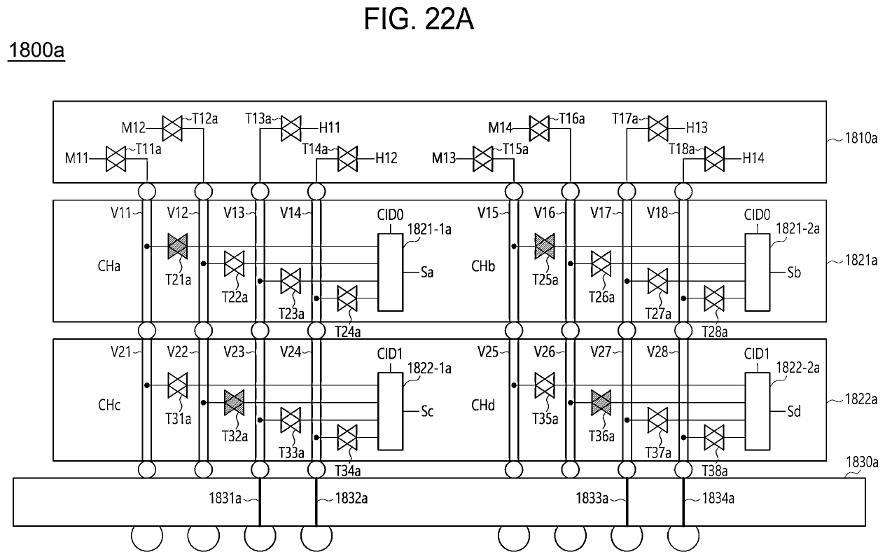

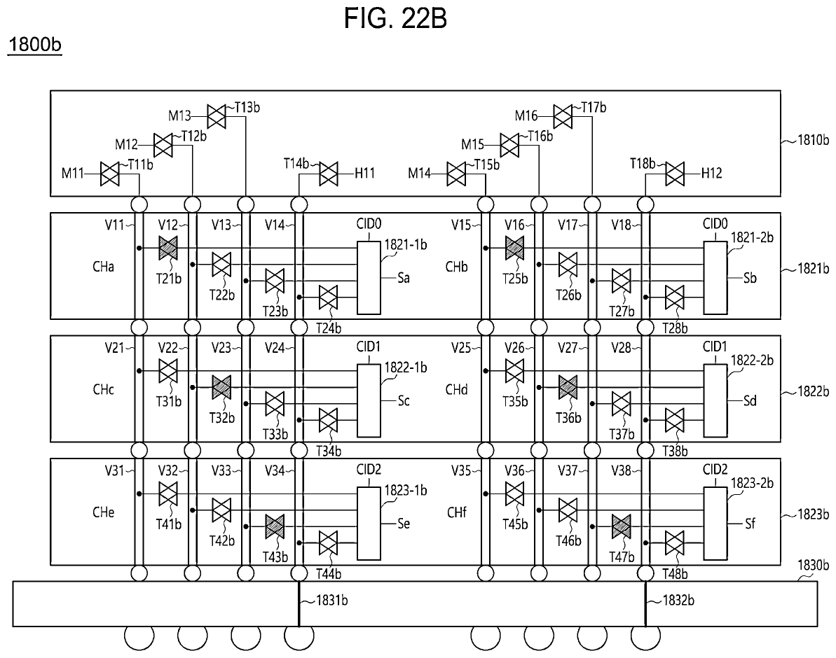

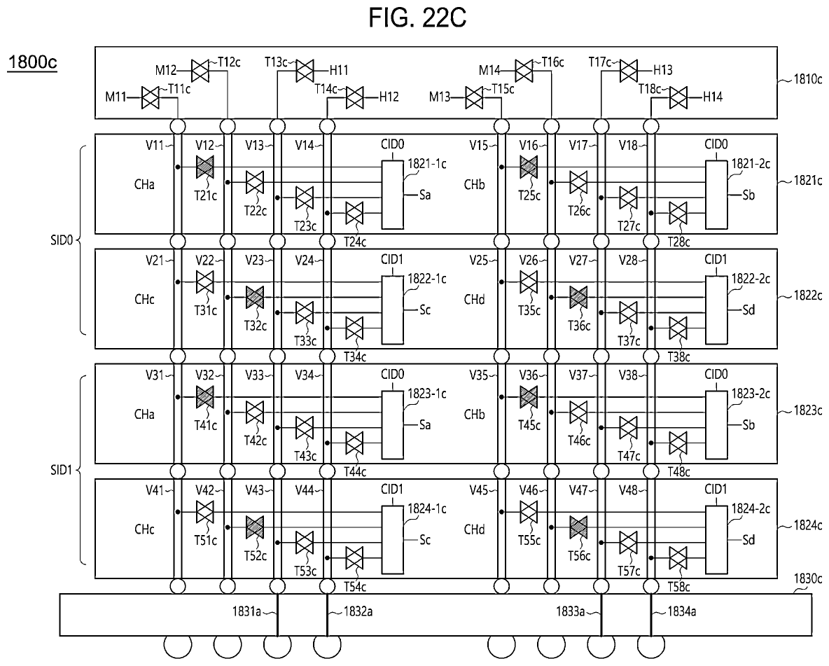

FIG. 22A is a diagram illustrating a connection structure of a computing system 1800a according to an embodiment of the present disclosure. Referring to FIG. 22A, the computing system may include a host die 1810a, a first memory die 1821a, a second memory die 1822a, and a substrate 1830a. The second memory die 1822a may be disposed on the substrate 1830a, and the first memory die 1821a may be disposed on the second memory die 1822a. The host die 1810a may be disposed on the first memory die 1821a. A plurality of through vias may be formed in the first and second memory dies 1821a, 1822a. The plurality of through vias may be coupled by a multi-drop method, and components of computing system 1800a may be connected using microbumps. The first and second memory dies 1821a, 1822a may include at least n through vias, and may be implemented in structural configurations illustrated in FIGS. 21A, 21B and 21C by way of non-limiting examples. Here, n may be an integer of two or more. The n through vias may form one signal path group. The n through vias may be coupled to n memory dies and/or n channels. For example, when a signal path group includes four through vias, the signal path group may be independently coupled to up to four memory dies and/or four channels. When the signal path group including four through vias is independently coupled to only two memory dies and/or two channels, the remaining two through vias are not coupled to memory dies or channels. Thus, two through vias of a signal path group with four through vias may be used to electrically connect the host die 1810a with internal circuits of the first and second memory dies 1821a, 1822a, and the remaining two through vias may be used to electrically connect the host die 1810a with the substrate 1830a. The first and second memory dies 1821a, 1822a may each include first to eighth through vias V11-V18, V21-V28 positioned at first to eighth positions. The first through vias V11, V21 may be electrically connected to each other, and the second through vias V12, V22 may be electrically connected to each other. The third through vias V13, V23 may be electrically connected to each other, and the fourth through vias V14, V24 may be electrically connected to each other. The fifth through vias V15, V25 may be electrically connected to each other, and the sixth through vias V16, V26 may be electrically connected to each other. The seventh through vias V17, V27 may be electrically connected to each other, and the eighth through vias V17, V28 may be electrically connected to each other. The first and second memory dies 1821a, 1822a may each include two channels. The first memory die 1821a may include a first channel CHa and a second channel CHb, and the second memory die 1822a may include a third channel CHc and a fourth channel CHd. The first to fourth through vias V11-V14, V21-V24 may form a first signal path group, and the fifth to eighth through vias V15-V18, V25-V28 may form a second signal path group. For example, the first through vias V11, V21 may be used to transmit signals of the first channel CHa, and the second through vias V12, V22 may be used to transmit signals of the third channel CHc. The third and fourth through vias V13-V14, V23-V24 might not be used to transmit signals of the first and third channels CHa, CHc. The fifth through vias V15, V25 may be used to transmit signals of the second channel CHb, and the sixth through vias V16, V26 may be used to transmit signals of the fourth channel CHd. The seventh and eighth through vias V17-V18, V27-V28 might not be used to transmit signals of the second and fourth channels CHb, CHd. The host die 1810a may be coupled to internal circuits of the first memory die 1821a through the first through vias V11, V21 and the fifth through vias V15, V25. The host die 1810a may be coupled to an internal circuit of the first channel CHa through the first through vias V11, V21, and may be coupled to an internal circuit of the second channel CHb through the fifth through vias V15, V25. The host die 1810a may be coupled to internal circuits of the second memory die 1822a through the second through vias V12, V22 and the sixth through vias V16, V26. The host die 1810a may be coupled to an internal circuit of the third channel CHc through the second through vias V12, V22 and to an internal circuit of the fourth channel CHd through the sixth through vias V16, V26. The host die 1810a may be coupled to the substrate 1830a through the third through vias V13, V23, the fourth through vias V14, V24, the seventh through vias V17, V27, and the eighth through vias V18, V28. The third through vias V13, V23, the fourth through vias V14, V24, the seventh through vias V17, V27, and the eighth through vias V18, V28 may be coupled to first to fourth signal paths 1831a, 1832a, 1833a, 1834a formed in the substrate 1830a, respectively. The host die 1810a may be coupled to an external device of the computing system 1800a through the third through vias V13, V23, the fourth through vias V14, V24, the seventh through vias V17, V27, and the eighth through vias V18, V28.

The host die 1810a may include a first transceiver T11a, a second transceiver T12a, a third transceiver T13a, a fourth transceiver T14a, a fifth transceiver T15a, a sixth transceiver T16a, a seventh transceiver T17a, and an eighth transceiver T18a. The first to eighth transceivers T11a-T18a may be included as components of an interface circuit 1613 illustrated in FIG. 20. The first transceiver T11a may be coupled to the first through vias V11, V21, may transmit a first memory signal M11 to the first through vias V11, V21, and may receive a signal transmitted through the first through vias V21, V11 as the first memory signal M11. The second transceiver T12a may be coupled to the second through vias V12, V22, transmit a second memory signal M12 to the second through vias V12, V22, and receive a signal transmitted through the second through vias V12, V22 as the second memory signal M12. The third transceiver T13a may be coupled to the third through vias V13, V23, transmit a first host signal H11 to the third through vias V13, V23, and receive a signal transmitted through the third through vias V13, V23 as the first host signal H11. The fourth transceiver T14a may be coupled to the fourth through vias V14, V24, transmit a second host signal H12 to the fourth through vias V14, V24, and receive a signal transmitted through the fourth through vias V14, V24 as the second host signal H12. The fifth transceiver T15a may be coupled to the fifth through vias V15, V25, transmit a third memory signal M13 to the fifth through vias V15, V25, and receive a signal transmitted through the fifth through vias V15, V25 as the third memory signal M13. The sixth transceiver T16a may be coupled to the sixth through vias V16, V26, transmit a fourth memory signal M14 to the sixth through vias V16, V26, and receive a signal transmitted through the sixth through vias V16, V26 as the fourth memory signal M14. The seventh transceiver T17a may be coupled to the seventh through vias V17, V27, transmit a third host signal H13 to the seventh through vias V17, V27, and receive a signal transmitted through the seventh through vias V17, V27 as the third host signal H13. The eighth transceiver T18a may be coupled to the eighth through vias V18, V28, transmit a fourth host signal H14 to the eighth through vias V18, V28, and receive a signal transmitted through the eighth through vias V18, V28 as the fourth host signal H14. In an embodiment of the present disclosure, the memory signals may include any type of signal that may be transmitted between the host die and the memory dies. In an embodiment of the present disclosure, the host signals may include any type of signal that may be transmitted between the host die and an external device. While the first to fourth memory signals M11-M14 are illustrated as bidirectional signals, the first to fourth memory signals M11-M14 may also be unidirectional signals. Depending on the characteristics of the first to fourth memory signals M11-M14, the first, second, fifth and sixth transceivers T11a, T12a, T15a, T16a may be replaced by receivers or transmitters. For example, when the first to fourth memory signals M11-M14 are unidirectional signals (such as command address signals) transmitted from the host die 1810a to the first and second memory dies 1821a, 1822a, the first, second, fifth, and sixth transceivers T11a, T12a, T15a, T16a may be replaced by transmitters. Conversely, when the first to fourth memory signals M11-M14 are unidirectional signals (such as error detection signals) transmitted from the first and second memory dies 1821a, 1822a to the host die 1810a, the first, second, fifth, and sixth transceivers T11a, T12a, T15a, T16a may be replaced by receivers. Although the first to fourth host signals H11-H14 are described as bidirectional, the first to fourth host signals H11-H14 may be unidirectional. The third, fourth, seventh, and eighth transceivers T13a, T14a, T17a, T18a may be replaced by receivers or transmitters depending on the characteristics of the first to fourth host signals H11-H14. For example, when the first to fourth host signals H11-H14 are unidirectional signals from the host die 1810a to the external device, the third, fourth, seventh, and eighth transceivers T13a, T14a, T17a, T18a may be replaced by transmitters. When the first to fourth host signals H11-H14 are unidirectional signals from the external device to the host die 1810a, the third, fourth, seventh, and eighth transceivers T13a, T14a, T17a, T18a may be replaced by receivers. In an embodiment, one of the first to fourth host signals H11-H14 may be a power voltage, and the host die 1810a might not include a transceiver coupled to a through via through which a power voltage is transmitted. The power voltage transmitted using a through via may be fed to a power mesh of the host die 1810a without a transceiver.

The first memory die 1821a may include a first transceiver T21a, a second transceiver T22a, a third transceiver T23a, a fourth transceiver T24a, a fifth transceiver T25a, a sixth transceiver T26a, a seventh transceiver T27a, an eighth transceiver T28a, a first path selection circuit 1821-1a, and a second path selection circuit 1821-2a. The first transceiver T21a may be coupled between the first through via V11 and the first path selection circuit 1821-1a. The second transceiver T22a may be coupled between the second through via V12 and the first path selection circuit 1821-1a. The third transceiver T23a may be coupled between the third through via V13 and the first path selection circuit 1821-1a. The fourth transceiver T24a may be coupled between the fourth through via V14 and the first path selection circuit 1821-1a. The fifth transceiver T25a may be coupled between the fifth through via V15 and the second path selection circuit 1821-2a. The sixth transceiver T26a may be coupled between the sixth through via V16 and the second path selection circuit 1821-2a. The seventh transceiver T27a may be coupled between the seventh through via V17 and the second path selection circuit 1821-2a. The eighth transceiver T28a may be coupled between the eighth through via V18 and the second path selection circuit 1821-2a.

The second memory die 1822a may have substantially the same structure as the first memory die 1821a. The second memory die 1822a may include a first transceiver T31a, a second transceiver T32a, a third transceiver T33a, a fourth transceiver T34a, a fifth transceiver T35a, a sixth transceiver T36a, a seventh transceiver T37a, an eighth transceiver T38a, a third path selection circuit 1822-1a, and a fourth path selection circuit 1822-2a. The first transceiver T31a may be coupled between the first through via V21 and the third path selection circuit 1822-1a. The second transceiver T32a may be coupled between the second through via V22 and the third path selection circuit 1822-1a. The third transceiver T33a may be coupled between the third through via V23 and the third path selection circuit 1822-1a. The fourth transceiver T34a may be coupled between the fourth through via V24 and the third path selection circuit 1822-1a. The fifth transceiver T35a may be coupled between the fifth through via V25 and the fourth path selection circuit 1822-2a. The sixth transceiver T36a may be coupled between the sixth through via V26 and the fourth path selection circuit 1822-2a. The seventh transceiver T37a may be coupled between the seventh through via V27 and the fourth path selection circuit 1822-2a. The eighth transceiver T38a may be coupled between the eighth through via V28 and the fourth path selection circuit 1822-2a. Depending on the characteristics of the first to fourth memory signals M11-M14, the first to eighth transceivers T21a-T28a, T31a-T38a of the first and second memory dies 1821a, 1822a may be replaced by transmitters or receivers, respectively.

A chip ID signal may be assigned to each of the first and second memory dies 1821a, 1822a, respectively, and a signal path of each of the first and second memory dies 1821a, 1822a may be set according to the chip ID signal of the memory die. For example, a first chip ID signal CID0 may be assigned to the first memory die 1821a and a second chip ID signal CID1 may be assigned to the second memory die 1822a. As an example, the first chip ID signal CID0 may activate the first and fifth transceivers T21a, T25a and deactivate the second, third, fourth, sixth, seventh, and eighth transceivers T22a-T24a, T26a-. The first path selection circuit 1821-1a may be coupled to the first transceiver T21a based on the first chip ID signal CID0. The first path selection circuit 1821-1a may output the first memory signal M11 transmitted from the host die 1810a through the first through via V11 and the first transceiver T21a as a first channel signal Sa, and may output the first channel signal Sa to the host die 1810a through the first transceiver T21a and the first through via V11. An internal circuit of the first channel CHa may receive the first channel signal Sa from the first path selection circuit 1821-1a and output the first channel signal Sa to the first path selection circuit 1821-1a. The second path selection circuit 1821-2a may be coupled to the fifth transceiver T25a based on the first chip ID signal CID0. The second path selection circuit 1821-2a may output the third memory signal M13 transmitted from the host die 1810a through the fifth through via V15 and the fifth transceiver T25a as the second channel signal Sb, and may output the second channel signal Sb to the host die 1810a through the fifth transceiver T25a and the fifth through via V15. An internal circuit of the second channel CHb may receive the second channel signal Sb from the second path selection circuit 1821-2a and output the second channel signal Sb to the second path selection circuit 1821-2a.

The second chip ID signal CID1 may activate the second and sixth transceivers T32a, T36a and deactivate the first, third, fourth, fifth, seventh and eighth transceivers T31a, T33a-T35a, T37a-T38a. The third path selection circuit 1822-1a may be coupled to the second transceiver T32a based on the second chip ID signal CID1. The third path selection circuit 1822-1a may output the second memory signal M12 transmitted from the host die 1810a through the second through via V22 and the second transceiver T32a as the third channel signal Sc, and may output the third channel signal Sc to the host die 1810a through the second transceiver T32a and the second through via V22. An internal circuit of the third channel CHc may receive the third channel signal Sc from the third path selection circuit 1822-1a and output the third channel signal Sc to the third path selection circuit 1822-1a. The fourth path selection circuit 1822-2a may be coupled to the sixth transceiver T36a based on the second chip ID signal CID1. The fourth path selection circuit 1822-2a may output the fourth memory signal M14 transmitted from the host die 1810a through the sixth through via V26 and the sixth transceiver T36a as the fourth channel signal Sd, and may output the fourth channel signal Sd to the host die 1810a through the sixth transceiver T36a and the sixth through via V26. An internal circuit of the fourth channel CHd may receive the fourth channel signal Sd from the fourth path selection circuit 1822-2a and output the fourth channel signal Sd to the fourth path selection circuit 1822-2a. Because the third, fourth, seventh and eighth transceivers T23a, T33a, T24a, T34a, T27a, T37a, T28a, T38a of the first and second memory dies 1821a, 1822a are deactivated, the third, fourth, seventh, and eighth through vias V13, V14, V17, V18, V23, V24, V27, V28 may be electrically isolated from internal circuits of the first and second memory dies 1821a, 1822a.

FIG. 22B is a diagram illustrating a connection structure of a computing system 1800b according to an embodiment of the present disclosure. Referring to FIG. 22B, the computing system 1800b may include a host die 1810b, a first memory die 1821b, a second memory die 1822b, a third memory die 1823b, and a substrate 1830b. The third memory die 1823b may be disposed on the substrate 1830b, the second memory die 1822b may be disposed on the third memory die 1823b, and the first memory die 1821b may be disposed on the second memory die 1822b. The host die 1810b may be disposed on the first memory die 1821b. A plurality of through vias may be formed in the first to third memory dies 1821b, 1822b, 1823b, and may be implemented in structural configurations illustrated in FIGS. 21A, 21B and 21C by way of non-limiting examples. The plurality of through vias may be coupled in a multi-drop method, and components of computing system 1800b may be connected using microbumps. In general, the number of signals transmitted between the host die and the memory dies may be greater than the number of signals transmitted between the host die and an external device. Accordingly, it may be desirable to maximize the number of through vias electrically connecting the host die 1810b with internal circuits of the first to third memory dies 1821b, 1822b, 1823b. The computing system 1800b may include a greater number of channels than the computing system 1800a of FIG. 22A. The first to third memory dies 1821b, 1822b, 1823b may each include first to eighth through vias V11-V18, V21-V28, V31-V38 arranged at first to eighth positions. The first through vias V11, V21, V31 may be electrically connected to each other, and the second through vias V12, V22, V32 may be electrically connected to each other. The third through vias V13, V23, V33 may be electrically connected to each other, and the fourth through vias V14, V24, V34 may be electrically connected to each other. The fifth through vias V15, V25, V35 may be electrically connected to each other, and the sixth through vias V16, V26, V36 may be electrically connected to each other. The seventh through vias V17, V27, V37 may be electrically connected to each other, and the eighth through vias V18, V28, V38 may be electrically connected to each other. Each of the first to third memory dies 1821b, 1822b, 1823b may include two channels. The first memory die 1821b may include a first channel CHa and a second channel CHb, the second memory die 1822b may include a third channel CHc and a fourth channel CHd, and the third memory die 1823b may include a fifth channel CHe and a sixth channel CHf. The first to fourth through vias V11-V14, V21-V24, V31-V34 may form a first signal path group, and the fifth to eighth through vias V15-V18, V25-V28, V35-V38 may form a second signal path group. For example, the first through vias V11, V21, V31 may be used to transmit signals of the first channel CHa. The second through vias V12, V22, V32 may be used to transmit signals of the third channel CHc. The third through vias V13, V23, V33 may be used to transmit signals of the fifth channel CHe. The fourth through vias V14, V24, V34 might not be used to transmit signals of the first, third and fifth channels CHa, CHc, CHe. The fifth through vias V15, V25, V35 may be used to transmit signals of the second channel CHb. The sixth through vias V16, V26, V36 may be used to transmit signals of the fourth channel CHd. The seventh through vias V17, V27, V37 may be used to transmit signals of the sixth channel CHf. The eighth through vias V18, V28, V38 might not be used to transmit signals of the second, fourth, and sixth channels CHb, CHd, CHf. The host die 1810b may be coupled to internal circuits of the first memory die 1821b through the first through vias V11, V21, V31 and the fifth through vias V15, V25, V35. The host die 1810b may be coupled to an internal circuit of the first channel CHa through the first through vias V11, V21, V31 and with an internal circuit of the second channel CHb through the fifth through vias V15, V25, V35. The host die 1810b may be coupled to internal circuits of the second memory die 1822b through the second through vias V12, V22, V32 and the sixth through vias V16, V26, V36. The host die 1810b may be coupled to an internal circuit of the third channel CHc through the second through vias V12, V22, V32, and may be coupled to an internal circuit of the fourth channel CHd through the sixth through vias V16, V26, V36. The host die 1810b may be coupled to internal circuits of the third memory die 1823b through the third through vias V13, V23, V33 and the seventh through vias V17, V27, V37. The host die 1810b may be coupled to an internal circuit of the fifth channel CHe through the third through vias V13, V23, V33 and with an internal circuit of the sixth channel CHf through the seventh through vias V17, V27, V37. The host die 1810b may be coupled to the substrate 1830b through the fourth through vias V14, V24, V34 and the eighth through vias V18, V28, V38. The fourth through vias V14, V24, V34 and the eighth through vias V18, V28, V38 may be coupled to a first signal path 1831b and a second signal path 1832b disposed in the substrate 1830b, respectively. The host die 1810b may be coupled to an external device of the computing system 1800b through the fourth through vias V14, V24, V34 and the eighth through vias V18, V28, V38.

The host die 1810b may include a first transceiver T11b, a second transceiver T12b, a third transceiver T13b, a fourth transceiver T14b, a fifth transceiver T15b, a sixth transceiver T16b, a seventh transceiver T17b, and an eighth transceiver T18b. The first to eighth transceivers T11b-T18b may be included as components of the interface circuit 1613 shown in FIG. 20. The first transceiver T11b may be coupled to the first through vias V11, V21, V31, may transmit a first memory signal M11 to the first through vias V11, V21, V31, and may receive a signal transmitted through the first through vias V11, V21, V31 as the first memory signal M11. The second transceiver T11b may be coupled to the second through vias V12, V22, V32, transmit a second memory signal M12 to the second through vias V12, V22, V32, and receive a signal transmitted through the second through vias V12, V22, V32 as the second memory signal M12. The third transceiver T13b may be coupled to the third through vias V13, V23, V33, transmit a third memory signal M13 to the third through vias V13, V23, V33, and receive a signal transmitted through the third through vias V13, V23, V33 as the third memory signal M13. The fourth transceiver T14b may be coupled to the fourth through vias V14, V24, V34, transmit a first host signal H11 to the fourth through vias V14, V24, V34, and receive a signal transmitted through the fourth through vias V14, V24, V34 as the first host signal H11. The fifth transceiver T15b may be coupled to the fifth through vias V15, V25, V35, transmit a fourth memory signal M14 to the fifth through vias V15, V25, V35, and receive a signal transmitted through the fifth through vias V15, V25, V35 as the fourth memory signal M14. The sixth transceiver T16b may be coupled to the sixth through vias V16, V26, V36, transmit a fifth memory signal M15 to the sixth through vias V16, V26, V36, and receive a signal transmitted through the sixth through vias V16, V26, V36 as the fifth memory signal M15. The seventh transceiver T17b may be coupled to the seventh through vias V17, V27, V37, transmit a sixth memory signal M16 to the seventh through vias V17, V27, V37, and receive a signal transmitted through the seventh through vias V17, V27, V37 as the sixth memory signal M16. The eighth transceiver T18b may be coupled to the eighth through vias V18, V28, V38, transmit a second host signal H12 to the eighth through vias V18, V28, V38, and receive a signal transmitted through the eighth through vias V18, V28, V38 as the second host signal H12. Although the first to sixth memory signals M11-M16 are described as bidirectional signals, the first to sixth memory signals M11-M16 may also be unidirectional signals. Depending on the characteristics of the first to six memory signals M11-M16, the first, second, third, fifth, sixth and seventh transceivers T11b-T13b, T15b-T17b may be replaced by receivers or transmitters. While the first and second host signals H11, H12 are described as bidirectional signals, the first and second host signals H11, H12 may also be unidirectional signals. Depending on the characteristics of the first and second host signals H11, H12, the fourth and eighth transceivers T14b, T18b may be replaced by receivers or transmitters.

The first memory die 1821b may include a first transceiver T21b, a second transceiver T22b, a third transceiver T23b, a fourth transceiver T24b, a fifth transceiver T25b, a sixth transceiver T26b, a seventh transceiver T27b, an eighth transceiver T28b, a first path selection circuit 1821-1b, and a second path selection circuit 1821-2b. The first transceiver T21b may be coupled between the first through via V11 and the first path selection circuit 1821-1b. The second transceiver T22b may be coupled between the second through via V12 and the first path selection circuit 1821-1b. The third transceiver T23b may be coupled between the third through via V13 and the first path selection circuit 1821-1b. The fourth transceiver T24b may be coupled between the fourth through via V14 and the first path selection circuit 1821-1b. The fifth transceiver T25b may be coupled between the fifth through via V15 and the second path selection circuit 1821-2b. The sixth transceiver T26b may be coupled between the sixth through via V16 and the second path selection circuit 1821-2b. The seventh transceiver T27b may be coupled between the seventh through via V17 and the second path selection circuit 1821-2b. The eighth transceiver T28b may be coupled between the eighth through via V18 and the second path selection circuit 1821-2b.

The second memory die 1822b may have substantially the same structure as the first memory die 1821b. The second memory die 1822b may include a first transceiver T31b, a second transceiver T32b, a third transceiver T33b, a fourth transceiver T34b, a fifth transceiver T35b, a sixth transceiver T36b, a seventh transceiver T37b, an eighth transceiver T38b, a third path selection circuit 1822-1b, and a fourth path selection circuit 1822-2b. The first transceiver T31b may be coupled between the first through via V21 and the third path selection circuit 1822-1b. The second transceiver T32b may be coupled between the second through via V22 and the third path selection circuit 1822-1b. The third transceiver T33b may be coupled between the third through via V23 and the third path selection circuit 1822-1b. The fourth transceiver T34b may be coupled between the fourth through via V24 and the third path selection circuit 1822-1b. The fifth transceiver T35b may be coupled between the fifth through via V25 and the fourth path selection circuit 1822-2b. The sixth transceiver T36b may be coupled between the sixth through via V26 and the fourth path selection circuit 1822-2b. The seventh transceiver T37b may be coupled between the seventh through via V27 and the fourth path selection circuit 1822-2b. The eighth transceiver T38b may be coupled between the eighth through via V28 and the fourth path selection circuit 1822-2b.

The third memory die 1823b may have substantially the same structure as the first and second memory dies 1821b, 1822b. The third memory die 1823b may include a first transceiver T41b, a second transceiver T42b, a third transceiver T43b, a fourth transceiver T44b, a fifth transceiver T45b, a sixth transceiver T46b, a seventh transceiver T47b, an eighth transceiver T48b, a fifth path selection circuit 1823-1b, and a sixth path selection circuit 1823-2b. The first transceiver T41b may be coupled between the first through via V31 and the fifth path selection circuit 1823-1b. The second transceiver T42b may be coupled between the second through via V32 and the fifth path selection circuit 1823-1b. The third transceiver T43b may be coupled between the third through via V33 and the fifth path selection circuit 1823-1b. The fourth transceiver T44b may be coupled between the fourth through via V34 and the fifth path selection circuit 1823-1b. The fifth transceiver T45b may be coupled between the fifth through via V35 and the sixth path selection circuit 1823-2b. The sixth transceiver T46b may be coupled between the sixth through via V36 and the sixth path selection circuit 1823-2b. The seventh transceiver T47b may be coupled between the seventh through via V37 and the sixth path selection circuit 1823-2b. The eighth transceiver T48b may be coupled between the eighth through via V38 and the sixth path selection circuit 1823-2b. Depending on the characteristics of the first to six memory signals M11-M16 and the first and second host signals H11, H12, the first to eighth transceivers T21b-T28b, T31b-T38b, T41b-T48b of the first to third memory die 1821b, 1822b, 1823b may be replaced by transmitters or receivers, respectively.

A chip ID signal may be assigned to each of the first to third memory dies 1821b, 1822b, 1823b, respectively, and a signal path of each of the first to third memory dies 1821b, 1822b, 1823b may be set according to the chip ID signal of the memory die. For example, a first chip ID signal CID0 may be assigned to the first memory die 1821b, a second chip ID signal CID1 may be assigned to the second memory die 1822b, and a third chip ID signal CID2 may be assigned to the third memory die 1823b. Based on the first chip ID signal CID0, the first and fifth transceivers T21b, T25b may be activated, and the second, third, fourth, sixth, seventh, and eighth transceivers T22b-T24b, T26b-T28b may be deactivated. The first path selection circuit 1821-1b may be coupled to the first transceiver T21b based on the first chip ID signal CID0. The first path selection circuit 1821-1b may output the first memory signal M11 transmitted from the host die 1810b through the first through via V11 and the first transceiver T21b as the first channel signal Sa, and may output the first channel signal Sa to the host die 1810b through the first transceiver T21b and the first through via V11. An internal circuit of the first channel CHa may receive the first channel signal Sa from the first path selection circuit 1821-1b and output the first channel signal Sa to the first path selection circuit 1821-1b. The second path selection circuit 1821-2b may be coupled to the fifth transceiver T25b based on the first chip ID signal CID0. The second path selection circuit 1821-2b may output the fourth memory signal M14 transmitted from the host die 1810b through the fifth through via V15 and the fifth transceiver T25b as the second channel signal Sb, and may output the second channel signal Sb to the host die 1810b through the fifth transceiver T25b and the fifth through via V15. An internal circuit of the second channel CHb may receive the second channel signal Sb from the second path selection circuit 1821-2b and output the second channel signal Sb to the second path selection circuit 1821-2b.

Based on the second chip ID signal CID1, the second and sixth transceivers T32b, T36b may be activated and the first, third, fourth, fifth, seventh and eighth transceivers T31b, T33b-T35b, T37b-T38b may be deactivated. The third path selection circuit 1822-1b may be coupled to the second transceiver T32b based on the second chip ID signal CID1. The third path selection circuit 1822-1b may output the second memory signal M12 transmitted from the host die 1810b through the second through via V22 and the second transceiver T32b as the third channel signal Sc, and may output the third channel signal Sc to the host die 1810b through the second transceiver T32b and the second through via V22. An internal circuit of the third channel CHc may receive the third channel signal Sc from the third path selection circuit 1822-1b and output the third channel signal Sc to the third path selection circuit 1822-1b. The fourth path selection circuit 1822-2b may be coupled to the sixth transceiver T36b based on the second chip ID signal CID1. The fourth path selection circuit 1822-2b may output the fifth memory signal M15 transmitted from the host die 1810b through the sixth through via V26 and the sixth transceiver T36b as the fourth channel signal Sd, and may output the fourth channel signal Sd to the host die 1810b through the sixth transceiver T36b and the sixth through via V26. An internal circuit of the fourth channel CHd may receive the fourth channel signal Sd from the fourth path selection circuit 1822-2b and output the fourth channel signal Sd to the fourth path selection circuit 1822-2b.

Based on the third chip ID signal CID2, the third and seventh transceivers T43b, T47b may be activated, and the first, second, fourth, fifth, sixth, and eighth transceivers T41b-T42b, T44b-T46b, T48b may be deactivated. The fifth path selection circuit 1823-1b may be coupled to the third transceiver T43b based on the third chip ID signal CID2. The fifth path selection circuit 1823-1b may output the third memory signal M13 transmitted from the host die 1810b through the third through via V33 and the third transceiver T43b as the fifth channel signal Se, and may output the fifth channel signal Se to the host die 1810b through the third transceiver T43b and the third through via V33. An internal circuit of the fifth channel CHe may receive the fifth channel signal Se from the fifth path selection circuit 1823-1b and output the fifth channel signal Se to the fifth path selection circuit 1823-1b. The sixth path selection circuit 1823-2b may be coupled to the seventh transceiver T47b based on the third chip ID signal CID2. The sixth path selection circuit 1823-2b may output the sixth memory signal M16 transmitted from the host die 1810b through the seventh through via V37 and the seventh transceiver T47b as the sixth channel signal Sf, and may output the sixth channel signal Sf to the host die 1810b through the seventh transceiver T47b and the seventh through via V37. An internal circuit of the sixth channel CHf may receive the sixth channel signal Sf from the sixth path selection circuit 1823-2b and output the sixth channel signal Sf to the sixth path selection circuit 1823-2b. Because the fourth and eighth transceivers T24b, T28b, T34b, T38b, T44b, T48b of the first to third memory dies 1821b, 1822b, 1823b are deactivated, the fourth and eighth through vias V14, V18, V24, V28, V34, V38 may be electrically isolated from the internal circuits of the first to third memory dies 1821b, 1822b, 1823b.

FIG. 22C is a diagram illustrating a connection structure of a computing system 1800c according to an embodiment of the present disclosure. Referring to FIG. 22C, the computing system 1800c may include a host die 1810c, a first memory die 1821c, a second memory die 1822c, a third memory die 1823c, a fourth memory die 1824c, and a substrate 1830c. The fourth memory die 1824c may be disposed on the substrate 1830c, and the third memory die 1823c may be disposed on the fourth memory die 1824c. The second memory die 1822c may be disposed on the third memory die 1823c. The first memory die 1821c may be disposed on the second memory die 1822c. The host die 1810c may be disposed on the first memory die 1821c. A plurality of through vias may be included in the first to fourth memory dies 1821c, 1822c, 1823c, 1824c. The memory dies may be implemented in structural configurations illustrated in FIGS. 21A, 21B and 21C by way of non-limiting examples. The plurality of through vias may be coupled in a multi-drop method, and components of computing system 1800c may be connected using microbumps. The computing system 1800c may increase the memory density of the computing system 1800c by increasing the number of memory dies, which may be sequentially stacked. The computing system 1800c may include the same number of channels as the computing system 1800a of FIG. 22A, but may have twice the memory density.

Each of the first to fourth memory dies 1821c, 1822c, 1823c, 1824c may include first to eighth through vias V11-V18, V21-V28, V31-V38, V41-V48 formed at first to eighth positions. The first through vias V11, V21, V31, V41 may be electrically connected to each other, and the second through vias V12, V22, V32, V42 may be electrically connected to each other. The third through vias V13, V23, V33, V43 may be electrically connected to each other, and the fourth through vias V14, V24, V34, V44 may be electrically connected to each other. The fifth through vias V15, V25, V35, V45 may be electrically connected to each other, and the sixth through vias V16, V26, V36, V46 may be electrically connected to each other. The seventh through vias V17, V27, V37, V47 may be electrically connected to each other, and the eighth through vias V18, V28, V38, V48 may be electrically connected to each other. The first to fourth memory dies 1821c, 1822c, 1823c, 1824c may each include two channels. The first and third memory dies 1821c, 1823c may include the same channels, and the second and fourth memory dies 1822c, 1824c may include the same channels. For example, the first and third memory dies 1821c, 1823c may include a first channel CHa and a second channel CHb, and the second and fourth memory dies 1822c, 1824c may include a third channel CHc and a fourth channel CHd. The first to fourth memory dies 1821c, 1822c, 1823c, 1824c may be selectively accessed by a slice ID signal. For example, the first and second memory dies 1821c, 1822c may be accessed by a first slice ID signal SID0, and the third and fourth memory dies 1823c, 1824c may be accessed by a second slice ID signal SID1. The first and second slice ID signals SID0, SID1 may be signals provided from the host die 1810c to the first to fourth memory dies 1821c, 1822c, 1823c, 1824c. When the first slice ID signal SID0 is enabled, the first and second channels CHa, CHb of the first memory die 1821c and the third and fourth channels CHc, CHd of the second memory die 1822c may be accessed. When the second slice ID signal SID1 is enabled, the first and second channels CHa, CHb of the third memory die 1823c and the third and fourth channels CHc, CHd of the fourth memory die 1824c may be accessed. The first to fourth through vias V11-V14, V21-V24, V31-V34, V41-V44 may form a first signal path group, and the fifth to eighth through vias V15-V18, V25-V28, V35-V38, V45-V48 may form a second signal path group. For example, the first through vias V11, V21, V31, V41 may be used to transmit signals of the first channel CHa, and the second through vias V12, V22, V32, V42 may be used to transmit signals of the third channel CHc. The third through vias V13, V23, V33, V43 and the fourth through vias V14, V24, V34, V44 might not be used to transmit signals of the first and third channels CHa, CHc. The fifth through vias V15, V25, V35, V45 may be used to transmit signals of the second channel CHb, and the sixth through vias V16, V26, V36, V46 may be used to transmit signals of the fourth channel CHd. The seventh through vias V17, V27, V37, V47 and the eighth through vias V18, V28, V38, V48 might not be used to transmit signals of the second and fourth channels CHb, CHd. The host die 1810c may be coupled to internal circuits of the first and third memory dies 1821c, 1823c through the first through vias V11, V21, V31, V41 and the fifth through vias V15, V25, V35, V45. The host die 1810c may be coupled to internal circuits of the first channel CHa of the first and third memory dies 1821c, 1823c through the first through vias V11, V21, V31, V41, and may be coupled to internal circuits of the second channel CHb of the first and third memory dies 1821c, 1823c through the fifth through vias V15, V25, V35, V45. The host die 1810c may be coupled to internal circuits of the second and fourth memory dies 1822c, 1824c through the second through vias V12, V22, V32, V42 and the sixth through vias V16, V26, V36, V46. The host die 1810c may be coupled to internal circuits of the third channel CHc of the second and fourth memory dies 1822c, 1824c through the second through vias V12, V22, V32, V42, and may be coupled to internal circuits of the fourth channel CHd of the second and fourth memory dies 1822c, 1824c through the sixth through vias V16, V26, V36, V46. The host die 1810c may be coupled to the substrate 1830c through the third through vias V13, V23, V33, V43, the fourth through vias V14, V24, V34, V44, the seventh through vias V17, V27, V37, V47, and the eighth through vias V18, V28, V38, V48. The third through vias V13, V23, V33, V43, the fourth through vias V14, V24, V34, V44, the seventh through vias V17, V27, V37, V47 and the eighth through vias V18, V28, V38, V48 may be coupled to a first signal path 1831c, a second signal path 1832c, a third signal path 1833c, and a fourth signal path 1834c in the substrate 1830c, respectively. The host die 1810c may be coupled to an external device of the computing system 1800c through the third through vias V13, V23, V33, V43, the fourth through vias V14, V24, V34, V44, the seventh through vias V17, V27, V37, V47, and the eighth through vias V18, V28, V38, V48 and the signal paths in the substrate 1830c.

The host die 1810c may include a first transceiver T1c, a second transceiver T12c, a third transceiver T13c, a fourth transceiver T14c, a fifth transceiver T15c, a sixth transceiver T16c, a seventh transceiver T17c, and an eighth transceiver T18c. The first to eighth transceivers T11c-T18c may be included as components of the interface circuit 1613 shown in FIG. 20. The first transceiver T11c may be coupled to the first through vias V11, V21, V31, V41, may transmit a first memory signal M11 to the first through vias V11, V21, V31, V41, and may receive a signal transmitted through the first through vias V11, V21, V31, V41 as the first memory signal M11. The second transceiver T12c may be coupled to the second through vias V12, V22, V32, V42, transmit a second memory signal M12 to the second through vias V12, V22, V32, V42, and receive a signal transmitted through the second through vias V12, V22, V32, V42 as the second memory signal M12. The third transceiver T13c may be coupled to the third through vias V13, V23, V33, V43, transmit a first host signal H11 to the third through vias V13, V23, V33, V43, and receive a signal transmitted through the third through vias V13, V23, V33, V43 as the first host signal H11. The fourth transceiver T14c may be coupled to the fourth through vias V14, V24, V34, V44, transmit a second host signal H12 to the fourth through vias V14, V24, V34, V44, and receive a signal transmitted through the fourth through vias V14, V24, V34, V44 as the second host signal H12. The fifth transceiver T15c may be coupled to the fifth through vias V15, V25, V35, V45, transmit a third memory signal M13 to the fifth through vias V15, V25, V35, V45, and receive a signal transmitted through the fifth through vias V15, V25, V35, V45 as the third memory signal M13. The sixth transceiver T16c may be coupled to the sixth through vias V16, V26, V36, V46, transmit a fourth memory signal M14 to the sixth through vias V16, V26, V36, V46, and receive a signal transmitted through the sixth through vias V16, V26, V36, V46 as the fourth memory signal M14. The seventh transceiver T17c may be coupled to the seventh through vias V17, V27, V37, V47, transmit a third host signal H13 to the seventh through vias V17, V27, V37, V47, and receive a signal transmitted through the seventh through vias V17, V27, V37, V47 as the third host signal H13. The eighth transceiver T18c may be coupled to the eighth through vias V18, V28, V38, V48, transmit a fourth host signal H14 to the eighth through vias V18, V28, V38, V48, and receive a signal transmitted through the eighth through vias V18, V28, V38, V48 as the fourth host signal H14. Although the first to fourth memory signals M11-M14 are described as bidirectional signals, the first to fourth memory signals M11-M14 may also be unidirectional signals. Depending on the characteristics of the first to fourth memory signals M11-M14, the first, second, fifth and sixth transceivers T11c, T12c, T15c, T16c may be replaced by receivers or transmitters. While the first to fourth host signals H11-H14 are described as bidirectional, the first to fourth host signals H11-H14 may be unidirectional. The third, fourth, seventh, and eighth transceivers T13c, T14c, T17c, T18c may be replaced by receivers or transmitters depending on the characteristics of the first to fourth host signals H11-H14.

The first memory die 1821c may include a first transceiver T21c, a second transceiver T22c, a third transceiver T23c, a fourth transceiver T24c, a fifth transceiver T25c, a sixth transceiver T26c, a seventh transceiver T27c, an eighth transceiver T28c, a first path selection circuit 1821-1c, and a second path selection circuit 1821-2c. The first transceiver T21c may be coupled between the first through via V11 and the first path selection circuit 1821-1c. The second transceiver T22c may be coupled between the second through via V12 and the first path selection circuit 1821-1c. The third transceiver T23c may be coupled between the third through via V13 and the first path selection circuit 1821-1c. The fourth transceiver T24c may be coupled between the fourth through via V14 and the first path selection circuit 1821-1c. The fifth transceiver T25c may be coupled between the fifth through via V15 and the second path selection circuit 1821-2c. The sixth transceiver T26c may be coupled between the sixth through via V16 and the second path selection circuit 1821-2c. The seventh transceiver T27c may be coupled between the seventh through via V17 and the second path selection circuit 1821-2c. The eighth transceiver T28c may be coupled between the eighth through via V18 and the second path selection circuit 1821-2c.

The second memory die 1822c may have substantially the same structure as the first memory die 1821c. The second memory die 1822c may include a first transceiver T31c, a second transceiver T32c, a third transceiver T33c, a fourth transceiver T34c, a fifth transceiver T35c, a sixth transceiver T36c, a seventh transceiver T37c, an eighth transceiver T38c, a third path selection circuit 1822-1c, and a fourth path selection circuit 1822-2c. The first transceiver T31c may be coupled between the first through via V21 and the third path selection circuit 1822-1c. The second transceiver T32c may be coupled between the second through via V22 and the third path selection circuit 1822-1c. The third transceiver T33c may be coupled between the third through via V23 and the third path selection circuit 1822-1c. The fourth transceiver T34c may be coupled between the fourth through via V24 and the third path selection circuit 1822-1c. The fifth transceiver T35c may be coupled between the fifth through via V25 and the fourth path selection circuit 1822-2c. The sixth transceiver T36c may be coupled between the sixth through via V26 and the fourth path selection circuit 1822-2c. The seventh transceiver T37c may be coupled between the seventh through via V27 and the fourth path selection circuit 1822-2c. The eighth transceiver T38c may be coupled between the eighth through via V28 and the fourth path selection circuit 1822-2c.

The third memory die 1823c may have substantially the same structure as the first and second memory dies 1821c, 1822c. The third memory die 1823c may include a first transceiver T41c, a second transceiver T42c, a third transceiver T43c, a fourth transceiver T44c, a fifth transceiver T45c, a sixth transceiver T46c, a seventh transceiver T47c, an eighth transceiver T48c, a fifth path selection circuit 1823-1c, and a sixth path selection circuit 1823-2c. The first transceiver T41c may be coupled between the first through via V31 and the fifth path selection circuit 1823-1c. The second transceiver T42c may be coupled between the second through via V32 and the fifth path selection circuit 1823-1c. The third transceiver T43c may be coupled between the third through via V33 and the fifth path selection circuit 1823-1c. The fourth transceiver T44c may be coupled between the fourth through via V34 and the fifth path selection circuit 1823-1c. The fifth transceiver T45c may be coupled between the fifth through via V35 and the sixth path selection circuit 1823-2c. The sixth transceiver T46c may be coupled between the sixth through via V36 and the sixth path selection circuit 1823-2c. The seventh transceiver T47c may be coupled between the seventh through via V37 and the sixth path selection circuit 1823-2c. The eighth transceiver T48c may be coupled between the eighth through via V38 and the sixth path selection circuit 1823-2c.

The fourth memory die 1824c may have substantially the same structure as the first to third memory dies 1821c, 1822c, 1823c. The fourth memory die 1824c may include a first transceiver T51c, a second transceiver T52c, a third transceiver T53c, a fourth transceiver T54c, a fifth transceiver T55c, a sixth transceiver T56c, a seventh transceiver T57c, an eighth transceiver T58c, a seventh path selection circuit 1824-1c, and an eighth path selection circuit 1824-2c. The first transceiver T51c may be coupled between the first through via V41 and the seventh path selection circuit 1824-1c. The second transceiver T52c may be coupled between the second through via V42 and the seventh path selection circuit 1824-1c. The third transceiver T53c may be coupled between the third through via V43 and the seventh path selection circuit 1824-1c. The fourth transceiver T54c may be coupled between the fourth through via V44 and the seventh path selection circuit 1824-1c. The fifth transceiver T55c may be coupled between the fifth through via V45 and the eighth path selection circuit 1824-2c. The sixth transceiver T56c may be coupled between the sixth through via V46 and the eighth path selection circuit 1824-2c. The seventh transceiver T57c may be coupled between the seventh through via V47 and the eighth path selection circuit 1824-2c. The eighth transceiver T58c may be coupled between the eighth through via V48 and the eighth path selection circuit 1824-2c. Depending on the characteristics of the first to fourth memory signals M11-M14, the first to eighth transceivers T21c-T28c, T31c-T38c, T41c-T48c, T51c-T58c of the first to fourth memory dies 1821c, 1822c, 1823c, 1824c may be replaced by transmitters or receivers.

A chip ID signal may be assigned to each of the first to fourth memory dies 1821c, 1822c, 1823c, 1824c respectively, and a signal path of each of the first to fourth memory dies 1821c, 1822c, 1823c, 1824c may be set according to the chip ID signal. For example, a first chip ID signal CID0 may be assigned to the first and third memory dies 1821c, 1823c, and a second chip ID signal CID1 may be assigned to the second and fourth memory dies 1822c, 1824c. Based on the first chip ID signal CID0, the first and fifth transceivers T21c, T25c may be activated, and the second, third, fourth, sixth, seventh, and eighth transceivers T22c-T24c, T26c-T28c may be deactivated. The first path selection circuit 1821-1c may be coupled to the first transceiver T21c based on the first chip ID signal CID0. The first path selection circuit 1821-1c may output the first memory signal M11 transmitted from the host die 1810c through the first through via V11 and the first transceiver T21c as a first channel signal Sa, and may output the first channel signal Sa to the host die 1810c through the first transceiver T21c and the first through via V11. When the first slice ID signal SID0 is enabled, an internal circuit of the first channel CHa of the first memory die 1821c may receive the first channel signal Sa from the first path selection circuit 1821-1c and output the first channel signal Sa to the first path selection circuit 1821-1c. The second path selection circuit 1821-2c may be coupled to the fifth transceiver T25c based on the first chip ID signal CID0. The second path selection circuit 1821-2c may output the third memory signal M13 transmitted from the host die 1810c through the fifth through via V15 and the fifth transceiver T25c as a second channel signal Sb, and may output the second channel signal Sb to the host die 1810c through the fifth transceiver T25c and the fifth through via V15. When the first slice ID signal SID0 is enabled, an internal circuit of the second channel CHb of the first memory die 1821c may receive the second channel signal Sb from the second path selection circuit 1821-2c and output the second channel signal Sb to the second path selection circuit 1821-2c.

Based on the second chip ID signal CID1, the second and sixth transceivers T32c, T36c may be activated, and the first, third, fourth, fifth, seventh, and eighth transceivers T31c, T33c-T35c, T37c-T38c may be deactivated. The third path selection circuit 1822-1c may be coupled to the second transceiver T32c based on the second chip ID signal CID1. The third path selection circuit 1822-1c may output the second memory signal M12 transmitted from the host die 1810c through the second through via V22 and the second transceiver T32c as a third channel signal Sc, and may output the third channel signal Sc to the host die 1810c through the second transceiver T32c and the second through via V22. When the first slice ID signal SID0 is enabled, an internal circuit of the third channel CHc of the second memory die 1822c may receive the third channel signal Sc from the third path selection circuit 1822-1c and output the third channel signal Sc to the third path selection circuit 1822-1c. The fourth path selection circuit 1822-2c may be coupled to the sixth transceiver T36c based on the second chip ID signal CID1. The fourth path selection circuit 1822-2c may output the fourth memory signal M14 transmitted from the host die 1810c through the sixth through via V26 and the sixth transceiver T36c as a fourth channel signal Sd, and may output the fourth channel signal Sd to the host die 1810c through the sixth transceiver T36c and the sixth through via V26. When the first slice ID signal SID0 is enabled, the internal circuit of the fourth channel CHd of the second memory die 1822c may receive the fourth channel signal Sd from the fourth path selection circuit 1822-2c and output the fourth channel signal Sd to the fourth path selection circuit 1822-2c.

Based on the first chip ID signal CID0, the first and fifth transceivers T41c, T45c may be activated, and the second, third, fourth, sixth, seventh, and eighth transceivers T42c-T44c, T46c-T48c may be deactivated. The fifth path selection circuit 1823-1c may be coupled to the first transceiver T41c based on the first chip ID signal CID0. The fifth path selection circuit 1823-1c may output the first memory signal M11 transmitted from the host die 1810c through the first through via V31 and the first transceiver T41c as the first channel signal Sa, and may output the first channel signal Sa to the host die 1810c through the first transceiver T41c and the first through via V31. When the second slice ID signal SID1 is enabled, an internal circuit of the first channel CHa of the third memory die 1823c may receive the first channel signal Sa from the fifth path selection circuit 1823-1c and output the first channel signal Sa to the fifth path selection circuit 1823-1c. The sixth path selection circuit 1823-2c may be coupled to the fifth transceiver T45c based on the first chip ID signal CID0. The sixth path selection circuit 1823-2c may output the third memory signal M13 transmitted from the host die 1810c through the fifth through via V35 and the fifth transceiver T45c as the second channel signal Sb, and may output the second channel signal Sb to the host die 1810c through the fifth transceiver T45c and the fifth through via V35. When the second slice ID signal SID1 is enabled, an internal circuit of the second channel CHb of the third memory die 1823c may receive the second channel signal Sb from the sixth path selection circuit 1823-2c and output the second channel signal Sb to the sixth path selection circuit 1823-2c.

Based on the second chip ID signal CID1, the second and sixth transceivers T52c, T56c may be activated and the first, third, fourth, fifth, seventh and eighth transceivers T51c, T53c-T55c, T57c-T58c may be deactivated. The seventh path selection circuit 1824-1c may be coupled to the second transceiver T52c based on the second chip ID signal CID1. The seventh path selection circuit 1824-1c may output the second memory signal M12 transmitted from the host die 1810c through the second through via V42 and the second transceiver T52c as the third channel signal Sc, and may output the third channel signal Sc to the host die 1810c through the second transceiver T52c and the second through via V42. When the second slice ID signal SID1 is enabled, an internal circuit of the third channel CHc of the fourth memory die 1824c may receive the third channel signal Sc from the seventh path selection circuit 1824-1c and output the third channel signal Sc to the seventh path selection circuit 1824-1c. The eighth path selection circuit 1824-2c may be coupled to the sixth transceiver T56c based on the second chip ID signal CID1. The eighth path selection circuit 1824-2c may output the fourth memory signal M14 transmitted from the host die 1810c through the sixth through via V46 and the sixth transceiver T56c as the fourth channel signal Sd, and may output the fourth channel signal Sd to the host die 1810c through the sixth transceiver T56c and the sixth through via V46. When the second slice ID signal SID1 is enabled, an internal circuit of the fourth channel CHd of the fourth memory die 1824c may receive the fourth channel signal Sd from the eighth path selection circuit 1824-2c and output the fourth channel signal Sd to the eighth path selection circuit 1824-2c. The third, fourth, seventh and eighth transceivers T23c, T24c, T27c, T28c, T33c, T34c, T37c, T38c, T43c, T44c, T47c, T48c, T53c, T54c, T57c, T58c of the first to fourth memory dies 1821c, 1822c, 1823c, 1824c are deactivated. As a result, the third through vias V13, V23, V33, V43, the fourth through vias V14, V24, V34, V44, the seventh through vias V17, V27, V37, V47, and the eighth through vias V18, V28, V38, V48 may be electrically isolated from the internal circuits of the first to fourth memory dies 1821c, 1822c, 1823c, 1824c.

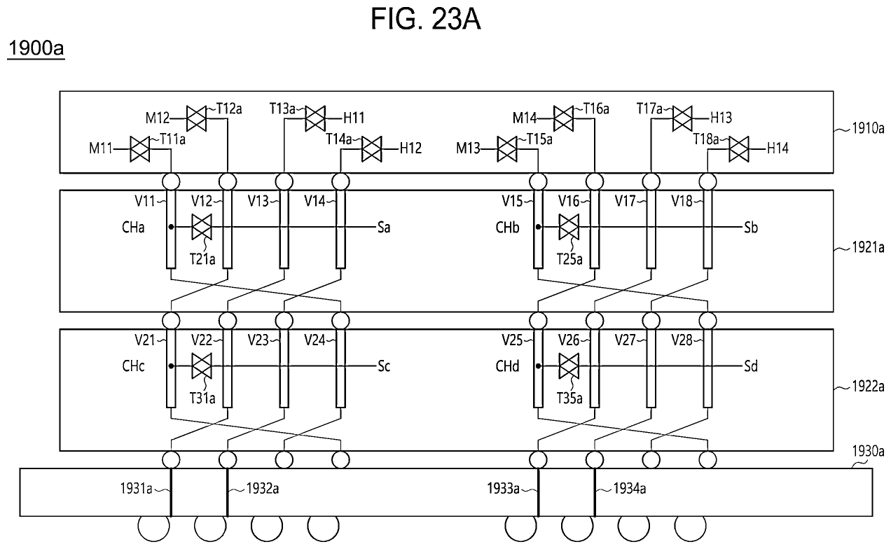

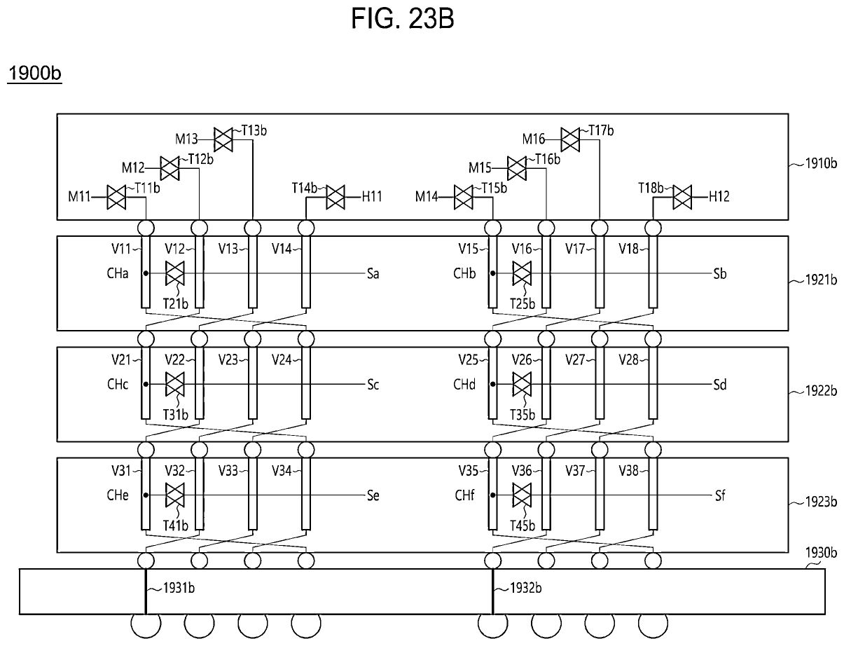

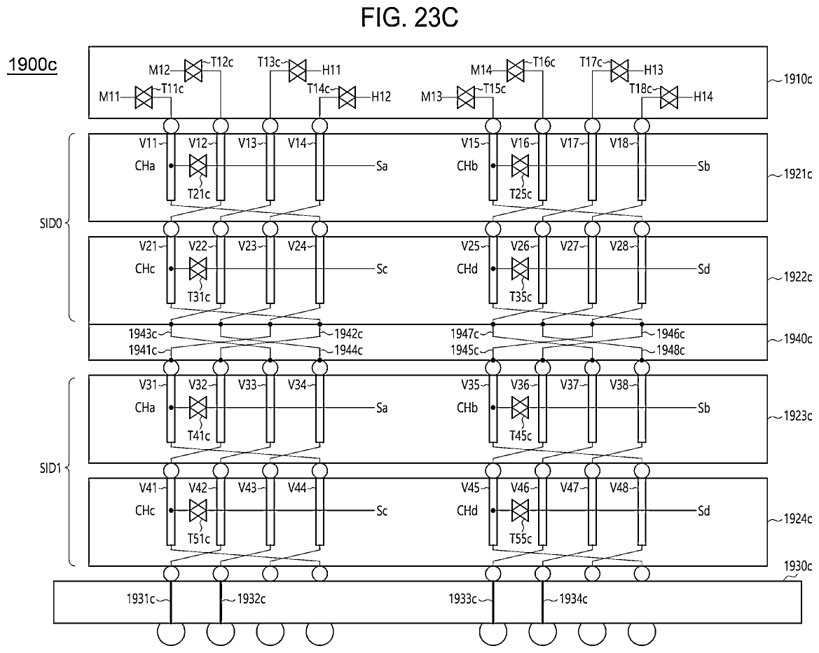

FIG. 23A is a diagram illustrating a connection structure of a computing system 1900a according to an embodiment of the present disclosure. Referring to FIG. 23A, the computing system 1900a may include a host die 1910a, a first memory die 1921a, a second memory die 1922a, and a substrate 1930a. The second memory die 1922a may be disposed on the substrate 1930a, and the first memory die 1921a may be disposed on the second memory die 1922a. The host die 1910a may be disposed on the first memory die 1921a. A plurality of through vias may be formed in the first and second memory dies 1921a, 1922a. The plurality of through vias may be coupled in a P2P method, and components of computing system 1900a may be connected using microbumps. When the plurality of through vias are coupled in a P2P method, the first and second memory dies 1921a, 1922a might not need to be equipped with the path selection circuits shown in FIG. 22A, and the transceivers connected to each through via may be eliminated, thereby increasing the area margin of the memory die. The first and second memory dies 1921a, 1922a may include at least n through vias, and may be implemented in structural configurations illustrated in FIGS. 21A, 21B and 21C by way of non-limiting examples. Here, n may be an integer of two or more. The n through vias may form one signal path group. The n through vias may be coupled to n memory dies and/or n channels. For example, when a signal path group includes four through vias, the signal path group may be independently coupled to up to four memory dies and/or four channels. When the signal path group including four through vias is independently coupled to only two memory dies and/or two channels, the remaining two through vias are not coupled to memory dies or channels. Thus, two through vias of the signal path group may be used to connect the host die 1910a to the internal circuits of the first and second memory dies 1921a, 1922a, and the remaining two through vias may be used to connect the host die 1910a to the substrate 1930a.

The first and second memory dies 1921a, 1922a may each include first to eighth through vias V11-V18, V21-V28 arranged at first to eighth positions. In an embodiment implemented with P2P connections, however, the through vias V11-V14 and V15-V18 of the first memory die 1921a may be electrically connected to any of the through vias V21-V24 and V25-V28 of the second memory die 1922a, respectively, regardless of the position of the via in the memory die. For example, the first through via V11 of the first memory die 1921a may be electrically connected with the fourth through via V24 of the second memory die 1922a. The second through via V12 of the first memory die 1921a may be coupled to the first through via V21 of the second memory die 1922a. The third through via V13 of the first memory die 1921a may be coupled to the second through via V22 of the second memory die 1922a. The fourth through via V14 of the first memory die 1921a may be coupled to the third through via V23 of the second memory die 1922a. The fifth through via V15 of the first memory die 1921a may be electrically connected with the eighth through via V28 of the second memory die 1922a. The sixth through via V16 of the first memory die 1921a may be coupled to the fifth through via V25 of the second memory die 1922a. The seventh through via V17 of the first memory die 1921a may be coupled to the sixth through via V26 of the second memory die 1922a. The eighth through via V18 of the first memory die 1921a may be coupled to the seventh through via V27 of the second memory die 1922a. The first and second memory dies 1921a, 1922a may each include one or more channels. For example, the first and second memory dies 1921a, 1922a may each include two channels. The first memory die 1921a may include a first channel CHa and a second channel CHb, and the second memory die 1922a may include a third channel CHc and a fourth channel CHd. The first to fourth through vias V11-V14, V21-V24 may form a first signal path group, and the fifth to eighth through vias V15-V18, V25-V28 may form a second signal path group. For example, the first through via V11 of the first memory die 1921a and the fourth through via V24 of the second memory die 1922a may be used to transmit signals of the first channel CHa, and the second through via V12 of the first memory die 1921a and the first through via V21 of the second memory die 1922a may be used to transmit signals of the third channel CHc. The third and fourth through vias V13, V14 of the first memory die 1921a and the second and third through vias V22, V23 of the second memory die 1922a might not be used to transmit signals of the first and third channels CHa, CHc. The fifth through via V15 of the first memory die 1921a and the eighth through via V28 of the second memory die 1922a may be used to transmit signals of the second channel CHb, and the sixth through via V16 of the first memory die 1921a and the fifth through via V25 of the second memory die 1922a may be used to transmit signals of the fourth channel CHd. The seventh and eighth through vias V17, V18 of the first memory die 1921a and the sixth and seventh through vias V26, V27 of the second memory die 1922a might not be used to transmit signals of the second and fourth channels CHb, CHd.

The host die 1910a may be coupled to internal circuits of the first memory die 1921a through the first and fifth through vias V11, V15 of the first memory die 1921a. The host die 1910a may be coupled to an internal circuit of the first channel CHa through the first through via V11, and may be coupled to an internal circuit of the second channel CHb through the fifth through via V15. The host die 1910a may be coupled to internal circuits of the second memory die 1922a through the first and fifth through vias V21, V25 of the second memory die 1922a. The host die 1910a may be coupled to an internal circuit of the third channel CHc through the first through via V21, and may be coupled to an internal circuit of the fourth channel CHd through the fifth through via V25. The host die 1910a may be coupled to the substrate 1930a through the third through via V13 of the first memory die 1921a and the second through via V22 of the second memory die 1922a. The host die 1910a may be coupled to the substrate 1930a through the fourth through via V14 of the first memory die 1921a and the third through via V23 of the second memory die 1922a. The host die 1910a may be coupled to the substrate 1930a through the seventh through via V17 of the first memory die 1921a and the sixth through via V26 of the second memory die 1922a. The host die 1910a may be coupled to the substrate 1930a through the eighth through via V18 of the first memory die 1921a and the seventh through via V27 of the second memory die 1922a. The second, third, sixth and seventh through vias V22, V23, V26, V27 of the second memory die 1922a are respectively connected to a first signal path 1931a, a second signal path 1932a, a third signal path 1933a and a fourth signal path 1934a of the substrate. The host die 1910a may be coupled to an external device of the computing system 1900a through the third, fourth, seventh, and eighth through vias V13, V14, V17, V18 of the first memory die 1921a, the second, third, sixth, and seventh through vias V22, V23, V26, V27 of the second memory die 1922a, and the first to fourth signal paths 1931a, 1932a, 1933a, 1934a.

The host die 1910a may include a first transceiver T11a, a second transceiver T12a, a third transceiver T13a, a fourth transceiver T14a, a fifth transceiver T15a, a sixth transceiver T16a, a seventh transceiver T17a, and an eighth transceiver T18a. The first to eighth transceivers T11a-T18a may be included as components of the interface circuit 1613 shown in FIG. 20. The first transceiver T11a may be coupled to the first through via V11 of the first memory die 1921a, may transmit a first memory signal M11 to the first through via V11, and may receive a signal transmitted through the first through via V11 as the first memory signal M11. The second transceiver T12a may be coupled to a second through via V12 of the first memory die 1921a, transmit a second memory signal M12 to the second through via V12, and receive a signal transmitted through the second through via V12 as the second memory signal M12. The third transceiver T13a may be coupled to the third through via V13 of the first memory die 1921a, transmit a first host signal H11 to the third through via V13, and receive a signal transmitted through the third through via V13 as the first host signal H11. The fourth transceiver T14a may be coupled to the fourth through via V14 of the first memory die 1921a, transmit a second host signal H12 to the fourth through via V14, and receive a signal transmitted through the fourth through via V14 as the second host signal H12. The fifth transceiver T15a may be coupled to the fifth through via V15 of the first memory die 1921a, transmit a third memory signal M13 to the fifth through via V15, and receive a signal transmitted through the fifth through via V15 as the third memory signal M13. The sixth transceiver T16a may be coupled to a sixth through via V16 of the first memory die 1921a, transmit a fourth memory signal M14 to the sixth through via V16, and receive a signal transmitted through the sixth through via V16 as the fourth memory signal M14. The seventh transceiver T17a may be coupled to the seventh through via V17 of the first memory die 1921a, transmit a third host signal H13 to the seventh through via V17, and receive a signal transmitted through the seventh through via V17 as the third host signal H13. The eighth transceiver T18a may be coupled to the eighth through via V18 of the first memory die 1921a, transmit a fourth host signal H14 to the eighth through via V18, and receive a signal transmitted through the eighth through via V18 as the fourth host signal H14. Although the first to fourth memory signals M11-M14 are described as bidirectional signals, the first to fourth memory signals M11-M14 may also be unidirectional signals. Depending on the characteristics of the first to fourth memory signals M11-M14, the first, second, fifth and sixth transceivers T11a, T12a, T15a, T16a may be replaced by receivers or transmitters. While the first to fourth host signals H11-H14 are described as bidirectional, the first to fourth host signals H11-H14 may be unidirectional. The third, fourth, seventh, and eighth transceivers T13a, T14a, T17a, T18a may be replaced by receivers or transmitters depending on the characteristics of the first to fourth host signals H11-H14.

The first memory die 1921a may include a first transceiver T21a and a second transceiver T25a. The first transceiver T21a may be coupled to the first through via V11. The first transceiver T21a may output a signal transmitted from the host die 1910a through the first through via V11 as a first channel signal Sa, and may output the first channel signal Sa to the host die 1910a through the first through via V11. The second transceiver T25a may be coupled to the fifth through via V15. The second transceiver T25a may output a signal transmitted from the host die 1910a through the fifth through via V15 as a second channel signal Sb and output the second channel signal Sb to the host die 1910a through the fifth through via V15. The second memory die 1922a may include a first transceiver T31a and a second transceiver T35a. The first transceiver T31a may be coupled to the first through via V21. The first transceiver T31a may output a signal transmitted from the host die 1910a through the first through via V21 as a third channel signal Sc, and may output the third channel signal Sc to the host die 1910a through the first through via V21. The second transceiver T35a may be coupled to the fifth through via V25. The second transceiver T35a may output a signal transmitted from the host die 1910a through the fifth through via V25 as a fourth channel signal Sd, and may output the fourth channel signal Sd to the host die 1910a through the fifth through via V25. Depending on the characteristics of the first to fourth memory signals M11-M14, the first and second transceivers T21a, T25a, T31a, T35a of the first and second memory dies 1921a, 1922a may be replaced by transmitters or receivers, respectively.

An internal circuit of the first channel CHa may be coupled to the first transceiver T21a, and may receive the first channel signal Sa from the first transceiver T21a or output the first channel signal Sa to the first transceiver T21a. An internal circuit of the second channel CHb may be coupled to the second transceiver T25a, and may receive the second channel signal Sb from the second transceiver T25a or output the second channel signal Sb to the second transceiver T25a. An internal circuit of the third channel CHc may be coupled to the first transceiver T31a, and may receive the third channel signal Sc from the first transceiver T31a or output the third channel signal Sc to the first transceiver T31a. An internal circuit of the fourth channel CHd may be coupled to the second transceiver T35a, and may receive the fourth channel signal Sd from the second transceiver T35a or output the fourth channel signal Sd to the second transceiver T35a. The third, fourth, seventh, and eighth through vias V13, V14, V17, V18 of the first memory die 1921a and the second, third, sixth, and seventh through vias V22, V23, V26, V27 of the second memory die 1922a may be electrically isolated from the internal circuits of the first and second memory dies 1921a, 1922a, respectively.

FIG. 23B is a diagram illustrating a connection structure of a computing system 1900b according to an embodiment of the present disclosure. Referring to FIG. 23B, the computing system 1900b may include a host die 1910b, a first memory die 1921b, a second memory die 1922b, a third memory die 1923b, and a substrate 1930b. The third memory die 1923b may be disposed on the substrate 1930b, the second memory die 1922b may be disposed on the third memory die 1923b, and the first memory die 1921b may be disposed on the second memory die 1922b. The host die 1910b may be disposed on the first memory die 1921b. A plurality of through vias may be formed in the first to third memory dies 1921b, 1922b, 1923b, and may be implemented in structural configurations illustrated in FIGS. 21A, 21B and 21C by way of non-limiting examples. The plurality of through vias may be coupled in a P2P method, and components of computing system 1900a may be connected using microbumps. In general, the number of signals transmitted between the host die and the memory dies may be greater than the number of signals transmitted between the host die and an external device. Accordingly, it may be desirable to maximize the number of through vias electrically connecting the host die 1910b with internal circuits of the first to third memory die 1921b, 1922b, 1923b. The computing system 1900b may include a greater number of channels than the computing system 1900a of FIG. 23A.

The first to third memory dies 1921b, 1922b, 1923b may each include first to eighth through vias V11-V18, V21-V28, V31-V38 disposed at first to eighth positions. In embodiments implemented with P2P connections, however, within a signal path group, the through vias V11-V14 and V15-V18 of the first memory die 1921b may be coupled to any of the through vias V21-V24 and V25-V28 of the second memory die 1922b respectively, regardless of the position of the via in the memory die, and the through vias V21-V24 and V25-V28 8 of the second memory die 1922b may be coupled to the through vias V31-V34 and V35-V38 of the third memory die 1923b respectively, regardless of the position of the via in the memory die. For example, the first through via V11 of the first memory die 1921b may be coupled to the fourth through via V24 of the second memory die 1922b, and the fourth through via V24 of the second memory die 1922b may be coupled to the third through via V33 of the third memory die 1923b. The second through via V12 of the first memory die 1921b may be coupled to the first through via V21 of the second memory die 1922b, and the first through via V21 of the second memory die 1922b may be coupled to the fourth through via V34 of the third memory die 1923b. The third through via V13 of the first memory die 1921b may be coupled to the second through via V22 of the second memory die 1922b, and the second through via V22 of the second memory die 1922b may be coupled to the first through via V31 of the third memory die 1923b. The fourth through via V14 of the first memory die 1921b may be coupled to the third through via V23 of the second memory die 1922b, and the third through via V23 of the second memory die 1922b may be coupled to the second through via V32 of the third memory die 1923b. The fifth through via V15 of the first memory die 1921b may be coupled to the eighth through via V28 of the second memory die 1922b, and the eighth through via V28 of the second memory die 1922b may be coupled to the seventh through via V37 of the third memory die 1923b. The sixth through via V16 of the first memory die 1921b may be coupled to the fifth through via V25 of the second memory die 1922b, and the fifth through via V25 of the second memory die 1922b may be coupled to the eighth through via V38 of the third memory die 1923b. The seventh through via V17 of the first memory die 1921b may be coupled to the sixth through via V26 of the second memory die 1922b, and the sixth through via V26 of the second memory die 1922b may be coupled to the fifth through via V35 of the third memory die 1923b. The eighth through via V18 of the first memory die 1921b may be coupled to the seventh through via V27 of the second memory die 1922b, and the seventh through via V27 of the second memory die 1922b may be coupled to the sixth through via V36 of the third memory die 1923b. Each of the first to third memory dies 1921b, 1922b, 1923b may include two channels. The first memory die 1921b may include a first channel CHa and a second channel CHb, the second memory die 1922b may include a third channel CHc and a fourth channel CHd, and the third memory die 1923b may include a fifth channel CHe and a sixth channel CHf. The first to fourth through vias V11-V14, V21-V24, V31-V34 may form a first signal path group, and the fifth to eighth through vias V15-V18, V25-V28, V35-V38 may form a second signal path group. For example, the first through via V11 of the first memory die 1921b, the fourth through via V24 of the second memory die 1922b, and the third through via V33 of the third memory die 1923b may be used to transmit signals of the first channel CHa. The second through via V12 of the first memory die 1921b, the first through via V21 of the second memory die 1922b, and the fourth through via V34 of the third memory die 1923b may be used to transmit signals of the third channel CHc. The third through via V13 of the first memory die 1921b, the second through via V22 of the second memory die 1922b, and the first through via V31 of the third memory die 1923b may be used to transmit signals of the fifth channel CHe. The fourth through via V14 of the first memory die 1921b, the third through via V23 of the second memory die 1922b, and the second through via V32 of the third memory die 1923b might not be used to transmit signals of the first, third, and fifth channels CHa, CHc, CHe. The fifth through via V15 of the first memory die 1921b, the eighth through via V28 of the second memory die 1922b, and the seventh through via V37 of the third memory die 1923b may be used to transmit signals of the second channel CHb. The sixth through via V16 of the first memory die 1921b, the fifth through via V25 of the second memory die 1922b, and the eighth through via V38 of the third memory die 1923b may be used to transmit signals of the fourth channel CHd. The seventh through via V17 of the first memory die 1921b, the sixth through via V26 of the second memory die 1922b, and the fifth through via V35 of the third memory die 1923b may be used to transmit signals of the sixth channel CHf. The eighth through via V18 of the first memory die 1921b, the seventh through via V27 of the second memory die 1922b, and the sixth through via V36 of the third memory die 1923b might not be used to transmit signals of the second, fourth, and sixth channels CHb, CHd, CHf.

The host die 1910b may be coupled to internal circuits of the first memory die 1921b through the first and fifth through vias V11, V15 of the first memory die 1921b. The host die 1910b may be coupled to an internal circuit of the first channel CHa through the first through via V11, and may be coupled to an internal circuit of the second channel CHb through the fifth through via V15. The host die 1910b may be coupled to internal circuits of the second memory die 1922b through the first and fifth through vias V21, V25 of the second memory die 1922b. The host die 1910b may be coupled to an internal circuit of the third channel CHc through the first through via V21, and may be coupled to an internal circuit of the fourth channel CHd through the fifth through via V25. The host die 1910b may be coupled to internal circuits of the third memory die 1923b through the first and fifth through vias V31, V35 of the third memory die 1923b. The host die 1910b may be coupled to an internal circuit of the fifth channel CHe through the first through via V31, and may be coupled to an internal circuit of the sixth channel CHf through the fifth through via V35. The host die 1910b may be coupled to the substrate 1930b through the fourth through via V14 of the first memory die 1921b, the third through via V23 of the second memory die 1922b, and the second through via V32 of the third memory die 1923b. The host die 1910b may be coupled to the substrate 1930b through the eighth through via V18 of the first memory die 1921b, the seventh through via V27 of the second memory die 1922b, and the sixth through via V36 of the third memory die 1923b. The second and sixth through vias V32, V36 of the third memory die 1923b are coupled to a first signal path 1931b and a second signal path 1932b of the substrate 1930b, respectively, and the host die 1910b may be coupled to an external device of the computing system 1900b through the fourth and eighth through vias V14, V18 of the first memory die 1921b, the third and seventh through vias V23, V27 of the second memory die 1922b, the second and sixth through vias V32, V36 of the third memory die 1923b, and the first and second signal paths 1931b, 1932b.

The host die 1910b may include a first transceiver T11b, a second transceiver T12b, a third transceiver T13b, a fourth transceiver T14b, a fifth transceiver T15b, a sixth transceiver T16b, a seventh transceiver T17b, and an eighth transceiver T18b. The first to eighth transceivers T11b-T18b may be included as components of the interface circuit 1613 shown in FIG. 20. The first transceiver T11b may be coupled to the first through via V11 of the first memory die 1921b, may transmit a first memory signal M11 to the first through via V11, and may receive a signal transmitted through the first through via V11 as the first memory signal M11. The second transceiver T12b may be coupled to the second through via V12 of the first memory die 1921b, transmit a second memory signal M12 to the second through via V12, and receive a signal transmitted through the second through via V12 as the second memory signal M12. The third transceiver T13b may be coupled to the third through via V13 of the first memory die 1921b, transmit a third memory signal M13 to the third through via V13, and receive a signal transmitted through the third through via V13 as the third memory signal M13. The fourth transceiver T14b may be coupled to the fourth through via V14 of the first memory die 1921b, transmit a first host signal H11 to the fourth through via V14, and receive a signal transmitted through the fourth through via V14 as the first host signal H11. The fifth transceiver T15b may be coupled to the fifth through via V15 of the first memory die 1921b, transmit a fourth memory signal M14 to the fifth through via V15, and receive a signal transmitted through the fifth through via V15 as the fourth memory signal M14. The sixth transceiver T16b may be coupled to the sixth through via V16 of the first memory die 1921b, transmit a fifth memory signal M15 to the sixth through via V16, and receive a signal transmitted through the sixth through via V16 as the fifth memory signal M15. The seventh transceiver T17b may be coupled to the seventh through via V17 of the first memory die 1921b, transmit the sixth memory signal M16 to the seventh through via V17, and receive a signal transmitted through the seventh through via V17 as the sixth memory signal M16. The eighth transceiver T18b may be coupled to the eighth through via V18 of the first memory die 1921b, transmit a second host signal H12 to the eighth through via V18, and receive a signal transmitted through the eighth through via V18 as the second host signal H12. Although the first to sixth memory signals M11-M16 are described as bidirectional signals, the first to sixth memory signals M11-M16 may also be unidirectional signals. Depending on the characteristics of the first to six memory signals M11-M16, the first, second, third, fifth, sixth and seventh transceivers T11b-T13b, T15b-T17b may be replaced by receivers or transmitters. Although the first and second host signals H11, H12 are described as bidirectional signals, the first and second host signals H11, H12 may be unidirectional signals. Depending on the characteristics of the first and second host signals H11, H12, the fourth and eighth transceivers T14b, T18b may be replaced by receivers or transmitters.

The first memory die 1921b may include a first transceiver T21b and a second transceiver T25b. The first transceiver T21b may be coupled to the first through via V11. The first transceiver T21b may output a signal transmitted from the host die 1910b through the first through via V11 as a first channel signal Sa, and may output the first channel signal Sa to the host die 1910b through the first through via V11. The second transceiver T25b may be coupled to the fifth through via V15. The second transceiver T25b may output a signal transmitted from the host die 1910b through the fifth through via V15 as a second channel signal Sb and output the second channel signal Sb to the host die 1910b through the fifth through via V15. The second memory die 1922b may include a first transceiver T31b and a second transceiver T35b. The first transceiver T31b may be coupled to the first through via V21. The first transceiver T31b may output a signal transmitted from the host die 1910b through the first through via V21 as a third channel signal Sc, and may output the third channel signal Sc to the host die 1910b through the first through via V21. The second transceiver T35b may be coupled to the fifth through via V25. The second transceiver T35b may output a signal transmitted from the host die 1910b through the fifth through via V25 as a fourth channel signal Sd, and may output the fourth channel signal Sd to the host die 1910b through the fifth through via V25. The third memory die 1923b may include a first transceiver T41b and a second transceiver T45b. The first transceiver T41b may be coupled to the first through via V31. The first transceiver T41b may output a signal transmitted from the host die 1910b through the first through via V31 as a fifth channel signal Se, and may output the fifth channel signal Se to the host die 1910b through the first through via V31. The second transceiver T45b may be coupled to the fifth through via V35. The second transceiver T45b may output a signal transmitted from the host die 1910b through the fifth through via V35 as a sixth channel signal Sf, and may output the sixth channel signal Sf to the host die 1910b through the fifth through via V35. Depending on the characteristics of the first to sixth memory signals M11-M16, the first and second transceivers T21b, T25b, T31b, T35b, T41b, T45b of the first to third memory dies 1921b, 1922b, 1923b may be replaced by transmitters or receivers, respectively.

An internal circuit of the first channel CHa may be coupled to the first transceiver T21b, and may receive the first channel signal Sa from the first transceiver T21b or output the first channel signal Sa to the first transceiver T21b. An internal circuit of the second channel CHb may be coupled to the second transceiver T25b, and may receive the second channel signal Sb from the second transceiver T25b or output the second channel signal Sb to the second transceiver T25b. An internal circuit of the third channel CHc may be coupled to the first transceiver T31b, and may receive the third channel signal Sc from the first transceiver T31b or output the third channel signal Sc to the first transceiver T31b. An internal circuit of the fourth channel CHd may be coupled to the second transceiver T35b, and may receive the fourth channel signal Sd from the second transceiver T35b or output the fourth channel signal Sd to the second transceiver T35b. An internal circuit of the fifth channel CHe may be coupled to the first transceiver T41b, and may receive the fifth channel signal Se from the first transceiver T41b or output the fifth channel signal Se to the first transceiver T41b. An internal circuit of the sixth channel CHf may be coupled to the second transceiver T45b, and may receive the sixth channel signal Sf from the second transceiver T45b or output the sixth channel signal Sf to the second transceiver T45b. The fourth and eighth through vias V14, V18 of the first memory die 1921b, the third and seventh through vias V23, V27 of the second memory die 1922b, and the second and sixth through vias V32, V36 of the third memory die 1923b may be electrically isolated from the internal circuits of the first to third memory dies 1921b, 1922b, 1923b, respectively.

FIG. 23C is a diagram illustrating a connection structure of a computing system 1900c according to an embodiment of the present disclosure. Referring to FIG. 23C, the computing system 1900c may include a host die 1910c, a first memory die 1921c, a second memory die 1922c, a third memory die 1923c, a fourth memory die 1924c, a substrate 1930c, and a redistribution layer 1940c. The fourth memory die 1924c may be disposed on the substrate 1930c, and the third memory die 1923c may be disposed on the fourth memory die 1924c. The second memory die 1922c may be disposed on the third memory die 1923c, and the first memory die 1921c may be disposed on the second memory die 1922c. The host die 1910c may be disposed on the first memory die 1921c. The redistribution layer 1940c may be disposed between the second memory die 1922c and the third memory die 1923c to electrically connect the second memory die 1922c and the third memory die 1923c. The redistribution layer 1940c may include a plurality of signal paths to electrically connect the second memory die 1922c and the third memory die 1923c. A plurality of through vias may be formed in the first to fourth memory dies 1921c, 1922c, 1923c, 1924c. The plurality of through vias may be coupled in a P2P method, and components of computing system 1900a may be connected using microbumps. The computing system 1900c may increase the memory density of the computing system 1900c by increasing the number of memory dies disposed between a host die and a substrate. For example, compared to a computing system 1900a illustrated in FIG. 23A, a computing system 1900c may include the same number of channels but may have twice the memory density.

The first to fourth memory dies 1921c, 1922c, 1923c, 1924c may each include first to eighth through vias V11-V18, V21-V28, V31-V38, V41-V48 located at first to eighth positions. The through vias of the first memory die 1921c may be coupled to through vias of the second memory die 1922c disposed at different positions. The through vias of the third memory die 1923c may be coupled to through vias of the fourth memory die 1924c disposed at different positions. Thus, a through via of a memory die in one position may be connected to a through via of an adjacent memory die in a different position. The redistribution layer 1940c may include completely form signal paths for channels formed in the first to fourth memory dies 1921c, 1922c, 1923c, 1924c when the first to fourth memory dies 1921c, 1922c, 1923c, 1924c have the same structure. The redistribution layer 1940c may electrically connect through vias of the second memory die 1922c with through vias of the third memory die 1923c that are disposed at different positions. For example, the first through via V11 of the first memory die 1921c may be coupled to the fourth through via V24 of the second memory die 1922c. The redistribution layer 1940c may electrically connect the fourth through via V24 of the second memory die 1922c with the first through via V31 of the third memory die 1923c through a first signal path 1941c. The first through via V31 of the third memory die 1923c may be coupled to the fourth through via V44 of the fourth memory die 1924c. The second through via V12 of the first memory die 1921c may be coupled to the first through via V21 of the second memory die 1922c. The redistribution layer 1940c may electrically connect the first through via V21 of the second memory die 1922c with the second through via V32 of the third memory die 1923c through a second signal path 1942c. The second through via V32 of the third memory die 1923c may be coupled to the first through via V41 of the fourth memory die 1924c. The third through via V13 of the first memory die 1921c may be coupled to the second through via V22 of the second memory die 1922c. The redistribution layer 1940c may connect the second through via V22 of the second memory die 1922c with the third through via V33 of the third memory die 1923c through a third signal path 1943c. The third through via V33 of the third memory die 1923c may be coupled to the second through via V42 of the fourth memory die 1924c. The fourth through via V14 of the first memory die 1921c may be coupled to the third through via V23 of the second memory die 1922c. The redistribution layer 1940c may electrically connect the third through via V23 of the second memory die 1922c with the fourth through via V34 of the third memory die 1923c through a fourth signal path 1944c. The fourth through via V34 of the third memory die 1923c may be coupled to the third through via V43 of the fourth memory die 1924c. The fifth through via V15 of the first memory die 1921c may be coupled to the eighth through via V28 of the second memory die 1922b. The redistribution layer 1940c may connect the eighth through via V28 of the second memory die 1922c with the fifth through via V35 of the third memory die 1923c through a fifth signal path 1945c. The fifth through via V35 of the third memory die 1923c may be coupled to the eighth through via V48 of the fourth memory die 1924c. The sixth through via V16 of the first memory die 1921c may be coupled to the fifth through via V25 of the second memory die 1922c. The redistribution layer 1940c may electrically connect the fifth through via V25 of the second memory die 1922c with the sixth through via V36 of the third memory die 1923c through a sixth signal path 1946c. The sixth through via V36 of the third memory die 1923c may be coupled to the fifth through via V45 of the fourth memory die 1924c. The seventh through via V17 of the first memory die 1921c may be coupled to the sixth through via V26 of the second memory die 1922c. The redistribution layer 1940c may connect the sixth through via V26 of the second memory die 1922c with the seventh through via V37 of the third memory die 1923c through a seventh signal path 1947c. The seventh through via V37 of the third memory die 1923c may be coupled to the sixth through via V46 of the fourth memory die 1924c. The eighth through via V18 of the first memory die 1921c may be coupled to the seventh through via V27 of the second memory die 1922c. The redistribution layer 1940c may electrically connect the seventh through via V27 of the second memory die 1922c with the eighth through via V38 of the third memory die 1923c through an eighth signal path 1948c. The eighth through via V38 of the third memory die 1923c may be coupled to the seventh through via V47 of the fourth memory die 1924c.

Each of the first to fourth memory dies 1921c, 1922c, 1923c, 1924c may include two channels. The first and third memory dies 1921c, 1923c may include the same channels, and the second and fourth memory dies 1922c, 1924c may include the same channels. For example, the first and third memory dies 1921c, 1923c may include a first channel CHa and a second channel CHb, and the second and fourth memory dies 1922c, 1924c may include a third channel CHc and a fourth channel CHd. The first to fourth memory dies 1921c, 1922c, 1923c, 1924c may be selectively accessed by a slice ID signal. For example, the first and second memory dies 1921c, 1922c may be accessed by a first slice ID signal SID0, and the third and fourth memory dies 1923c, 1924c may be accessed by a second slice ID signal SID1. The first and second slice ID signals SID0, SID1 may be signals provided from the host die 1910c to the first to fourth memory dies 1921c, 1922c, 1923c, 1924c. When the first slice ID signal SID0 is enabled, the first and second channels CHa, CHb of the first memory die 1921c and the third and fourth channels CHc, CHd of the second memory die 1922c may be accessed. When the second slice ID signal SID1 is enabled, the first and second channels CHa, CHb of the third memory die 1923c and the third and fourth channels CHc, CHd of the fourth memory die 1924c may be accessed. The first to fourth through vias V11-V14, V21-V24, V31-V34, V41-V44 may form a first signal path group, and the fifth to eighth through vias V15-V18, V25-V28, V35-V38, V45-V48 may form a second signal path group. For example, the first through via V11 of the first memory die 1921c, the fourth through via V24 of the second memory die 1922c, the first through via V31 of the third memory die 1923c, and the fourth through via V44 of the fourth memory die 1924c may be used to transmit signals of the first channel CHa. The second through via V12 of the first memory die 1921c, the first through via V21 of the second memory die 1922c, the second through via V32 of the third memory die 1923c, and the first through via V41 of the fourth memory die 1924c may be used to transmit signals of the third channel CHc. The third and fourth through vias V13, V14 of the first memory die 1921c, the second and third through vias V22, V23 of the second memory die 1922c, the third and fourth through vias V33, V34 of the fourth memory die 1924c, and the second and third through vias V42, V43 of the fourth memory die 1924c might not be used to transmit signals of the first and third channels CHa, CHc. The fifth through via V15 of the first memory die 1921c, the eighth through via V28 of the second memory die 1922c, the fifth through via V35 of the third memory die 1923c, and the eighth through via V48 of the fourth memory die 1924c may be used to transmit signals of the second channel CHb. The sixth through via V16 of the first memory die 1921c, the fifth through via V25 of the second memory die 1922c, the sixth through via V36 of the third memory die 1923c, and the fifth through via V45 of the fourth memory die 1924c may be used to transmit signals of the fourth channel CHd. The seventh and eighth through vias V17, V18 of the first memory die 1921c, the sixth and seventh through vias V26, V27 of the second memory die 1922c, the seventh and eighth through vias V37, V38 of the third memory die 1923c, and the sixth and seventh through vias V46, V47 of the fourth memory die 1924c might not be used to transmit signals of the second and fourth channels CHb, CHd.

The host die 1910c may be coupled to internal circuits of the first memory die 1921c through the first and fifth through vias V11, V15 of the first memory die 1921c. The host die 1910c may be coupled to an internal circuit of the first channel CHa of the first memory die 1921c through the first through via V11, and may be coupled to an internal circuit of the second channel CHb of the first memory die 1921c through the fifth through via V15. The host die 1910c may be coupled to internal circuits of the second memory die 1922c through the first and fifth through vias V21, V25 of the second memory die 1922c. The host die 1910c may be coupled to an internal circuit of the third channel CHc of the second memory die 1922c through the first through via V21, and may be coupled to an internal circuit of the fourth channel CHd of the second memory die 1922c through the fifth through via V25. The host die 1910c may be coupled to internal circuits of the third memory die 1923c through the first and fifth through vias V31, V35 of the third memory die 1923c. The host die 1910c may be coupled to an internal circuit of the first channel CHa of the third memory die 1923c through the first through via V31, and may be coupled to an internal circuit of the second channel CHb of the third memory die 1923c through the fifth through via V35. The host die 1910c may be coupled to internal circuits of the fourth memory die 1924c through the first and fifth through vias V41, V45 of the fourth memory die 1924c. The host die 1910c may be coupled to an internal circuit of the third channel CHc of the fourth memory die 1924c through the first through via V41, and may be coupled to an internal circuit of the fourth channel CHd of the fourth memory die 1924c through the fifth through via V45. The host die 1910c may be coupled to the substrate 1930c through the third, fourth, seventh and eighth through vias V13, V14, V17, V18 of the first memory die 1921c, the second, third, sixth and seventh through vias V22, V23, V26, V27 of the second memory die 1922c, the third, fourth, seventh, and eighth through vias V33, V34, V37, V38 of the third memory die 1923c, and the second, third, sixth, and seventh through vias V42, V43, V46, V47 of the fourth memory die 1924c. The second, third, sixth, and seventh through vias V42, V43, V46, V47 of the fourth memory die 1924c may be coupled to a first signal path 1931c, a second signal path 1932c, a third signal path 1933c, and a fourth signal path 1934c in the substrate 1930c, respectively. The host die 1910c may be coupled to an external device of the computing system 1900c through the signal paths 1931c, 1932c, 1933c, 1934c.

The host die 1910c may include a first transceiver T1c, a second transceiver T12c, a third transceiver T13c, a fourth transceiver T14c, a fifth transceiver T15c, a sixth transceiver T16c, a seventh transceiver T17c, and an eighth transceiver T18c. The first to eighth transceivers T11c-T18c may be included as components of the interface circuit 1613 shown in FIG. 20. The first transceiver T11c may be coupled to the first through via V11 of the first memory die 1921c, transmit a first memory signal M11 to the first through via V11, and may receive a signal transmitted through the first through via V11 as the first memory signal M11. The second transceiver T12c may be coupled to a second through via V12 of the first memory die 1921c, transmit a second memory signal M12 to the second through via V12, and receive a signal transmitted through the second through via V12 as the second memory signal M12. The third transceiver T13c may be coupled to the third through via V13 of the first memory die 1921c, transmit a first host signal H11 to the third through via V13, and receive a signal transmitted through the third through via V13 as the first host signal H11. The fourth transceiver T14c may be coupled to the fourth through via V14 of the first memory die 1921c, transmit a second host signal H12 to the fourth through via V14, and receive a signal transmitted through the fourth through via V14 as the second host signal H12. The fifth transceiver T15c may be coupled to the fifth through via V15 of the first memory die 1921c, transmit a third memory signal M13 to the fifth through via V15, and receive a signal transmitted through the fifth through via V15 as the third memory signal M13. The sixth transceiver T16c may be coupled to a sixth through via V16 of the first memory die 1921c, transmit a fourth memory signal M14 to the sixth through via V16, and receive a signal transmitted through the sixth through via V16 as the fourth memory signal M14. The seventh transceiver T17c may be coupled to the seventh through via V17 of the first memory die 1921c, transmit a third host signal H13 to the seventh through via V17, and receive a signal transmitted through the seventh through via V17 as the third host signal H13. The eighth transceiver T18c may be coupled to the eighth through via V18 of the first memory die 1921c, transmit a fourth host signal H14 to the eighth through via V18, and receive a signal transmitted through the eighth through via V18 as the fourth host signal H14. Although the first to fourth memory signals M11-M14 are described as bidirectional signals, the first to fourth memory signals M11-M14 may also be unidirectional signals. Depending on the characteristics of the first to fourth memory signals M11-M14, the first, second, fifth and sixth transceivers T11c, T12c, T15c, T16c may be replaced by receivers or transmitters. While the first to fourth host signals H11-H14 are described as bidirectional, the first to fourth host signals H11-H14 may be unidirectional. The third, fourth, seventh, and eighth transceivers T13c, T14c, T17c, T18c may be replaced by receivers or transmitters depending on the characteristics of the first to fourth host signals H11-H14.

The first memory die 1921c may include a first transceiver T21c and a second transceiver T25c. The first transceiver T21c may be coupled to the first through via V11. The first transceiver T21c may output a signal transmitted from the host die 1910c through the first through via V11 a first channel signal Sa, and may output the first channel signal Sa to the host die 1910c through the first through via V11. The second transceiver T25c may be coupled to the fifth through via V15. The second transceiver T25c may output a signal transmitted from the host die 1910c through the fifth through via V15 as a second channel signal Sb, and may output the second channel signal Sb to the host die 1910c through the fifth through via V15. The second memory die 1922c may include a first transceiver T31c and a second transceiver T35c. The first transceiver T31c may be coupled to the first through via V21. The first transceiver T31c may output a signal transmitted from the host die 1910c through the first through via V21 as a third channel signal Sc, and may output the third channel signal Sc to the host die 1910c through the first through via V21. The second transceiver T35c may be coupled to the fifth through via V25. The second transceiver T35c may output a signal transmitted from the host die 1910c through the fifth through via V25 as a fourth channel signal Sd, and may output the fourth channel signal Sd to the host die 1910c through the fifth through via V25.

The third memory die 1923c may include a first transceiver T41c and a second transceiver T45c. The first transceiver T41c may be coupled to the first through via V31. The first transceiver T41c may output a signal transmitted from the host die 1910c through the first through via V31 as the first channel signal Sa, and may output the first channel signal Sa to the host die 1910c through the first through via V31. The second transceiver T45c may be coupled to the fifth through via V35. The second transceiver T45c may output a signal transmitted from the host die 1910c through the fifth through via V35 as the second channel signal Sb, and may output the second channel signal Sb to the host die 1910c through the fifth through via V35. The fourth memory die 1924c may include a first transceiver T51c and a second transceiver T55c. The first transceiver T51c may be coupled to the first through via V41. The first transceiver T51c may output a signal transmitted from the host die 1910c through the first through via V41 as the third channel signal Sc, and may output the third channel signal Sc to the host die 1910c through the first through via V41. The second transceiver T55c may be coupled to the fifth through via V45. The second transceiver T55c may output a signal transmitted from the host die 1910c through the fifth through via V45 as the fourth channel signal Sd, and may output the fourth channel signal Sd to the host die 1910c through the fifth through via V45. Depending on the characteristics of the first to fourth memory signals M11-M14, the first and second transceivers T21c, T25c, T31c, T35c, T41c, T45c, T51c, T55c of the first to fourth memory dies 1921c, 1922c, 1923c, 1924c may be replaced by transmitters or receivers, respectively.

When the first slice ID signal SID0 is enabled, an internal circuit of the first channel CHa of the first memory die 1921c is coupled to the first transceiver T21c, and may receive the first channel signal Sa from the first transceiver T21c or output the first channel signal Sa to the first transceiver T21c. When the first slice ID signal SID0 is enabled, an internal circuit of the second channel CHb of the first memory die 1921c is coupled to the second transceiver T25c, and may receive the second channel signal Sb from the second transceiver T25c or output the second channel signal Sb to the second transceiver T25c. When the first slice ID signal SID0 is enabled, an internal circuit of the third channel CHc of the second memory die 1922c is coupled to the first transceiver T31c, and may receive the third channel signal Sc from the first transceiver T31c or output the third channel signal Sc to the first transceiver T31c. When the first slice ID signal SID0 is enabled, an internal circuit of the fourth channel CHd of the second memory die 1922c is coupled to the second transceiver T35c, and may receive the fourth channel signal Sd from the second transceiver T35c or output the fourth channel signal Sd to the second transceiver T35c. When the second slice ID signal SID1 is enabled, an internal circuit of the first channel CHa of the third memory die 1923c is coupled to the first transceiver T41c, and may receive the first channel signal Sa from the first transceiver T41c or output the first channel signal Sa to the first transceiver T41c. When the second slice ID signal SID1 is enabled, an internal circuit of the second channel CHb of the third memory die 1923c is coupled to the second transceiver T45c, and may receive the second channel signal Sb from the second transceiver T45c or output the second channel signal Sb to the second transceiver T45c. When the second slice ID signal SID1 is enabled, an internal circuit of the third channel CHc of the fourth memory die 1924c is coupled to the first transceiver T51c, and may receive the third channel signal Sc from the first transceiver T51c or output the third channel signal Sc to the first transceiver T51c. When the second slice ID signal SID1 is enabled, an internal circuit of the fourth channel CHd of the fourth memory die 1924c is coupled to the second transceiver T55c, and may receive the fourth channel signal Sd from the second transceiver T55c or output the fourth channel signal Sd to the second transceiver T55c. The third, fourth, seventh and eighth through vias V13, V14, V17, V18 of the first memory die 1921c may be electrically isolated from the internal circuits of the first memory die 1921c. The second, third, sixth, and seventh through vias V22, V23, V26, V27 of the second memory die 1922c may be electrically isolated from the internal circuits of the second memory die 1922c. The third, fourth, seventh, and eighth through vias V33, V34, V37, V38 of the third memory die 1923c may be electrically isolated from the internal circuits of the third memory die 1923c. The second, third, sixth, and seventh through vias V42, V43, V46, V47 of the fourth memory die 1924c may be electrically isolated from the internal circuits of the fourth memory die 1924c, respectively.

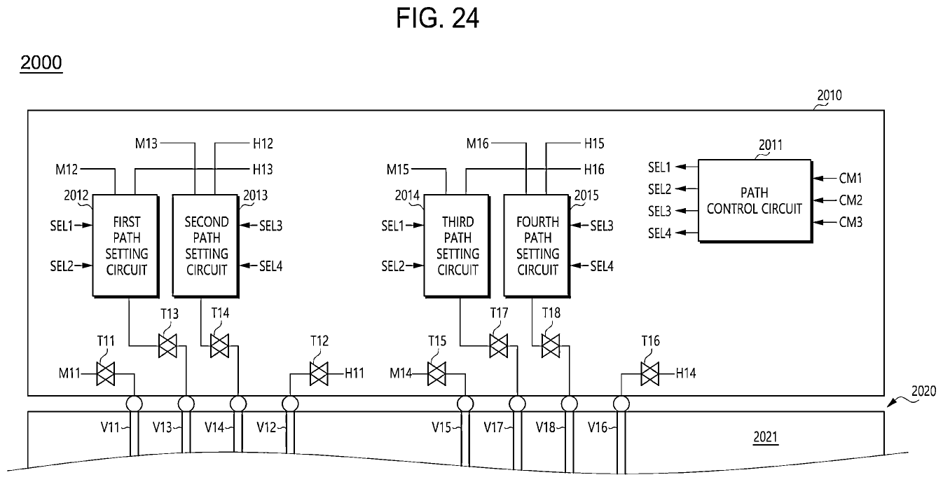

FIG. 24 is a diagram illustrating a configuration of a computing system 2000 according to an embodiment of the present disclosure. Referring to FIG. 24, the computing system 2000 may include a host die 2010 and a memory apparatus 2020. The host die 2010 may be disposed on the memory apparatus 2020. The host die 2010 may vary the paths through which memory signals and host signals are transmitted depending on the number of memory dies and/or the number of channels included in the memory apparatus 2020. In FIG. 24, the memory apparatus 2020 may include one or more memory dies. The memory apparatus 2020 may include at least a first memory die 2021, and the first memory die 2021 may include at least first to fourth through vias V11-V14 disposed at first to fourth positions. The first to fourth through vias V11-V14 may form a first signal path group. When the memory apparatus 2020 includes a plurality of memory dies, through vias of the plurality of memory dies may be coupled in a multi-drop method, or in a P2P method. The host die 2010 may set the first through via V11 as a path for transmitting a first memory signal M11. The first memory signal M11 may be transmitted from the host die 2010 to an internal circuit of the first memory die 2021 through the first through via V11, or may be transmitted from the internal circuit of the first memory die 2021 to the host die 2010. The host die 2010 may set the second through via V12 as a path for transmitting a first host signal H11. The first host signal H11 may be transmitted from the host die 2010 to an external device of the computing system 2000 through the second through via V12, or may be transmitted to the host die 2010 from the external device.

The host die 2010 may receive a plurality of channel mode signals. Based on the plurality of channel mode signals, the host die 2010 may set a path for a second memory signal M12 or a third host signal H13 transmitted using the third through via V13, and may set a path for a third memory signal M13 or a second host signal H12 transmitted using the fourth through via V14. The plurality of channel mode signals may include a first channel mode signal CM1, a second channel mode signal CM2, and a third channel mode signal CM3, although other embodiments are not limited to three signals. The first to third channel mode signals CM1, CM2, CM3 may include information regarding the number of memory dies and/or the number of channels that the memory apparatus 2020 includes. For example, assume that one memory die includes two channels. For example, the first channel mode signal CM1 may be applied when the memory apparatus 2020 includes at least one memory die and the number of channels is two. The second channel mode signal CM2 may be applied when the memory apparatus 2020 includes a number of memory dies corresponding to a multiple of two, and the number of channels is four. The third channel mode signal CM3 may be applied when the memory apparatus 2020 includes a number of memory dies corresponding to a multiple of three, and the number of channels is six. The first to third channel mode signals CM1, CM2, CM3 may be signals provided to the host die 2010 from the external device. In an embodiment, the first to third channel mode signals CM1, CM2, CM3 may be generated by counting the number of memory dies constituting the memory apparatus 2020 after the host die 2010 and the memory apparatus 2020 are disposed in the computing system 2000.

When the first channel mode signal CM1 is applied, the host die 2010 may set a path in which the third host signal H13 is transmitted using the third through via V13, and may set a path in which the second host signal H12 is transmitted using the fourth through via V14. The second host signal H12 may be transmitted from the host die 2010 to the external device, or may be transmitted from the external device to the host die 2010 through the fourth through via V14. The third host signal H13 may be transmitted from the host die 2010 to the external device, or may be transmitted from the external device to the host die 2010 through the third through via V13.

When the second channel mode signal CM2 is applied, the host die 2010 may set a path in which the second memory signal M12 is transmitted using the third through via V13, and may set a path in which the second host signal H12 is transmitted using the fourth through via V14. The second memory signal M12 may be transmitted from the host die 2010 to an internal circuit of another memory die disposed with the first memory die 2021 in the memory apparatus 2020, or may be transmitted from the internal circuit of the another memory die to the host die 2010 through the third through via V13. The second host signal H12 may be transmitted from the host die 2010 to the external device, or may be transmitted to the host die 2010 from the external device through the fourth through via V14.

When the third channel mode signal CM3 is applied, the host die 2010 may set a path in which the second memory signal M12 is transmitted using the third through via V13, and may set a path in which the third memory signal M13 is transmitted using the fourth through via V14. The second memory signal M12 may be transmitted from the host die 2010 to the another memory die or from the another memory die to the host die 2010 through the third through via V13. The third memory signal M13 may be transmitted from the host die 2010 to an internal circuit of yet another memory die disposed with the first memory die 2021 and the another memory die, or may be transmitted from the internal circuit of the yet another memory die to the host die 2010 through the fourth through via V14.

The host die 2010 may include a path control circuit 2011, a first path setting circuit 2012, a second path setting circuit 2013, a first transceiver T11, a second transceiver T12, a third transceiver T13, and a fourth transceiver T14. The path control circuit 2011, the first path setting circuit 2012, the second path setting circuit 2013, and the first to fourth transceivers T11-T14 may be included as components of an interface circuit 1613 shown in FIG. 20. The path control circuit 2011 may generate a first path selection signal SEL1, a second path selection signal SEL2, a third path selection signal SEL3, and a fourth path selection signal SEL4 based on the first to third channel mode signals CM1, CM2, CM3. When the first channel mode signal CM1 is applied, the path control circuit 2011 may utilize the second and fourth path selection signals SEL2, SEL4 but not the first and third path selection signals SEL1, SEL3. When the second channel mode signal CM2 is applied, the path control circuit 2011 may utilize the first and fourth path selection signals SEL1, SEL4 but not the second and third path selection signals SEL2, SEL3. When the third channel mode signal CM3 is applied, the path control circuit 2011 may use the first and third path selection signals SEL1, SEL3 but not the second and fourth path selection signals SEL2, SEL4.

The first path setting circuit 2012 may receive the first path selection signal SEL1, the second path selection signal SEL2, the second memory signal M12, and the third host signal H13. Based on the first and second path selection signals SEL1, SEL2, the first path setting circuit 2012 may set a path in which one of the second memory signal M12 and the third host signal H13 is transmitted using the third through via V13. When the first path selection signal SEL1 is applied, the first path setting circuit 2012 may set the third through via V13 as the path through which the third host signal H13 is transmitted. The first path setting circuit 2012 may transmit the third host signal H13 to the third through via V13 or receive a signal transmitted from the third through via V13 as the third host signal H13. When the second path selection signal SEL2 is applied, the first path setting circuit 2012 may set the third through via V13 as the path through which the second memory signal M12 is transmitted. The first path setting circuit 2012 may transmit the second memory signal M12 to the third through via V13 or receive a signal transmitted from the third through via V13 as the second memory signal M12.

The second path setting circuit 2013 may receive the third path selection signal SEL3, the fourth path selection signal SEL4, the third memory signal M13, and the second host signal H12. Based on the third and fourth path selection signals SEL3, SEL4, the second path setting circuit 2013 may set a path in which one of the third memory signal M13 and the second host signal H12 is transmitted using the fourth through via V14. When the third path selection signal SEL3 is applied, the second path setting circuit 2013 may set the fourth through via V14 as the path through which the third memory signal M13 is transmitted. The second path setting circuit 2013 may transmit the third memory signal M13 to the fourth through via V14 or receive a signal transmitted from the fourth through via V14 as the third memory signal M13. When the fourth path selection signal SEL4 is applied, the second path setting circuit 2013 may set the fourth through via V14 as the path through which the second host signal H12 is transmitted. The second path setting circuit 2013 may transmit the second host signal H12 to the fourth through via V14 or receive a signal transmitted from the fourth through via V14 as the second host signal H12.

The first transceiver T11 may transmit the first memory signal M11 to the first through via V11 or receive a signal transmitted through the first through via V11 as the first memory signal M11. The second transceiver T12 may transmit the first host signal H11 to the second through via V12 or receive a signal transmitted through the second through via V12 as the first host signal H11. The third transceiver T13 may be coupled between the first path setting circuit 2012 and the third through via V13. The third transceiver T13 may output a signal output from the first path setting circuit 2012 to the third through via V13, or may output a signal transmitted through the third through via V13 to the first path setting circuit 2012. The fourth transceiver T14 may be coupled between the second path setting circuit 2013 and the fourth through via V14. The fourth transceiver T14 may output a signal output from the second path setting circuit 2013 to the fourth through via V14, or may output a signal transmitted through the fourth through via V14 to the second path setting circuit 2013. The first to fourth transceivers T11-T14 may be replaced by transmitters or receivers depending on the characteristics of the first to third memory signals M11-M13 and the first to third host signals H11-H13.

The first memory die 2021 may further include fifth to eighth through vias V15-V18. The fifth to eighth through vias V15-V18 may form a second signal path group. The host die 2010 may set the fifth through via V15 as a path through which a fourth memory signal M14 is transmitted. The fourth memory signal M14 may be transmitted from the host die 2010 to an internal circuit of the first memory die 2021, or from the first memory die 2021 to the host die 2010 through the fifth through via V15. The host die 2010 may set the sixth through via V16 as a path through which a fourth host signal H14 is transmitted. The fourth host signal H14 may be transmitted from the host die 2010 to an external device of the computing system 2000, or may be transmitted to the host die 2010 from the external device through the sixth through via V16.

When the first channel mode signal CM1 is applied, the host die 2010 may set the seventh through via V17 as a path through which the sixth host signal H16 is transmitted, and may set the eighth through via V18 as a path through which the fifth host signal H15 is transmitted. The fifth host signal H15 may be transmitted from the host die 2010 to the external device, or may be transmitted from the external device to the host die 2010 through the eighth through via V18. The sixth host signal H16 may be transmitted from the host die 2010 to the external device, or may be transmitted from the external device to the host die 2010 through the seventh through via V17.

When the second channel mode signal CM2 is applied, the host die 2010 may set the seventh through via V17 as a path through which the fifth memory signal M15 is transmitted, and may set the eighth through via V18 as a path through which the fifth host signal H15 is transmitted. The fifth memory signal M15 may be transmitted from the host die 2010 to another memory die disposed with the first memory die 2021, or may be transmitted from the another memory die to the host die 2010 through the seventh through via V17. The fifth host signal H15 may be transmitted from the host die 2010 to the external device, or may be transmitted from the external device to the host die 2010 through the eighth through via V18.

When the third channel mode signal CM3 is asserted, the host die 2010 may set the seventh through via V17 as a path through which the fifth memory signal M15 is transmitted, and may set the eighth through via V18 as a path through which the sixth memory signal M16 is transmitted. The fifth memory signal M15 may be transmitted from the host die 2010 to the another memory die, or may be transmitted from the another memory die to the host die 2010 through the seventh through via V17. The sixth memory signal M16 may be transmitted from the host die 2010 to yet another memory die disposed with the first memory die 2021 and the another memory die, or may be transmitted from the yet another memory die to the host die 2010 through the eighth through via V18.

The host die 2010 may include a third path setting circuit 2014, a fourth path setting circuit 2015, a fifth transceiver T15, a sixth transceiver T16, a seventh transceiver T17, and an eighth transceiver T18. The third path setting circuit 2014, the fourth path setting circuit 2015, and the fifth to eighth transceivers T15-T18 may be included as components of the interface circuit 1613 shown in FIG. 20. The third path setting circuit 2014 may receive the first path selection signal SEL1, the second path selection signal SEL2, the fifth memory signal M15, and the sixth host signal H16. Based on the first and second path selection signals SEL1, SEL2, the third path setting circuit 2014 may set a path through which one of the fifth memory signal M15 and the sixth host signal H16 is transmitted to the seventh through via V17. When the first path selection signal SEL1 is applied, the third path setting circuit 2014 may set the seventh through via V17 as the path through which the fifth memory signal M15 is transmitted. The third path setting circuit 2014 may transmit the fifth memory signal M15 to the seventh through via V17 or receive a signal transmitted from the seventh through via V17 as the fifth memory signal M15. When the second path selection signal SEL2 is applied, the third path setting circuit 2014 may set the seventh through via V17 as the path through which the sixth host signal H16 is transmitted. The third path setting circuit 2014 may transmit the sixth host signal H16 to the seventh through via V17 or receive a signal transmitted from the seventh through via V17 as the sixth host signal H16.

The fourth path setting circuit 2015 may receive the third path selection signal SEL3, the fourth path selection signal SEL4, the sixth memory signal M16, and the fifth host signal H15. Based on the third and fourth path selection signals SEL3, SEL4, the fourth path setting circuit 2015 may set the eighth through via V18 as a path through which one of the sixth memory signal M16 and the fifth host signal H15 is transmitted. When the third path selection signal SEL3 is applied, the fourth path setting circuit 2015 may set the eighth through via V18 as the path through which the sixth memory signal M16 is transmitted. The fourth path setting circuit 2015 may transmit the sixth memory signal M16 to the eighth through via V18 or receive a signal transmitted from the eighth through via V18 as the sixth memory signal M16. When the fourth path selection signal SEL4 is applied, the fourth path setting circuit 2015 may set the eighth through via V18 as the path through which the fifth host signal H15 is transmitted. The fourth path setting circuit 2015 may transmit the fifth host signal H15 to the eighth through via V18 or receive a signal transmitted from the eighth through via V18 as the fifth host signal H15.

The fifth transceiver T15 may transmit the fourth memory signal M14 to the fifth through via V15 or receive a signal transmitted through the fifth through via V15 as the fourth memory signal M14. The sixth transceiver T16 may transmit the fourth host signal H14 to the sixth through via V16 or receive a signal transmitted through the sixth through via V16 as the fourth host signal H14. The seventh transceiver T17 may be coupled between the third path setting circuit 2014 and the seventh through via V17. The seventh transceiver T17 may output a signal output from the third path setting circuit 2014 to the seventh through via V17, or may output a signal transmitted through the seventh through via V17 to the third path setting circuit 2014. The eighth transceiver T18 may be coupled between the fourth path setting circuit 2015 and the eighth through via V18. The eighth transceiver T18 may output a signal output from the fourth path setting circuit 2015 to the eighth through via V18, or may output a signal transmitted through the eighth through via V18 to the fourth path setting circuit 2015. The fifth to eighth transceivers T15-T18 may be replaced by transmitters or receivers depending on the characteristics of the fourth to sixth memory signals M14-M16 and the fourth to sixth host signals H14-H16.

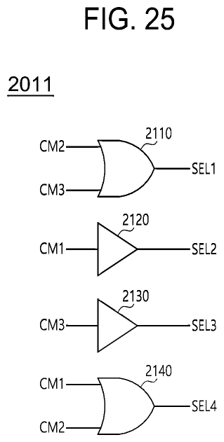

FIG. 25 is a diagram illustrating a schematic configuration of the path control circuit 2011 shown in FIG. 24. Referring to FIG. 25, the path control circuit 2011 may include a first OR gate 2110, a first buffer 2120, a second buffer 2130, and a second OR gate 2140. The first OR gate 2110 may receive the second and third channel mode signals CM2, CM3, and may generate the first path selection signal SEL1 by applying an OR operation to the second and third channel mode signals CM2, CM3. The first buffer 2120 may receive the first channel mode signal CM1, and may buffer the first channel mode signal CM1 to generate the second path selection signal SEL2. The second buffer 2130 may receive the third channel mode signal CM3, and may buffer the third channel mode signal CM3 to generate the third path selection signal SEL3. The second OR gate 2140 may receive the first and second channel mode signals CM1, CM2, and may generate the fourth path selection signal SEL4 by applying an OR operation to the first and second channel mode signals CM1, CM2.

A person skilled in the art to which the present disclosure pertains can understand that the present disclosure may be carried out in other specific forms without changing its technical spirit or essential features. Therefore, it should be understood that the embodiments described above are illustrative in all aspects, not limitative. The scope of the present disclosure is defined by the claims to be described below rather than the detailed description, and it should be construed that the meaning and scope of the claims and all changes or modified forms derived from the equivalent concept thereof are included in the scope of the present disclosure.

What is claimed is:

1. A computing system, comprising:
a substrate;
a memory apparatus disposed on the substrate and including at least one memory die, the at least one memory die including a plurality of through vias; and
a host die disposed on the memory apparatus and coupled to the substrate through at least one of the plurality of through vias.

2. The computing system of claim 1, wherein the at least one memory die includes a first through via formed at a first position and a second through via formed at a second position, and
wherein the first through via couples the host die and an internal circuit of the at least one memory die, and the second through via couples the host die and the substrate.

3. The computing system of claim 2, wherein the host die comprises:
a host;
a memory controller coupled to the host; and
an interface circuit coupled between the memory controller and the at least one memory die, and coupled to the internal circuit of the at least one memory die through the first through via.

4. The computing system of claim 3, wherein the host is coupled to the substrate through the second through via, and the second through via is electrically isolated from the internal circuit of the at least one memory die.

5. The computing system of claim 3, wherein the host die further comprises a test circuit, the at least one memory die further comprising a third through via formed at a third position, and
wherein the test circuit is coupled to the substrate through the third through via.

6. The computing system of claim 3, wherein a frequency of a signal transmitted through a signal transmission line coupling the memory controller and the interface circuit is equal to or higher than a frequency of a signal transmitted through the first through via.

7. A computing system, comprising:
a substrate;
a host die; and
first and second memory dies disposed sequentially between the substrate and the host die,
wherein each of the first and second memory dies includes a first through via formed at a first position, a second through via formed at a second position, and a third through via formed at a third position, and
wherein the host die is coupled to the substrate through at least one of the first to third through vias of the first memory die and at least one of the first to third through vias of the second memory die.

8. The computing system of claim 7, wherein the first through via of the first memory die is coupled to the first through via of the second memory die, the second through via of the first memory die is coupled to the second through via of the second memory die, and the third through via of the first memory die is coupled to the third through via of the second memory die, and
wherein the host die is coupled to an internal circuit of the first memory die through the first through vias, is coupled to an internal circuit of the second memory die through the second through vias, and is coupled to the substrate through the third through vias.

9. The computing system of claim 8, wherein the host die comprises:
a host;
a memory controller coupled to the host; and
an interface circuit coupling the memory controller with the first and second memory dies,
wherein the interface circuit is coupled to the internal circuit of the first memory die through the first through vias, and with the internal circuit of the second memory die through the second through vias.

10. The computing system of claim 9, wherein the host is coupled to an external device of the computing system through the third through vias and the substrate, and the third through vias are electrically isolated from the internal circuits of the first and second memory dies.

11. The computing system of claim 9, wherein the host die further comprises a test circuit, and each of the first and second memory dies further comprises a fourth through via formed at a fourth position, and
wherein the test circuit is coupled to the substrate through the fourth through vias.

12. The computing system of claim 9, wherein a frequency of a signal transmitted through a signal transmission line coupling the memory controller and the interface circuit is equal to or higher than a frequency of signal transmitted through the first through vias and a frequency of signal transmitted through the second through vias.

13. The computing system of claim 7, wherein the first through via of the first memory die is coupled to the third through via of the second memory die, the second through via of the first memory die is coupled to the first through via of the second memory die, and the third through via of the first memory die is coupled to the second through via of the second memory die, and
wherein the host die is coupled to an internal circuit of the first memory die through the first through via of the first memory die, is coupled to an internal circuit of the second memory die through the first through via of the second memory die, and is coupled to the substrate through the third through via of the first memory die and the second through via of the second memory die.

14. The computing system of claim 13, wherein the host die comprises:
a host;
a memory controller coupled to the host; and
an interface circuit coupling the memory controller with the first and second memory dies,
wherein the interface circuit is coupled to the internal circuit of the first memory die through the first through via of the first memory die, and with the internal circuit of the second memory die through the first through via of the second memory die.

15. The computing system of claim 14, wherein the host is coupled to an external device of the computing system through the third through via of the first memory die and the second through via of the second memory die, and the third through via of the first memory die and the second through via of the second memory die are electrically isolated from the internal circuits of the first and second memory dies.

16. The computing system of claim 14, wherein a frequency of a signal transmitted through a signal transmission line coupling the memory controller and the interface circuit is equal to or higher than a frequency of a signal transmitted through the first through via of the first memory die and the third through via of the second memory die.

17. The computing system of claim 14, wherein a frequency of a signal transmitted through a signal transmission line coupling the memory controller and the interface circuit is equal to or higher than a frequency of a signal transmitted through the second through via of the first memory die and the first through via of the second memory die.

18. A computing system, comprising:
a substrate;
a host die;
a first memory die; and
a second memory die,
wherein the second memory die is disposed on the substrate, the first memory die is disposed on the second memory die, and the host die is disposed on the first memory die;
the first memory die is accessed by a first slice ID signal, forms a first channel, and includes first to third through vias formed at first to third positions, respectively;
the second memory die is accessed by the first slice ID signal, forms a second channel, and includes first to third through vias formed at the first to third positions, respectively; and
the host die is coupled to the substrate through one of the first to third through vias of the first memory die and one of the first to third through vias of the second memory die.

19. The computing system of claim 18, wherein the first through via of the first memory die is coupled to the first through via of the second memory die, the second through via of the first memory die is coupled to the second through via of the second memory die, and the third through via of the first memory die is coupled to the third through via of the second memory die, and
wherein the host die is coupled to an internal circuit of the first memory die through the first through vias, is coupled to an internal circuit of the second memory die through the second through vias, and is coupled to the substrate through the third through vias.

20. The computing system of claim 18, wherein the host die is coupled to an external device of the computing system through the third through vias and the substrate, and the third through vias are electrically isolated from internal circuits of the first and second memory dies.

21. The computing system of claim 18, further comprising a third memory die and a fourth memory die,
wherein the fourth memory die is disposed on the substrate, and the third memory die is disposed between the second and fourth memory dies;
the third memory die is accessed by a second slice ID signal, forms the first channel, and includes first to third through vias formed at the first to third positions, respectively; and
the fourth memory die is accessed by the second slice ID signal, forms the second channel, and includes first to third through vias formed at the first to third positions, respectively.

22. The computing system of claim 21, wherein the first through via of the third memory die is coupled to the first through vias of the second and fourth memory dies, the second through via of the third memory die is coupled to the second through vias of the second and fourth memory dies, and the third through via of the third memory die is coupled to the third through vias of the second and fourth memory dies, and
wherein the host die is coupled to an internal circuit of the third memory die through the first through vias, and is coupled to an internal circuit of the fourth memory die through the second through vias.

23. The computing system of claim 22, wherein the third through vias of the third and fourth memory dies are electrically isolated from the internal circuits of the third and fourth memory dies.

24. The computing system of claim 18, wherein the first through via of the first memory die is coupled to the third through via of the second memory die, the second through via of the first memory die is coupled to the first through via of the second memory die, and the third through via of the first memory die is coupled to the second through via of the second memory die, and
wherein the host die is coupled to an internal circuit of the first memory die through the first through via of the first memory die, is coupled to an internal circuit of the second memory die through the first through via of the second memory die, and is coupled to the substrate through the third through via of the first memory die and the second through via of the second memory die.

25. The computing system of claim 24, wherein the third through via of the first memory die and the second through via of the second memory die are electrically isolated from the internal circuits of the first and second memory dies.

26. The computing system of claim 24, further comprising:
a third memory die;
a redistribution layer; and
a fourth memory die,
wherein
the fourth memory die is disposed on the substrate, the third memory die is disposed on the fourth memory die, and the redistribution layer is disposed between the second and third memory dies;
the third memory die is accessed by a second slice ID signal, forms the first channel, and includes first and third through vias formed at the first and third positions, respectively; and
the fourth memory die is accessed by the second slice ID signal, forms the second channel, and includes first to third through vias formed at the first to third positions, respectively.

27. The computing system of claim 26, wherein the redistribution layer couples the third through via of the second memory die with the first through via of the third memory die, couples the first through via of the second memory die with the second through via of the third memory die, and couples the second through via of the second memory die with the third through via of the third memory die.

28. The computing system of claim 27, wherein the first through via of the third memory die is coupled to the third through via of the fourth memory die, the second through via of the third memory die is coupled to the first through via of the fourth memory die, and the third through via of the third memory die is coupled to the second through via of the fourth memory die, and
wherein the host die is coupled to an internal circuit of the third memory die through the first through via of the third memory die, and is coupled to an internal circuit of the fourth memory die through the first through via of the fourth memory die.

29. The computing system of claim 28, wherein the third through via of the third memory die and the second through via of the fourth memory die are electrically isolated from internal circuits of the third and fourth memory dies.
